(19) United States
(12) Patent Application Publication
(10) Pub. No.: US 2024/0268231 A1
(43) Pub. Date: Aug. 8, 2024

(54) LIGHT EMITTING ELEMENT AND POLYCYCLIC COMPOUND FOR THE SAME

(71) Applicant: Samsung Display Co., Ltd., Yongin-si (KR)

(72) Inventors: Yuma AOKI, Yokohama (JP); Tetsuji HAYANO, Yokohama (JP); Yuji SUZAKI, Yokohama (JP)

(21) Appl. No.: 18/512,455

(22) Filed: Nov. 17, 2023

(30) Foreign Application Priority Data
Jan. 16, 2023 (KR) 10-2023-005946

(51) Int. Cl. H10K 85/60; C09K 11/06; H10K 50/11; H10K 85/40

(52) U.S. Cl. CPC H10K 85/658; C09K 11/06; H10K 50/11; H10K 85/40; H10K 85/631; H10K 85/654; H10K 85/6572; H10K 85/6574; H10K 85/6576; C07B 2200/05; H10K 2101/20

(57) ABSTRACT

A light emitting element includes a first electrode, a second electrode facing the first electrode, and at least one functional layer between the first electrode and the second electrode, wherein the at least one functional layer includes a first compound represented by Formula 1, and thus the light emitting element may exhibit long lifespan.

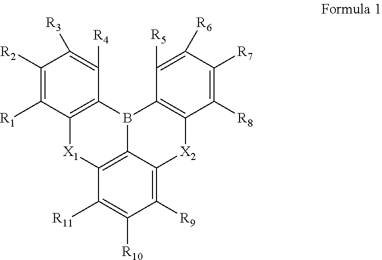

### CROSS-REFERENCE TO RELATED APPLICATION

This application claims priority to and the benefit of Korean Patent Application No. 10-2023-0005946, filed on Jan. 16, 2023, in the Korean Intellectual Property Office, the entire content of which is hereby incorporated by reference.

### BACKGROUND

### 1. Field

One or more embodiments of the present disclosure relate to a polycyclic compound and a light emitting element including the same, and for example, to a light emitting element including the polycyclic compound in an emission layer of the light emitting element.

### 2. Description of the Related Art

As image display devices, organic electroluminescence display devices and/or the like have been actively developed lately. The organic electroluminescence display devices and/or the like are display devices that include self-luminescent light emitting elements in which holes and electrons separately injected from a first electrode and a second electrode recombine in an emission layer of the light emitting elements, and thus a luminescent material in the emission layer emits light to accomplish display (e.g., of an image).

For application of light emitting elements to display devices, there is a demand or desire for light emitting elements having a low driving voltage, high luminous efficiency, and long life, and thus the development of materials, for light emitting elements, capable of stably attaining such characteristics is being continuously required and pursued.

In recent years, in order to obtain a highly luminous efficient organic electroluminescence element, technologies pertaining to phosphorescence emission utilizing triplet state energy or delayed fluorescence utilizing triplet-triplet annihilation (TTA) in which singlet excitons are generated through the collision of triplet excitons are being developed and exploited, and thermally activated delayed fluorescence (TADF) materials utilizing a delayed fluorescence phenomenon are under research and development.

### SUMMARY

One or more aspects of embodiments of the present disclosure are directed toward a light emitting element having improved element service life.

One or more aspects of embodiments of the present disclosure are directed toward a polycyclic compound capable of improving element service life.

Additional aspects will be set forth in part in the description which follows and, in part, will be apparent from the description, or may be learned by practice of the presented embodiments.

One or more embodiments of the present disclosure provide a light emitting element including a first electrode, a second electrode facing the first electrode, and at least one functional layer between the first electrode and the second electrode, wherein the at least one functional layer includes a first compound represented by

### Formula 1.

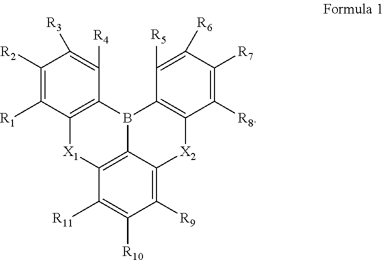

In Formula 1, X₁ and X₂ may each independently be O, S, Se, CRₐR_{b}, SiR_{c}R_{d}, or NR₁₂, and X₁ and X₂ are not both (e.g., simultaneously) O, Ra to Ra may each independently be hydrogen, a substituted or unsubstituted alkyl group having 1 to 30 carbon atoms, or a substituted or unsubstituted aryl group having 6 to 30 ring-forming carbon atoms, and at least one selected from among R₁ to R₁₂ is represented by Formula 2, and the others (the remainder) may each independently be hydrogen, deuterium, a halogen, a cyano group, a substituted or unsubstituted oxy group, a substituted or unsubstituted thio group, a substituted or unsubstituted silyl group, a substituted or unsubstituted amine group, a substituted or unsubstituted alkyl group having 1 to 30 carbon atoms, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 2 to 30 ring-forming carbon atoms.

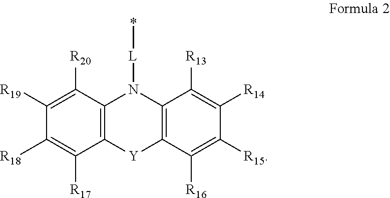

In Formula 2, L may be a direct linkage or a substituted or unsubstituted arylene group having 6 to 30 ring-forming carbon atoms, Y may be a direct linkage, O, S, Se, CRₑR_{f}, SiR_{g}Rₙ, or NRᵢ, Rₑ to Rᵢ may each independently be a substituted or unsubstituted alkyl group having 1 to 30 carbon atoms, or a substituted or unsubstituted aryl group having 6 to 30 ring-forming carbon atoms, at least one selected from among R₁₄ to R₁₉ is a substituted or unsubstituted cycloalkyl group having 5 to 30 ring-forming carbon atoms, and the others (the remainder) may each independently be hydrogen or deuterium, when R₁₄ to R₁₉ are a crosslinked cycloalkyl group (e.g., a bridged cycloalkyl group), each of a plurality of rings included in the crosslinked cycloalkyl group has 5 to 10 ring-forming carbon atoms, R₁₃ and R₂₀ may each independently be hydrogen, deuterium, or a substituted or unsubstituted cycloalkyl group having 3 to 30 ring-forming carbon atoms, and Formula 1 may include a structure in which one or more hydrogens may be substituted with deuterium.

In one or more embodiments, Formula 2 may be represented by Formula 2-1a or Formula 2-1b.

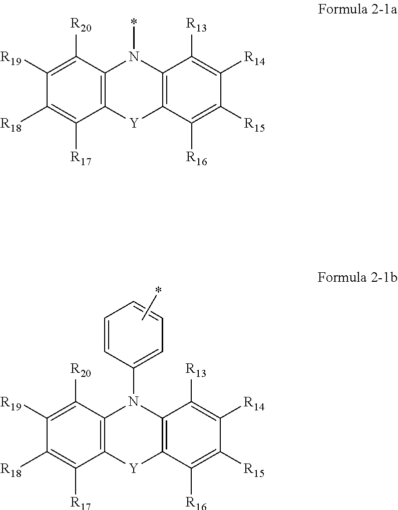

In Formulas 2-1a and 2-1b, Y, and R₁₃ to R₂₀ may each independently be the same as defined in Formula 2.

In one or more embodiments, Formula 2 may be represented by any one selected from among Formulas 2-2a to 2-2g.

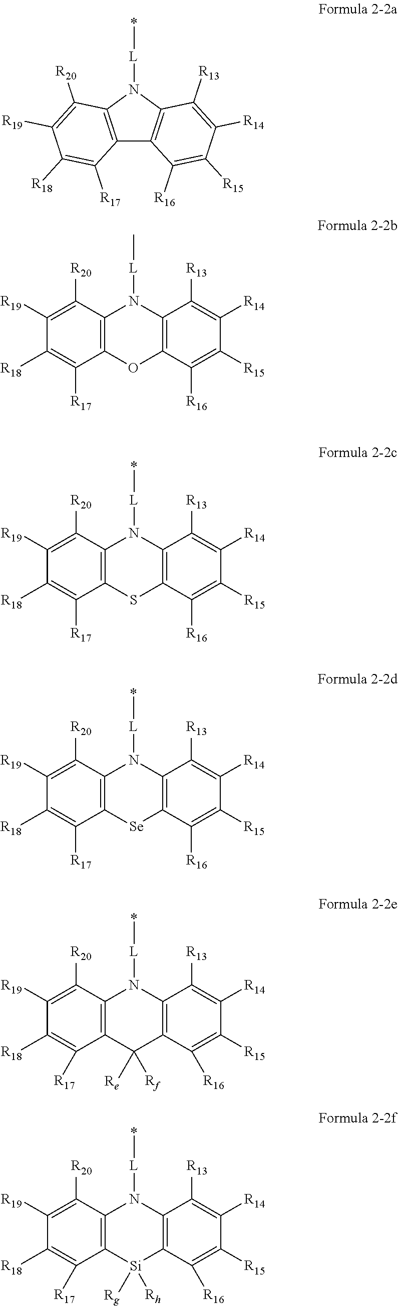

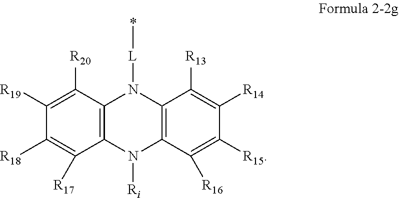

In Formulas 2-2a to 2-2g, Rₑ to Rᵢ may each independently be an unsubstituted methyl group or an unsubstituted phenyl group, and L, and R₁₃ to R₂₀ may each independently be the same as defined in Formula 2.

In one or more embodiments, Formula 2 may be represented by any one selected from among 2-3a to 2-3e.

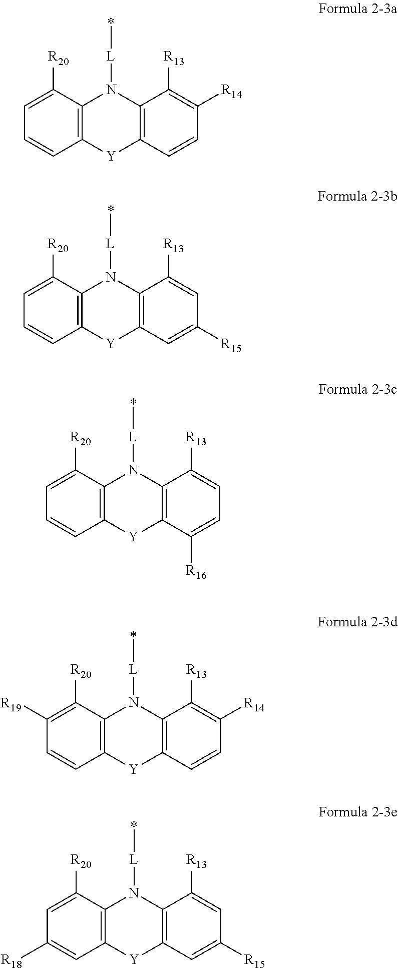

In Formulas 2-3a to 2-3e above, R₁₄, R₁₅, R₁₆, R₁₈, and R₁₉ may each independently be a substituted or unsubstituted cycloalkyl group having 5 to 30 ring-forming carbon atoms, L, Y, R₁₃, and R₂₀ may each independently be the same as defined in Formula 2, and Formulas 2-3a to 2-3e may (e.g., may each) include a structure in which one or more hydrogens may be substituted with deuterium.

In one or more embodiments, at least one selected from among R₁₄ to R₁₉ may be represented by any one selected from among Formulas A1 to A5, and the others (the remainder) may each independently be hydrogen or deuterium.

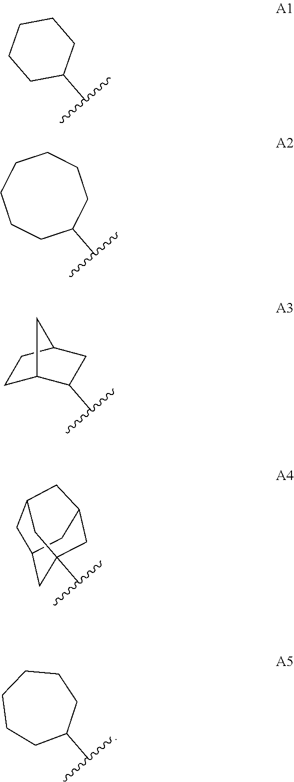 [SMILES: *C1CCCCC1 ; *C1CCCCCCC1 ; *C1CC2CCC1C2 ; *C12CC3CC(CC(C3)C1)C2 ; *C1CCCCCC1]

In one or more embodiments, Ra to Ra may each independently be hydrogen, an unsubstituted methyl group, or an unsubstituted phenyl group.

In one or more embodiments, the at least one functional layer may include at least one selected from compounds of Compound Group 1.

In one or more embodiments, the at least one functional layer may further include at least one of a second compound represented by Formula HT or a third compound represented by Formula ET.

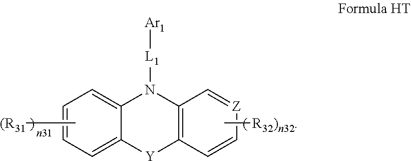

In Formula HT, L₁ may be a direct linkage, a substituted or unsubstituted arylene group having 6 to 30 ring-forming carbon atoms, or a substituted or unsubstituted heteroarylene group having 2 to 30 ring-forming carbon atoms, Ar₁ may be a substituted or unsubstituted aryl group having 6 to 30 ring-forming carbon atoms, or a substituted or unsubstituted heteroaryl group having 2 to 30 ring-forming carbon atoms, Y may be a direct linkage, CR_{y1}R_{y2}, or SiR_{y3}R_{y4}, Z is CR_{z} or N, R_{y1} to R_{y4}, R₃₁, R₃₂, and Rz may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring, and n31 is an integer of 0 to 4, and n32 is an integer of 0 to 3.

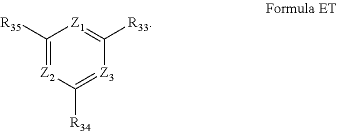

In Formula ET, Z₁ to Z₃ may each independently be N or CR₃₆, and at least one (or any one) selected from Z₁ to Z₃ is N, and R₃₃ to R₃₆ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring.

In one or more embodiments, the at least one functional layer may include the first compound, the second compound, and the third compound.

In one or more embodiments, the at least one functional layer may include an emission layer, a hole transport region between the first electrode and the emission layer, and an electron transport region between the emission layer and the second electrode, wherein the emission layer may include the first compound, and at least one of the second compound or the third compound.

In one or more embodiments, the emission layer may be to emit delayed fluorescence.

In one or more embodiments, the emission layer may be to emit blue light.

In one or more embodiments, the at least one functional layer may further include a fourth compound represented by Formula PS.

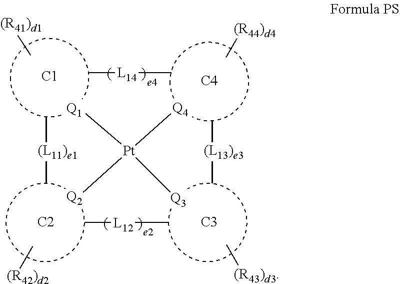

In Formula PS, Q₁ to Q₄ may each independently be C or N, C1 to C4 may each independently be a substituted or unsubstituted hydrocarbon ring having 5 to 30 ring-forming carbon atoms, or a substituted or unsubstituted heterocycle having 2 to 30 ring-forming carbon atoms, L₁₁ to L₁₄ may each independently be a direct linkage,

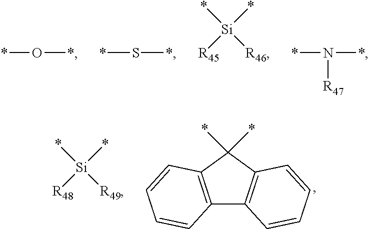

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, and in L₁₁ to L₁₄, “-*” is a site linked to C1 to C4, e1 to e4 may each independently be 0 or 1, R₄₁ to R₄₉ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring, and d1 to d4 may each independently be an integer of 0 to 4.

In one or more embodiments, the at least one functional layer may include the first compound, the second compound, the third compound, and the fourth compound.

In one or more embodiments of the present disclosure, a light emitting element includes a first electrode, a second electrode facing the first electrode, and an emission layer between the first electrode and the second electrode, wherein the emission layer includes a polycyclic compound represented by Formula 1.

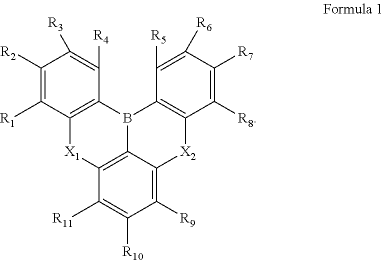

In Formula 1 above, X₁ and X₂ may each independently be O, S, Se, CRₐR_{b}, SiR_{c}R_{d}, or NR₁₂, embodiments in which X₁ and X₂ are both (e.g., simultaneously) O are excluded, at least one selected from among R₁ to R₁₂ may be an N-containing tricyclic heteroaryl group, and the others (the remainder) may each independently be hydrogen, deuterium, a halogen, a cyano group, a substituted or unsubstituted oxy group, a substituted or unsubstituted thio group, a substituted or unsubstituted silyl group, a substituted or unsubstituted amine group, a substituted or unsubstituted alkyl group having 1 to 30 carbon atoms, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 2 to 30 ring-forming carbon atoms, the N-containing tricyclic heteroaryl group may be substituted with at least one substituted or unsubstituted cycloalkyl group having 5 to 30 ring-forming carbon atoms, when the at least one substituted or unsubstituted cycloalkyl group having 5 to 30 ring-forming carbon atoms is a crosslinked cycloalkyl group (e.g., a bridged cycloalkyl group), each of a plurality of rings included in the crosslinked cycloalkyl group has 5 to 30 ring-forming carbon atoms, Ra to Ra may each independently be hydrogen, a substituted or unsubstituted alkyl group having 1 to 30 carbon atoms, or a substituted or unsubstituted aryl group having 6 to 30 ring-forming carbon atoms, and Formula 1 may include a structure in which one or more hydrogens may be substituted with deuterium.

In one or more embodiments, the at least one substituted or unsubstituted cycloalkyl group having 5 to 30 ring-forming carbon atoms may be represented by any one selected from among Formulas A1 to A5.

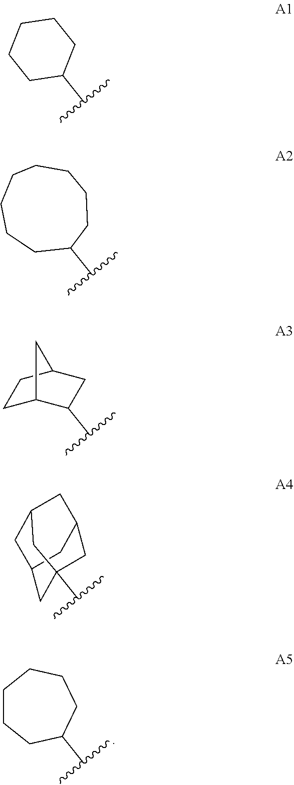 [SMILES: *C1CCCCC1 ; *C1CCCCCCCC1 ; *C1CC2CCC1C2 ; *C12CC3CC(CC(C3)C1)C2 ; *C1CCCCCC1]

In one or more embodiments of the present disclosure, a polycyclic compound may be represented by Formula 1.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. Above and/or other aspects of the present disclosure should become apparent and appreciated from the following description of embodiments taken in conjunction with the accompanying drawings. In the drawings:

FIG. 1 is a plan view of a display device according to one or more embodiments of the present disclosure;

FIG. 2 is a cross-sectional view of a display device according to one or more embodiments of the present disclosure;

FIG. 3 is a cross-sectional view schematically showing a light emitting element according to one or more embodiments of the present disclosure;

FIG. 4 is a cross-sectional view schematically showing a light emitting element according to one or more embodiments of the present disclosure;

FIG. 5 is a cross-sectional view schematically showing a light emitting element according to one or more embodiments of the present disclosure;

FIG. 6 is a cross-sectional view schematically showing a light emitting element according to one or more embodiments of the present disclosure;

FIG. 7 is a cross-sectional view of a display device according to one or more embodiments of the present disclosure;

FIG. 8 is a cross-sectional view of a display device according to one or more embodiments of the present disclosure;

FIG. 9 is a cross-sectional view showing a display device according to one or more embodiments of the present disclosure;

FIG. 10 is a cross-sectional view showing a display device according to one or more embodiments of the present disclosure; and

FIG. 11 is a perspective view schematically showing an electronic device according to one or more embodiments of the present disclosure.

### DETAILED DESCRIPTION

The present disclosure may be modified in many alternate forms, and thus specific embodiments will be exemplified in the drawings and described in more detail. It should be understood, however, that it is not intended to limit the present disclosure to the particular forms disclosed, but rather, is intended to cover all modifications, equivalents, and alternatives falling within the spirit and scope of the present disclosure.

In describing the drawings, like reference numerals are utilized for like elements. In the drawings, the sizes of elements may be exaggerated for clarity. It will be understood that, although the terms “first,” “second,”, “third,” and/or the like may be utilized herein to describe one or more suitable elements, these elements should not be limited by these terms. These terms are only utilized to distinguish one element from another element. For example, a first element may be referred to as a second element, and similarly, a second element may be referred to as a first element without departing from the teachings of the present disclosure. The singular forms are intended to include the plural forms as well, unless the context clearly indicates otherwise.

In the present disclosure, it should be understood that the terms “comprise(s)/include(s),” or “have/has” are intended to specify the presence of stated features, integers, steps, operations, elements, components, or combinations thereof in the disclosure, but do not preclude the presence or addition of one or more other features, integers, steps, operations, elements, components, or combinations thereof.

In the present disclosure, it should be understood that when an element such as a layer, a film, a region, or a substrate is referred to as being “on” or “above” another element, it may be “directly on” the other element or intervening elements may also be present. In contrast, it should be understood that when an element such as a layer, a film, a region, or a substrate is referred to as being “beneath” or “under” another element, it may be “directly under” the other element or intervening elements may also be present. In some embodiments, in the present disclosure, it should be understood that when an element is referred to as being “on” another element, it may be as being “above” or “under” the other element.

As used herein, the terms “and”, “or”, and “and/or” may include any and all combinations of one or more of the associated listed items. Expressions such as “at least one of,” “one of,” and “selected from,” when preceding a list of elements, modify the entire list of elements and do not modify the individual elements of the list. For example, “at least one of a, b, or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation.

As utilized herein, the term “substituted or unsubstituted” may indicate that one is substituted or unsubstituted with at least one substituent selected from the group consisting of deuterium, a halogen, a cyano group, a nitro group, an amino group, a silyl group, oxy group, thio group, sulfinyl group, sulfonyl group, carbonyl group, a boron group, a phosphine oxide group, a phosphine sulfide group, an alkyl group, an alkenyl group, an alkynyl group, a hydrocarbon ring group, an aryl group, and a heterocyclic group. In some embodiments, each of the substituents presented as an example above may be substituted or unsubstituted. For example, a biphenyl group may be interpreted as an aryl group or as a phenyl group substituted with a phenyl group.

As utilized herein, the term “bonded to an adjacent group to form a ring” may indicate that one is bonded to an adjacent group to form a substituted or unsubstituted hydrocarbon ring, or a substituted or unsubstituted heterocycle. The hydrocarbon ring may include an aliphatic hydrocarbon ring and an aromatic hydrocarbon ring. The heterocycle may include an aliphatic heterocycle and an aromatic heterocycle. The hydrocarbon ring and the heterocycle may be monocyclic or polycyclic. In some embodiments, the rings formed by being bonded to each other may be linked to another ring to form a spiro structure.

As utilized herein, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as mutually “adjacent groups” and two ethyl groups in 1,1-diethylcyclopentane may be interpreted as mutually “adjacent groups”. In some embodiments, two methyl groups in 4,5-dimethylphenanthrene may be interpreted as mutually “adjacent groups”.

As utilized herein, examples of a halogen may include fluorine, chlorine, bromine, and iodine.

As utilized herein, an alkyl group may be linear or branched. The number of carbon atoms in the alkyl group may be 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-heneicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but embodiments of the present disclosure are not limited thereto.

As utilized herein, a cycloalkyl group may refer to a cyclic alkyl group. The number of carbon atoms in the cycloalkyl group may be 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and/or the like, but embodiments of the present disclosure are not limited thereto.

As utilized herein, an alkenyl group may refer to a hydrocarbon group including at least one carbon-carbon double bond in the middle or end of an alkyl group having 2 or more carbon atoms. The alkenyl group may be linear or branched. The number of carbon atoms thereof is not particularly limited, for example, may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styryl vinyl group, and/or the like, but embodiments of the present disclosure are not limited thereto.

As utilized herein, an alkynyl group may refer to a hydrocarbon group including at least one carbon-carbon triple bond in the middle or end of an alkyl group having 2 or more carbon atoms. The alkynyl group may be linear or branched. The number of carbon atoms thereof is not particularly limited, for example, may be 2 to 30, 2 to 20, or 2 to 10. Examples of the alkynyl group may include an ethynyl group, a propynyl group, and/or the like, but embodiments of the present disclosure are not limited thereto.

As utilized herein, a hydrocarbon ring group may refer to any functional group or substituent derived from an aliphatic hydrocarbon ring. The hydrocarbon ring group may be a saturated hydrocarbon ring group having 5 to 20 ring-forming carbon atoms.

As utilized herein, an aryl group may refer to any functional group or substituent derived from an aromatic hydrocarbon ring. The aryl group may be a monocyclic aryl group or a polycyclic aryl group. The number of ring-forming carbon atoms in the aryl group may be 6 to 60, 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and/or the like, but embodiments of the present disclosure are not limited thereto.

As utilized herein, a fluorenyl group may be substituted, and two substituents may be bonded to each other to form a spiro structure. An example that the fluorenyl group is substituted is as follows. However, embodiments of the present disclosure are not limited thereto.

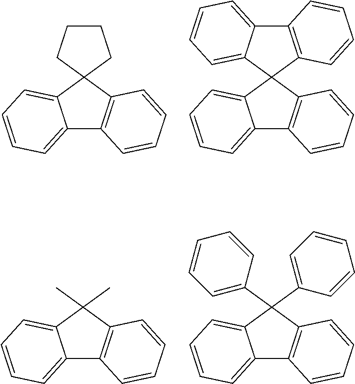

As utilized herein, a heterocyclic group may refer to any functional group or substituent derived from a ring containing at least one of B, O, N, P, Si, or S as a heteroatom. The heterocyclic group may include an aliphatic heterocyclic group and/or an aromatic heterocyclic group. The aromatic heterocyclic group may be a heteroaryl group. The aliphatic heterocycle and the aromatic heterocycle may be monocyclic or polycyclic. When the heterocyclic group contains two or more heteroatoms, the two or more heteroatoms may be the same as or different from each other.

As utilized herein, the aliphatic heterocyclic group may contain at least one of B, O, N, P, Si or S as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and/or the like, but embodiments of the present disclosure are not limited to thereto.

As utilized herein, a heteroaryl group may include at least one of B, O, N, P, Si, or S as a heteroatom. When the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 60, 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and/or the like, but embodiments of the present disclosure are not limited thereto.

As utilized herein, the above description of the aryl group may be applied to an arylene group, except that the arylene group is a divalent group. The above description of the heteroaryl group may be applied to a heteroarylene group, except that the heteroarylene group is a divalent group.

As utilized herein, a silyl group may include an alkyl silyl group and/or an aryl silyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like, but embodiments of the present disclosure are not limited thereto.

As utilized herein, the number of carbon atoms in an amino group is not particularly limited, for example, may be 1 to 30. The amino group may include an alkyl amino group, an aryl amino group, or a heteroaryl amino group. Examples of the amino group may include a methylamino group, a dimethylamino group, a phenylamino group, a diphenylamino group, a naphthylamino group, a 9-methyl-anthracenylamino group, a triphenylamino group, and/or the like, but embodiments of the present disclosure are not limited thereto.

As utilized herein, the number of carbon atoms in a carbonyl group is not particularly limited, for example, may be 1 to 40, 1 to 30, or 1 to 20. For example, the carbonyl group may have the following structure, but embodiments of the present disclosure are not limited thereto.

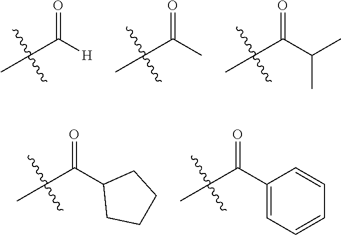

As utilized herein, the number of carbon atoms in a sulfinyl group or a sulfonyl group is not particularly limited, for example, may be 1 to 30. The sulfinyl group may include an alkyl sulfinyl group and/or an aryl sulfinyl group. The sulfonyl group may include an alkyl sulfonyl group and/or an aryl sulfonyl group.

As utilized herein, a thio group may include an alkyl thio group and/or an aryl thio group. The thio group may indicate the one that a sulfur atom is bonded to an alkyl group or an aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, and/or the like, but embodiments of the present disclosure are not limited to thereto.

As utilized herein, an oxy group may indicate the one that an oxygen atom is bonded to an alkyl group or aryl group as defined above. The oxy group may include an alkoxy group and/or an aryl oxy group. The alkoxy group may be linear, branched, or cyclic. The number of carbon atoms in the alkoxy group is not particularly limited, but may be, for example, 1 to 20, or 1 to 10. Examples of the oxy group may include methoxy, ethoxy, n-propoxy, isopropoxy, butoxy, pentyloxy, hexyloxy, octyloxy, nonyloxy, decyloxy, benzyloxy, and/or the like, but embodiments of the present disclosure are not limited thereto.

As utilized herein, a boron group may refer to one that a boron atom is bonded to an alkyl group or aryl group as defined above. The boron group includes an alkyl boron group and/or an aryl boron group. Examples of the boron group may include a dimethyl boron group, a diethyl boron group, a t-butylmethyl boron group, a diphenyl boron group, a phenyl boron group, and/or the like, but embodiments of the present disclosure are not limited thereto.

As utilized herein, the number of carbon atoms in an amine group is not particularly limited, for example, may be 1 to 30. The amine group may include an alkyl amine group and/or an aryl amine group. Examples of the amine group may include a methylamine group, a dimethylamine group, a phenylamine group, a diphenylamine group, a naphthylamine group, a 9-methyl-anthracenylamine group, a triphenylamine group, and/or the like, but embodiments of the present disclosure are not limited thereto.

As utilized herein, the above-described examples of the alkyl group may also apply to an alkylthio group, an alkyl sulfoxy group, an alkylaryl group, an alkylamino group, an alkyl boron group, an alkyl silyl group, and an alkyl amine group.

As utilized herein, the above-described examples of the aryl group may also apply to an aryloxy group, an arylthio group, an aryl sulfoxy group, an arylamino group, an aryl boron group, an aryl silyl group, and an aryl amine group.

As utilized herein, a direct linkage may refer to a single bond.

In some embodiments, as utilized herein, “

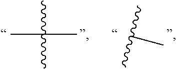

and “-*” may refer to sites to be connected.

Hereinafter, embodiments of the present disclosure will be described in more detail with reference to the accompanying drawings.

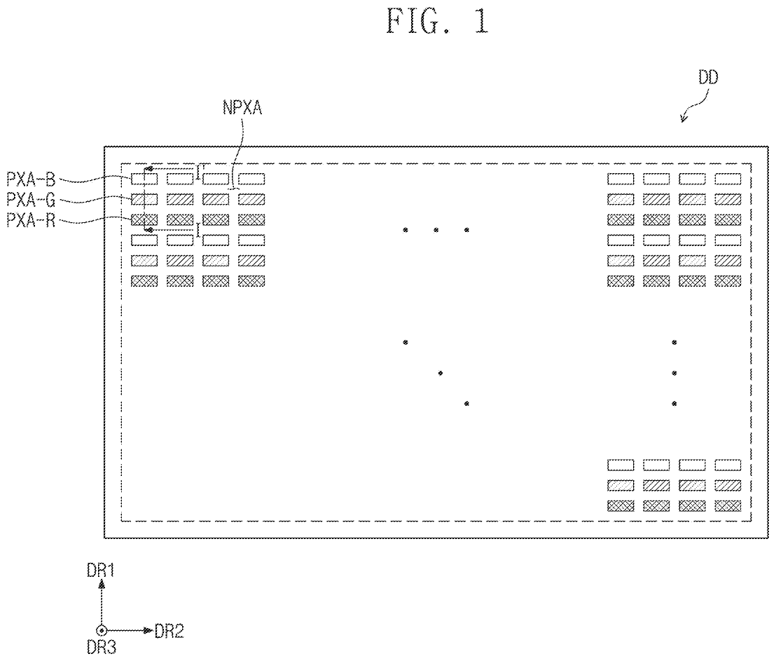

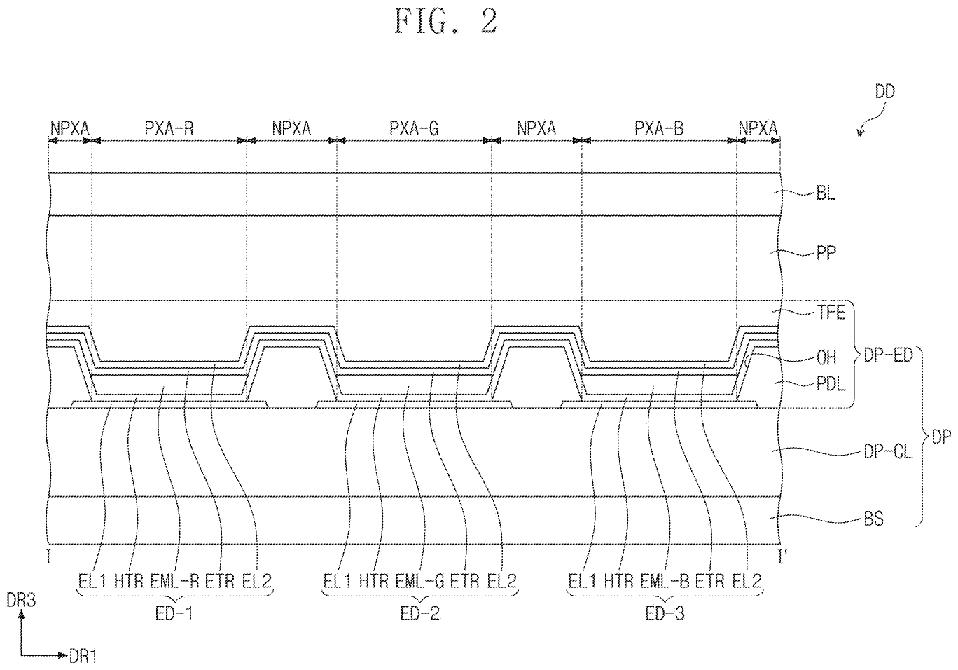

FIG. 1 is a plan view showing a display device DD according to one or more embodiments of the present disclosure. FIG. 2 is a cross-sectional view of a display device DD according to one or more embodiments of the present disclosure. FIG. 2 is a cross-sectional view showing a portion corresponding to line I-l′ of FIG. 1.

The display device DD may include a display panel DP and an optical layer PP disposed on the display panel DP. The display panel DP may include luminescence devices ED-1, ED-2, and ED-3. The display device DD may include a plurality of light emitting elements ED-1, ED-2, and ED-3. The optical layer PP may be disposed on the display panel DP to control reflected light in the display panel DP due to external light. The optical layer PP may include, for example, a polarizing layer and/or a color filter layer. In some embodiments, unlike what is shown in the drawings, the optical layer PP may not be provided in the display device DD.

A base substrate BL may be disposed or provided on the optical layer PP. The base substrate BL may be a member providing a base surface on which the optical layer PP is disposed. The base substrate BL may be a glass substrate, a metal substrate, a plastic substrate, and/or the like. However, embodiments of the present disclosure are not limited thereto, and the base substrate BL may be an inorganic layer, an organic layer, or a composite material layer. In some embodiments, unlike what is shown, the base substrate BL may not be provided.

The display device DD according to one or more embodiments may further include a filling layer. The filling layer may be disposed between a display element layer DP-ED and the base substrate BL. The filling layer may be an organic material layer. The filling layer may include at least one selected from among an acrylic resin, a silicone-based resin, and an epoxy-based resin.

The display panel DP may include a base layer BS, a circuit layer DP-CL provided on the base layer BS, and a display element layer DP-ED. The display element layer DP-ED may include pixel defining films PDL, a plurality of light emitting elements ED-1, ED-2, and ED-3 disposed between the pixel defining films PDL, and an encapsulation layer TFE disposed on the plurality of light emitting elements ED-1, ED-2, and ED-3.

The base layer BS may be a member providing a base surface on which the display element layer DP-ED is disposed. The base layer BS may be a glass substrate, a metal substrate, a plastic substrate, and/or the like. However, embodiments of the present disclosure are not limited thereto, and the base layer BS may be an inorganic layer, an organic layer, or a composite material layer.

In one or more embodiments, the circuit layer DP-CL may be disposed on the base layer BS, and the circuit layer DP-CL may include a plurality of transistors. The transistors may each include a control electrode, an input electrode, and an output electrode. For example, the circuit layer DP-CL may include switching transistors and driving transistors for driving the plurality of light emitting elements ED-1, ED-2, and ED-3 of the display element layer DP-ED.

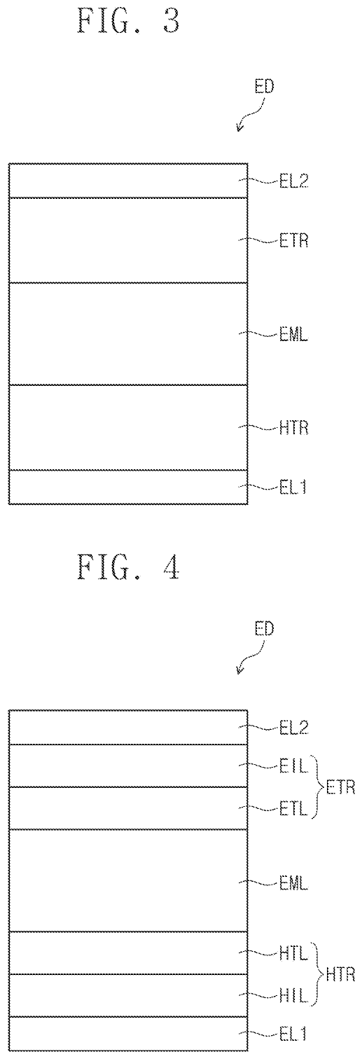

The light emitting elements ED-1, ED-2, and ED-3 may each independently have a structure of a light emitting element ED according to an embodiment of FIGS. 3 to 6, which will be described later. The light emitting elements ED-1, ED-2, and ED-3 may each include a first electrode EL1, a hole transport region HTR, a respective one selected from emission layers EML-R, EML-G, and EML-B, an electron transport region ETR, and a second electrode EL2.

FIG. 2 shows an embodiment in which the respective emission layers EML-R, EML-G, and EML-B of the light emitting elements ED-1, ED-2, and ED-3 are disposed in openings OH defined in the pixel defining films PDL, and the hole transport region HTR, the electron transport region ETR, and the second electrode EL2 are provided as a common layer throughout the light emitting elements ED-1, ED-2, and ED-3. However, embodiments of the present disclosure are not limited thereto. In one or more embodiments, the hole transport region HTR and the electron transport region ETR may be provided to be patterned inside the openings OH defined in the pixel defining films PDL. For example, in some embodiments, the hole transport region HTR, the respective emission layers EML-R, EML-G, and EML-B, and the electron transport region ETR, and/or the like of the light emitting elements ED-1, ED-2, and ED-3 may be patterned and provided through an inkjet printing method.

The encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be a single layer or a laminated layer of a plurality of layers. The encapsulation layer TFE may include at least one insulating layer. In some embodiments, the encapsulation layer TFE may include at least one inorganic film (hereinafter, an encapsulation inorganic film). In some embodiments, the encapsulation layer TFE may include at least one organic film (hereinafter, an encapsulation organic film) and at least one encapsulation inorganic film.

The encapsulation inorganic film protects the display element layer DP-ED from moisture/oxygen, and the encapsulation organic film protects the display element layer DP-ED from foreign substances such as dust particles. The encapsulation inorganic film may include silicon nitride, silicon oxy nitride, silicon oxide, titanium oxide, aluminum oxide, and/or the like, but is not particularly limited thereto. The encapsulation organic film may include an acrylic compound, an epoxy-based compound, and/or the like. In one or more embodiments, the encapsulation organic film may include a photopolymerizable organic material, and is not particularly limited.

The encapsulation layer TFE may be disposed on the second electrode EL2 and may be disposed to fill the openings OH.

Referring to FIG. 1 and FIG. 2, the display device DD may include non-light emitting regions NPXA and light emitting regions PXA-R, PXA-G, and PXA-B. The light emitting regions PXA-R, PXA-G, and PXA-B may each be a region emitting light generated from each of the light emitting elements ED-1, ED-2, and ED-3, respectively. The light emitting regions PXA-R, PXA-G, and PXA-B may be spaced apart from each other when viewed on a plane (e.g., in a plan view).

The light emitting regions PXA-R, PXA-G, and PXA-B may each be a region separated by the pixel defining films PDL. The non-light emitting regions NPXA may be regions between neighboring light emitting regions PXA-R, PXA-G, and PXA-B, and may correspond to the pixel defining film PDL. In some embodiments, as utilized herein, the light emitting regions PXA-R, PXA-G, and PXA-B may each correspond to a pixel. The pixel defining film PDL may separate the light emitting elements ED-1, ED-2, and ED-3. The respective emission layers EML-R, EML-G, and EML-B of the light emitting elements ED-1, ED-2, and ED-3 may be disposed and separated in openings OH defined by the pixel defining films PDL.

The light emitting regions PXA-R, PXA-G, and PXA-B may be divided into a plurality of groups according to the color of each light generated from the light emitting elements ED-1, ED-2, and ED-3. In the display device DD of one or more embodiments shown in FIGS. 1 and 2, three light emitting regions PXA-R, PXA-G, and PXA-B which emit red light, green light, and blue light, respectively, are shown as an example. For example, in one or more embodiments, the display device DD may include a red light emitting region PXA-R, a green light emitting region PXA-G, and a blue light emitting region PXA-B, which are distinct or apart from one another.

In the display device DD according to one or more embodiments, the plurality of light emitting elements ED-1, ED-2, and ED-3 may be to emit light having different wavelength ranges. For example, in some embodiments, the display device DD may include a first light emitting element ED-1 to emit red light, a second light emitting element ED-2 to emit green light, and a third light emitting element ED-3 to emit blue light. For example, in one or more embodiments, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, embodiments of the present disclosure are not limited thereto, and the first to third light emitting elements ED-1, ED-2, and ED-3 may be to emit light in substantially the same wavelength range or emit light in at least one different wavelength range. For example, in some embodiments, the first to third light emitting elements ED-1, ED-2, and ED-3 all may be to emit blue light.

The light emitting regions PXA-R, PXA-G, and PXA-B in the display device DD according to one or more embodiments may be arranged in the form of a stripe. Referring to FIG. 1, a plurality of red light emitting regions PXA-R may be arranged with each other along a second direction axis DR2, a plurality of green light emitting regions PXA-G may be arranged with each other along the second direction axis DR2, and a plurality of blue light emitting regions PXA-B may be arranged with each other along the second direction DR2. In some embodiments, the red light emitting region PXA-R, the green light emitting region PXA-G, and the blue light emitting region PXA-B may be alternately arranged in turn along a first direction DR1.

FIG. 1 and FIG. 2 show that the light emitting regions PXA-R, PXA-G, and PXA-B are all similar in size, but embodiments of the present disclosure are not limited thereto, and the light emitting regions PXA-R, PXA-G and PXA-B may be different in size from each other according to wavelength range of emitted light. In some embodiments, the areas of the light emitting regions PXA-R, PXA-G, and PXA-B may refer to areas when viewed on a plane defined by the first direction DR1 and the second direction DR2 (e.g., areas in a plan view).

In some embodiments, the arrangement of the light emitting regions PXA-R, PXA-G, and PXA-B is not limited to what is shown in FIG. 1, and the order in which the red light emitting region PXA-R, the green light emitting region PXA-G, and the blue light emitting region PXA-B are arranged comes with varied combination according to display quality characteristics required for the display device DD. For example, the light emitting regions PXA-R, PXA-G, and PXA-B may be arranged in the form of a pentile (PENTILE®) (for example, an RGBG matrix, an RGBG structure, or an RGBG matrix structure) or a diamond (Diamond Pixel™) (e.g., a display (e.g., an OLED display) containing red, blue, and green (RGB) light-emitting regions arranged in the shape of diamonds). PENTILE® is a duly registered trademark of Samsung Display Co., Ltd. Diamond Pixel™ is a trademark of Samsung Display Co., Ltd.

In some embodiments, areas of each of the light emitting regions PXA-R, PXA-G, and PXA-B may be different in size from one another. For example, in some embodiments, the green light emitting region PXA-G may be smaller than the blue light emitting region PXA-B in size, but embodiments of the present disclosure are not limited thereto.

In the display device DD according to one or more embodiments which is shown in FIG. 2, at least one selected from among the first to third light emitting elements ED-1, ED-2, and ED-3 may include a polycyclic compound according to one or more embodiments of the present disclosure.

Hereinafter, FIGS. 3 to 6 each are a cross-sectional view schematically showing a light emitting element according to one or more embodiments of the present disclosure. The light emitting element ED according to one or more embodiments may include a first electrode EL1, a second electrode EL2 facing the first electrode EL1, and at least one functional layer between the first electrode EL1 and the second electrode EL2. The light emitting element ED according to one or more embodiments may include a polycyclic compound according to one or more embodiments, which will be described later, in at least one functional layer. In some embodiments, the polycyclic compound of one or more embodiments may be referred to as a first compound herein.

The light emitting element ED may include a hole transport region HTR, an emission layer EML, and an electron transport region ETR, which are sequentially stacked in the stated order, as at least one functional layer. Referring to FIG. 3, the light emitting element ED according to one or more embodiments may include a first electrode EL1, a hole transport region HTR, an emission layer EML, an electron transport region ETR, and a second electrode EL2. In some embodiments, the light emitting element ED according to one or more embodiments may include a polycyclic compound according to one or more embodiments of the present disclosure, which will be described later, in the emission layer EML.

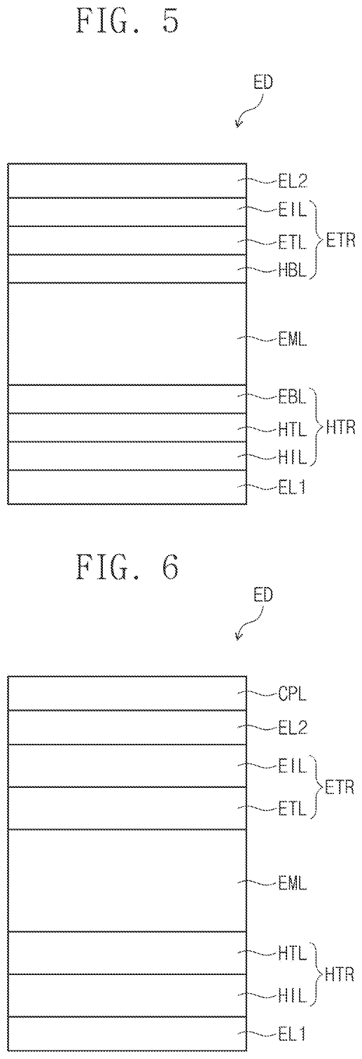

FIG. 4 shows, compared with FIG. 3, a cross-sectional view of a light emitting element ED of one or more embodiments in which the hole transport region HTR may include a hole injection layer HIL and a hole transport layer HTL, and the electron transport region ETR may include an electron injection layer EIL and an electron transport layer ETL. In some embodiments, FIG. 5 shows, compared with FIG. 3, a cross-sectional view of a light emitting element ED according to one or more embodiments in which the hole transport region HTR may include a hole injection layer HIL, a hole transport layer HTL, and an electron blocking layer EBL, and the electron transport region ETR may include an electron injection layer EIL, an electron transport layer ETL, and a hole blocking layer HBL. FIG. 6 shows, compared with FIG. 4, a cross-sectional view of a light emitting element ED according to one or more embodiments, in which a capping layer CPL disposed on the second electrode EL2 is provided.

The first electrode EL1 has conductivity (e.g., is a conductor). The first electrode EL1 may be formed of a metal material, a metal alloy, and/or a conductive compound. The first electrode EL1 may be an anode or a cathode. However, embodiments of the present disclosure are not limited thereto. In some embodiments, the first electrode EL1 may be a pixel electrode. The first electrode EL1 may be a transmissive electrode, a transflective electrode, or a reflective electrode. The first electrode may include at least one selected from silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), and zinc (Zn), two or more compounds selected therefrom, two or more mixtures selected therefrom, and/or an oxide thereof.

When the first electrode EL1 is a transmissive electrode, the first electrode EL1 may include a transparent metal oxide such as indium tin oxide (ITO), indium zinc oxide (IZO), zinc oxide (ZnO), and/or indium tin zinc oxide (ITZO). When the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stack structure of LiF and Ca), LiF/Al (a stack structure of LiF and Al), Mo, Ti, W, a compound thereof, or a mixture thereof (e.g., a mixture of Ag and Mg). In some embodiments, the first electrode EL1 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), and/or the like. For example, in some embodiments, the first electrode EL1 may have a three-layer structure of ITO/Ag/ITO, but is not limited thereto. In addition, embodiments of the present disclosure are not limited thereto, and the first electrode EL1 may include the above-described metal materials, a combination of two or more metal materials selected from the above-described metal materials, and/or oxides of the above-described metal materials. The first electrode EL1 may have a thickness of about 700 Å to about 10000 Å. For example, in some embodiments, the first electrode EL1 may have a thickness of 1000 Å to about 3000 Å.

The hole transport region HTR may be provided on the first electrode EL1. The hole transport region HTR may include at least one selected from among a hole injection layer HIL, a hole transport layer HTL, a buffer layer, a light emitting auxiliary layer, and an electron blocking layer EBL. The hole transport region HTR may have, for example, a thickness of about 50 Å to about 15000 Å.

The hole transport region HTR may have a single layer formed of a single material, a single layer formed of a plurality of different materials, or a multilayer structure having a plurality of layers formed of a plurality of different materials.

For example, in one or more embodiments, the hole transport region HTR may have a single-layer structure formed of a hole injection layer HIL or a hole transport layer HTL, or a single-layer structure formed of a hole injection material or a hole transport material. For example, in some embodiments, the hole transport region HTR may have a single-layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order (e.g., in each stated order) from the first electrode EL1, but embodiments of the present disclosure are not limited thereto.

The hole transport region HTR may be formed utilizing one or more suitable methods such as a vacuum deposition method, a spin coating method, a casting method, a Langmuir-Blodgett (LB) method, an inkjet printing method, a laser printing method, and/or a laser induced thermal imaging (LITI) method.

The hole transport region HTR may include a compound represented by Formula H-1.

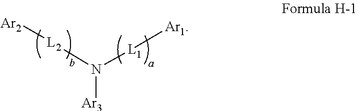

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In some embodiments, when a or b is an integer of 2 or greater, a plurality of Li's and L₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₃ may be a substituted or unsubstituted aryl group having 6 to 30 ring-forming carbon atoms.

The compound represented by Formula H-1 may be a monoamine compound. In some embodiments, the compound represented by Formula H-1 may be a diamine compound in which at least one selected from among Ar₁ to Ar₃ includes an amine group as a substituent. In some embodiments, the compound represented by Formula H-1 may be a carbazole-based compound including a substituted or unsubstituted carbazole group in at least one of Ar₁ or Ar₂, or a substituted or unsubstituted fluorene-based group in at least one of Ar₁ or Ar₂.

The compound represented by Formula H-1 may be any one selected from among compounds from Compound Group H-1. However, the compounds listed in Compound Group H-1 are presented as a mere example, and the compound represented by Formula H-1 is not limited to those listed in Compound Group H-1.

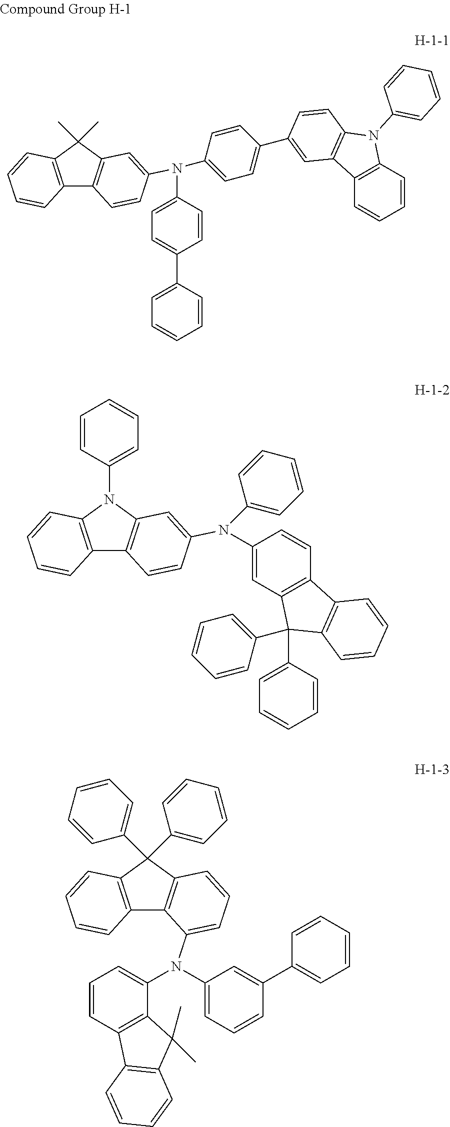 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

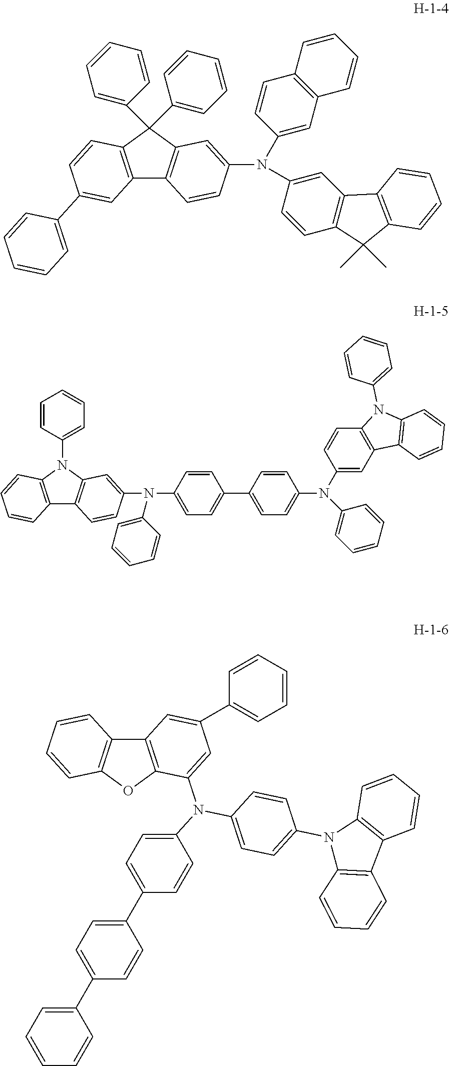 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

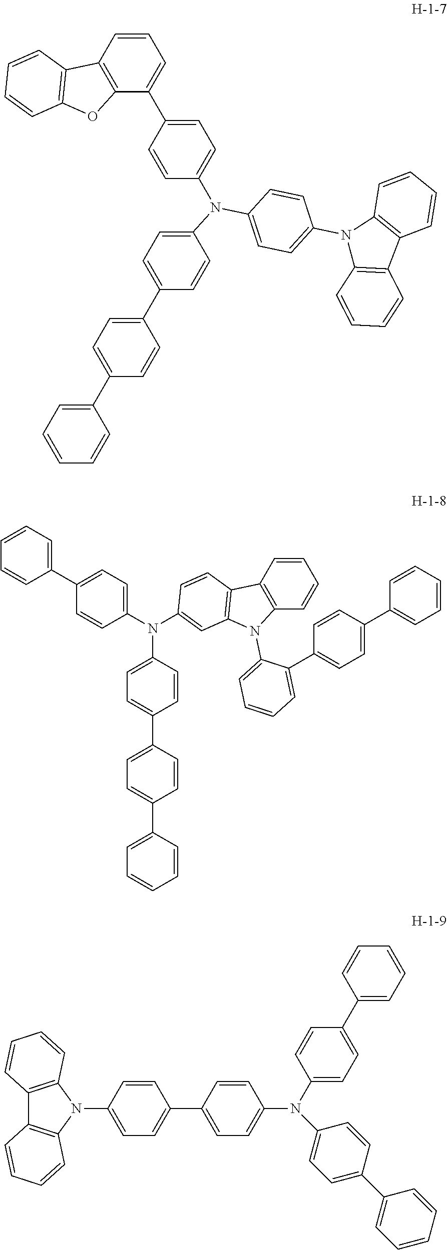 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

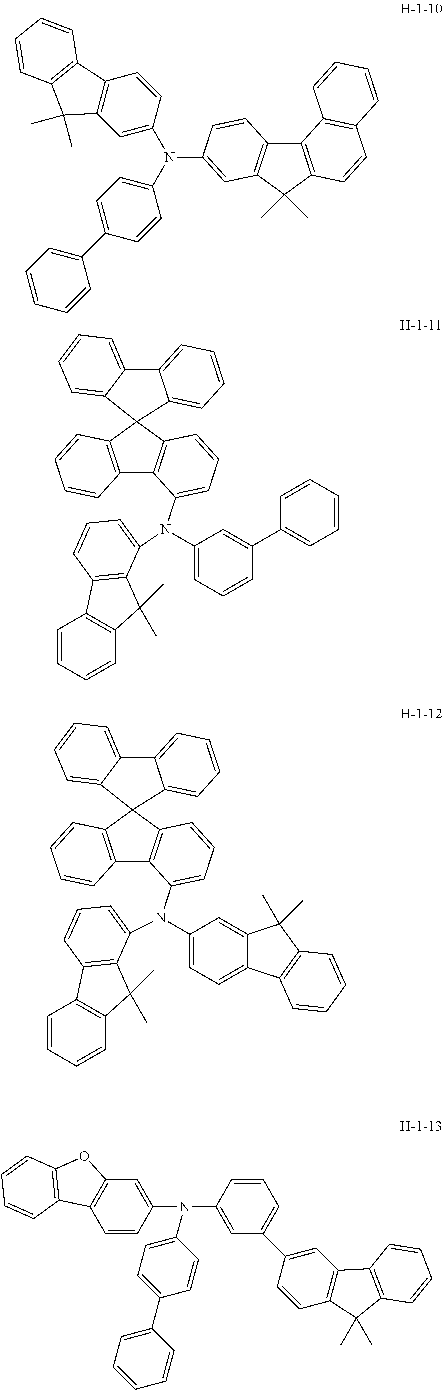

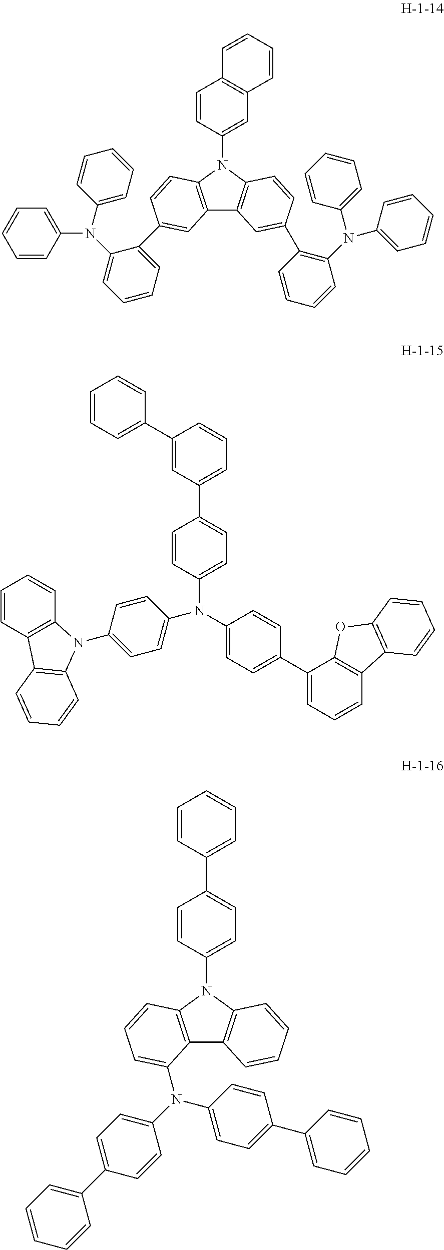 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

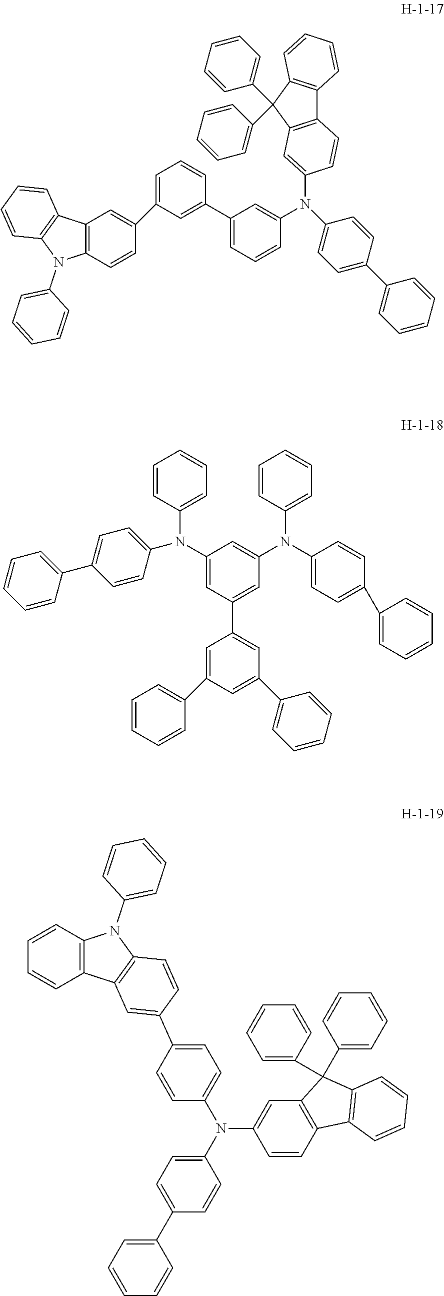 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

In one or more embodiments, the hole transport region HTR may include a phthalocyanine compound such as copper phthalocyanine, N1, N1′-([1,1′-biphenyl]-4,4′-diyl)bis(N1-phenyl-N4,N4-di-m-tolylbenzene-1,4-diamine) (DNTPD), 4,4′,4″-[tris(3-methylphenyl)phenylamino]triphenylamine (m-MTDATA), 4,4′4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/Dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalen-1-yl)-N,N′-diphenyl-benzidine (NPB), triphenylamine-containing polyetherketone (TPAPEK), 4-isopropyl-4′-methyldiphenyliodonium tetrakis(pentafluorophenyl)borate, dipyrazino[2,3-f: 2′,3′-h]quinoxaline-2,3,6,7,10,11-hexacarbonitrile (HATCN), and/or the like.

In one or more embodiments, the hole transport region HTR may include one or more carbazole-based derivatives such as N-phenyl carbazole and polyvinyl carbazole, one or more fluorene-based derivatives, N,N′-bis(3-methylphenyl)-N,N′-diphenyl-[1,1-biphenyl]-4,4′-diamine (TPD), one or more triphenylamine-based derivatives such as 4,4′,4″-tris(N-carbazolyl)triphenylamine (TCTA), N,N′-di(1-naphthalen-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), and/or the like.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

The hole transport region HTR may include at least one selected from the compounds of the hole transport region described above in at least one selected from among the hole injection layer HIL, the hole transport layer HTL, and the electron blocking layer EBL.

The hole transport region HTR may have a thickness of about 100 Å to about 10000 Å, for example, about 100 Å to about 5000 Å. When the hole transport region HTR includes a hole injection layer HIL, the hole injection layer HIL may have a thickness of, for example, about 30 Å to about 1000 Å. When the hole transport region HTR includes a hole transport layer HTL, the hole transport layer HTL may have a thickness of about 30 Å to about 1000 Å. When the hole transport region HTR includes an electron blocking layer EBL, the electron blocking layer EBL may have a thickness of, for example, about 10 Å to about 1000 Å. When the thicknesses of the hole transport region HTR, the hole injection layer HIL, the hole transport layer HTL, and the electron blocking layer EBL satisfy the above-described ranges, satisfactory hole transport properties may be obtained without a substantial increase in driving voltage.

In one or more embodiments, the hole transport region HTR may further include, in addition to the above-described materials, a charge generation material to increase conductivity. The charge generation material may be substantially uniformly or non-uniformly dispersed in the hole transport region HTR. The charge generation material may be, for example, a p-dopant. The p-dopant may include at least one of halogenated metal compounds, quinone derivatives, metal oxides, or cyano group-containing compounds, but embodiments of the present disclosure are not limited thereto. For example, in one or more embodiments, the p-dopant may include one or more halogenated metal compounds such as Cul and/or Rbl, one or more quinone derivatives such as tetracyanoquinodimethane (TCNQ) and/or 2,3,5,6-tetrafluoro-7,7,8,8-tetracyanoquinodimethane (F4-TCNQ), one or more metal oxides such as tungsten oxides and/or molybdenum oxides, one or more cyano group-containing compounds such as dipyrazino[2,3-f: 2′,3′-h]quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but embodiments of the present disclosure are not limited thereto.

As described above, in some embodiments, the hole transport region HTR may further include at least one of a buffer layer or an electron blocking layer EBL in addition to the hole injection layer HIL and the hole transport layer HTL. The buffer layer may compensate a resonance distance according to wavelengths of light emitted from an emission layer EML, and may thus increase light emitting efficiency. Materials which may be included in the hole transport region HTR may be utilized as materials included in the buffer layer. The electron blocking layer EBL may be a layer that serves to prevent or reduce electrons from being injected from the electron transport region ETR to the hole transport region HTR.

The emission layer EML may be provided on the hole transport region HTR. The emission layer EML may have, for example, a thickness of about 100 Å to about 1000 Å or about 100 Å to about 300 Å. The emission layer EML may have a single layer formed of a single material, a single layer formed of a plurality of different materials, or a multilayer structure having a plurality of layers formed of a plurality of different materials.

The light emitting element ED according to one or more embodiments may include a first electrode EL1, a second electrode EL2, and at least one functional layer, and the at least one functional layer includes a polycyclic compound according to one or more embodiments. In one or more embodiments, at least one functional layer may include an emission EML, and the emission layer EML may include a polycyclic compound of one or more embodiments. In one or more embodiments, the emission layer EML may include the polycyclic compound of one or more embodiments as a dopant.

The polycyclic compound of one or more embodiments may include a structure in which a plurality of aromatic rings are fused through one boron atom, a first atom, and a second atom. For example, the polycyclic compound of one or more embodiments may include a structure in which first to third aromatic rings are fused through one boron atom, a first atom, and a second atom. The first to third aromatic rings may each be linked to the boron atom, the first and second aromatic rings may be further linked through the first atom, the second and third aromatic rings may be further linked through the second atom, and the first and third aromatic rings may be linked through the boron atom. As utilized herein, a structure in which first to third aromatic rings are fused through one boron atom, a first atom, and a second atom may be referred to as a “core structure”.

In one or more embodiments, the first to third aromatic rings may be substituted or unsubstituted benzene rings. The first atom and the second atom may each independently be selected from an oxygen atom, a sulfur atom, a selenium atom, a carbon atom, a silicon atom, and a nitrogen atom. When the first atom and the second atom are nitrogen atoms, a phenyl group may be bonded to the nitrogen atoms.

In the polycyclic compound of one or more embodiments, an N-containing tricyclic heterocyclic group may be bonded to at least one of three benzene rings of the core structure or a phenyl group bonded to a nitrogen atom. When both (e.g., simultaneously) the first atom and the second atom are not nitrogen atoms, an N-containing tricyclic heterocyclic group may be bonded to at least one of the three benzene rings of the core structure.

For example, in one or more embodiments, the N-containing tricyclic heterocyclic group may include one nitrogen atom as a heteroatom, or may further include an oxygen atom, a sulfur atom, a selenium atom, a silicon atom, or a nitrogen atom, in addition to the one nitrogen atom. The N-containing tricyclic heterocyclic group may be substituted with at least one cycloalkyl group. The number of ring-forming carbon atoms of the at least one cycloalkyl group substituted on the N-containing tricyclic heterocyclic group may be 5 to 30. In some embodiments, when at least one cycloalkyl group substituted on the N-containing tricyclic heterocyclic group is a crosslinked cycloalkyl group (e.g., a bridged cycloalkyl group), each of a plurality of rings included in the crosslinked cycloalkyl group has 5 to 10 ring-forming carbon atoms.

In one or more embodiments, the emission layer EML may include a first compound represented by Formula 1. As utilized herein, the first compound corresponds to the polycyclic compound according to one or more embodiments.

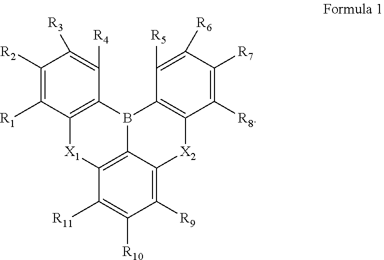

In Formula 1, X₁ and X₂ may each independently be O, S, Se, CRₐR_{b}, SiR_{c}R_{d}, or NR₁₂, X₁ and X₂ may be the same or different. However, embodiments in which X₁ and X₂ are both (e.g., simultaneously) O are excluded, Ra to Ra may each independently be hydrogen, a substituted or

unsubstituted alkyl group having 1 to 30 carbon atoms, or a substituted or unsubstituted aryl group having 6 to 30 ring-forming carbon atoms, and Ra to Ra may be the same, or at least one may be different from the others. For example, in one or more embodiments, Ra to Ra may each independently be hydrogen, an unsubstituted methyl group, or an unsubstituted phenyl group.

At least one selected from among R₁ to R₁₂ may be represented by Formula 2, and the others (the remainder) may each independently be hydrogen, deuterium, a halogen, a cyano group, a substituted or unsubstituted oxy group, a substituted or unsubstituted thio group, a substituted or unsubstituted silyl group, a substituted or unsubstituted amine group, a substituted or unsubstituted alkyl group having 1 to 30 carbon atoms, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 2 to 30 ring-forming carbon atoms. For example, in one or more embodiments, one selected from among R₁ to R₁₂ may be represented by Formula 2, or two selected from among R₁ to R₁₂ may be represented by Formula 2. R₁ to R₁₂ may be the same, or at least one selected from among R₁ to R₁₂ may be different from the others.

The others which are not represented by Formula 2 among R₁ to R₁₂ may each independently be hydrogen, deuterium, fluorine, chlorine, a cyano group, an oxy group substituted with a methyl group or a phenyl group, a thio group substituted with a methyl group or a phenyl group, a silyl group substituted with a phenyl group, an amine group substituted with a methyl group or a phenyl group, a methyl group unsubstituted or substituted with deuterium, an unsubstituted isopropyl group, an unsubstituted t-butyl group, an unsubstituted hexyl group, a phenyl group unsubstituted or substituted with deuterium, an unsubstituted pyridine group, an unsubstituted pyrimidine group, an unsubstituted triazine group, an unsubstituted quinoline group, a carbazole group substituted with a phenyl group, a benzofuran group substituted with a methyl group, an unsubstituted dibenzofuran group, a thiophene group substituted with a methyl group, a benzothiophene group substituted with a phenyl group, or an unsubstituted dibenzothiophene group.

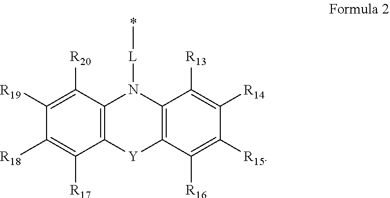

In Formula 2, L may be a direct linkage or a substituted or unsubstituted arylene group having 6 to 30 ring-forming carbon atoms. For example, in one or more embodiments, L may be a direct linkage or an unsubstituted phenylene group.

Y may be a direct linkage, O, S, Se, CRₑR_{f}, SiR_{g}Rₕ, or NRᵢ.

Rₑ to Rᵢ may each independently be a substituted or unsubstituted alkyl group having 1 to 30 carbon atoms, or a substituted or unsubstituted aryl group having 6 to 30 ring-forming carbon atoms. Rₑ to Rᵢ may be the same, or at least one selected from Rₑ to Rᵢ may be different from the others. For example, in some embodiments, Rₑ to Rᵢ may each independently be an unsubstituted methyl group or an unsubstituted phenyl group.

At least one selected from among R₁₄ to R₁₉ is a substituted or unsubstituted cycloalkyl group having 5 to 30 ring-forming carbon atoms, and the others (the remainder) may each independently be hydrogen or deuterium. For example, in some embodiments, one selected from among R₁₄ to R₁₉ may be a substituted or unsubstituted cycloalkyl group having 5 to 30 ring-forming carbon atoms, or two selected from among R₁₄ to R₁₉ may be a substituted or unsubstituted cycloalkyl group having 5 to 30 ring-forming carbon atoms. When R₁₄ to R₁₉ are a crosslinked cycloalkyl group (e.g., a bridged cycloalkyl group), each of a plurality of rings included in the crosslinked cycloalkyl group has 5 to 10 ring-forming carbon atoms. R₁₄ to R₁₉ may be the same, or at least one selected from among R₁₄ to R₁₉ may be different from the others. For example, in one or more embodiments, at least one selected from among R₁₄ to R₁₉ may be an unsubstituted cyclohexyl group, an unsubstituted cycloheptyl group, an unsubstituted cyclononyl group, an unsubstituted bicycloheptyl group, or an unsubstituted adamantyl group.

R₁₃ and R₂₀ may each independently be hydrogen, deuterium, or a substituted or unsubstituted cycloalkyl group having 3 to 30 ring-forming carbon atoms. For example, in one or more embodiments, R₁₃ and R₂₀ may each independently be hydrogen, deuterium, or an unsubstituted adamantyl group. R₁₃ and R₂₀ may be the same, or at least one selected from R₁₃ and R₂₀ may be different from the others.

In Formula 2, “*-” is a site linked to the core structure of Formula 1. For example, in some embodiments, it may be linked to a benzene ring of the core structure of Formula 1. In some embodiments, when X₁ and X₂ are nitrogen atoms, X₁ and X₂ may be linked to a phenyl group bonded to a nitrogen atom. In these embodiments, the core structure of Formula 1 may indicate the following structure, and in the following structure, X₁ and X₂ may each independently be the same as defined in Formula 1.

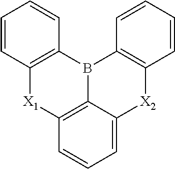

Formula 1 may include a structure in which one or more hydrogens may be substituted with deuterium. For example, in some embodiments, Formula 1 may have a structure without deuterium atoms or may have a structure in which some or all of the hydrogen atoms are substituted with deuterium atoms. For example, in Formula 1, when the others which are not represented by Formula 2 among R₁ to R₁₂ are each a hydrogen atom, the others which are not represented by Formula 2 among R₁ to R₁₂ may all be hydrogen atoms, or some or all of the others may be substituted with deuterium atoms. In some embodiments, in Formula 2, when the others which are not a substituted or unsubstituted cycloalkyl group having 5 to 30 ring-forming carbon atoms among R₁₄ to R₁₉ are each hydrogen, the others which are not a substituted or unsubstituted cycloalkyl group having 5 to 30 ring-forming carbon atoms among R₁₄ to R₁₉ may all be hydrogens, or some or all of the others may be substituted with deuterium.

In one or more embodiments, Formula 2 may be represented by Formula 2-1a or Formula 2-1b.

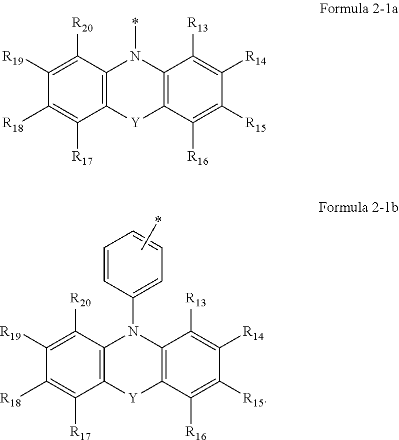

Formula 2-1a and Formula 2-1b may each specify L in Formula 2. For example, Formula 2-1a may indicate an embodiment in which L in Formula 2 is a direct linkage, and Formula 2-1b may indicate an embodiment in which L in Formula 2 is an unsubstituted phenylene group.

In Formulas 2-1a and 2-1b, Y, and R₁₃ to R₂₀ may each independently be the same as defined in Formula 2.

In Formulas 2-1a and 2-1b, *- is a site linked to the core structure of Formula 1. For example, in some embodiments, it may be linked to a benzene ring of the core structure of Formula 1. In some embodiments, when X₁ and X₂ are nitrogen atoms, X₁ and X₂ may be linked to a phenyl group bonded to a nitrogen atom.

In one or more embodiments, Formula 2 may be represented by any one selected from among Formulas 2-2a to 2-2g.

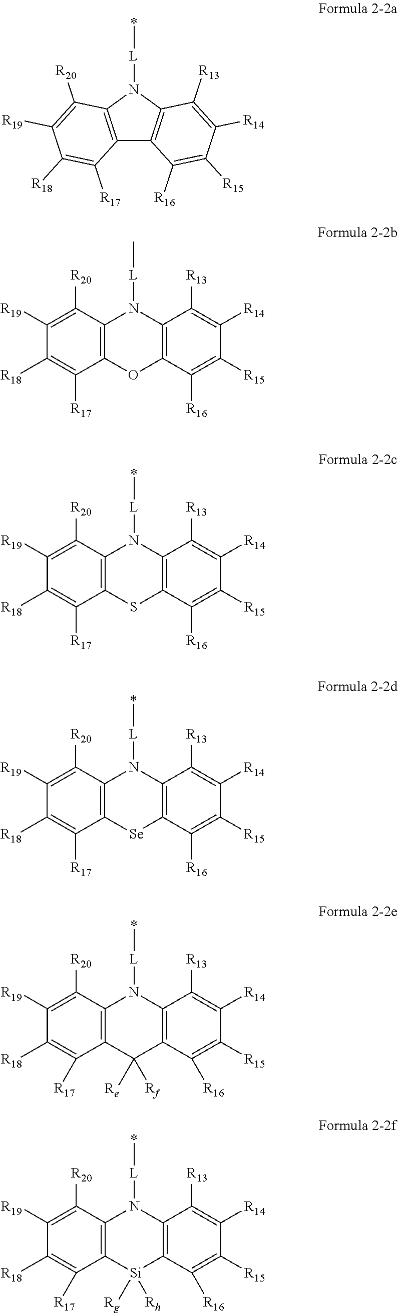

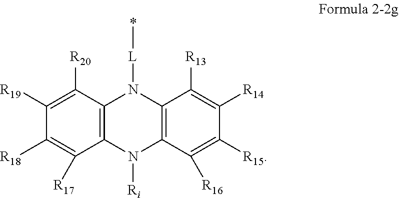

Formulas 2-2a to 2-2g may each specify Y in Formula 2. For example, Formula 2-1a may indicate an embodiment in which Y in Formula 2 is a direct linkage, Formula 2-1b may indicate an embodiment in which Y in Formula 2 is O, Formula 2-1c may indicate an embodiment in which Y in Formula 2 is S, Formula 2-1d may indicate an embodiment in which Y in Formula 2 is Se, Formula 2-1e may indicate an embodiment in which Y in Formula 2 is CRₑR_{f}, Formula 2-2f may indicate an embodiment in which Y in Formula 2 is SiR_{g}Rₕ, and Formula 2-2g may indicate an embodiment in which Y in Formula 2 is NRᵢ.

In Formulas 2-2a to 2-2g, Rₑ to Rᵢ may each independently be an unsubstituted methyl group or an unsubstituted phenyl group. Rₑ to Rᵢ may be the same, or at least one selected from Rₑ to Rᵢ may be different from the others.

L, and R₁₃ to R₂₀ may each independently be the same as defined in Formula 2.

In Formulas 2-2a to 2-2g, *- is a site linked to the core structure of Formula 1. For example, in some embodiments, it may be linked to a benzene ring of the core structure of Formula 1. In some embodiments, when X₁ and X₂ are nitrogen atoms, X₁ and X₂ may be linked to a phenyl group bonded to a nitrogen atom.

In one or more embodiments, Formula 2 may be represented by any one selected from among Formulas 2-3a to 2-3e.

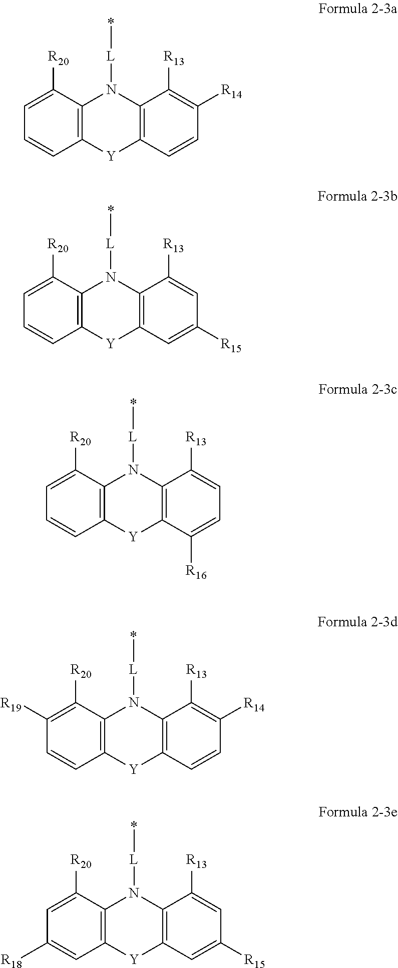

Formulas 2-3a to 2-3e may specify positions at which at least one substituted or unsubstituted cycloalkyl group having 5 to 30 ring-forming carbon atoms in Formula 2 is substituted/bonded.

In Formulas 2-3a to 2-3e, R₁₄, R₁₅, R₁₆, R₁₈, and R₁₉ may each independently be a substituted or unsubstituted cycloalkyl group having 5 to 30 ring-forming carbon atoms. For example, in one or more embodiments, R₁₄, R₁₅, R₁₆, R₁₈, and R₁₉ may each independently be an unsubstituted cyclohexyl group, an unsubstituted cycloheptyl group, an unsubstituted cyclononyl group, an unsubstituted bicycloheptyl group, or an unsubstituted adamantyl group. R₁₄, R₁₅, R₁₆, R₁₈, and R₁₉ may be the same, or at least one selected therefrom may be different from the others.

L, Y, R₁₃, and R₂₀ may each independently be the same as defined in Formula 2.

Formulas 2-3a to 2-3e may (e.g., may each) include a structure in which one or more hydrogens may be substituted with deuterium.

In Formulas 2-3a to 2-3e, *- is a site linked to the core structure of Formula 1. For example, in some embodiments, it may be linked to a benzene ring of the core structure of Formula 1. In some embodiments, when X₁ and X₂ are nitrogen atoms, X₁ and X₂ may be linked to a phenyl group bonded to a nitrogen atom.

In one or more embodiments, at least one selected from among R₁₄ to R₁₉ may be represented by any one selected from among Formulas A1 to A5, and the others (the remainder) may each independently be hydrogen or deuterium.

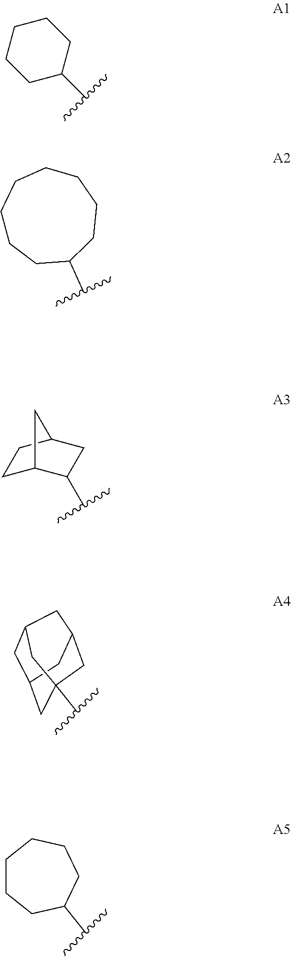 [SMILES: *C1CCCCC1 ; *C1CCCCCCCC1 ; *C1CC2CCC1C2 ; *C12CC3CC(CC(C3)C1)C2 ; *C1CCCCCC1]

In Formulas A1 to A5,

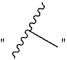

is a site linked to Formula 2. For example, it may be linked to at least one of the two benzene rings linked to the nitrogen atom of Formula 2.

In one or more embodiments, the polycyclic compound represented by Formula 1 may be any one selected from compounds of Compound Group 1. For example, the at least one functional layer may include at least one selected from the compounds of Compound Group 1.

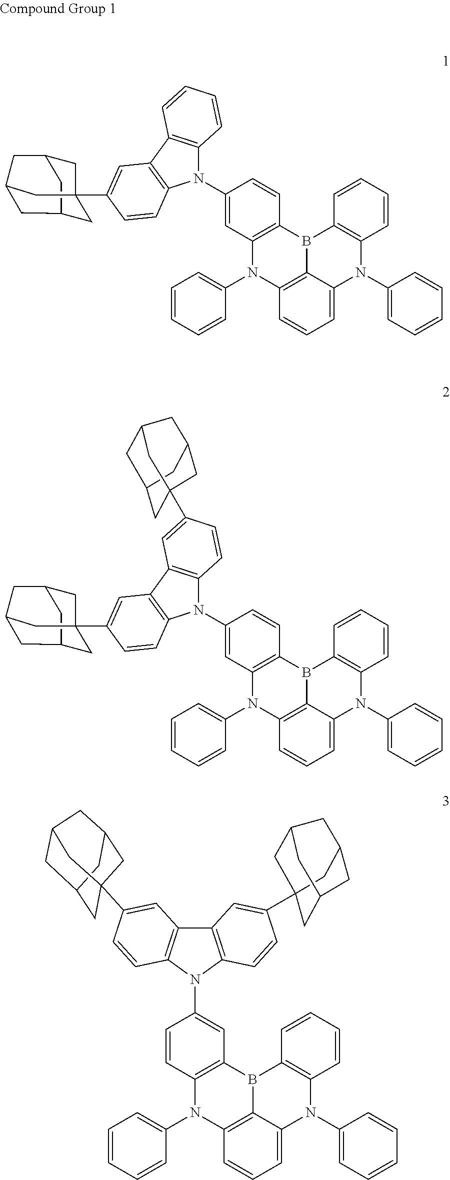 [SMILES: c1ccc(N2c3ccccc3B3c4ccc(-n5c6ccccc6c6cc(C78CC9CC(CC(C9)C7)C8)ccc65)cc4N(c4ccccc4)c4cccc2c43)cc1 ; c1ccc(N2c3ccccc3B3c4ccc(-n5c6ccc(C78CC9CC(CC(C9)C7)C8)cc6c6cc(C78CC9CC(CC(C9)C7)C8)ccc65)cc4N(c4ccccc4)c4cccc2c43)cc1 ; c1ccc(N2c3ccccc3B3c4cc(-n5c6ccc(C78CC9CC(CC(C9)C7)C8)cc6c6cc(C78CC9CC(CC(C9)C7)C8)ccc65)ccc4N(c4ccccc4)c4cccc2c43)cc1]

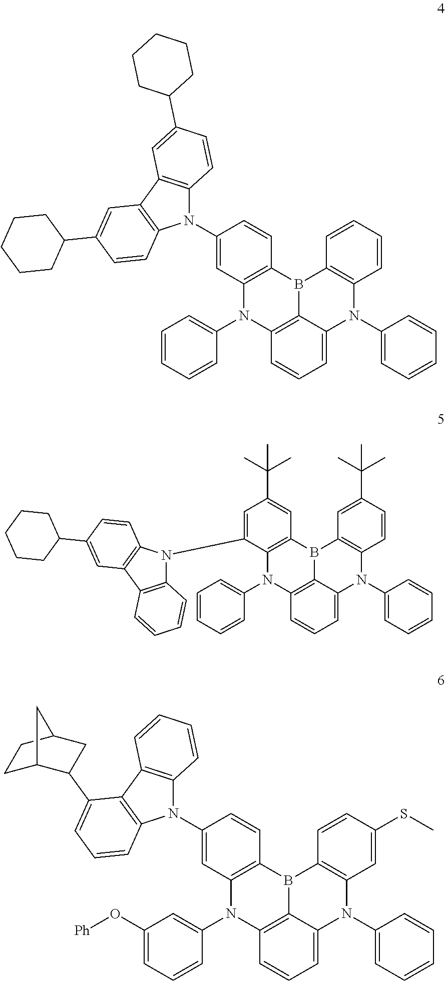 [SMILES: c1ccc(N2c3ccccc3B3c4ccc(-n5c6ccc(C7CCCCC7)cc6c6cc(C7CCCCC7)ccc65)cc4N(c4ccccc4)c4cccc2c43)cc1 ; CC(C)(C)c1ccc2c(c1)B1c3cc(C(C)(C)C)cc(-n4c5ccccc5c5cc(C6CCCCC6)ccc54)c3N(c3ccccc3)c3cccc(c31)N2c1ccccc1 ; CSc1ccc2c(c1)N(c1ccccc1)c1cccc3c1B2c1ccc(-n2c4ccccc4c4c(C5CC6CCC5C6)cccc42)cc1N3c1cccc(Oc2ccccc2)c1]

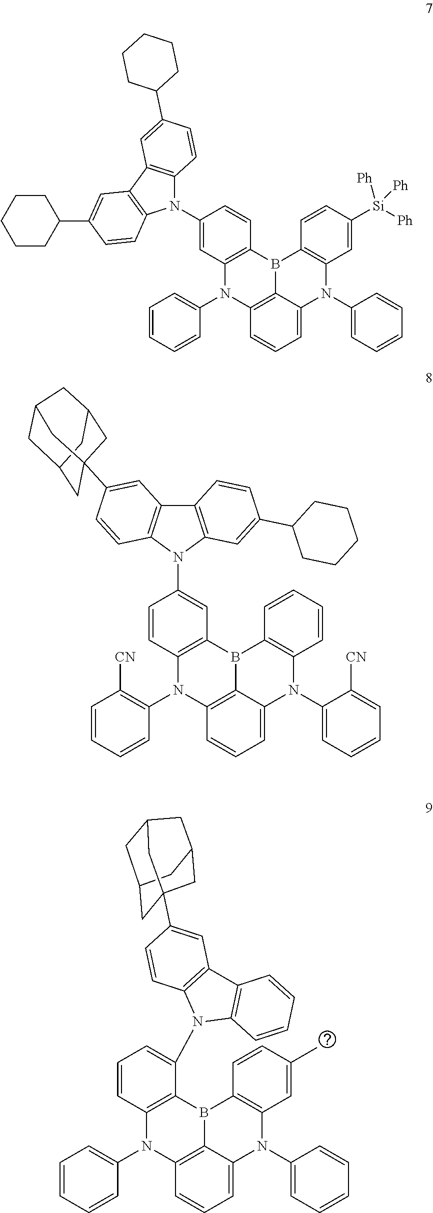 [SMILES: c1ccc(N2c3cc(-n4c5ccc(C6CCCCC6)cc5c5cc(C6CCCCC6)ccc54)ccc3B3c4ccc([Si](c5ccccc5)(c5ccccc5)c5ccccc5)cc4N(c4ccccc4)c4cccc2c43)cc1 ; N#Cc1ccccc1N1c2ccccc2B2c3cc(-n4c5ccc(C67CC8CC(CC(C8)C6)C7)cc5c5ccc(C6CCCCC6)cc54)ccc3N(c3ccccc3C#N)c3cccc1c32 ; Cc1ccc2c(c1)N(c1ccccc1)c1cccc3c1B2c1c(cccc1-n1c2ccccc2c2cc(C45CC6CC(CC(C6)C4)C5)ccc21)N3c1ccccc1]

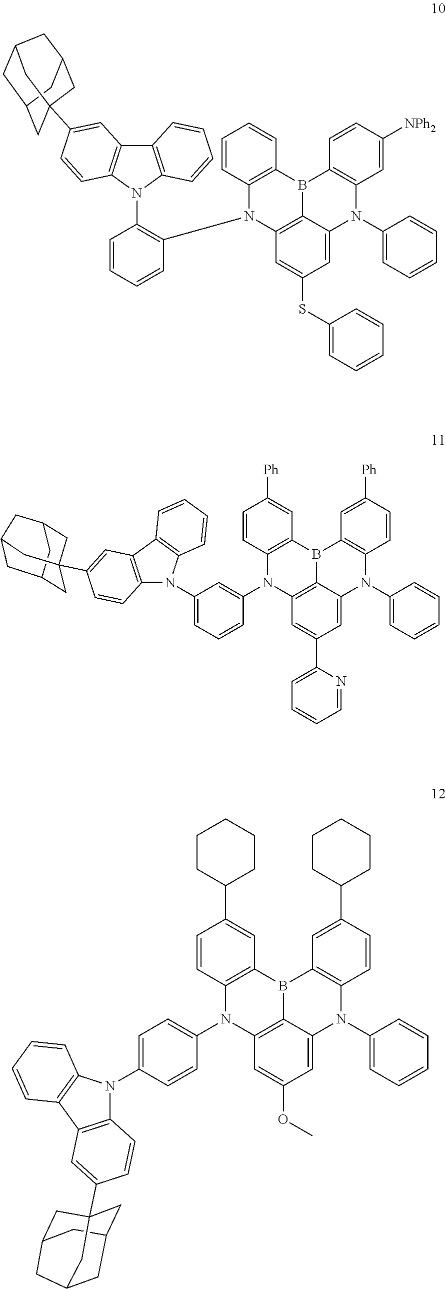

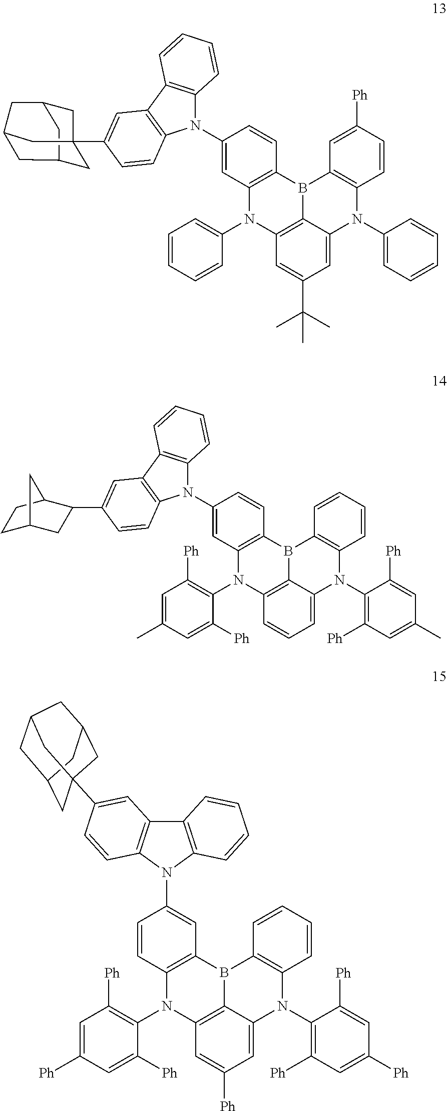 [SMILES: CC(C)(C)c1cc2c3c(c1)N(c1ccccc1)c1cc(-n4c5ccccc5c5cc(C67CC8CC(CC(C8)C6)C7)ccc54)ccc1B3c1cc(-c3ccccc3)ccc1N2c1ccccc1 ; Cc1cc(-c2ccccc2)c(N2c3ccccc3B3c4ccc(-n5c6ccccc6c6cc(C7CC8CCC7C8)ccc65)cc4N(c4c(-c5ccccc5)cc(C)cc4-c4ccccc4)c4cccc2c43)c(-c2ccccc2)c1 ; c1ccc(-c2cc(-c3ccccc3)c(N3c4ccccc4B4c5cc(-n6c7ccccc7c7cc(C89CC%10CC(CC(C%10)C8)C9)ccc76)ccc5N(c5c(-c6ccccc6)cc(-c6ccccc6)cc5-c5ccccc5)c5cc(-c6ccccc6)cc3c54)c(-c3ccccc3)c2)cc1]

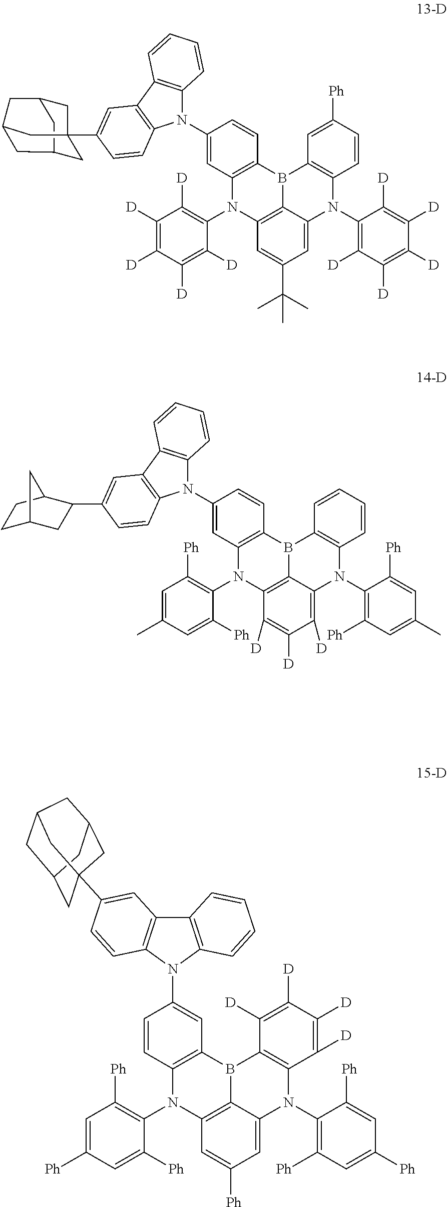

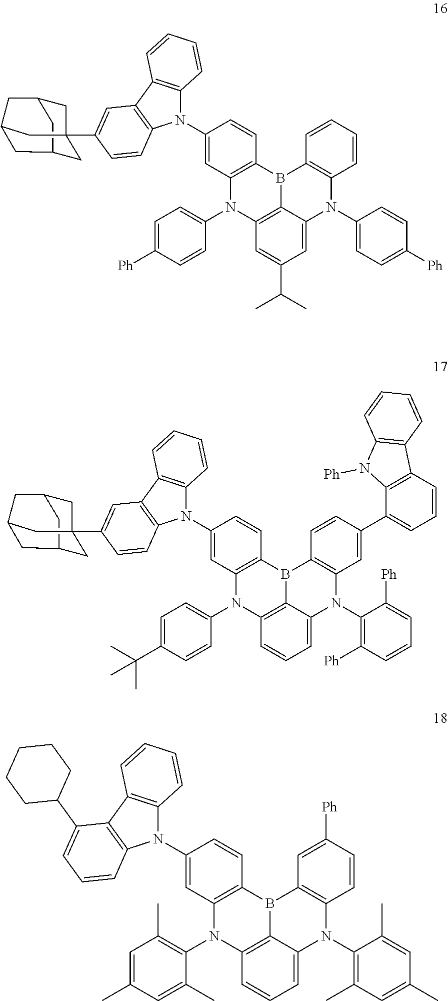 [SMILES: CC(C)c1cc2c3c(c1)N(c1ccc(-c4ccccc4)cc1)c1cc(-n4c5ccccc5c5cc(C67CC8CC(CC(C8)C6)C7)ccc54)ccc1B3c1ccccc1N2c1ccc(-c2ccccc2)cc1 ; CC(C)(C)c1ccc(N2c3cc(-n4c5ccccc5c5cc(C67CC8CC(CC(C8)C6)C7)ccc54)ccc3B3c4ccc(-c5cccc6c7ccccc7n(-c7ccccc7)c56)cc4N(c4c(-c5ccccc5)cccc4-c4ccccc4)c4cccc2c43)cc1 ; Cc1cc(C)c(N2c3ccc(-c4ccccc4)cc3B3c4ccc(-n5c6ccccc6c6c(C7CCCCC7)cccc65)cc4N(c4c(C)cc(C)cc4C)c4cccc2c43)c(C)c1]

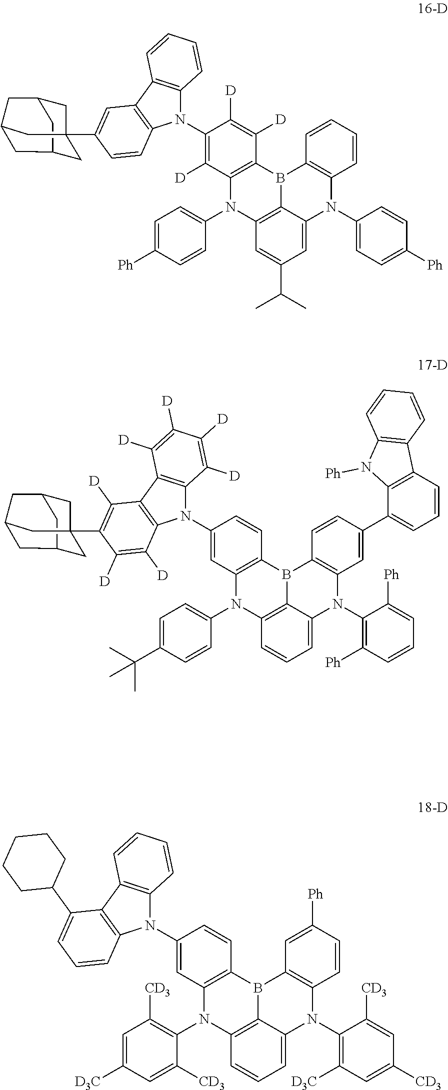

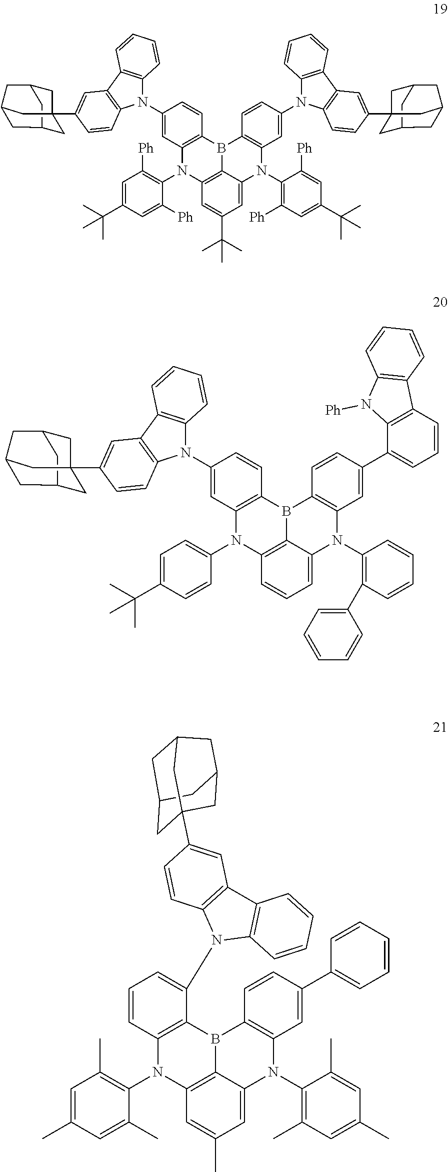

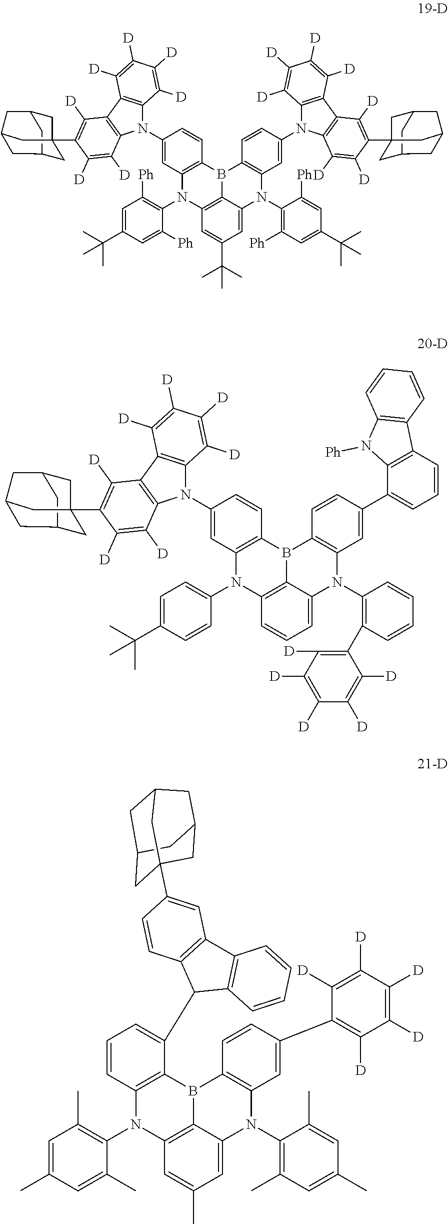

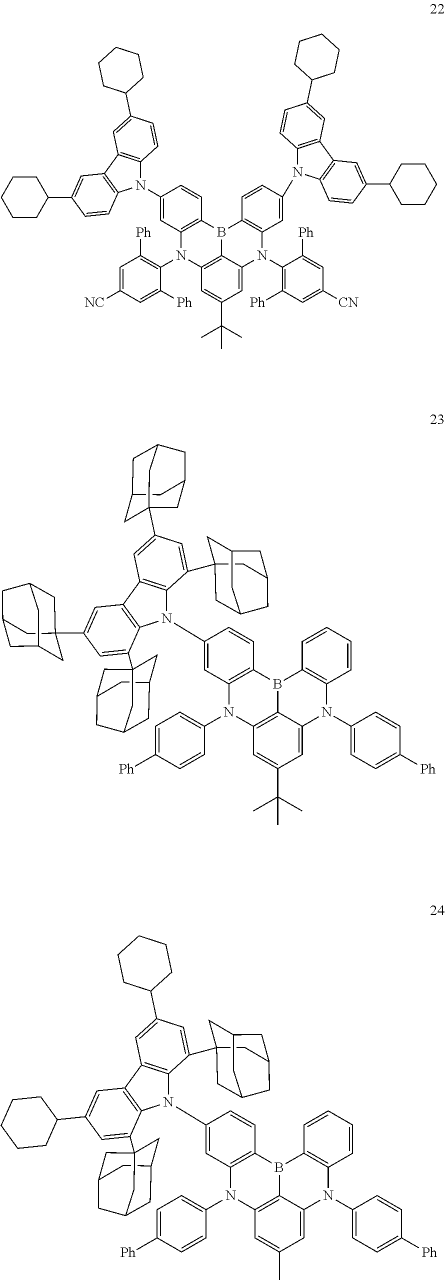

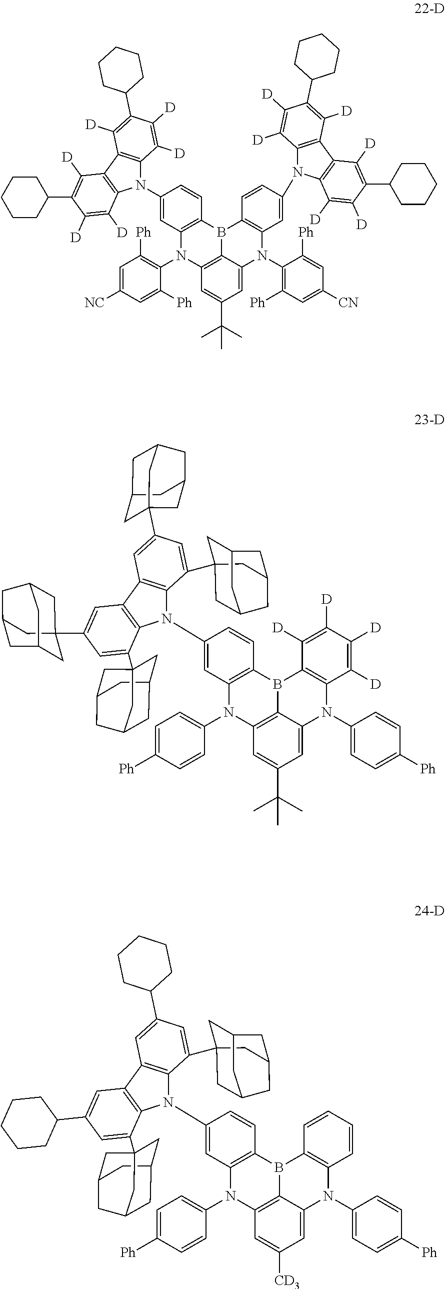

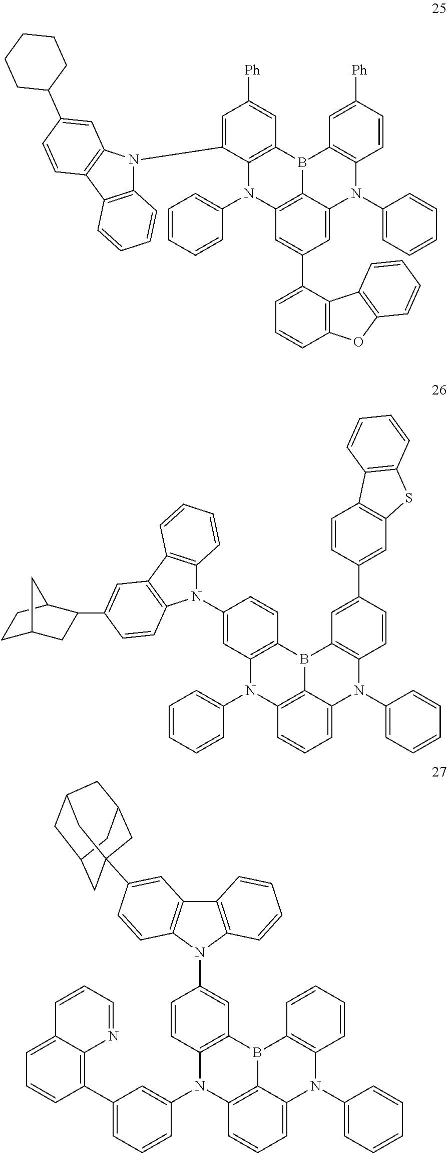 [SMILES: c1ccc(-c2ccc3c(c2)B2c4cc(-c5ccccc5)cc(-n5c6ccccc6c6ccc(C7CCCCC7)cc65)c4N(c4ccccc4)c4cc(-c5cccc6oc7ccccc7c56)cc(c42)N3c2ccccc2)cc1 ; c1ccc(N2c3ccc(-c4ccc5c(c4)sc4ccccc45)cc3B3c4ccc(-n5c6ccccc6c6cc(C7CC8CCC7C8)ccc65)cc4N(c4ccccc4)c4cccc2c43)cc1 ; c1ccc(N2c3ccccc3B3c4cc(-n5c6ccccc6c6cc(C78CC9CC(CC(C9)C7)C8)ccc65)ccc4N(c4cccc(-c5cccc6cccnc56)c4)c4cccc2c43)cc1]

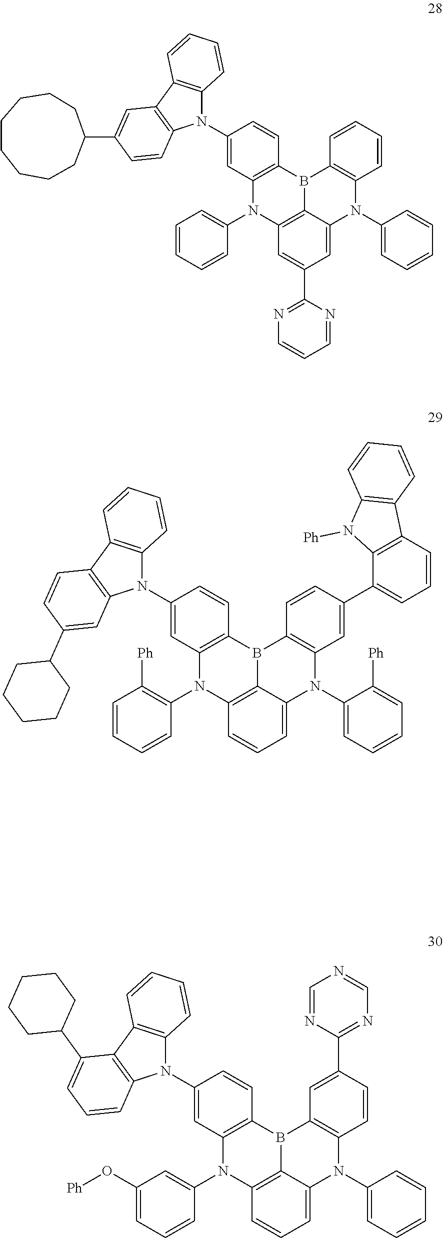 [SMILES: c1ccc(N2c3ccccc3B3c4ccc(-n5c6ccccc6c6cc(C7CCCCCCCC7)ccc65)cc4N(c4ccccc4)c4cc(-c5ncccn5)cc2c43)cc1 ; c1ccc(-c2ccccc2N2c3cc(-c4cccc5c6ccccc6n(-c6ccccc6)c45)ccc3B3c4ccc(-n5c6ccccc6c6ccc(C7CCCCC7)cc65)cc4N(c4ccccc4-c4ccccc4)c4cccc2c43)cc1 ; c1ccc(Oc2cccc(N3c4cc(-n5c6ccccc6c6c(C7CCCCC7)cccc65)ccc4B4c5cc(-c6ncncn6)ccc5N(c5ccccc5)c5cccc3c54)c2)cc1]

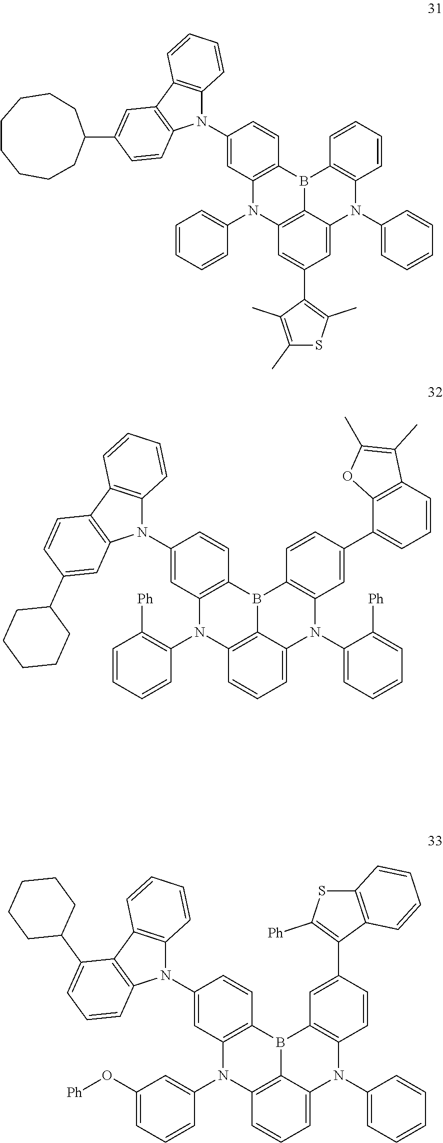 [SMILES: Cc1sc(C)c(-c2cc3c4c(c2)N(c2ccccc2)c2cc(-n5c6ccccc6c6cc(C7CCCCCCCC7)ccc65)ccc2B4c2ccccc2N3c2ccccc2)c1C ; Cc1oc2c(-c3ccc4c(c3)N(c3ccccc3-c3ccccc3)c3cccc5c3B4c3ccc(-n4c6ccccc6c6ccc(C7CCCCC7)cc64)cc3N5c3ccccc3-c3ccccc3)cccc2c1C ; c1ccc(Oc2cccc(N3c4cc(-n5c6ccccc6c6c(C7CCCCC7)cccc65)ccc4B4c5cc(-c6c(-c7ccccc7)sc7ccccc67)ccc5N(c5ccccc5)c5cccc3c54)c2)cc1]

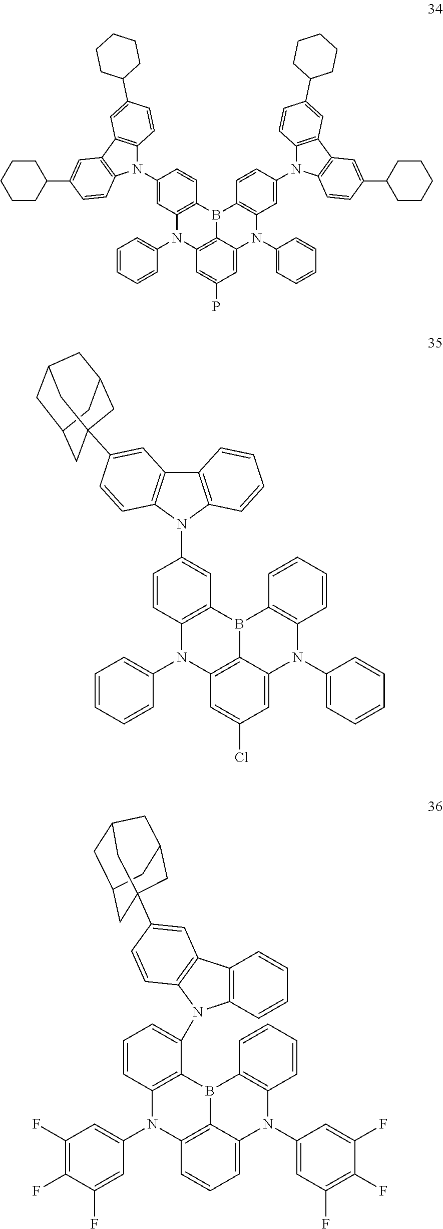

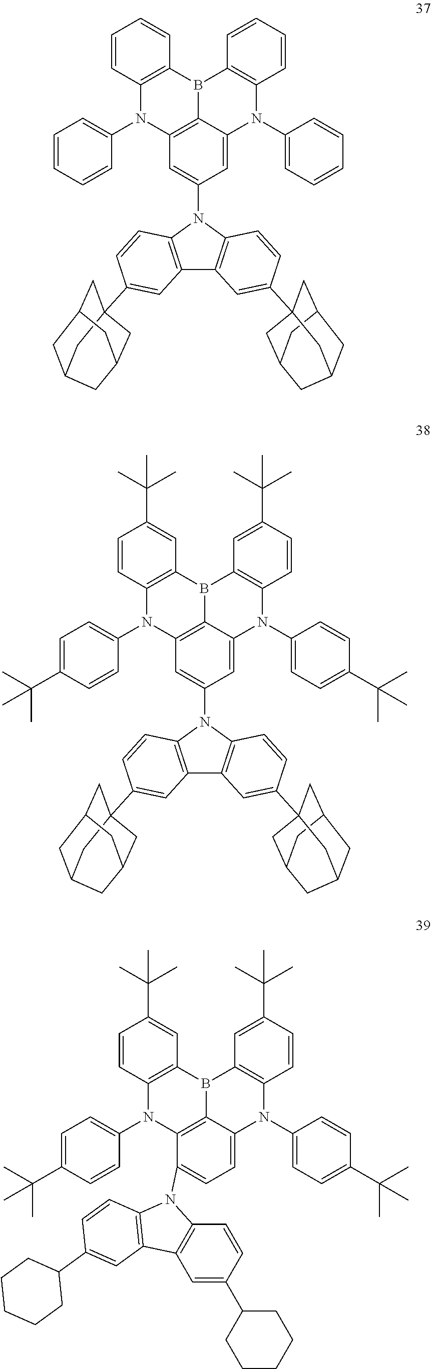 [SMILES: c1ccc(N2c3ccccc3B3c4ccccc4N(c4ccccc4)c4cc(-n5c6ccc(C78CC9CC(CC(C9)C7)C8)cc6c6cc(C78CC9CC(CC(C9)C7)C8)ccc65)cc2c43)cc1 ; CC(C)(C)c1ccc(N2c3ccc(C(C)(C)C)cc3B3c4cc(C(C)(C)C)ccc4N(c4ccc(C(C)(C)C)cc4)c4cc(-n5c6ccc(C78CC9CC(CC(C9)C7)C8)cc6c6cc(C78CC9CC(CC(C9)C7)C8)ccc65)cc2c43)cc1 ; CC(C)(C)c1ccc(N2c3ccc(C(C)(C)C)cc3B3c4cc(C(C)(C)C)ccc4N(c4ccc(C(C)(C)C)cc4)c4c(-n5c6ccc(C7CCCCC7)cc6c6cc(C7CCCCC7)ccc65)ccc2c43)cc1]

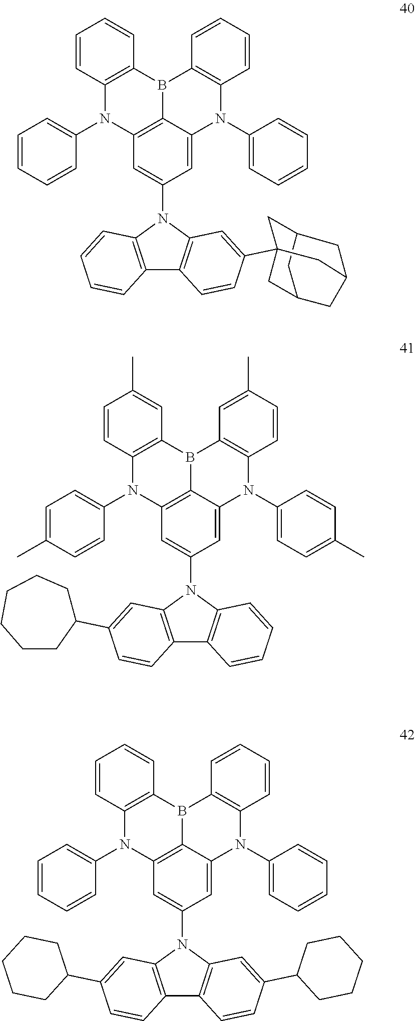 [SMILES: c1ccc(N2c3ccccc3B3c4ccccc4N(c4ccccc4)c4cc(-n5c6ccccc6c6ccc(C78CC9CC(CC(C9)C7)C8)cc65)cc2c43)cc1 ; Cc1ccc(N2c3ccc(C)cc3B3c4cc(C)ccc4N(c4ccc(C)cc4)c4cc(-n5c6ccccc6c6ccc(C7CCCCCC7)cc65)cc2c43)cc1 ; c1ccc(N2c3ccccc3B3c4ccccc4N(c4ccccc4)c4cc(-n5c6cc(C7CCCCC7)ccc6c6ccc(C7CCCCC7)cc65)cc2c43)cc1]

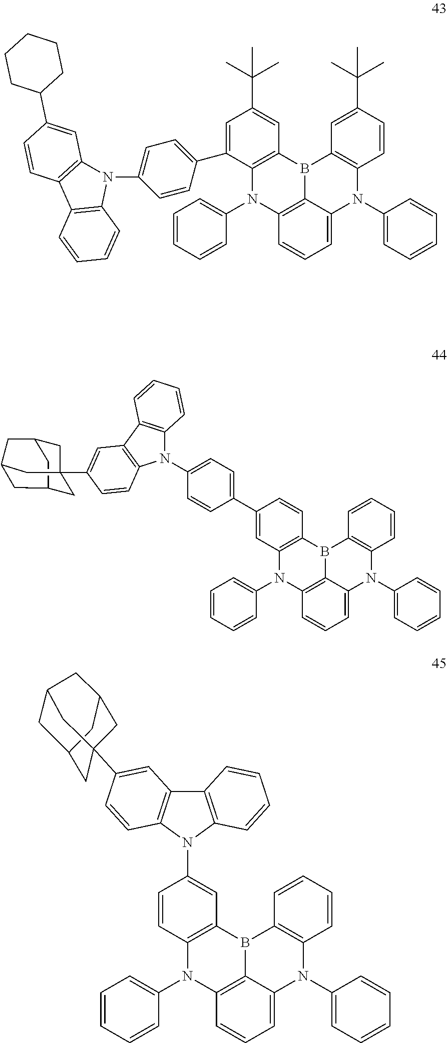 [SMILES: CC(C)(C)c1ccc2c(c1)B1c3cc(C(C)(C)C)cc(-c4ccc(-n5c6ccccc6c6ccc(C7CCCCC7)cc65)cc4)c3N(c3ccccc3)c3cccc(c31)N2c1ccccc1 ; c1ccc(N2c3ccccc3B3c4ccc(-c5ccc(-n6c7ccccc7c7cc(C89CC%10CC(CC(C%10)C8)C9)ccc76)cc5)cc4N(c4ccccc4)c4cccc2c43)cc1 ; c1ccc(N2c3ccccc3B3c4cc(-n5c6ccccc6c6cc(C78CC9CC(CC(C9)C7)C8)ccc65)ccc4N(c4ccccc4)c4cccc2c43)cc1]

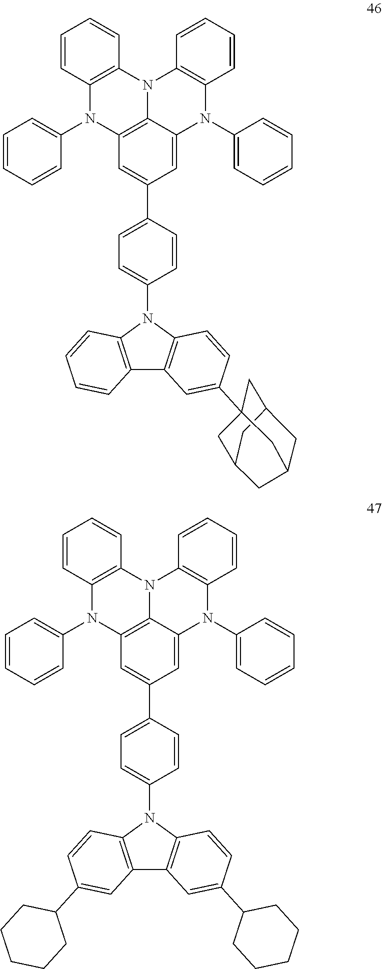 [SMILES: c1ccc(N2c3ccccc3N3c4ccccc4N(c4ccccc4)c4cc(-c5ccc(-n6c7ccccc7c7cc(C89CC%10CC(CC(C%10)C8)C9)ccc76)cc5)cc2c43)cc1 ; c1ccc(N2c3ccccc3N3c4ccccc4N(c4ccccc4)c4cc(-c5ccc(-n6c7ccc(C8CCCCC8)cc7c7cc(C8CCCCC8)ccc76)cc5)cc2c43)cc1]

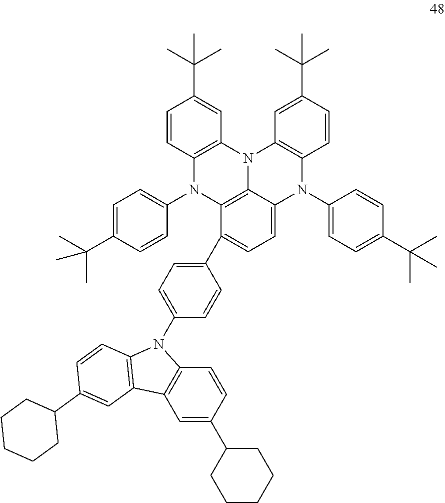 [SMILES: CC(C)(C)c1ccc(N2c3ccc(C(C)(C)C)cc3N3c4cc(C(C)(C)C)ccc4N(c4ccc(C(C)(C)C)cc4)c4c(-c5ccc(-n6c7ccc(C8CCCCC8)cc7c7cc(C8CCCCC8)ccc76)cc5)ccc2c43)cc1]

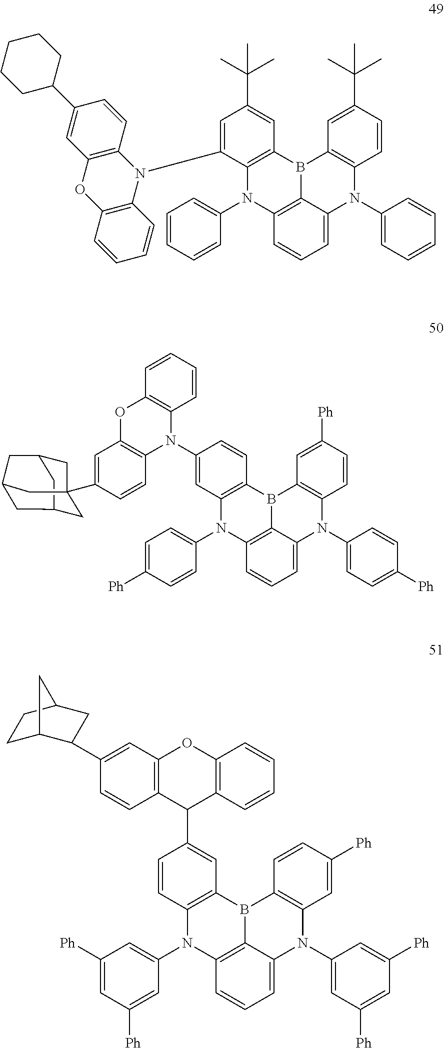 [SMILES: CC(C)(C)c1ccc2c(c1)B1c3cc(C(C)(C)C)cc(N4c5ccccc5Oc5cc(C6CCCCC6)ccc54)c3N(c3ccccc3)c3cccc(c31)N2c1ccccc1 ; c1ccc(-c2ccc(N3c4ccc(-c5ccccc5)cc4B4c5ccc(N6c7ccccc7Oc7cc(C89CC%10CC(CC(C%10)C8)C9)ccc76)cc5N(c5ccc(-c6ccccc6)cc5)c5cccc3c54)cc2)cc1 ; c1ccc(-c2cc(-c3ccccc3)cc(N3c4ccc(C5c6ccccc6Oc6cc(C7CC8CCC7C8)ccc65)cc4B4c5ccc(-c6ccccc6)cc5N(c5cc(-c6ccccc6)cc(-c6ccccc6)c5)c5cccc3c54)c2)cc1]

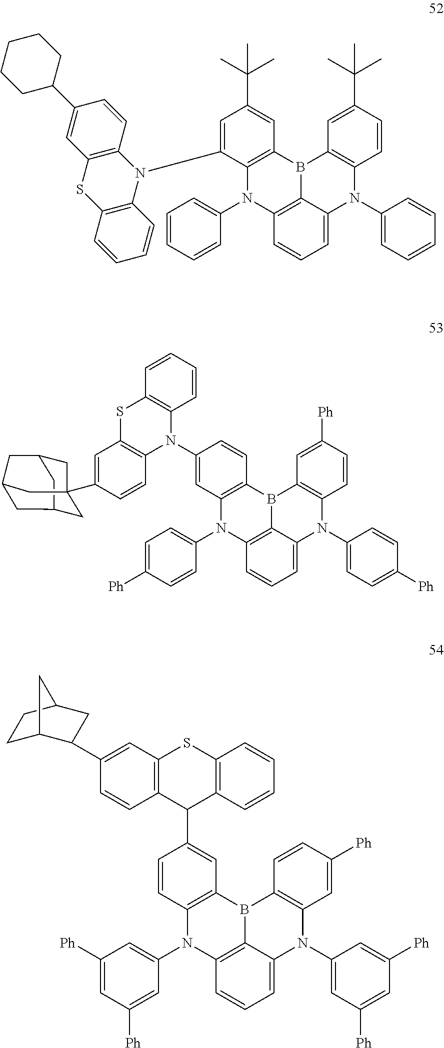 [SMILES: CC(C)(C)c1ccc2c(c1)B1c3cc(C(C)(C)C)cc(N4c5ccccc5Sc5cc(C6CCCCC6)ccc54)c3N(c3ccccc3)c3cccc(c31)N2c1ccccc1 ; c1ccc(-c2ccc(N3c4ccc(-c5ccccc5)cc4B4c5ccc(N6c7ccccc7Sc7cc(C89CC%10CC(CC(C%10)C8)C9)ccc76)cc5N(c5ccc(-c6ccccc6)cc5)c5cccc3c54)cc2)cc1 ; c1ccc(-c2cc(-c3ccccc3)cc(N3c4ccc(C5c6ccccc6Sc6cc(C7CC8CCC7C8)ccc65)cc4B4c5ccc(-c6ccccc6)cc5N(c5cc(-c6ccccc6)cc(-c6ccccc6)c5)c5cccc3c54)c2)cc1]

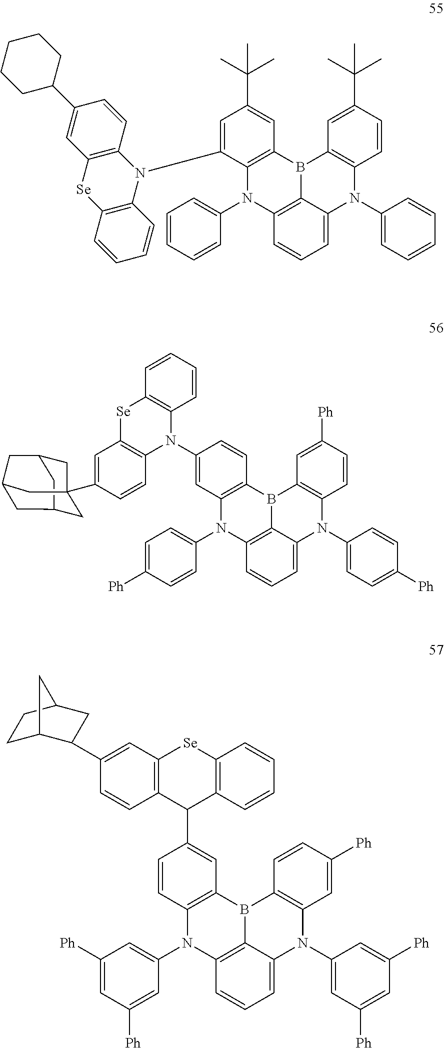 [SMILES: CC(C)(C)c1ccc2c(c1)B1c3cc(C(C)(C)C)cc(N4c5ccccc5[Se]c5cc(C6CCCCC6)ccc54)c3N(c3ccccc3)c3cccc(c31)N2c1ccccc1 ; c1ccc(-c2ccc(N3c4ccc(-c5ccccc5)cc4B4c5ccc(N6c7ccccc7[Se]c7cc(C89CC%10CC(CC(C%10)C8)C9)ccc76)cc5N(c5ccc(-c6ccccc6)cc5)c5cccc3c54)cc2)cc1 ; c1ccc(-c2cc(-c3ccccc3)cc(N3c4ccc(C5c6ccccc6[Se]c6cc(C7CC8CCC7C8)ccc65)cc4B4c5ccc(-c6ccccc6)cc5N(c5cc(-c6ccccc6)cc(-c6ccccc6)c5)c5cccc3c54)c2)cc1]

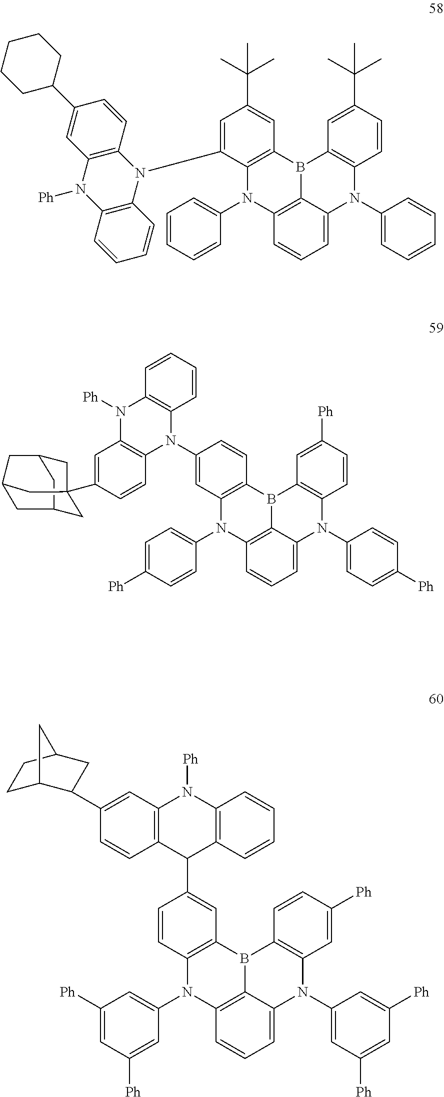 [SMILES: CC(C)(C)c1ccc2c(c1)B1c3cc(C(C)(C)C)cc(N4c5ccccc5N(c5ccccc5)c5cc(C6CCCCC6)ccc54)c3N(c3ccccc3)c3cccc(c31)N2c1ccccc1 ; c1ccc(-c2ccc(N3c4ccc(-c5ccccc5)cc4B4c5ccc(N6c7ccccc7N(c7ccccc7)c7cc(C89CC%10CC(CC(C%10)C8)C9)ccc76)cc5N(c5ccc(-c6ccccc6)cc5)c5cccc3c54)cc2)cc1 ; c1ccc(-c2cc(-c3ccccc3)cc(N3c4ccc(C5c6ccccc6N(c6ccccc6)c6cc(C7CC8CCC7C8)ccc65)cc4B4c5ccc(-c6ccccc6)cc5N(c5cc(-c6ccccc6)cc(-c6ccccc6)c5)c5cccc3c54)c2)cc1]

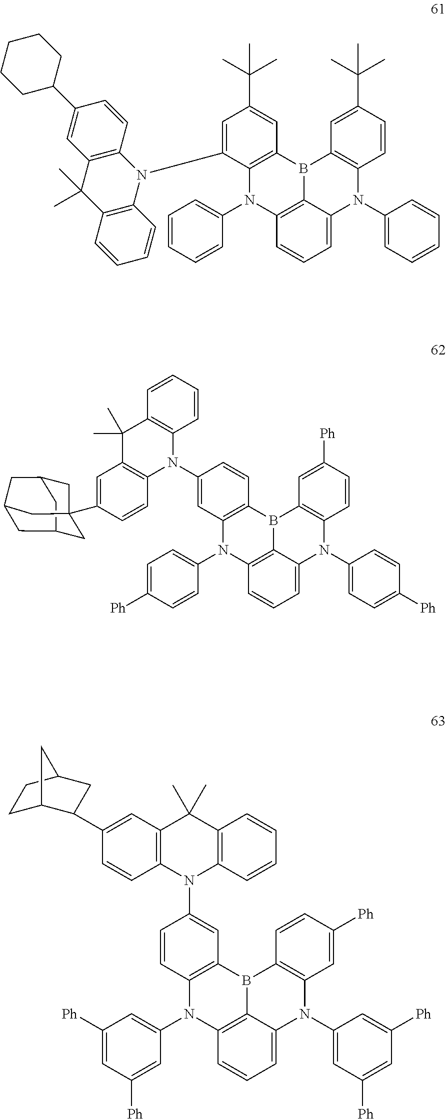 [SMILES: CC(C)(C)c1ccc2c(c1)B1c3cc(C(C)(C)C)cc(N4c5ccccc5C(C)(C)c5cc(C6CCCCC6)ccc54)c3N(c3ccccc3)c3cccc(c31)N2c1ccccc1 ; CC1(C)c2ccccc2N(c2ccc3c(c2)N(c2ccc(-c4ccccc4)cc2)c2cccc4c2B3c2cc(-c3ccccc3)ccc2N4c2ccc(-c3ccccc3)cc2)c2ccc(C34CC5CC(CC(C5)C3)C4)cc21 ; CC1(C)c2ccccc2N(c2ccc3c(c2)B2c4ccc(-c5ccccc5)cc4N(c4cc(-c5ccccc5)cc(-c5ccccc5)c4)c4cccc(c42)N3c2cc(-c3ccccc3)cc(-c3ccccc3)c2)c2ccc(C3CC4CCC3C4)cc21]

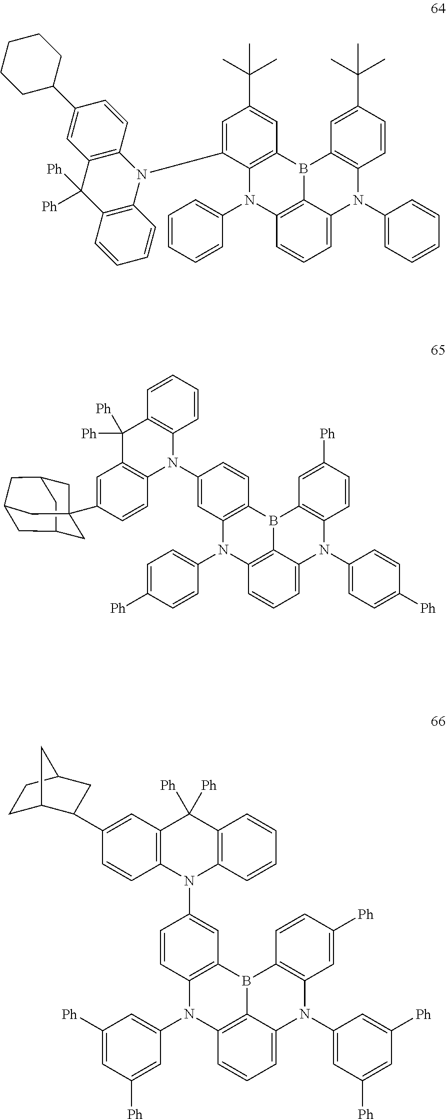 [SMILES: CC(C)(C)c1ccc2c(c1)B1c3cc(C(C)(C)C)cc(N4c5ccccc5C(c5ccccc5)(c5ccccc5)c5cc(C6CCCCC6)ccc54)c3N(c3ccccc3)c3cccc(c31)N2c1ccccc1 ; c1ccc(-c2ccc(N3c4ccc(-c5ccccc5)cc4B4c5ccc(N6c7ccccc7C(c7ccccc7)(c7ccccc7)c7cc(C89CC%10CC(CC(C%10)C8)C9)ccc76)cc5N(c5ccc(-c6ccccc6)cc5)c5cccc3c54)cc2)cc1 ; c1ccc(-c2cc(-c3ccccc3)cc(N3c4ccc(N5c6ccccc6C(c6ccccc6)(c6ccccc6)c6cc(C7CC8CCC7C8)ccc65)cc4B4c5ccc(-c6ccccc6)cc5N(c5cc(-c6ccccc6)cc(-c6ccccc6)c5)c5cccc3c54)c2)cc1]

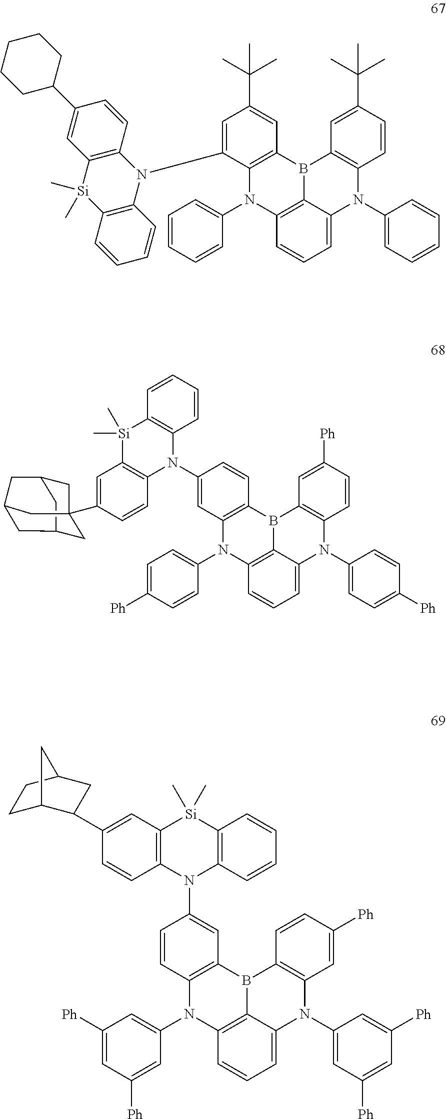 [SMILES: CC(C)(C)c1ccc2c(c1)B1c3cc(C(C)(C)C)cc(N4c5ccccc5[Si](C)(C)c5cc(C6CCCCC6)ccc54)c3N(c3ccccc3)c3cccc(c31)N2c1ccccc1 ; C[Si]1(C)c2ccccc2N(c2ccc3c(c2)N(c2ccc(-c4ccccc4)cc2)c2cccc4c2B3c2cc(-c3ccccc3)ccc2N4c2ccc(-c3ccccc3)cc2)c2ccc(C34CC5CC(CC(C5)C3)C4)cc21 ; C[Si]1(C)c2ccccc2N(c2ccc3c(c2)B2c4ccc(-c5ccccc5)cc4N(c4cc(-c5ccccc5)cc(-c5ccccc5)c4)c4cccc(c42)N3c2cc(-c3ccccc3)cc(-c3ccccc3)c2)c2ccc(C3CC4CCC3C4)cc21]

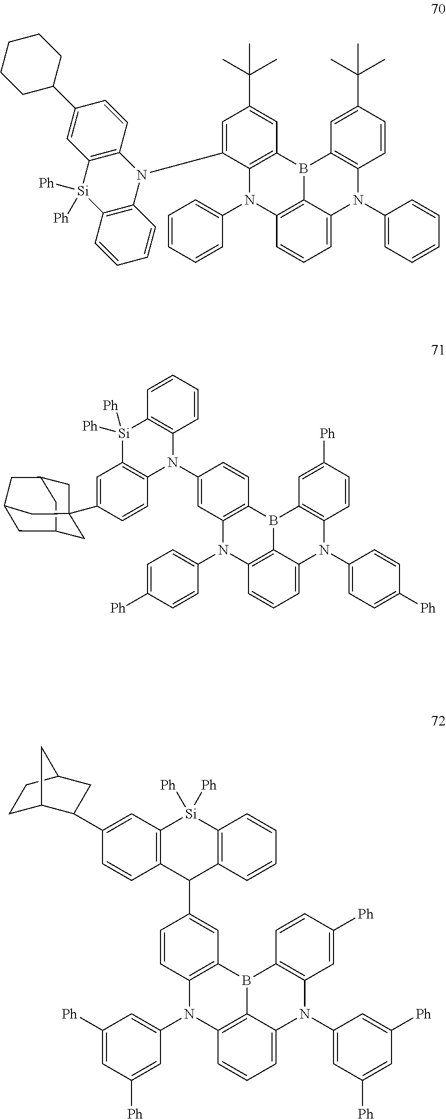 [SMILES: CC(C)(C)c1ccc2c(c1)B1c3cc(C(C)(C)C)cc(N4c5ccccc5[Si](c5ccccc5)(c5ccccc5)c5cc(C6CCCCC6)ccc54)c3N(c3ccccc3)c3cccc(c31)N2c1ccccc1 ; c1ccc(-c2ccc(N3c4ccc(-c5ccccc5)cc4B4c5ccc(N6c7ccccc7[Si](c7ccccc7)(c7ccccc7)c7cc(C89CC%10CC(CC(C%10)C8)C9)ccc76)cc5N(c5ccc(-c6ccccc6)cc5)c5cccc3c54)cc2)cc1 ; c1ccc(-c2cc(-c3ccccc3)cc(N3c4ccc(C5c6ccccc6[Si](c6ccccc6)(c6ccccc6)c6cc(C7CC8CCC7C8)ccc65)cc4B4c5ccc(-c6ccccc6)cc5N(c5cc(-c6ccccc6)cc(-c6ccccc6)c5)c5cccc3c54)c2)cc1]

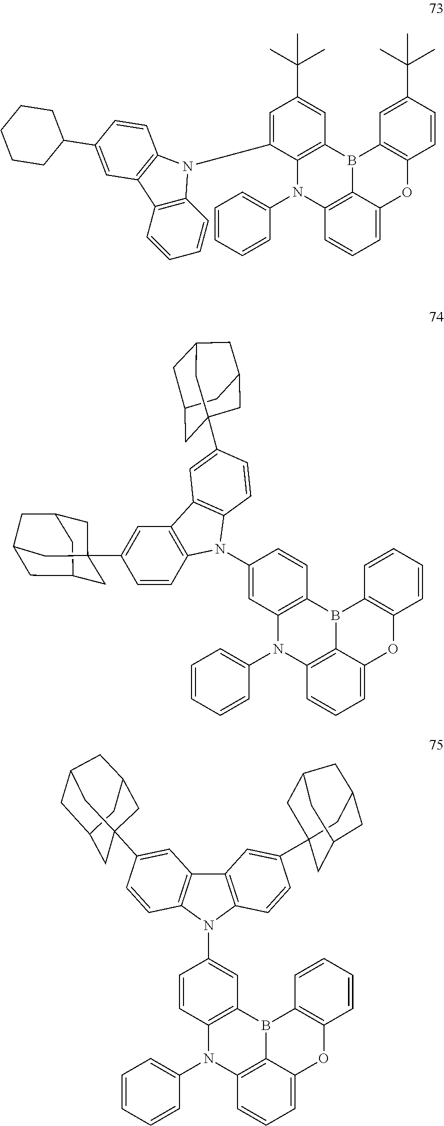 [SMILES: CC(C)(C)c1ccc2c(c1)B1c3cc(C(C)(C)C)cc(-n4c5ccccc5c5cc(C6CCCCC6)ccc54)c3N(c3ccccc3)c3cccc(c31)O2 ; c1ccc(N2c3cc(-n4c5ccc(C67CC8CC(CC(C8)C6)C7)cc5c5cc(C67CC8CC(CC(C8)C6)C7)ccc54)ccc3B3c4ccccc4Oc4cccc2c43)cc1 ; c1ccc(N2c3ccc(-n4c5ccc(C67CC8CC(CC(C8)C6)C7)cc5c5cc(C67CC8CC(CC(C8)C6)C7)ccc54)cc3B3c4ccccc4Oc4cccc2c43)cc1]

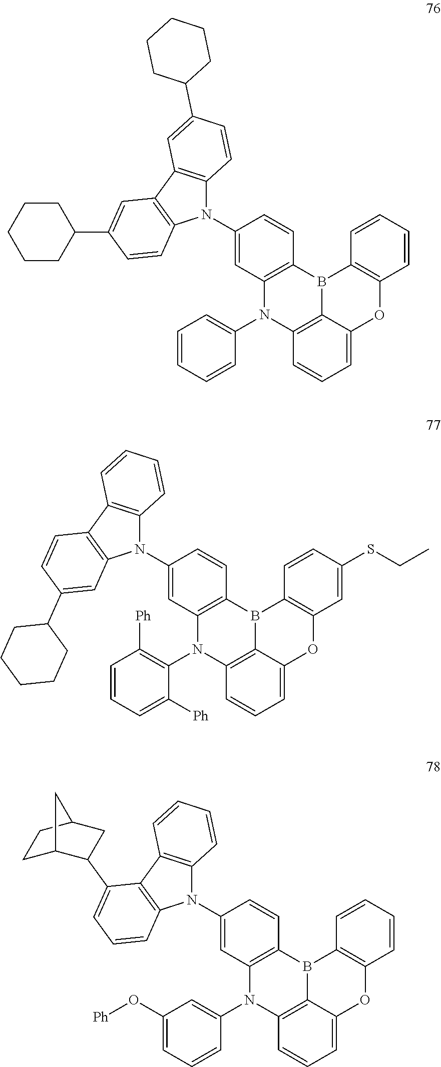 [SMILES: c1ccc(N2c3cc(-n4c5ccc(C6CCCCC6)cc5c5cc(C6CCCCC6)ccc54)ccc3B3c4ccccc4Oc4cccc2c43)cc1 ; CCSc1ccc2c(c1)Oc1cccc3c1B2c1ccc(-n2c4ccccc4c4ccc(C5CCCCC5)cc42)cc1N3c1c(-c2ccccc2)cccc1-c1ccccc1 ; c1ccc(Oc2cccc(N3c4cc(-n5c6ccccc6c6c(C7CC8CCC7C8)cccc65)ccc4B4c5ccccc5Oc5cccc3c54)c2)cc1]

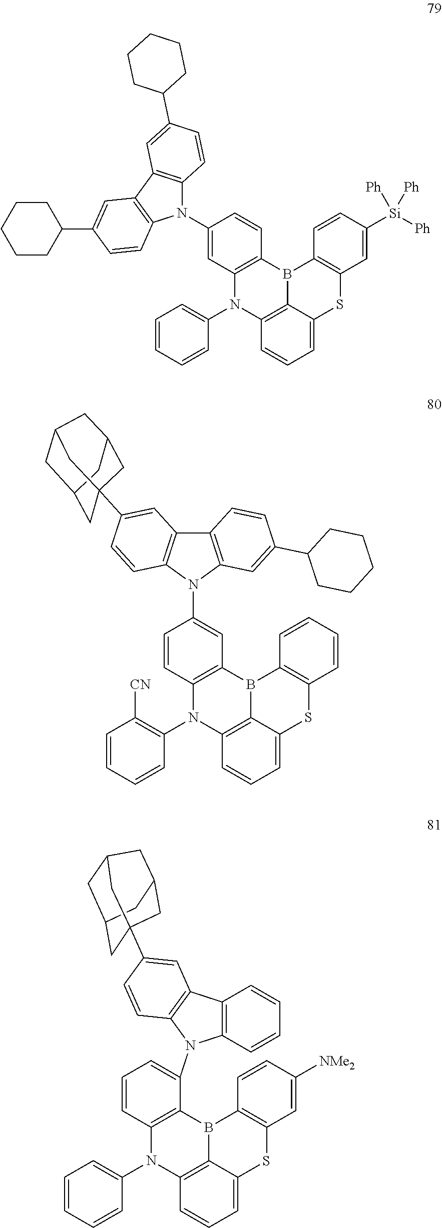 [SMILES: c1ccc(N2c3cc(-n4c5ccc(C6CCCCC6)cc5c5cc(C6CCCCC6)ccc54)ccc3B3c4ccc([Si](c5ccccc5)(c5ccccc5)c5ccccc5)cc4Sc4cccc2c43)cc1 ; N#Cc1ccccc1N1c2ccc(-n3c4ccc(C56CC7CC(CC(C7)C5)C6)cc4c4ccc(C5CCCCC5)cc43)cc2B2c3ccccc3Sc3cccc1c32 ; CN(C)c1ccc2c(c1)Sc1cccc3c1B2c1c(cccc1-n1c2ccccc2c2cc(C45CC6CC(CC(C6)C4)C5)ccc21)N3c1ccccc1]

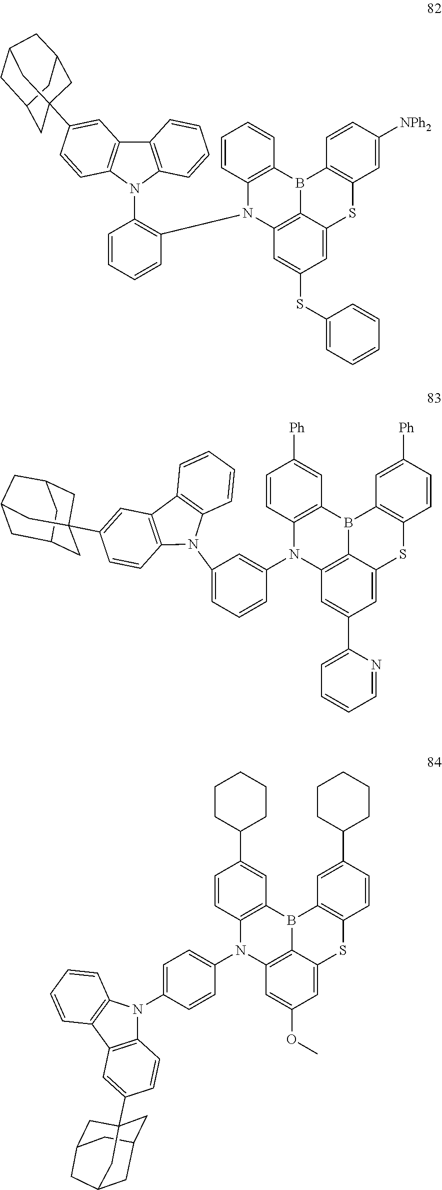

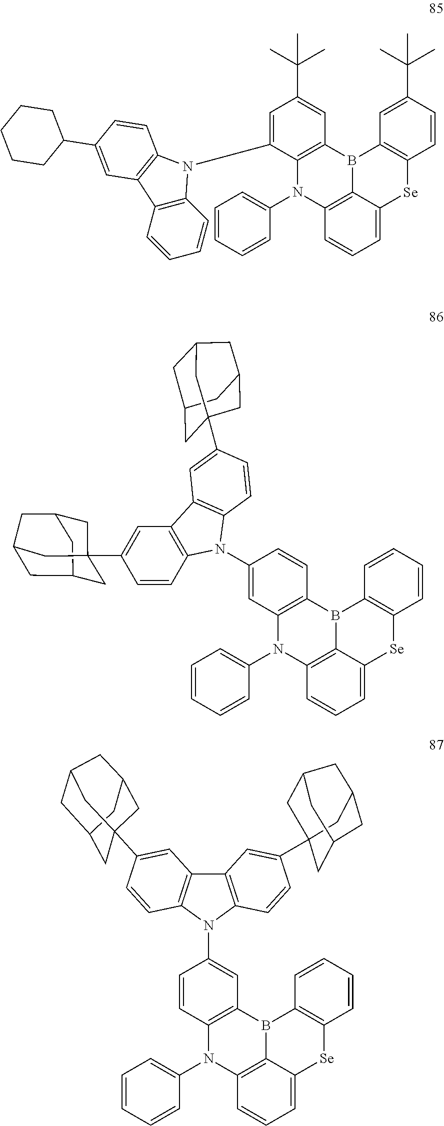 [SMILES: CC(C)(C)c1ccc2c(c1)B1c3cc(C(C)(C)C)cc(-n4c5ccccc5c5cc(C6CCCCC6)ccc54)c3N(c3ccccc3)c3cccc(c31)[Se]2 ; c1ccc(N2c3cc(-n4c5ccc(C67CC8CC(CC(C8)C6)C7)cc5c5cc(C67CC8CC(CC(C8)C6)C7)ccc54)ccc3B3c4ccccc4[Se]c4cccc2c43)cc1 ; c1ccc(N2c3ccc(-n4c5ccc(C67CC8CC(CC(C8)C6)C7)cc5c5cc(C67CC8CC(CC(C8)C6)C7)ccc54)cc3B3c4ccccc4[Se]c4cccc2c43)cc1]

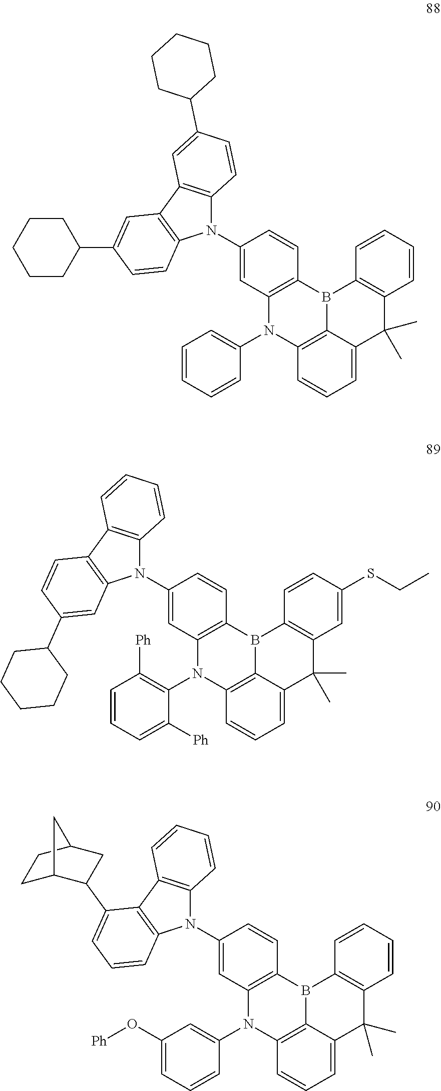 [SMILES: CC1(C)c2ccccc2B2c3ccc(-n4c5ccc(C6CCCCC6)cc5c5cc(C6CCCCC6)ccc54)cc3N(c3ccccc3)c3cccc1c32 ; CCSc1ccc2c(c1)C(C)(C)c1cccc3c1B2c1ccc(-n2c4ccccc4c4ccc(C5CCCCC5)cc42)cc1N3c1c(-c2ccccc2)cccc1-c1ccccc1 ; CC1(C)c2ccccc2B2c3ccc(-n4c5ccccc5c5c(C6CC7CCC6C7)cccc54)cc3N(c3cccc(Oc4ccccc4)c3)c3cccc1c32]

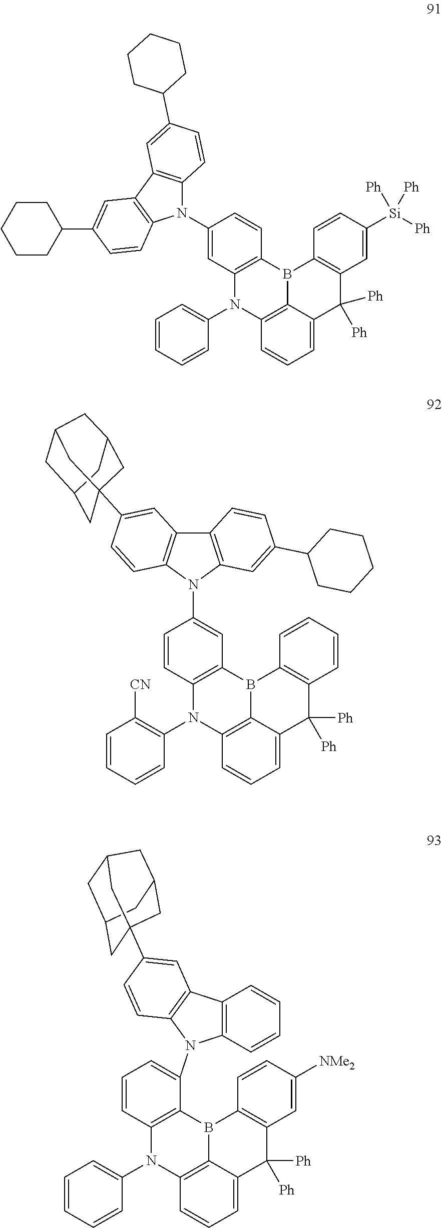 [SMILES: c1ccc(N2c3cc(-n4c5ccc(C6CCCCC6)cc5c5cc(C6CCCCC6)ccc54)ccc3B3c4ccc([Si](c5ccccc5)(c5ccccc5)c5ccccc5)cc4C(c4ccccc4)(c4ccccc4)c4cccc2c43)cc1 ; N#Cc1ccccc1N1c2ccc(-n3c4ccc(C56CC7CC(CC(C7)C5)C6)cc4c4ccc(C5CCCCC5)cc43)cc2B2c3ccccc3C(c3ccccc3)(c3ccccc3)c3cccc1c32 ; CN(C)c1ccc2c(c1)C(c1ccccc1)(c1ccccc1)c1cccc3c1B2c1c(cccc1-n1c2ccccc2c2cc(C45CC6CC(CC(C6)C4)C5)ccc21)N3c1ccccc1]

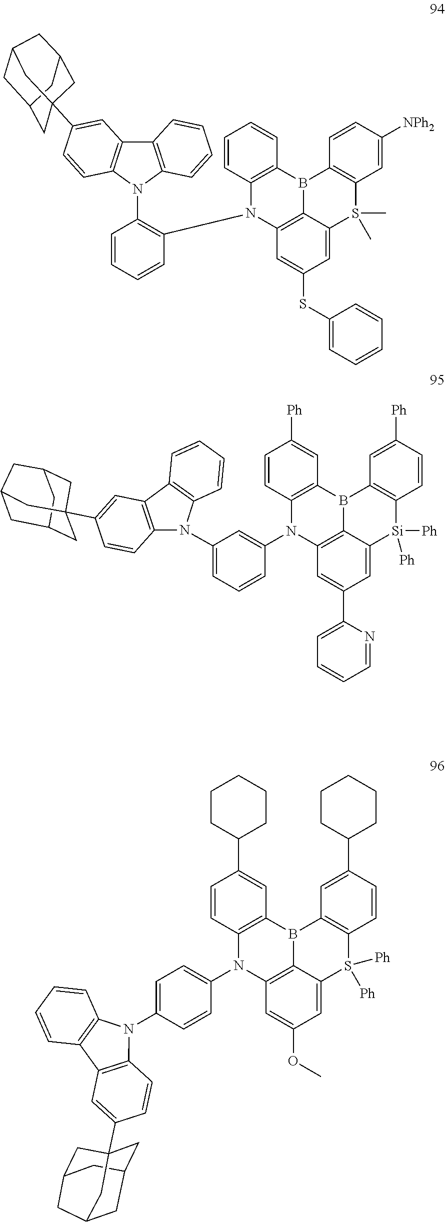

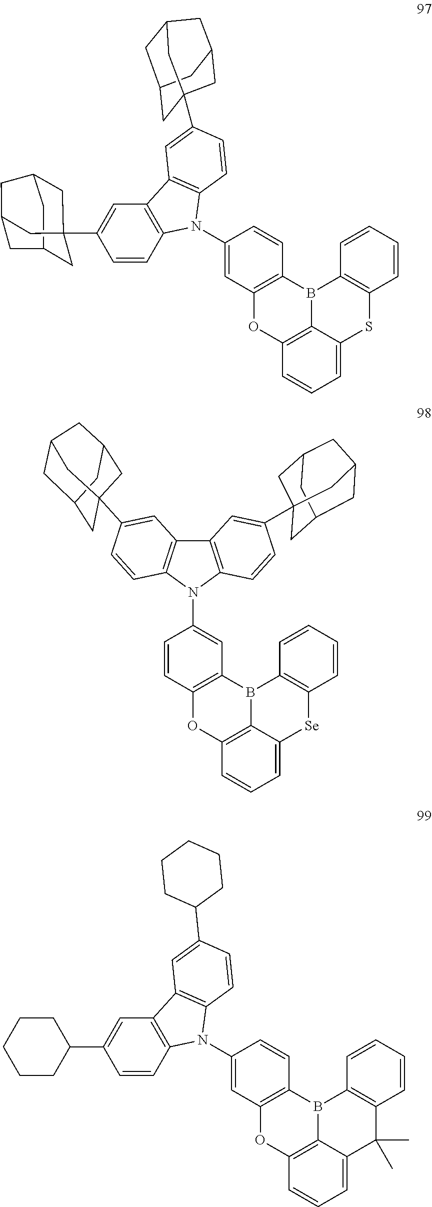 [SMILES: c1ccc2c(c1)Sc1cccc3c1B2c1ccc(-n2c4ccc(C56CC7CC(CC(C7)C5)C6)cc4c4cc(C56CC7CC(CC(C7)C5)C6)ccc42)cc1O3 ; c1ccc2c(c1)[Se]c1cccc3c1B2c1cc(-n2c4ccc(C56CC7CC(CC(C7)C5)C6)cc4c4cc(C56CC7CC(CC(C7)C5)C6)ccc42)ccc1O3 ; CC1(C)c2ccccc2B2c3ccc(-n4c5ccc(C6CCCCC6)cc5c5cc(C6CCCCC6)ccc54)cc3Oc3cccc1c32]

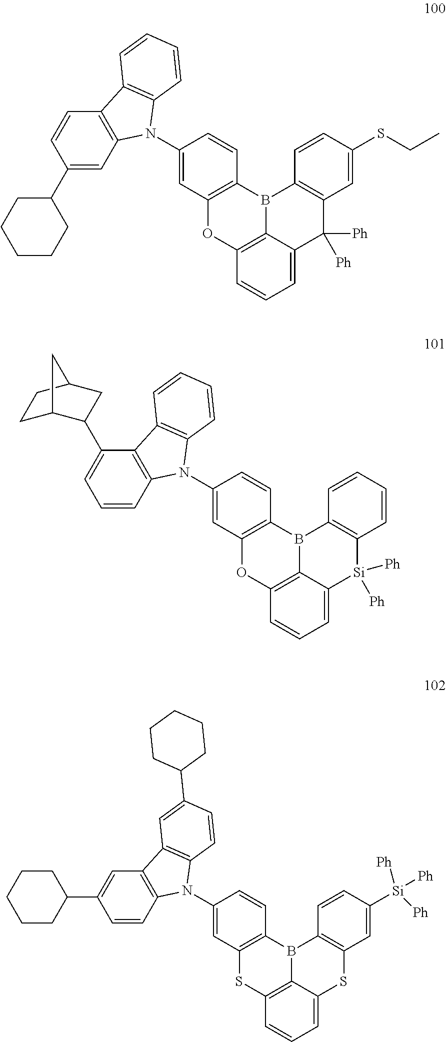 [SMILES: CCSc1ccc2c(c1)C(c1ccccc1)(c1ccccc1)c1cccc3c1B2c1ccc(-n2c4ccccc4c4ccc(C5CCCCC5)cc42)cc1O3 ; c1ccc([Si]2(c3ccccc3)c3ccccc3B3c4ccc(-n5c6ccccc6c6c(C7CC8CCC7C8)cccc65)cc4Oc4cccc2c43)cc1 ; c1ccc([Si](c2ccccc2)(c2ccccc2)c2ccc3c(c2)Sc2cccc4c2B3c2ccc(-n3c5ccc(C6CCCCC6)cc5c5cc(C6CCCCC6)ccc53)cc2S4)cc1]

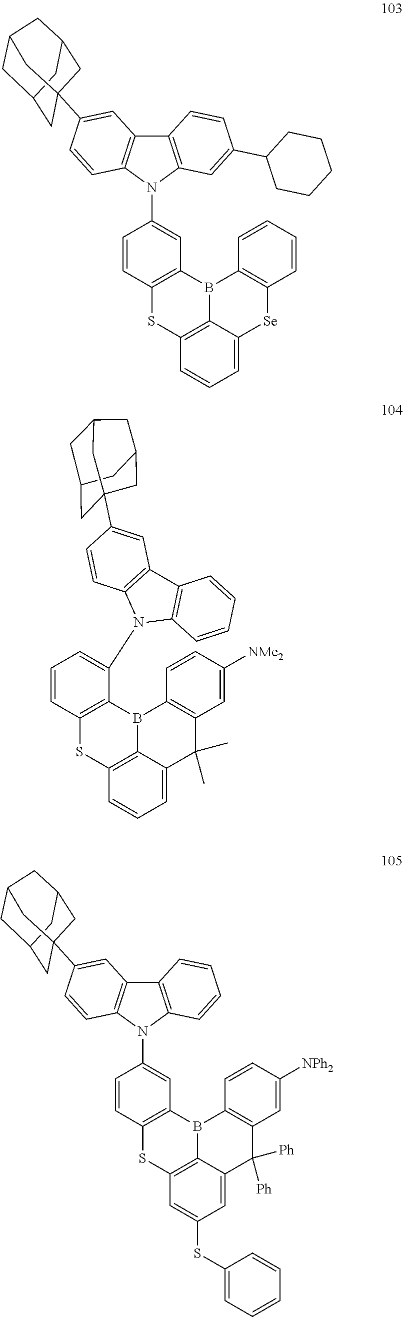

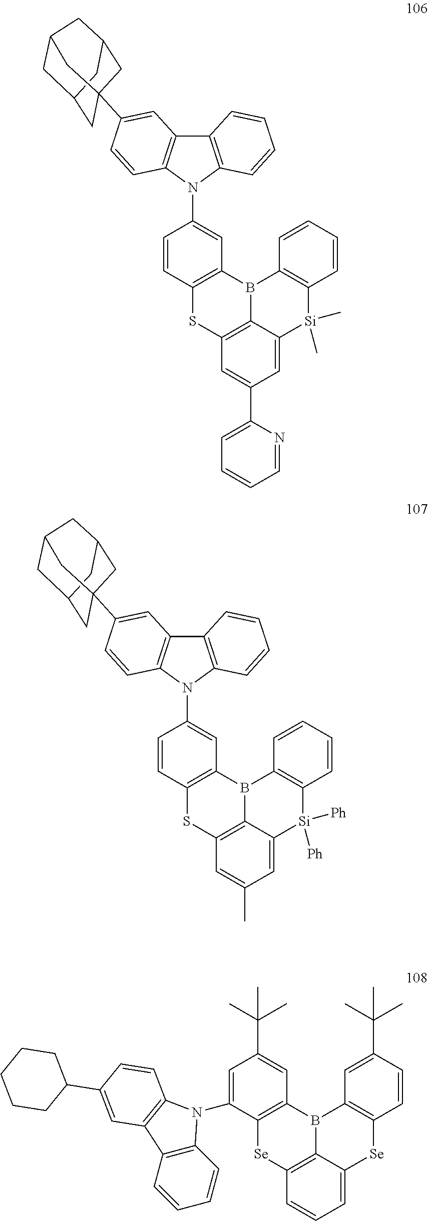 [SMILES: C[Si]1(C)c2ccccc2B2c3cc(-n4c5ccccc5c5cc(C67CC8CC(CC(C8)C6)C7)ccc54)ccc3Sc3cc(-c4ccccn4)cc1c32 ; Cc1cc2c3c(c1)[Si](c1ccccc1)(c1ccccc1)c1ccccc1B3c1cc(-n3c4ccccc4c4cc(C56CC7CC(CC(C7)C5)C6)ccc43)ccc1S2 ; CC(C)(C)c1ccc2c(c1)B1c3cc(C(C)(C)C)cc(-n4c5ccccc5c5cc(C6CCCCC6)ccc54)c3[Se]c3cccc(c31)[Se]2]

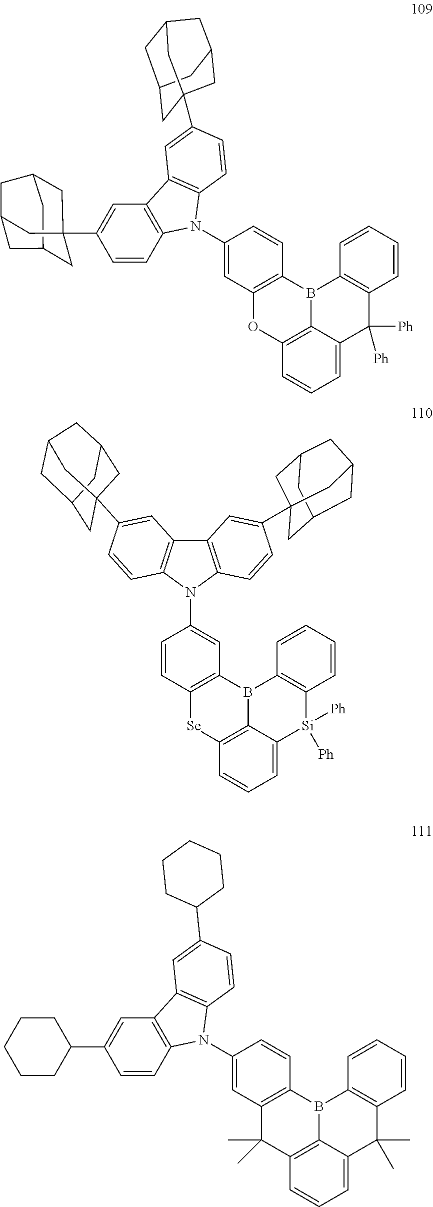 [SMILES: c1ccc(C2(c3ccccc3)c3ccccc3B3c4ccc(-n5c6ccc(C78CC9CC(CC(C9)C7)C8)cc6c6cc(C78CC9CC(CC(C9)C7)C8)ccc65)cc4Oc4cccc2c43)cc1 ; c1ccc([Si]2(c3ccccc3)c3ccccc3B3c4cc(-n5c6ccc(C78CC9CC(CC(C9)C7)C8)cc6c6cc(C78CC9CC(CC(C9)C7)C8)ccc65)ccc4[Se]c4cccc2c43)cc1 ; CC1(C)c2ccccc2B2c3ccc(-n4c5ccc(C6CCCCC6)cc5c5cc(C6CCCCC6)ccc54)cc3C(C)(C)c3cccc1c32]

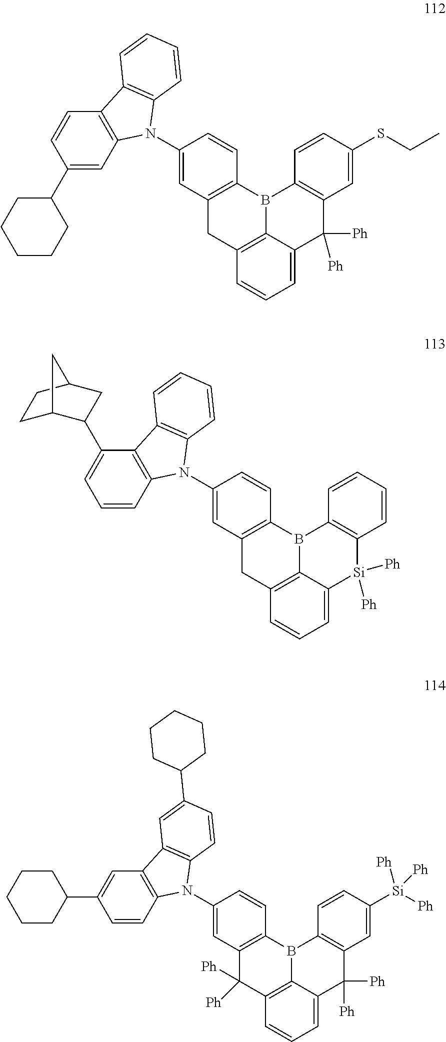 [SMILES: CCSc1ccc2c(c1)C(c1ccccc1)(c1ccccc1)c1cccc3c1B2c1ccc(-n2c4ccccc4c4ccc(C5CCCCC5)cc42)cc1C3 ; c1ccc([Si]2(c3ccccc3)c3ccccc3B3c4ccc(-n5c6ccccc6c6c(C7CC8CCC7C8)cccc65)cc4Cc4cccc2c43)cc1 ; c1ccc(C2(c3ccccc3)c3cc(-n4c5ccc(C6CCCCC6)cc5c5cc(C6CCCCC6)ccc54)ccc3B3c4ccc([Si](c5ccccc5)(c5ccccc5)c5ccccc5)cc4C(c4ccccc4)(c4ccccc4)c4cccc2c43)cc1]

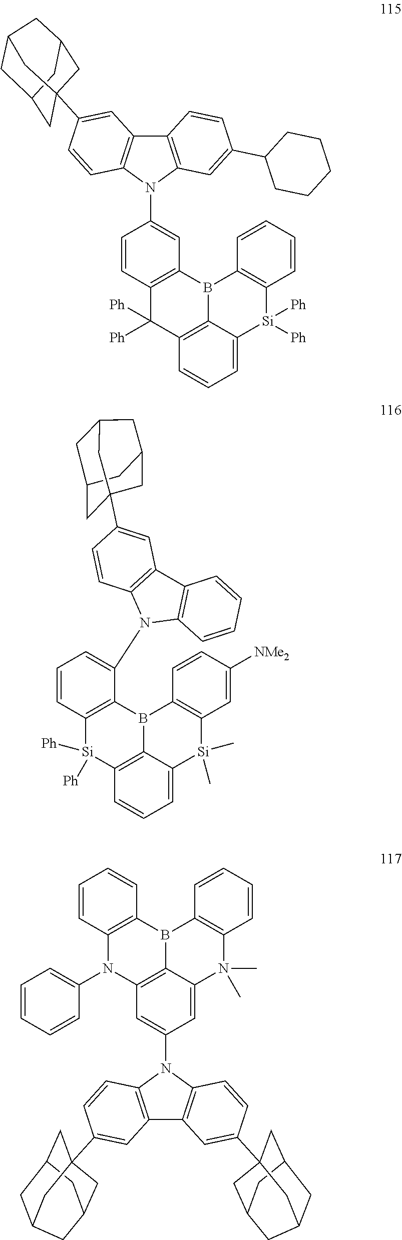

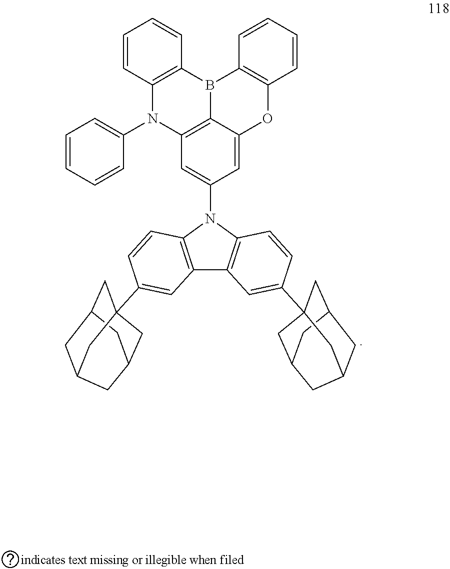 [SMILES: c1ccc(N2c3ccccc3B3c4ccccc4Oc4cc(-n5c6ccc(C78CC9CC(CC(C9)C7)C8)cc6c6cc(C78CC9CC(CC(C9)C7)C8)ccc65)cc2c43)cc1]

In Compound Group 1, “D” is deuterium, “Ph” is an unsubstituted phenyl group, and “Me” is an unsubstituted methyl group.

As described above, the polycyclic compound represented by Formula 1 of one or more embodiments of the present disclosure may include a core structure in which three benzene rings are fused through one boron atom, a first atom, and a second atom. The first atom and the second atom may each independently be selected from an oxygen atom, a sulfur atom, a selenium atom, a carbon atom, a silicon atom, and a nitrogen atom. When the first atom and the second atom are nitrogen atoms, a phenyl group may be bonded to the nitrogen atoms.

In some embodiments, in the polycyclic compound of one or more embodiments, an N-containing tricyclic heterocyclic group substituted with at least one cycloalkyl group may be bonded to one or more of three benzene rings of the core structure, or a phenyl group bonded to a nitrogen atom. The number of ring-forming carbon atoms in at least one cycloalkyl group is 5 to 30.

As the polycyclic compound represented by Formula 1 of one or more embodiments of the present disclosure has a structure in which an N-containing tricyclic heterocyclic group substituted with at least one cycloalkyl group is introduced into the core structure, the characteristics of a light emitting element of the present disclosure, for example, the lifespan of the light emitting element may be improved. For example, the at least one cycloalkyl group introduced in one or more embodiments of the present disclosure is a bulky electron donor unit, and molecules including the cycloalkyl group may have improved stability. Accordingly, the lifespan of a light emitting element to which the polycyclic compound of one or more embodiments of the present disclosure is applied may be improved.

The polycyclic compound represented by Formula 1 according to one or more embodiments of the present disclosure may be included in the emission layer EML. In some embodiments, the polycyclic compound of one or more embodiments may be included in the emission layer EML as a dopant material. The polycyclic compound of one or more embodiments may be a thermally activated delayed fluorescent material. The polycyclic compound of one or more embodiments may be utilized as a thermally activated delayed fluorescent dopant. For example, in the light emitting element ED of one or more embodiments, the emission layer EML may include at least one selected from the polycyclic compounds shown in Compound Group 1 as a thermally activated delayed fluorescent dopant. However, the utilization of the polycyclic compound of one or more embodiments is not limited thereto.

In one or more embodiments, the polycyclic compound represented by Formula 1 may be a thermally activated delayed fluorescent dopant in which a difference A Est between an energy level of a lowest triplet excited state T1 of the polycyclic compound and an energy level of a lowest singlet excited state S1 of the polycyclic compound is 0.6 eV or less. In some embodiments, the polycyclic compound may be a thermally activated delayed fluorescent dopant in which a difference A EST between the energy level of the lowest triplet excited state T1 (T1 level) of the polycyclic compound and the energy level of the lowest singlet excited state (S1 level) of the polycyclic compound is 0.2 eV or less.

In one or more embodiments, an emission spectrum of the polycyclic compound represented by Formula 1 may have a full width of half maximum of about 10 to about 35 nm. As the emission spectrum of the polycyclic compound of one or more embodiments has a full width of half maximum in the above range, light emitting efficiency may be improved when the polycyclic compound of one or more embodiments is applied to a light emitting element. In some embodiments, element service life may be improved when the polycyclic compound of one or more embodiments is utilized as a blue light emitting element material for a light emitting element.

In one or more embodiments, the polycyclic compound represented by Formula 1 may be to emit blue light. The polycyclic compound of one or more embodiments may have a maximum emission wavelength of about 450 nm to about 480 nm. For example, in some embodiments, the polycyclic compound may have a maximum emission wavelength of about 455 nm to about 470 nm.

In one or more embodiments, the emission layer EML may include at least one of a first compound represented by Formula 1, a second compound represented by Formula HT, or a third compound represented by Formula ET.

For example, in one or more embodiments, the second compound represented by Formula HT may be utilized as a hole transporting host material of the emission layer EML.

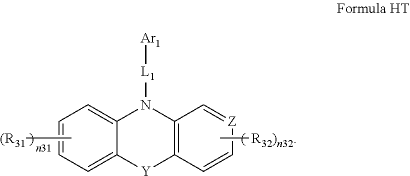

In Formula HT, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, in one or more embodiments, L₁ may be a direct linkage, a substituted or unsubstituted phenylene group, a substituted or unsubstituted divalent biphenyl group, a substituted or unsubstituted divalent carbazole group, and/or the like, but embodiments of the present disclosure are not limited thereto.

Ar₁ may be a substituted or unsubstituted aryl group having 6 to 30 ring-forming carbon atoms, or a substituted or unsubstituted heteroaryl group having 2 to 30 ring-forming carbon atoms. For example, in one or more embodiments, Ar₁ may be a substituted or unsubstituted carbazole group, a substituted or unsubstituted dibenzofuran group, a substituted or unsubstituted dibenzothiophene group, a substituted or unsubstituted biphenyl group, and/or the like, but embodiments of the present disclosure are not limited thereto.

Y may be a direct linkage, CR_{y1}R_{y2}, or SiR_{y3}R_{y4}. For example, two benzene rings linked to the nitrogen atom of Formula HT may be linked through a direct linkage,

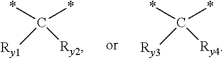

For example, in some embodiments, when Y is a direct linkage, a second compound represented by Formula HT may include a carbazole unit.

Z is CR_{z} or N.

R_{y1} to R_{y4}, R₃₁, R₃₂, and R_{z} may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring. For example, in one or more embodiments, R_{y1} to R_{y4} may each independently be a methyl group or a phenyl group. For example, in some embodiments, R₃₁ and R₃₂ may each independently be hydrogen or deuterium.

n31 is an integer of 0 to 4. When n31 is 0, the compound of an embodiment may not be substituted with R₃₁. When n31 is 4, and R₃₁'s are hydrogens, the embodiment may be the same as an embodiment when n31 is 0. When n31 is an integer of 2 or greater, two or more R₃₁'s may be the same or at least one may be different from the others.

n32 is independently an integer of 0 to 3. When n32 is 0, the compound of an embodiment may not be substituted with R₃₂. When n32 is 3, and R₃₂'s are hydrogens, the embodiments may be the same as an embodiment when n32 is 0. When n32 is an integer of 2 or greater, two or more R₃₂'s may be the same or at least one may be different from the others.

In one or more embodiments, the emission layer EML may include the third compound represented by Formula ET. For example, in one or more embodiments, the third compound may be utilized as an electron transporting host material of the emission layer EML.

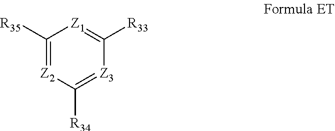

In Formula ET, Z₁ to Z₃ may each independently be N or CR₃₆, and at least ant one selected from among Z₁ to Z₃ is N. For example, in some embodiments, Z₁ to Z₃ may all be N. In some embodiments, Z₁ and Z₂ may be N, Z₃ may be CR₃₆; Z₁ may be CR₃₆, Z₂ and Z₃ may be N; or Z₁ and Z₃ may be N, and Z₂ may be CR₃₆. In some embodiments, Z₁ may be N, Z₂ and Z₃ may be CR₃₆; Z₂ may be N, Z₁ and Z₃ may be CR₃₆; or Z₃ may be N, and Z₁ and Z₂ may be CR₃₆.

R₃₃ to R₃₆ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring, and for example, in one or more embodiments, R₃₃ to R₃₆ may each independently be a substituted or unsubstituted phenyl group, a substituted or unsubstituted carbazole group, and/or the like, but embodiments of the present disclosure are not limited thereto.

For example, in one or more embodiments, the emission layer EML may include a second compound and a third compound, and the second compound and the third compound may form an exciplex. In the emission layer EML, the hole transporting host and the electron transporting host may form an exciplex. In those embodiments, the triplet energy of the exciplex formed by the hole transporting host and the electron transporting host corresponds to a difference between Lowest Unoccupied Molecular Orbital (LUMO) energy level of the electron transporting host and Highest Occupied Molecular Orbital (HOMO) energy level of the hole transporting host.

For example, in some embodiments, the triplet energy level (T1) of the exciplex formed by the hole transporting host and the electron transporting host may have an absolute value of about 2.4 eV to about 3.0 eV. In some embodiments, the triplet energy of the exciplex may have a value smaller than the energy gap of each host material. The exciplex may have a triplet energy of 3.0 eV or less, which is an energy gap between the hole transporting host and the electron transporting host.

In one or more embodiments, the emission layer EML may further include a fourth compound in addition to the first to third compounds described above. The fourth compound may be utilized as a phosphorescent sensitizer of the emission layer EML. Energy may be transferred from the fourth compound to the first compound to emit light.

For example, in one or more embodiments, the emission layer EML may include, as the fourth compound, an organometallic complex containing platinum (Pt) as a central metal atom and ligands bound to the central metal atom. In the light emitting element ED of one or more embodiments, the emission layer EML may include a compound represented by Formula PS as the fourth compound.

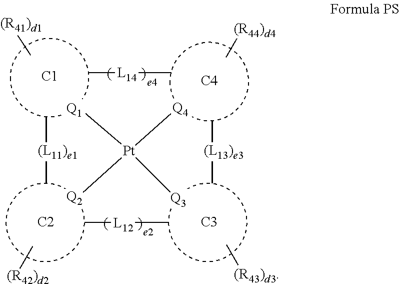

In Formula PS, Q₁ to Q₄ may each independently be C or N.

C1 to C4 may each independently be a substituted or unsubstituted hydrocarbon ring having 5 to 30 ring-forming carbon atoms, or a substituted or unsubstituted heterocycle having 2 to 30 ring-forming carbon atoms.

L₁₁ to L₁₄ may each independently be a direct linkage,

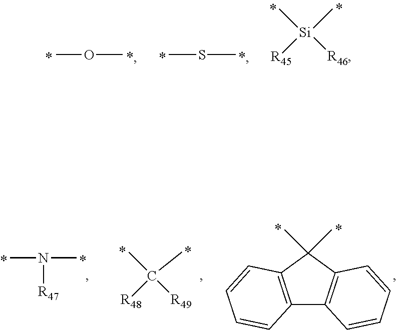

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms.

e1 to e4 may each independently be 0 or 1. When e1 is 0, C1 and C2 may not be connected. When e2 is 0, C2 and C3 may not be connected. When e3 is 0, C3 and C4 may not be connected. When e4 is 0, C1 and C4 may not be connected.

R₄₁ to R₄₉ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring. For example, in one or more embodiments, R₄₁ to R₄₉ may each independently be a substituted or unsubstituted methyl group, or a substituted or unsubstituted t-butyl group.

d1 to d4 may each independently be an integer of 0 to 4. When d1 to d4 are each 0, the fourth compound of one or more embodiments may not be substituted with R₄₁ to R₄₄. When d1 to d4 are each 4 and R₄₁ to R₄₄ are each hydrogen, the embodiments may be the same as embodiments when d1 to d4 are each 0. When d1 to d4 are each 2 or greater, the substituents in the parentheses may be the same or at least one may be different from the others.

In some embodiments, C1 to C4 may each independently be a substituted or unsubstituted hydrocarbon ring or a substituted or unsubstituted aromatic heterocycle, which is represented by any one selected from among C-1 to C-4.

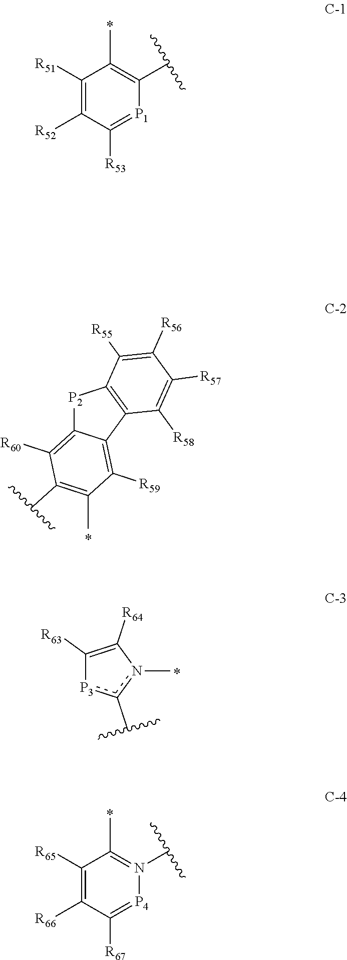

In C-1 to C-4, P₁— may be C-* or CR₅₄, P₂ may be N-* or NR₆₁, P₃ may be N-* or NR₆₂, and P₄ may be C-* or CR₆₈. R₅₁ to R₆₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In C-1 to C-4,

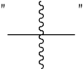

indicates a portion linked to a central metal atom, Pt, and “-*” indicates a portion linked to neighboring ring groups (C1 to C4) or linkers (L₁₁ to L₁₄).

The emission layer according to one or more embodiments may include the first compound represented by Formula 1, and at least one selected from among the second to fourth compounds. For example, in some embodiments, the emission layer EML may include the first compound, the second compound, and the third compound. In the emission layer EML, the second compound and the third compound form an exciplex, and energy may be transferred from the exciplex to the first compound to emit light.

In some embodiments, the emission layer EML may include the first compound, the second compound, the third compound, and the fourth compound. In the emission layer EML, the second compound and the third compound form an exciplex, and energy may be transferred from the exciplex to the fourth compound and the first compound to emit light. In some embodiments, the fourth compound may be a sensitizer. In the light emitting element ED of one or more embodiments, the fourth compound included in the emission layer EML may serve as a sensitizer to transfer energy from the host to the first compound, which is a light emitting dopant. For example, in some embodiments, the fourth compound serving as an auxiliary dopant may accelerate the energy transfer to the first compound serving as the light emitting dopant, thereby increasing the light emitting ratio of the first compound. As a result, the emission layer EML of one or more embodiments may have increased light emitting efficiency. In some embodiments, when the energy transfer to the first compound is increased, excitons formed in the emission layer EML do not accumulate in the emission layer EML and emit light quickly, resulting in less deterioration of the light emitting element. Accordingly, the light emitting element ED of one or more embodiments may have increased lifespan.

In one or more embodiments, the light emitting element ED may include all of a first compound, a second compound, a third compound, and a fourth compound, and the emission layer EML may thus include a combination of two host materials and two dopant materials. In the light emitting element ED of one or more embodiments, the emission layer EML includes two different hosts, a first compound emitting delayed fluorescence, and a fourth compound containing an organometallic complex, and may thus exhibit excellent or suitable light emitting efficiency.

In one or more embodiments, the second compound represented by Formula HT may be any one selected from among compounds of Compound Group HT. In some embodiments, the emission layer EML may include at least one selected from among the compounds shown in Compound Group HT, as a hole transporting host material. In Compound Group HT, “D” represents deuterium, and “Ph” is an unsubstituted phenyl group.

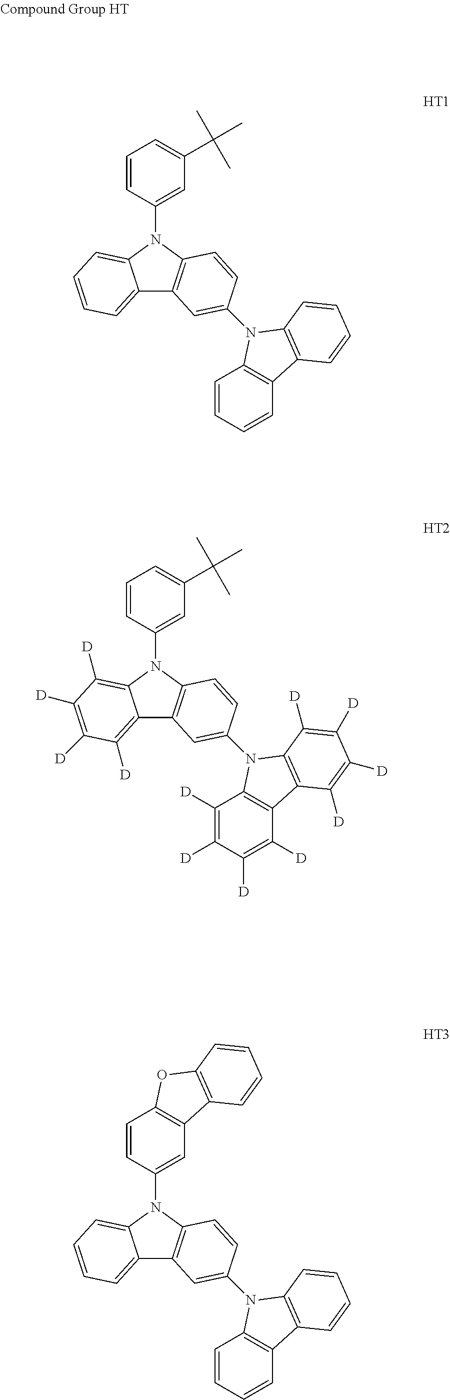 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

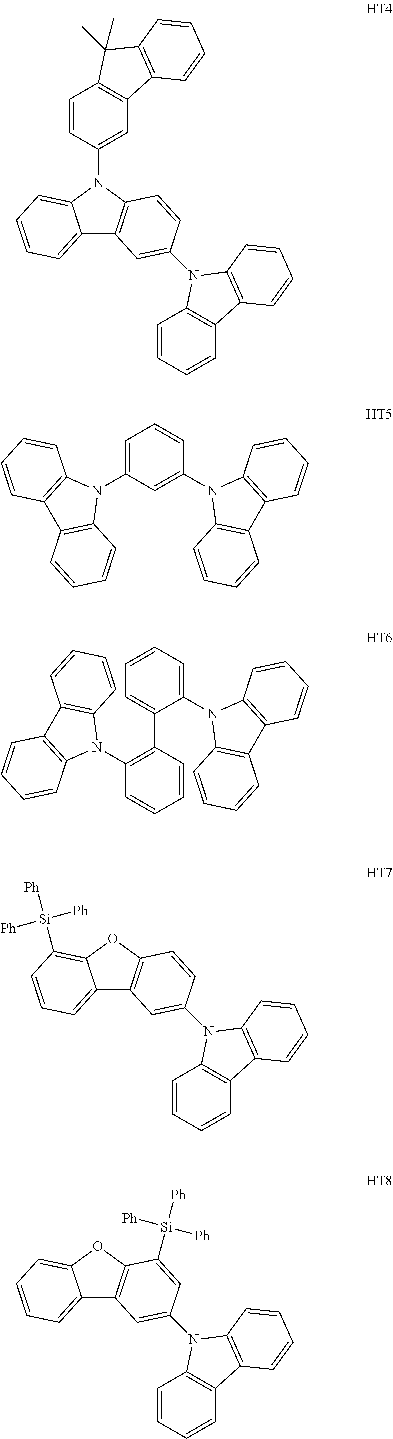 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

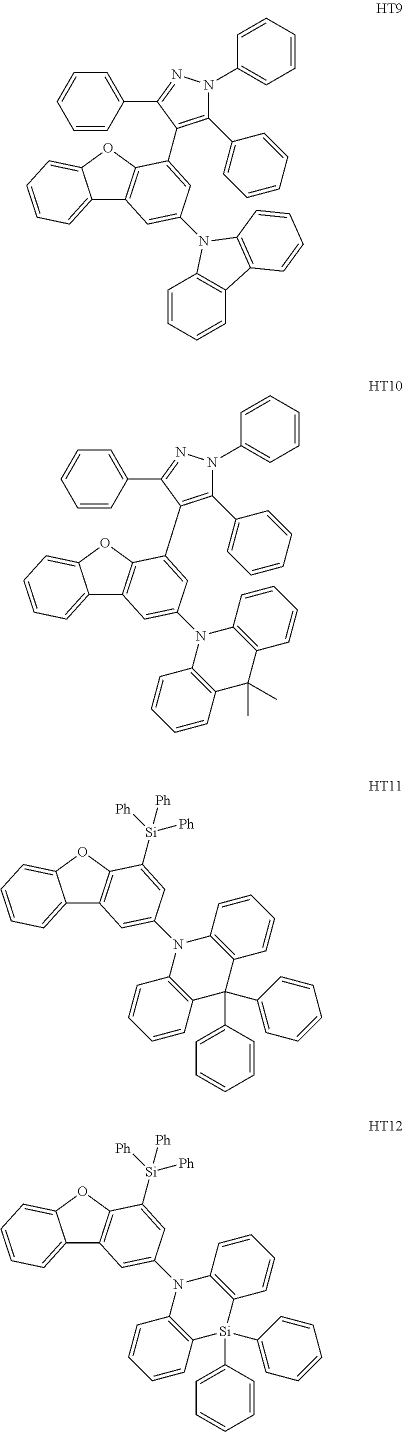 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

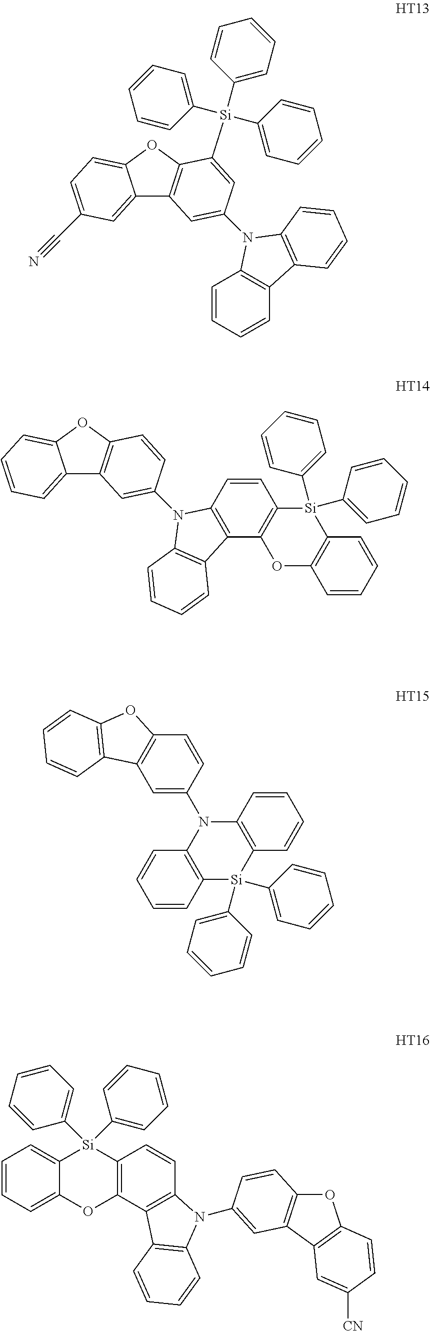 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

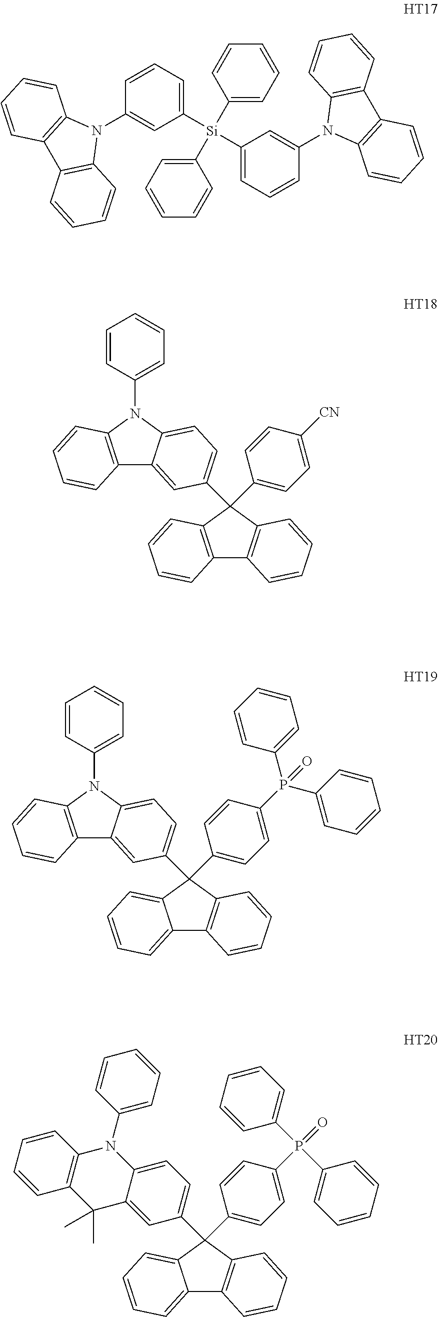 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

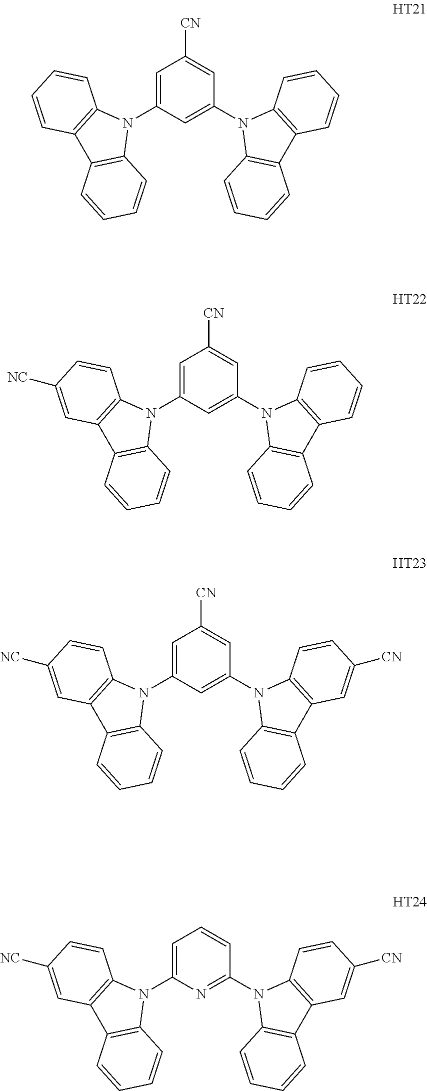 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

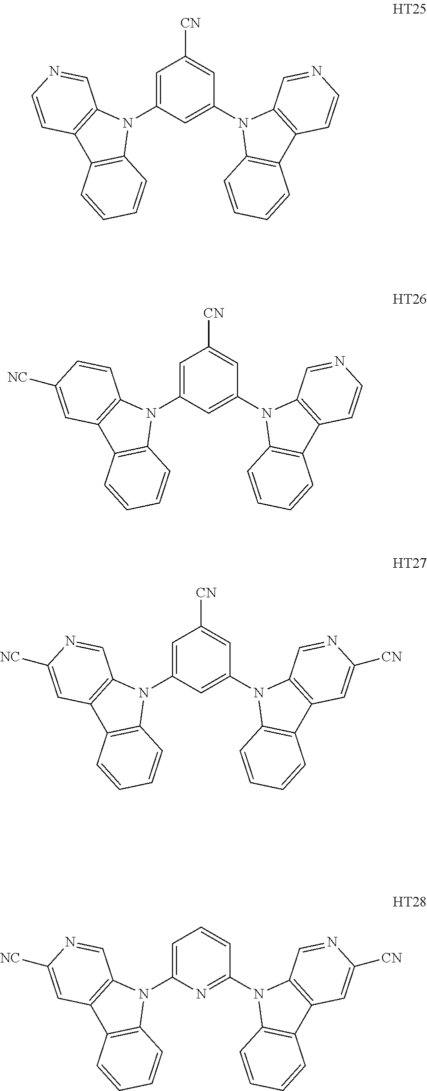 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

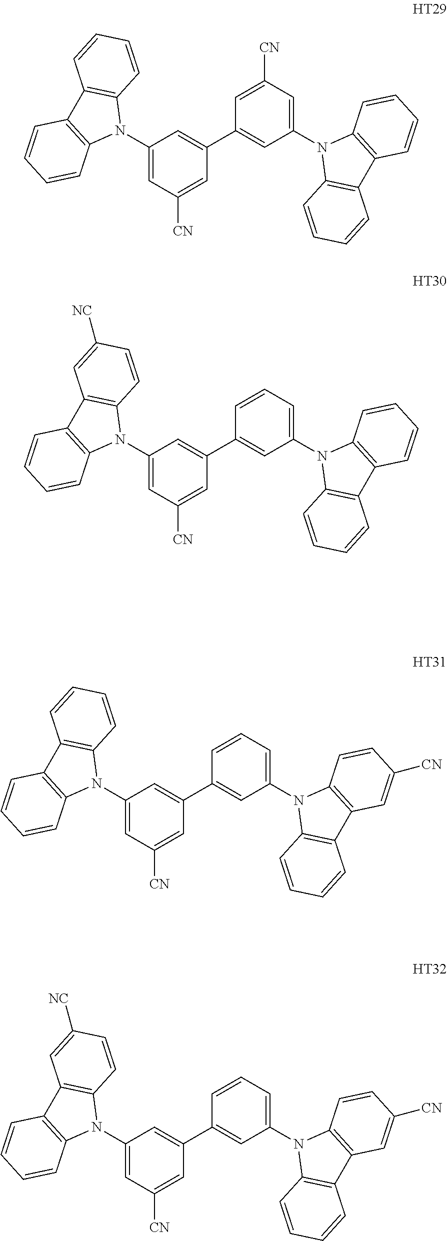 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

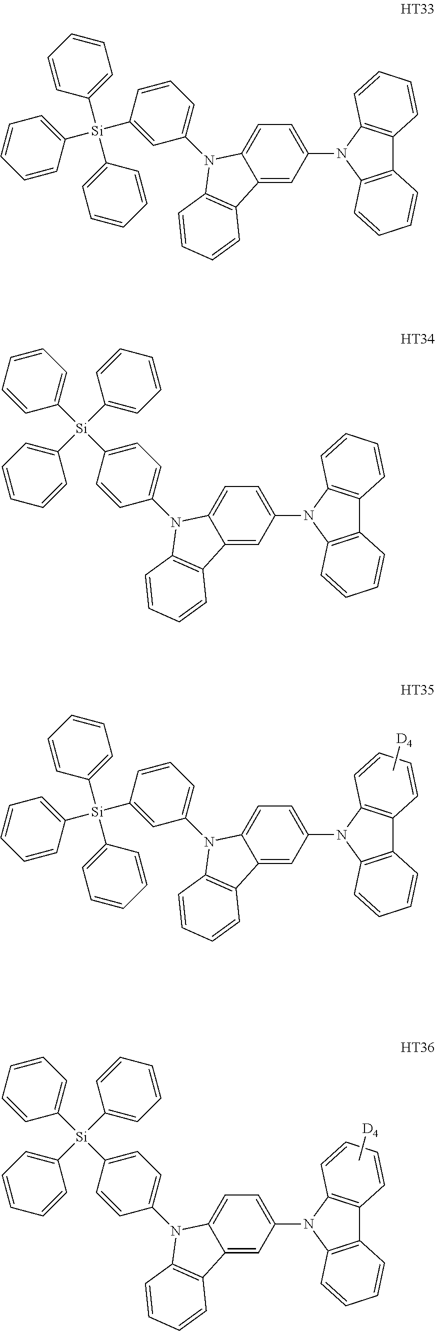

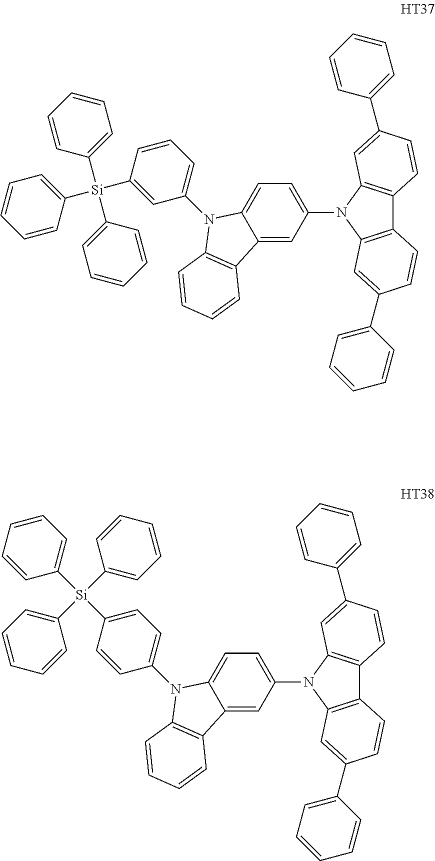 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1]

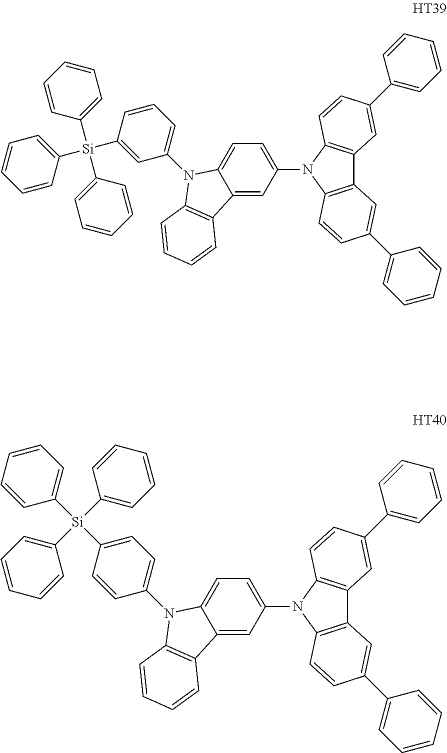 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

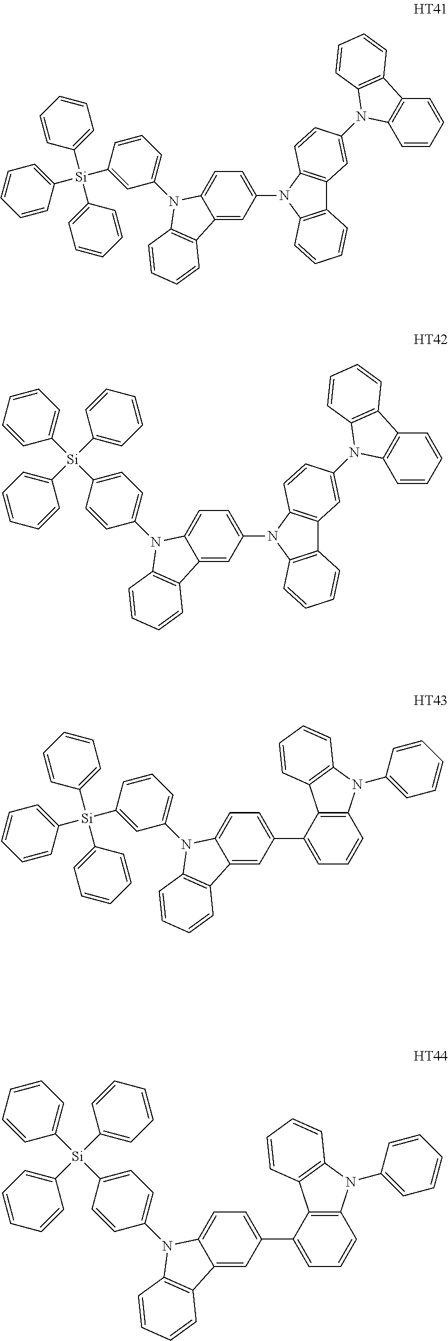 [SMILES: c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1 ; c1ccc(-n2c3ccccc3c3c(-c4ccc5c(c4)c4ccccc4n5-c4cccc([Si](c5ccccc5)(c5ccccc5)c5ccccc5)c4)cccc32)cc1 ; c1ccc(-n2c3ccccc3c3c(-c4ccc5c(c4)c4ccccc4n5-c4ccc([Si](c5ccccc5)(c5ccccc5)c5ccccc5)cc4)cccc32)cc1]

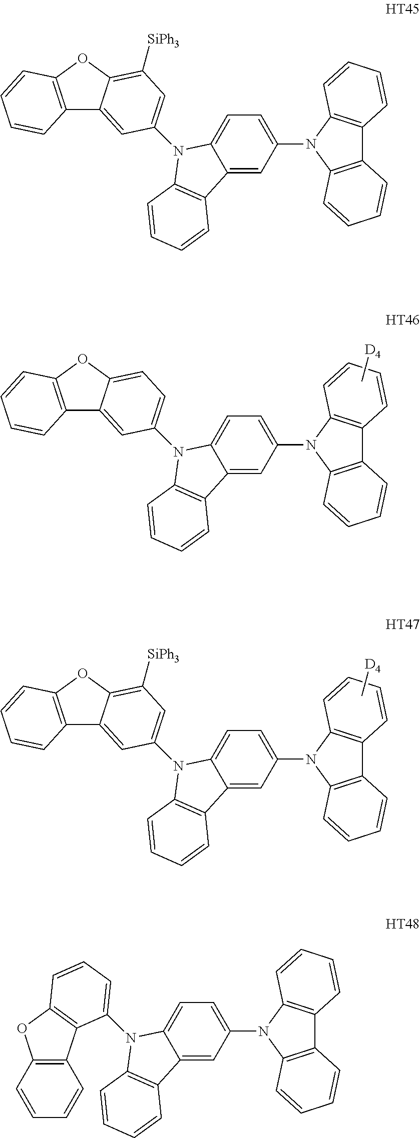

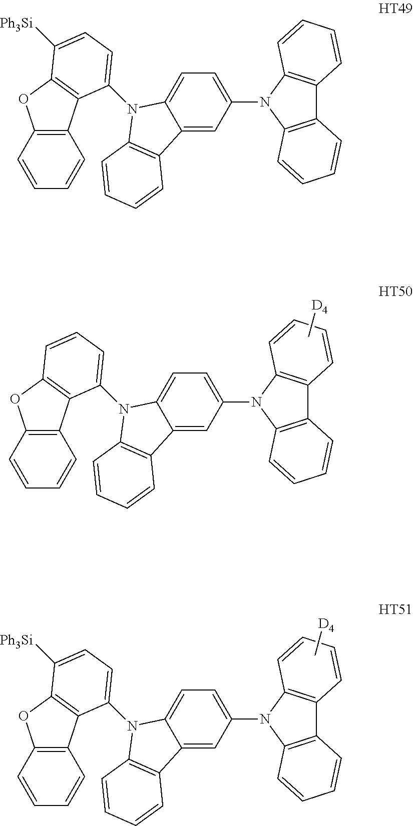

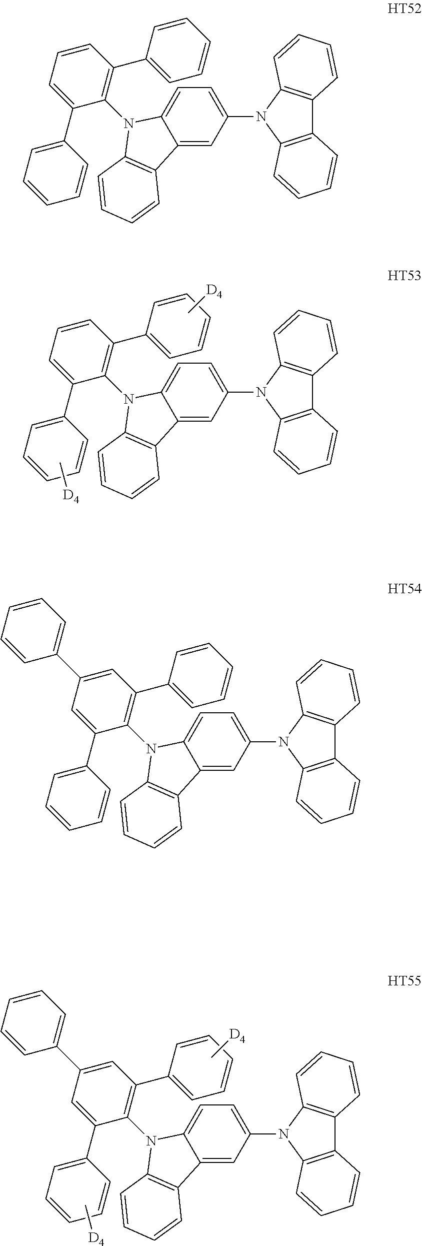

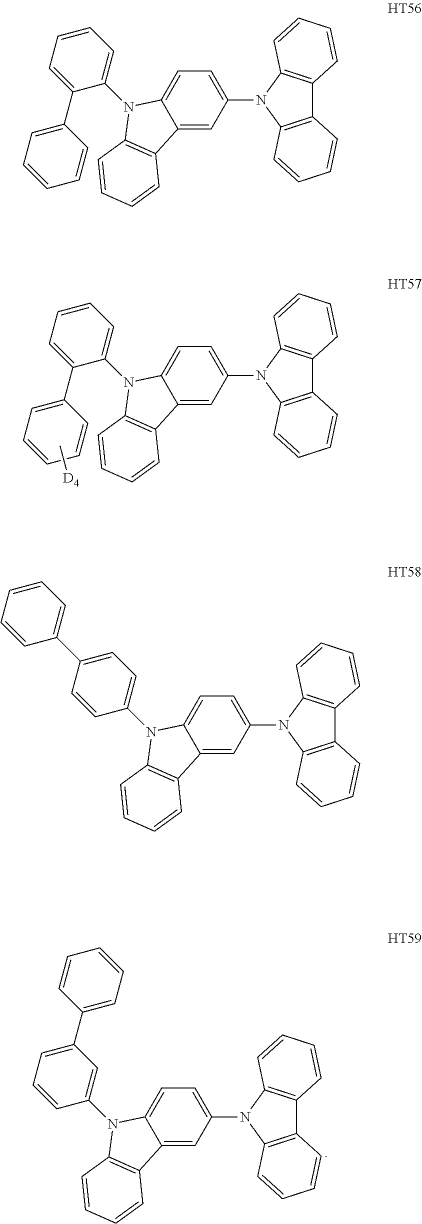

In one or more embodiments, the third compound represented by Formula ET may be any one selected from among compounds of Compound Group ET. In some embodiments, the emission layer EML may include at least one selected from the compounds shown in Compound Group ET, as an electron transporting host material. In Compound Group ET, “D” represents deuterium.

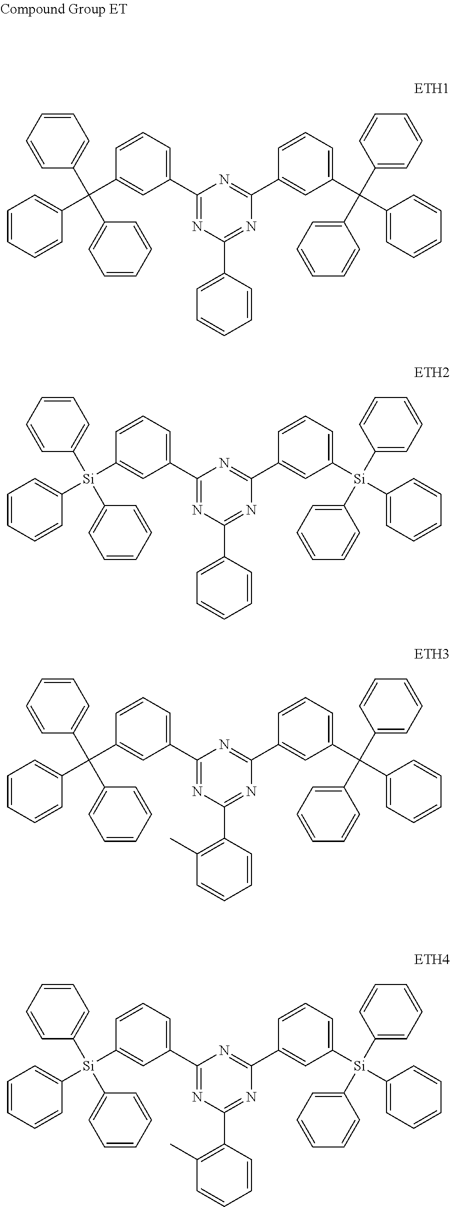 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

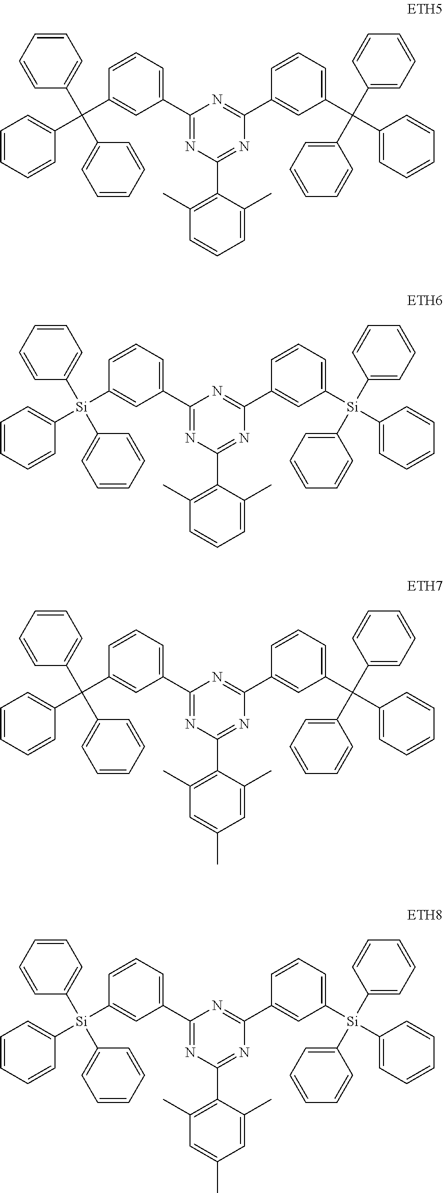 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

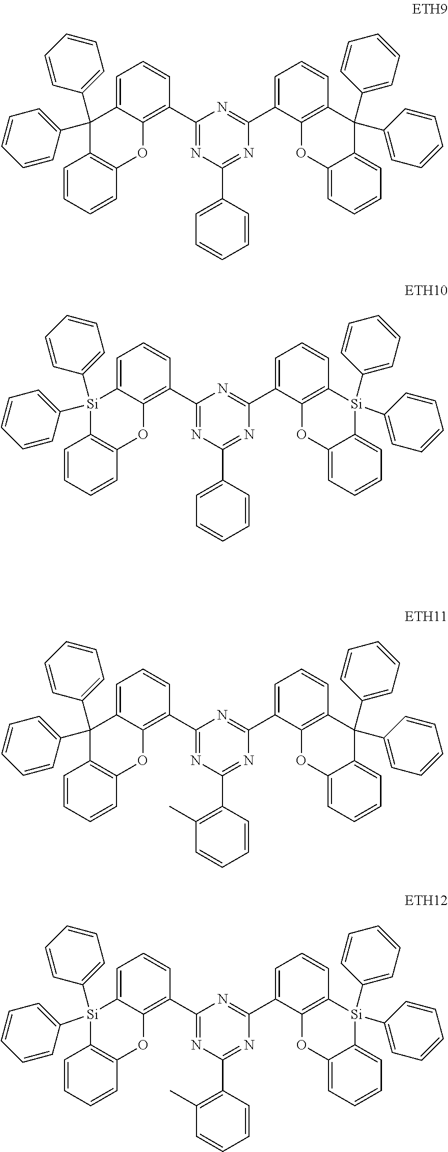 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

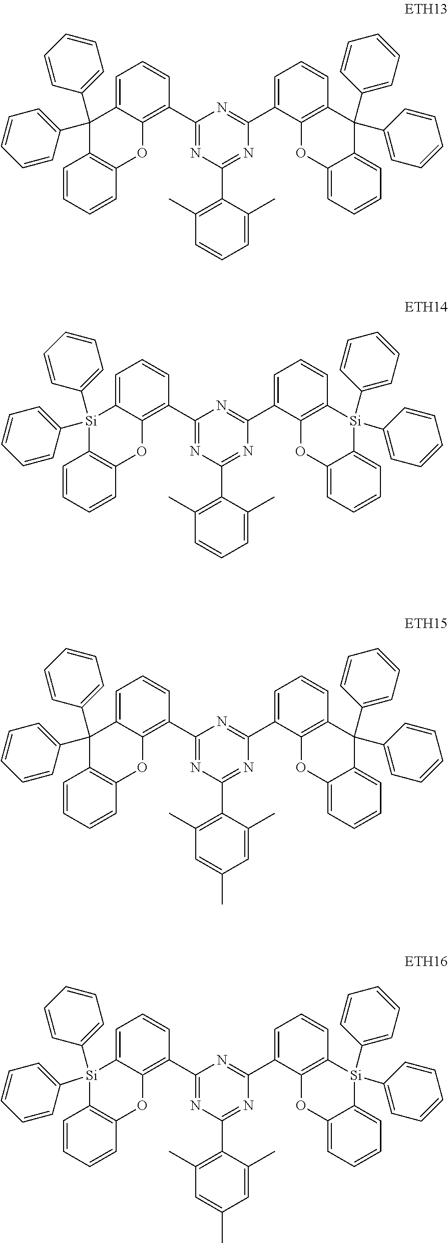 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

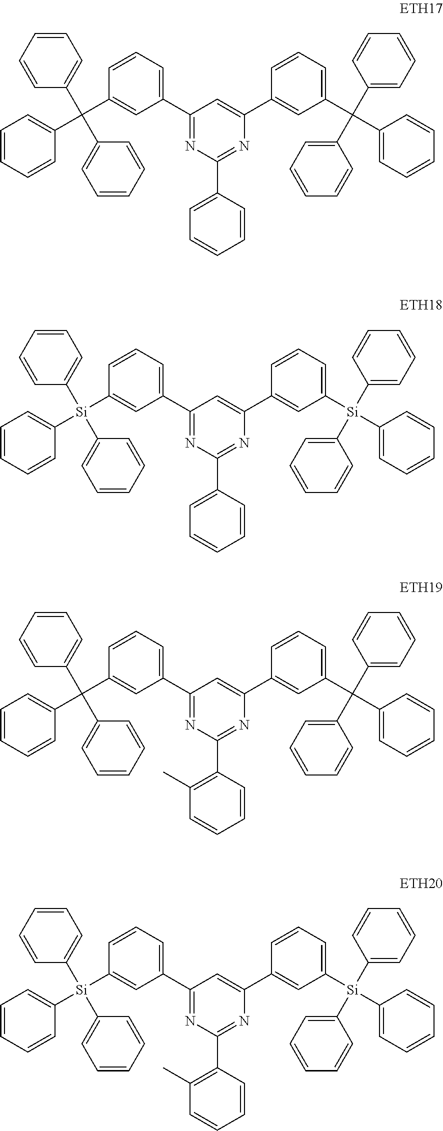 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

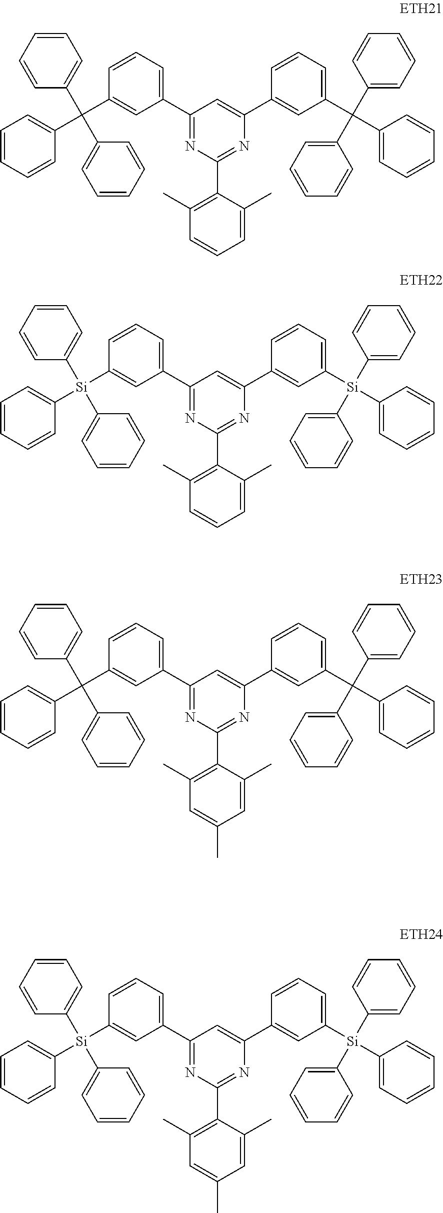 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

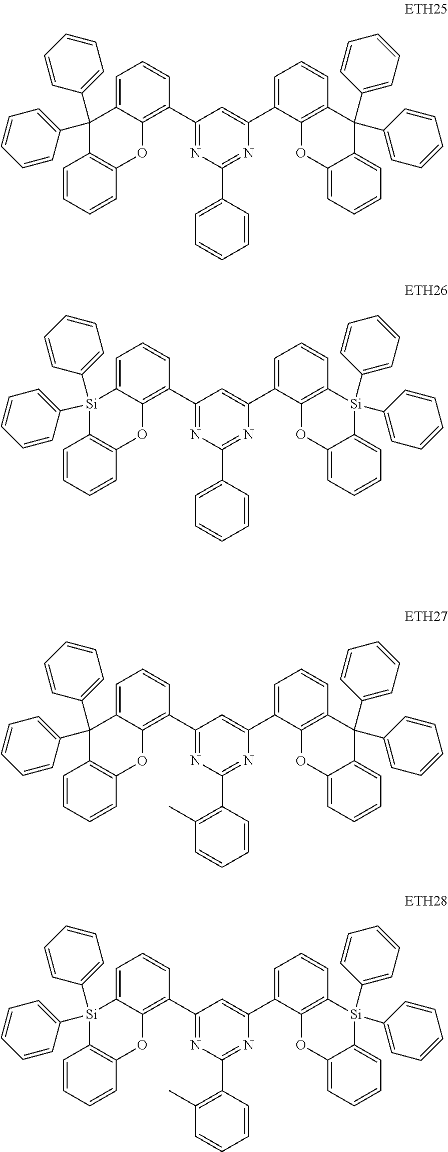 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

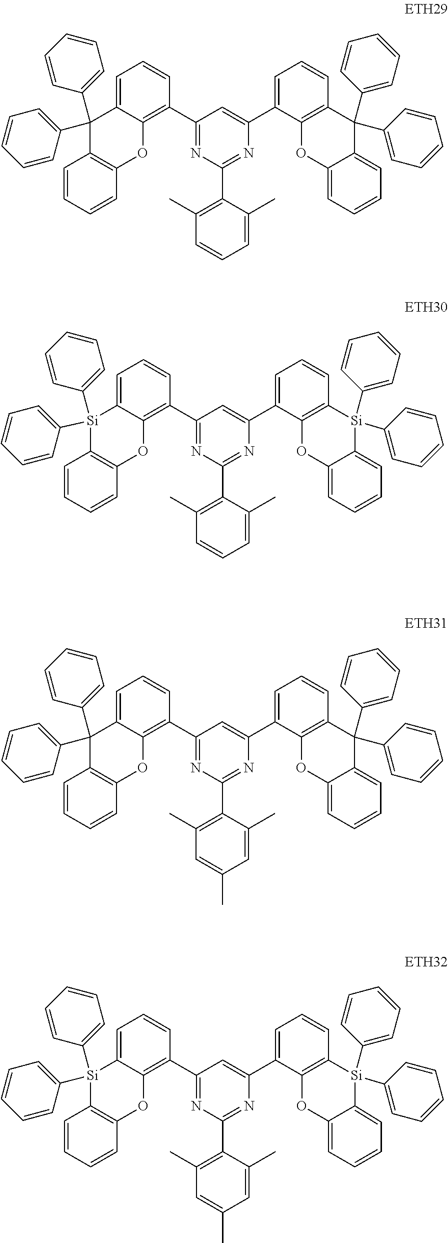 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

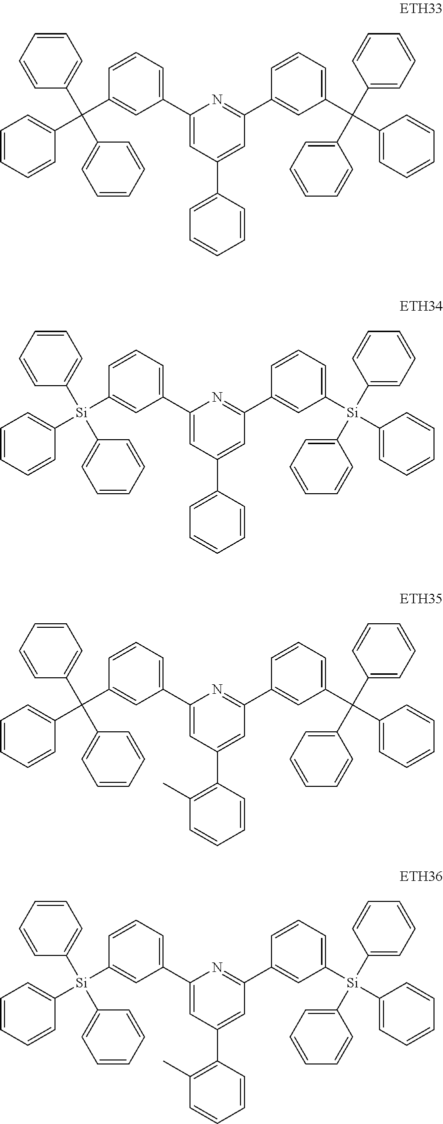 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

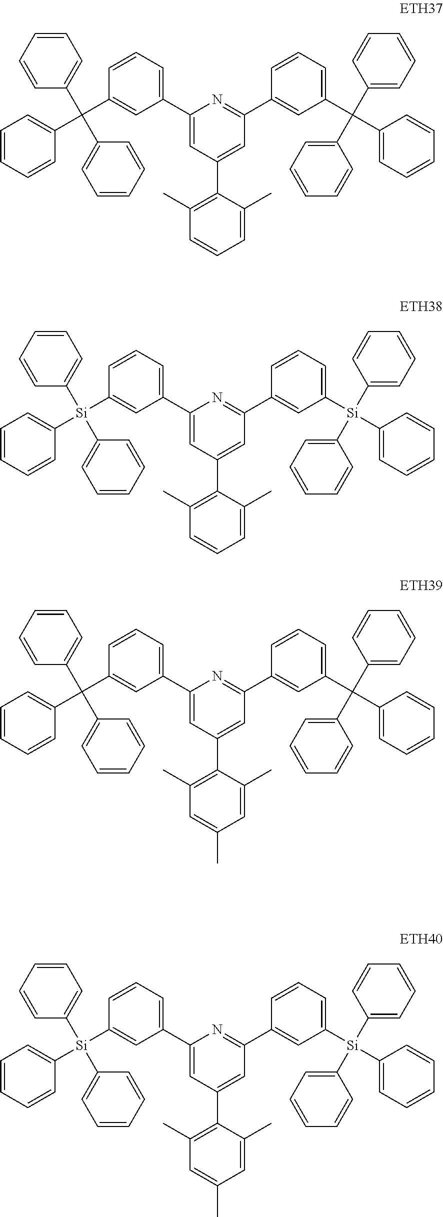 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

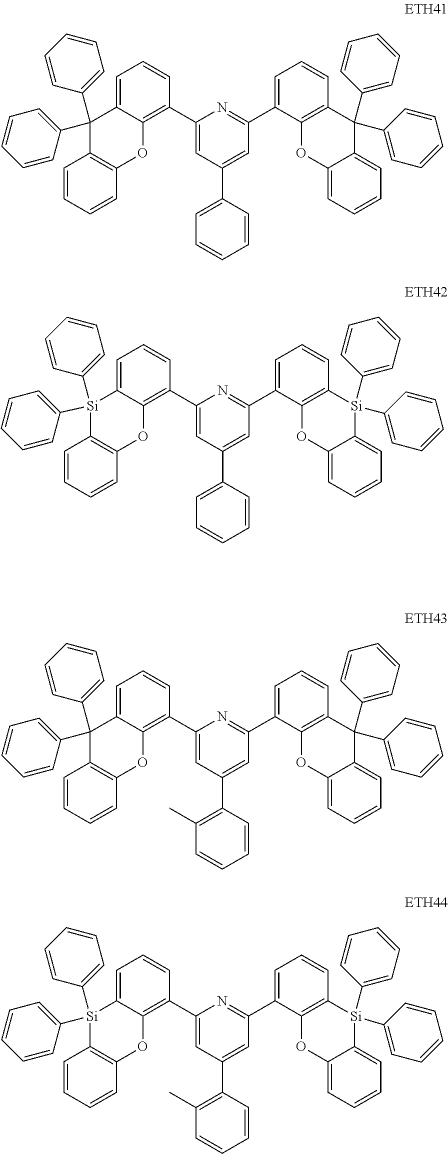 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

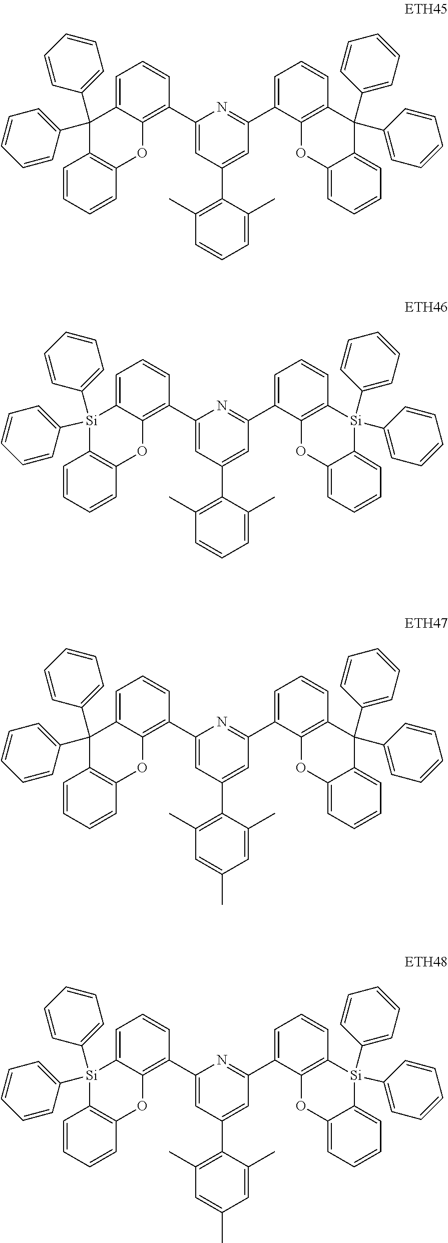 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

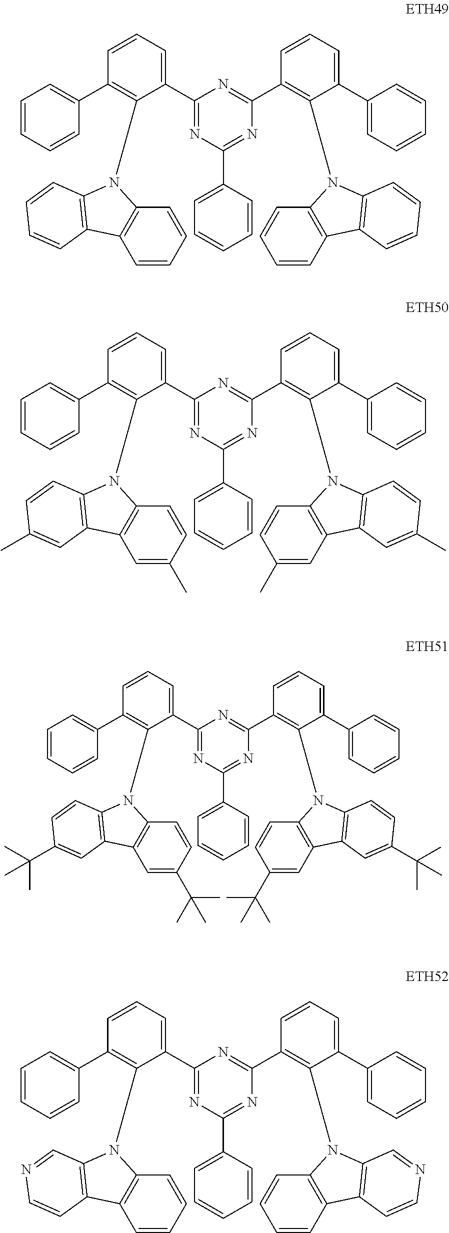

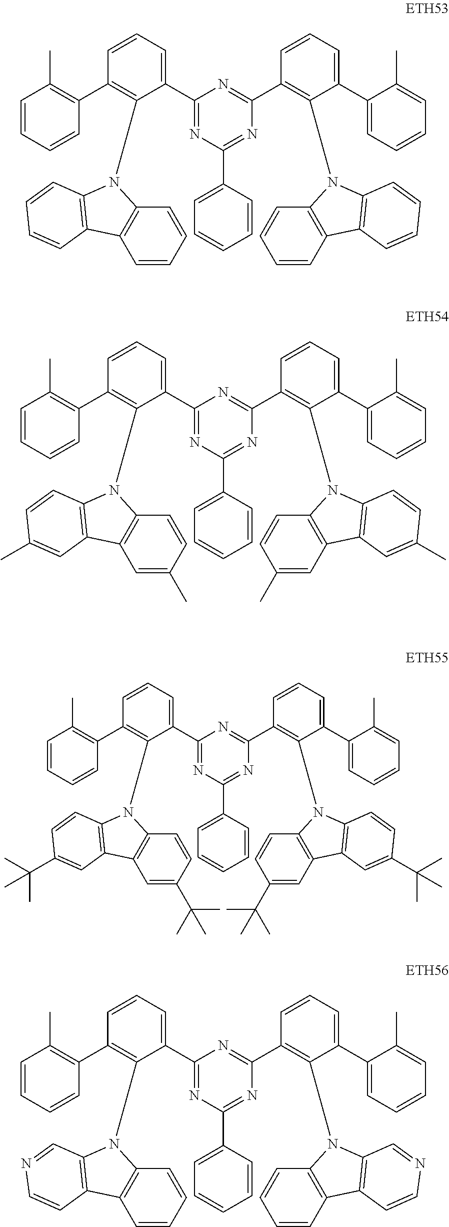

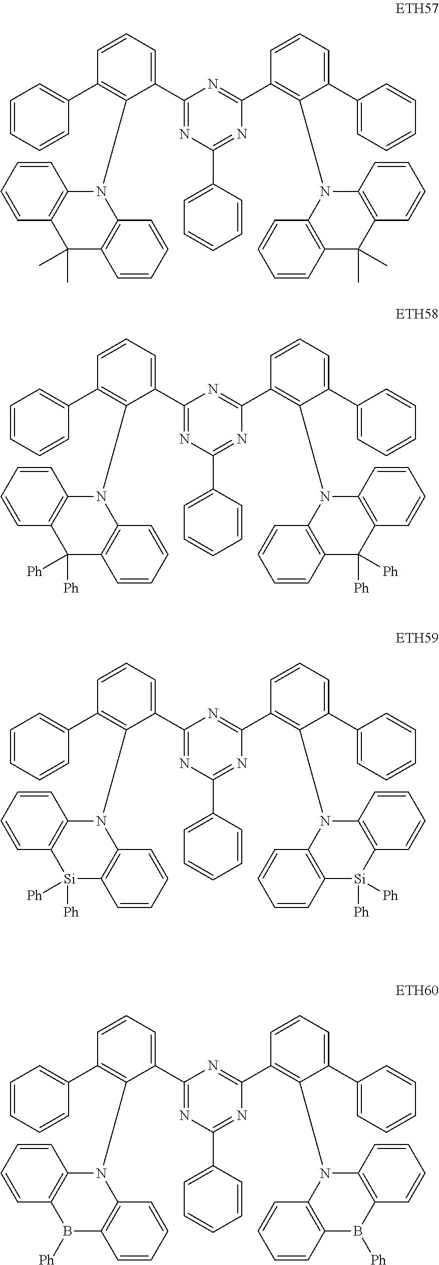

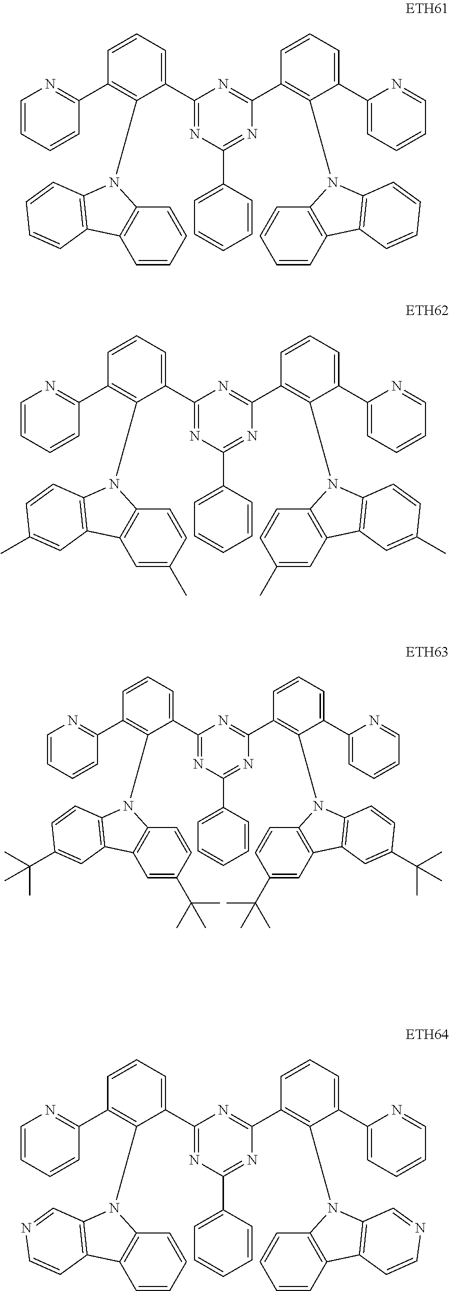

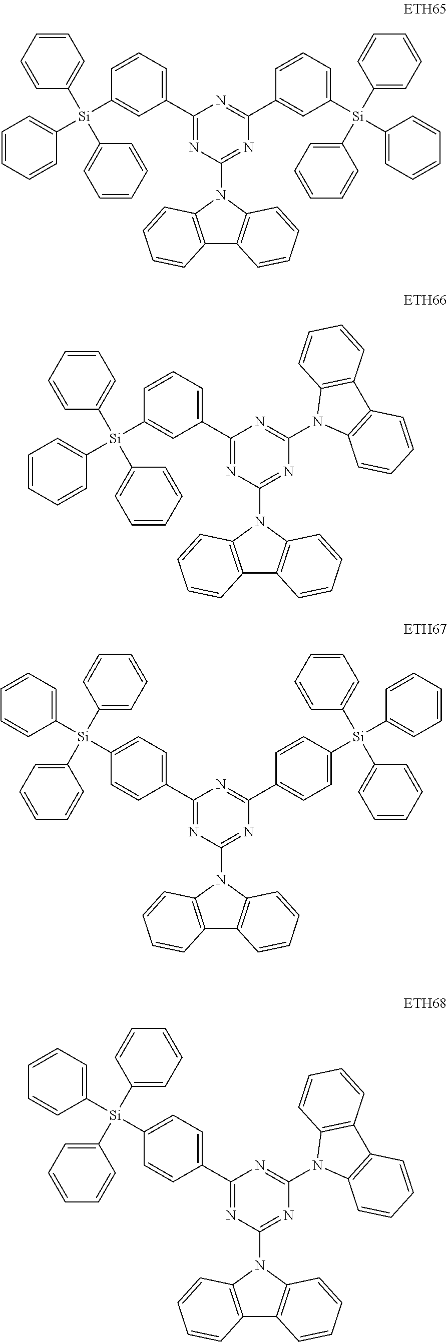 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

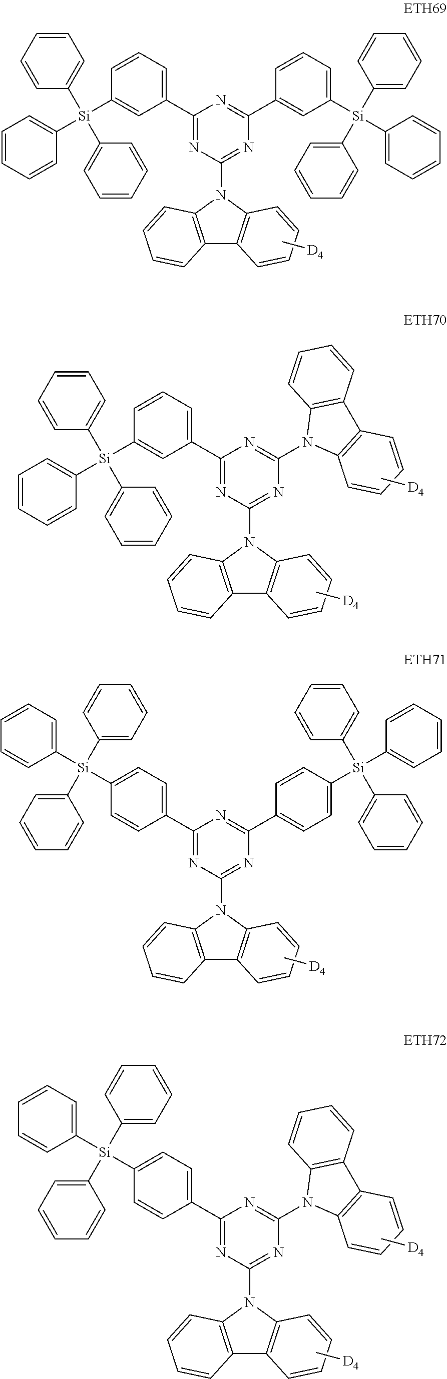

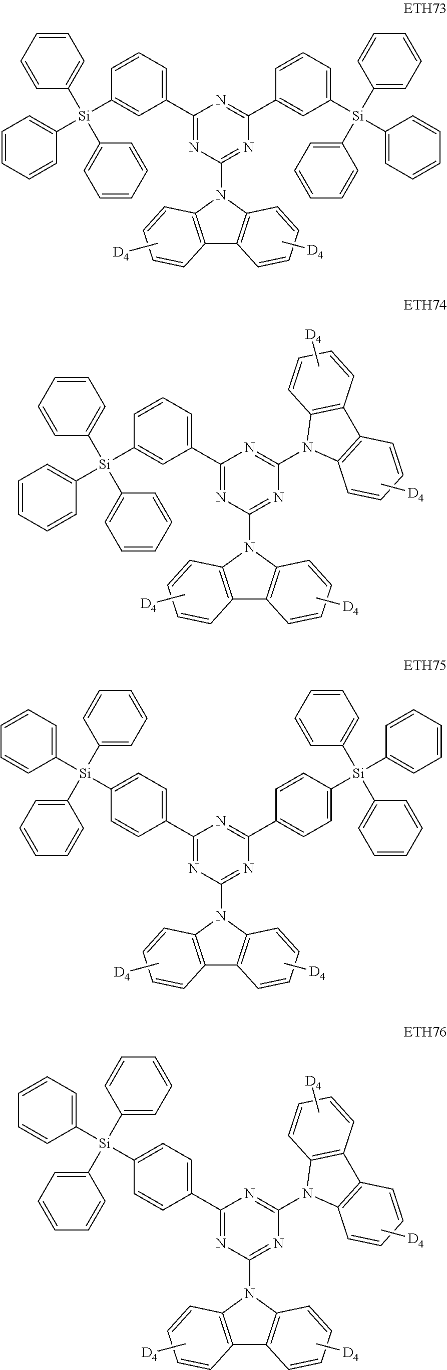

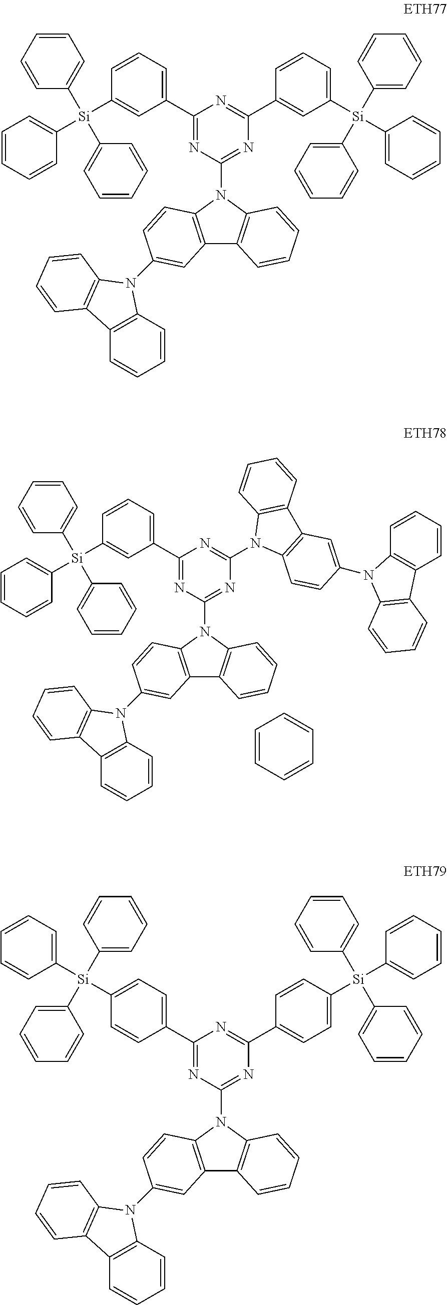

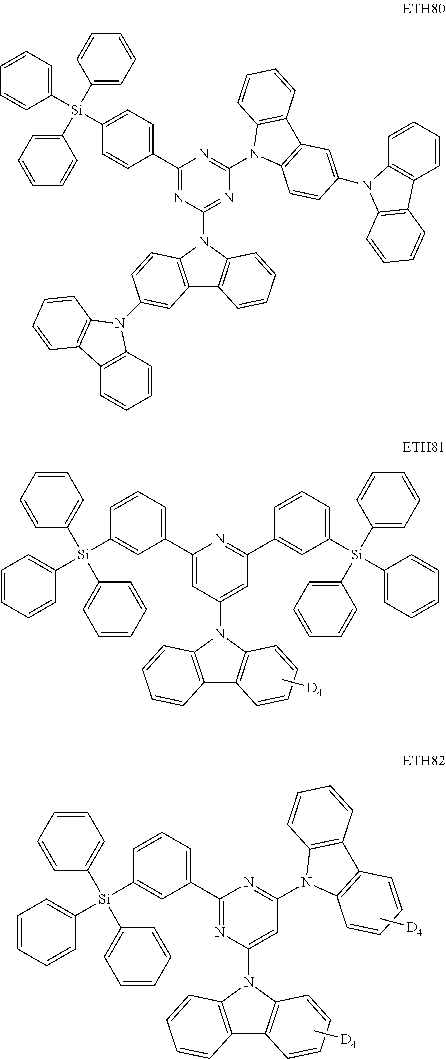

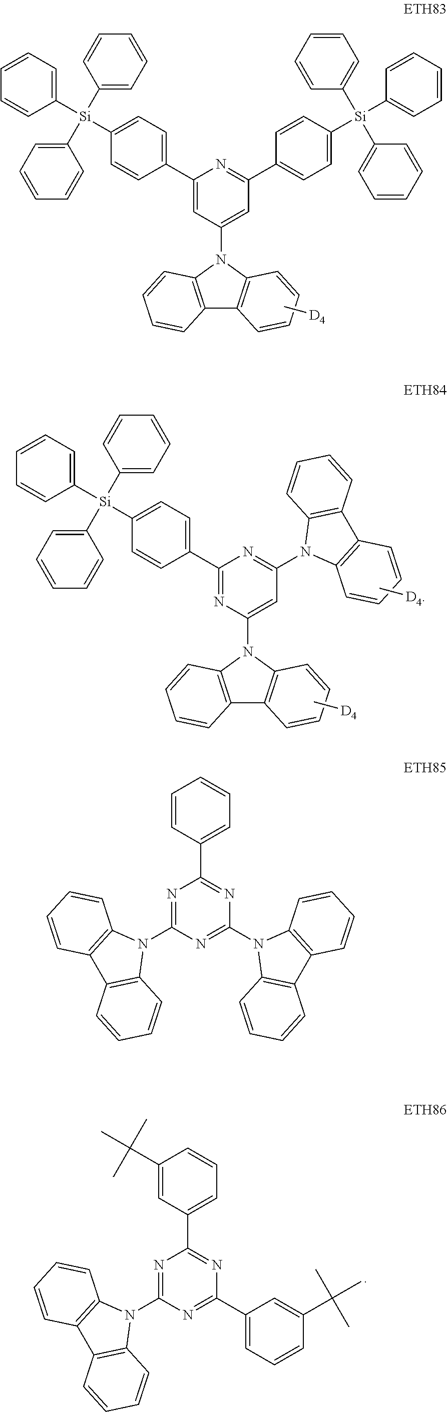

In one or more embodiments, the fourth compound represented by Formula PS may be any one selected from among compounds of Compound Group AD. In some embodiments, the emission layer EML may include at least one selected from the compounds shown in Compound Group AD as a sensitizer.

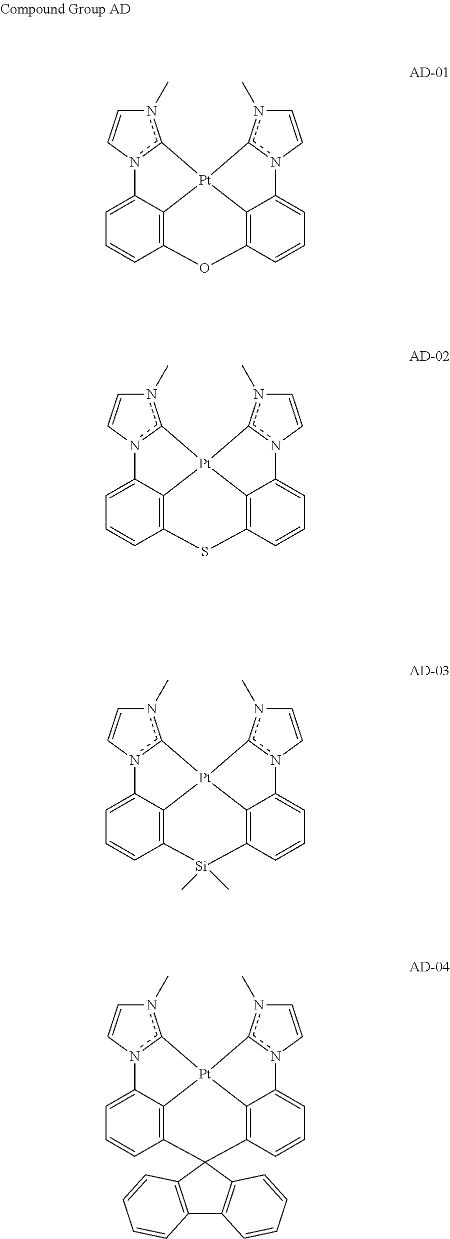

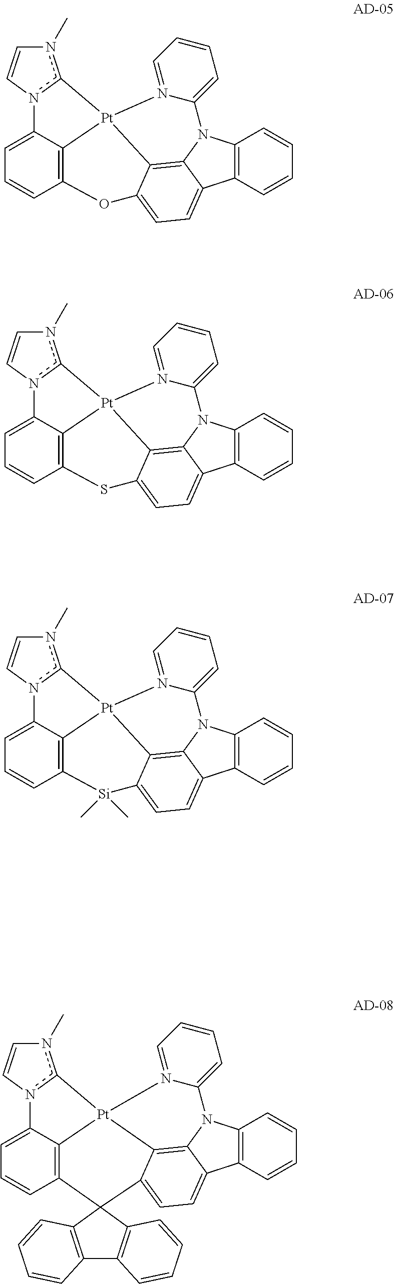

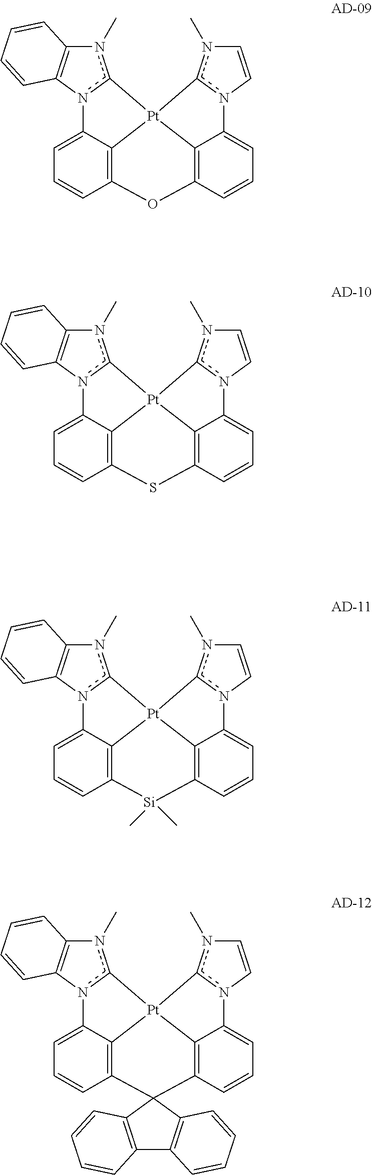

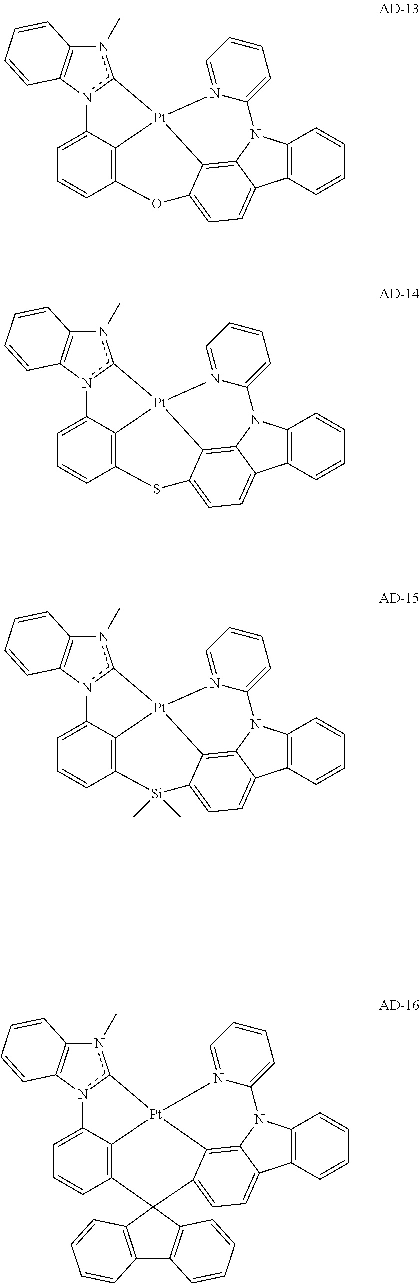

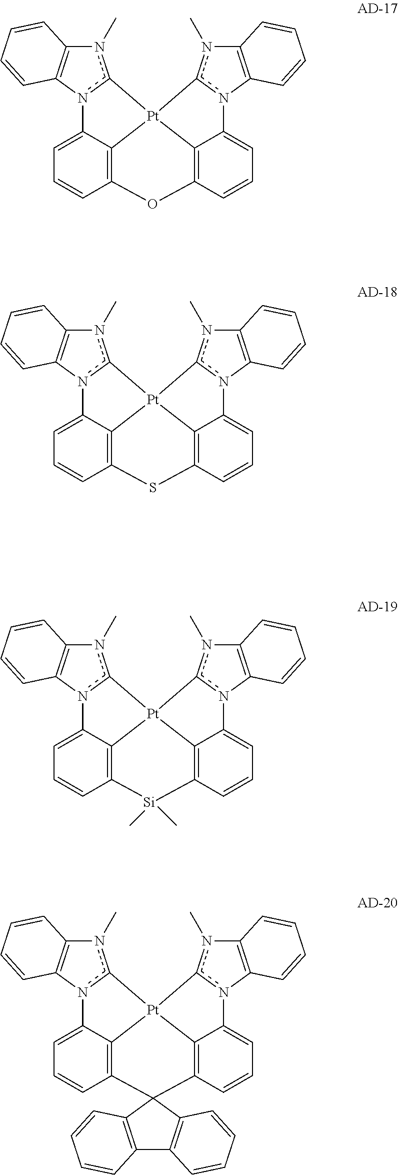

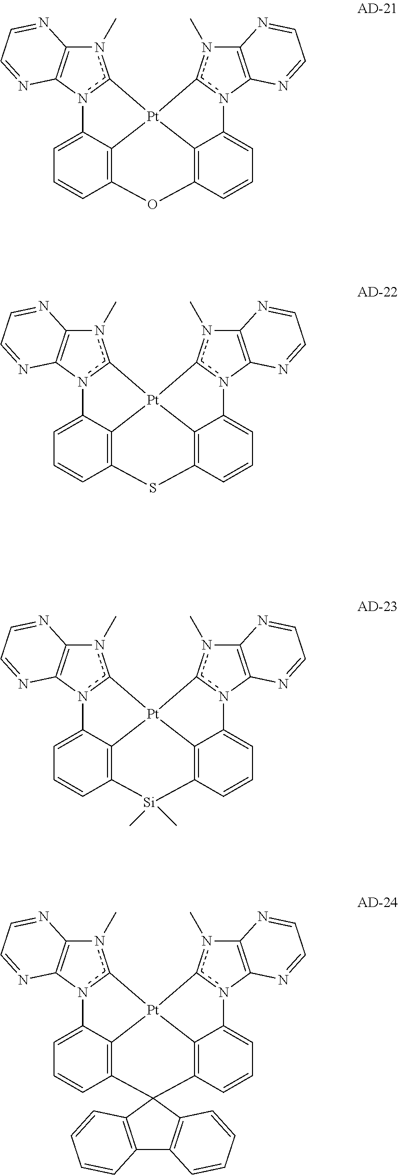

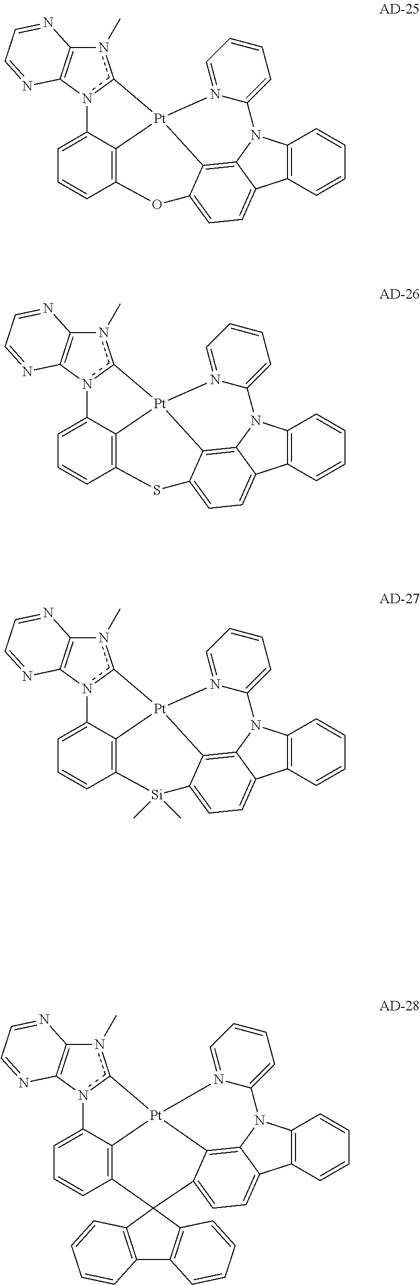

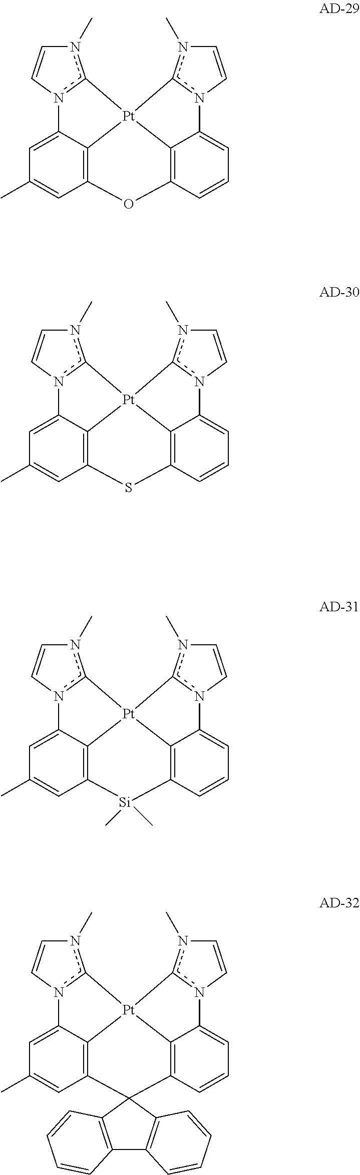

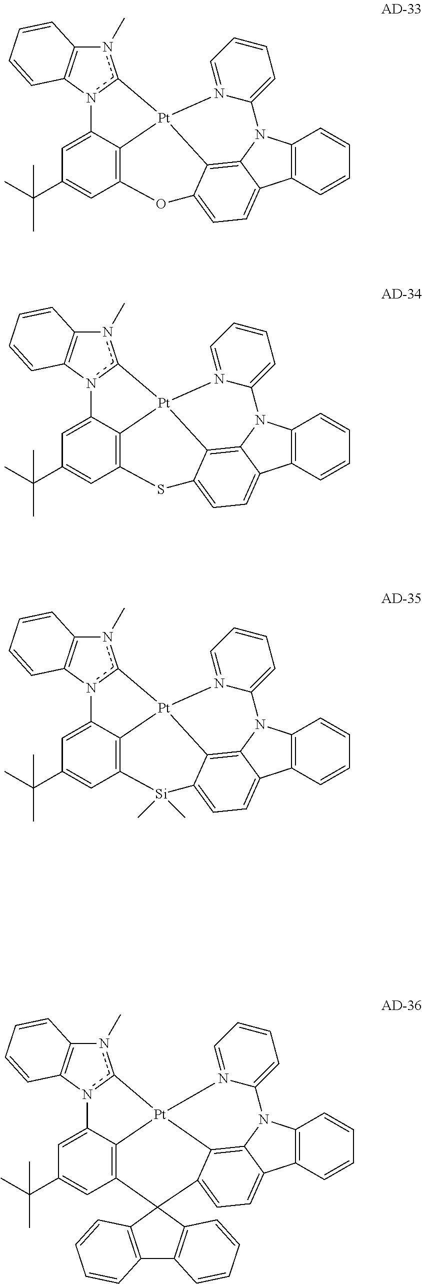

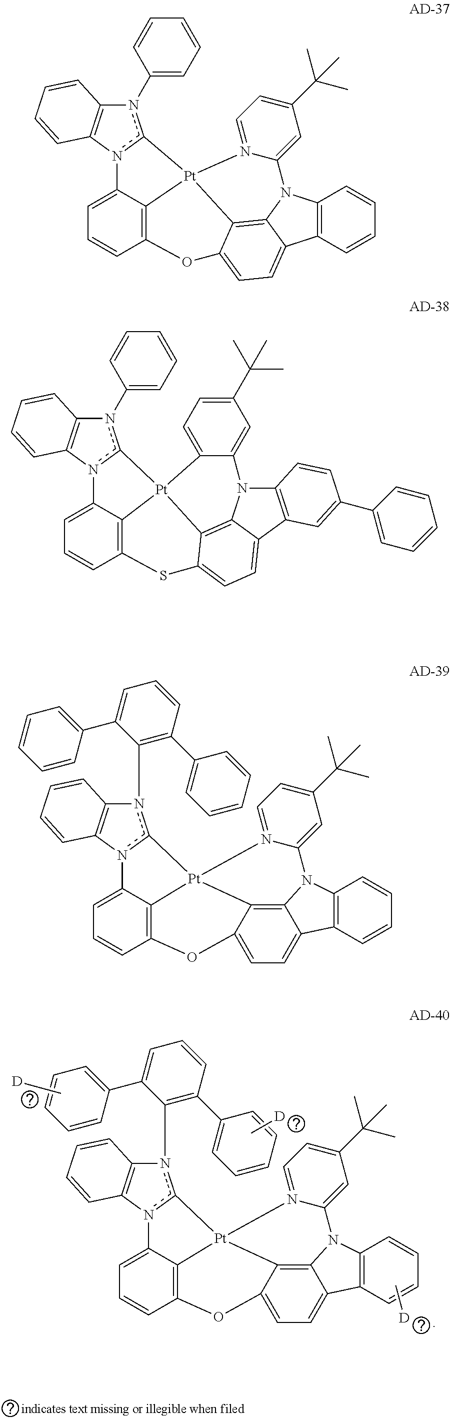

In some embodiments, the light emitting element ED of an embodiment may include a plurality of emission layers. The plurality of emission layers may be sequentially stacked and provided, and for example, the light emitting element ED including the plurality of emission layers may be to emit white light (e.g., combined white light). The light emitting element including the plurality of emission layers may be a light emitting element having a tandem structure. When the light emitting element ED includes the plurality of emission layers, at least one emission layer EML may include all of the first compound, the second compound, the third compound, and the fourth compound as described above.

In one or more embodiments, in the light emitting element ED of an embodiment, the emission layer EML may further include an anthracene derivative, a pyrene derivative, a fluoranthene derivative, a chrysene derivative, a dihydrobenzanthracene derivative, and/or a triphenylene derivative. In some embodiments, the emission layer EML may include an anthracene derivative and/or a pyrene derivative.

In the light emitting element ED of one or more embodiments shown in FIGS. 3 to 6, the emission layer EML may further include a suitable host and dopant in addition to the host and dopant described above. For example, in some embodiments, the emission layer EML may include a compound represented by Formula E-1. The compound represented by Formula E-1 may be utilized as a fluorescent host material.

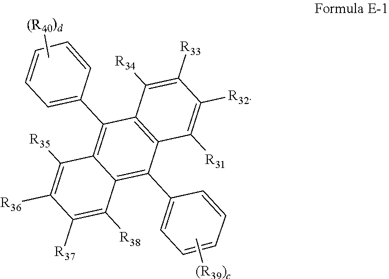

In Formula E-1, R₃₁ to R₄₀ may each independently be hydrogen, deuterium, a halogen, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. In some embodiments, one or more selected from R₃₁ to R₄₀ may be linked to an adjacent group to form a saturated hydrocarbon ring, an unsaturated hydrocarbon ring, a saturated heterocycle, or an unsaturated heterocycle.

In Formula E-1, c and d may each independently be an integer of 0 to 5.

The compound represented by Formula E-1 may be any one selected from among compounds E1 to E19.

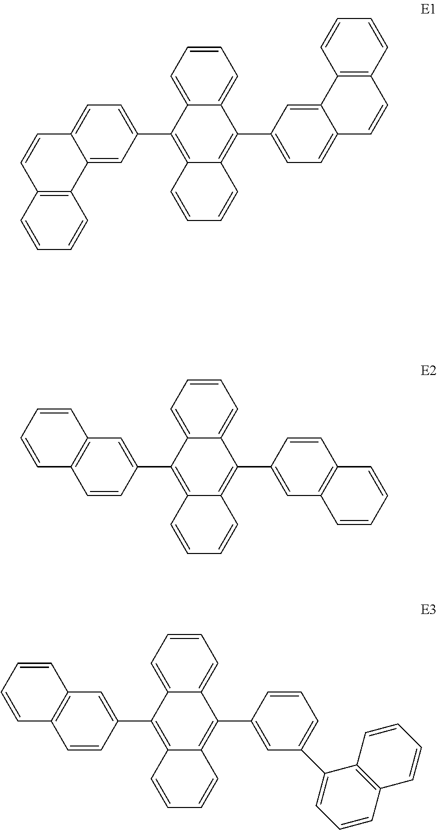

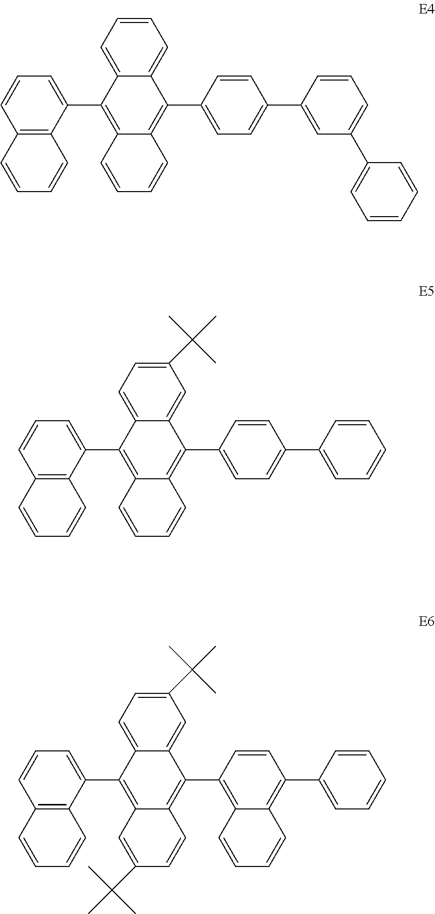

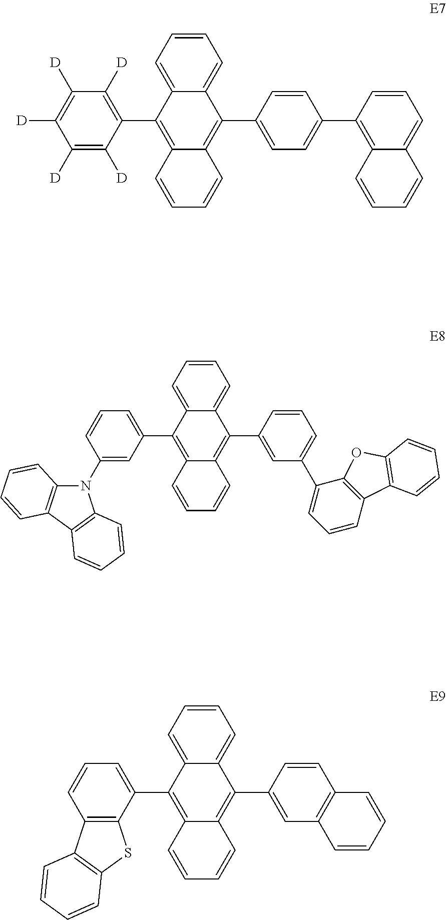 [SMILES: [2H]c1c([2H])c([2H])c(-c2c3ccccc3c(-c3ccc(-c4cccc5ccccc45)cc3)c3ccccc23)c([2H])c1[2H] ; c1cc(-c2c3ccccc3c(-c3cccc(-n4c5ccccc5c5ccccc54)c3)c3ccccc23)cc(-c2cccc3c2oc2ccccc23)c1 ; c1ccc2cc(-c3c4ccccc4c(-c4cccc5c4sc4ccccc45)c4ccccc34)ccc2c1]

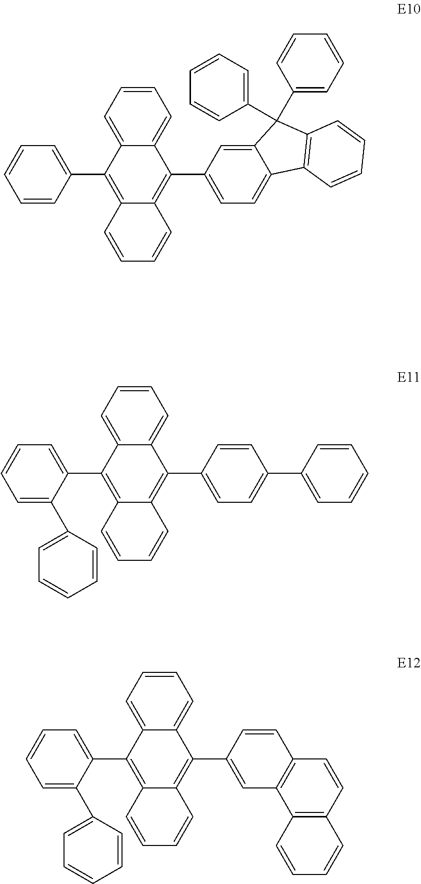

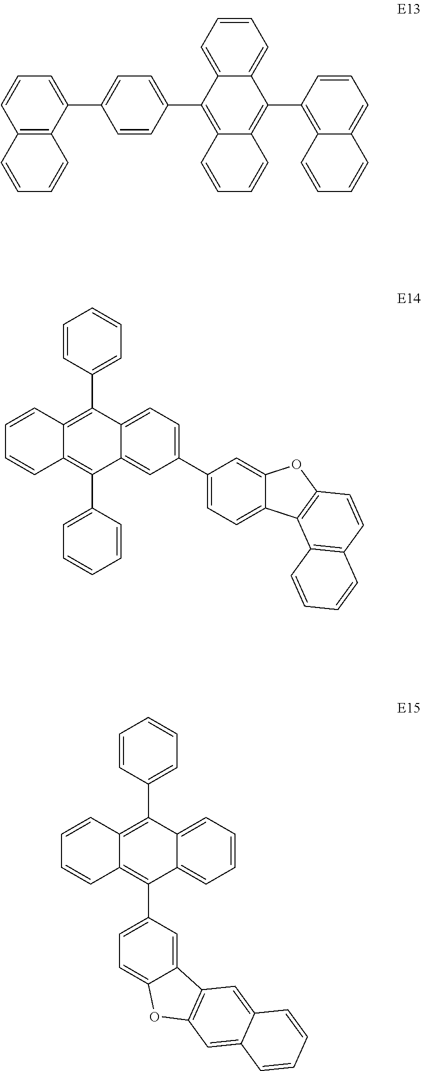

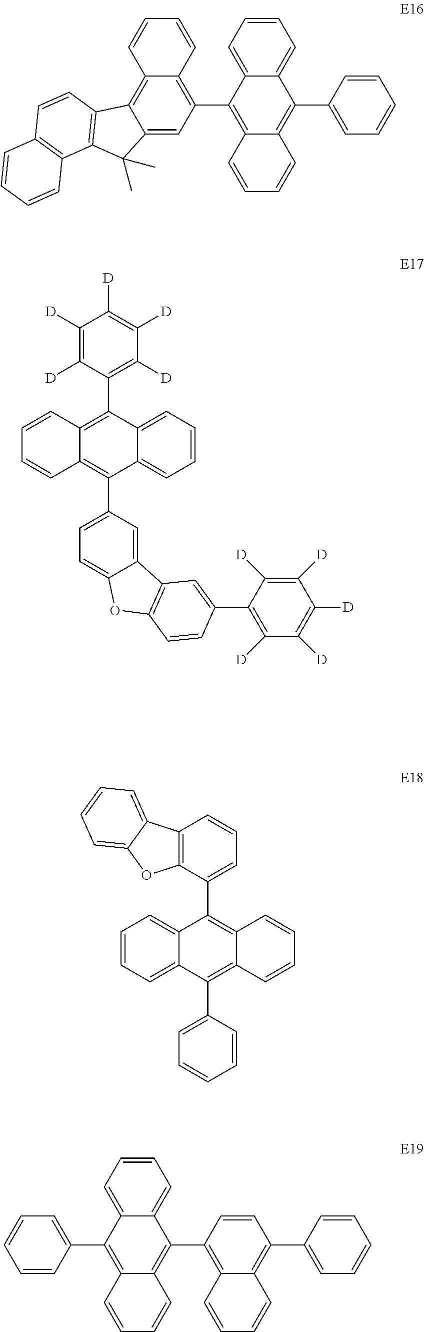

In one or more embodiments, the emission layer EML may include a compound represented by Formula E-2a or Formula E-2b. The compound represented by Formula E-2a or Formula E-2b may be utilized as a phosphorescent host material.

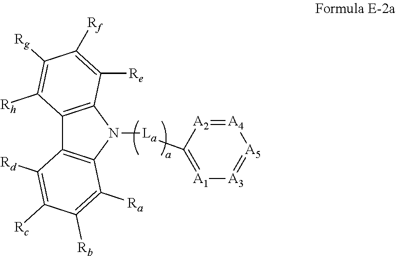

In Formula E-2a, a may be an integer of 0 to 10, and La may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a is an integer of 2 or greater, a plurality of La's may each independently be a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A1 to A₅ may be N or CRᵢ. Ra to Rᵢ may each independently be hydrogen, deuterium, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. In some embodiments, Ra to Rᵢ may be bonded to an adjacent group to form a hydrocarbon ring or a heterocycle containing N, O, S, and/or the like as a ring-forming atom.

In some embodiments, in Formula E-2a, two or three selected from A1 to A5 may be N, and the others (the remainder) may be CRᵢ.

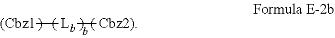

In Formula E-2b, Cbz1 and Cbz2 may each independently be an unsubstituted carbazole group or an aryl-substituted carbazole group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms, b may be an integer of 0 to 10, and when b is an integer of 2 or greater, a plurality of L_{b}'s may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be any one selected from among compounds from Compound Group E-2. However, the compounds listed in Compound Group E-2 are presented as a mere example, and the compound represented by Formula E-2a or Formula E-2b is not limited to those listed in Compound Group E-2.

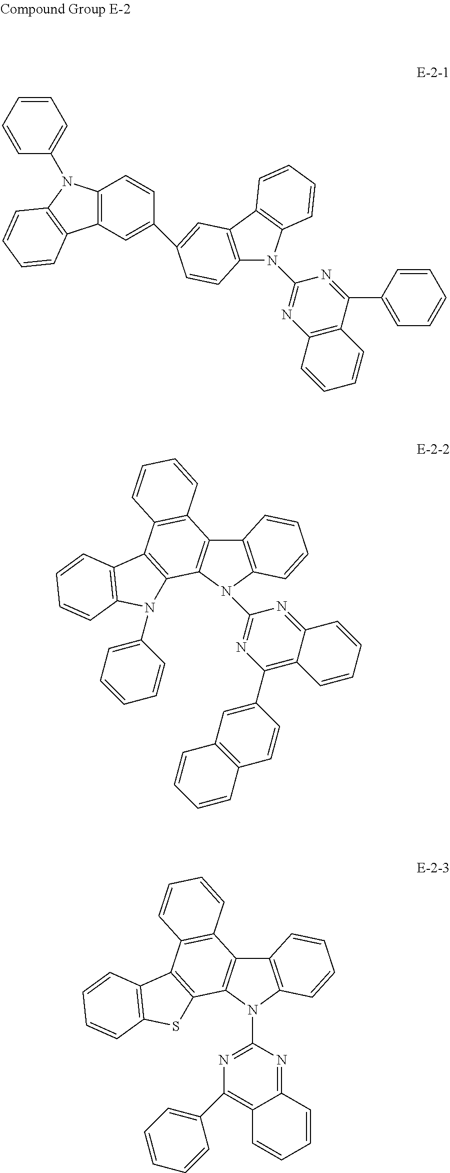 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

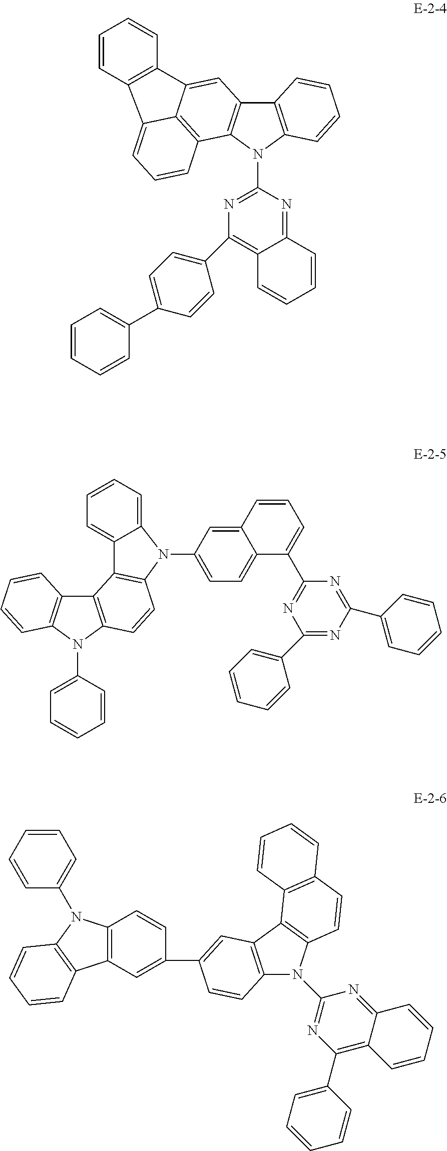 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

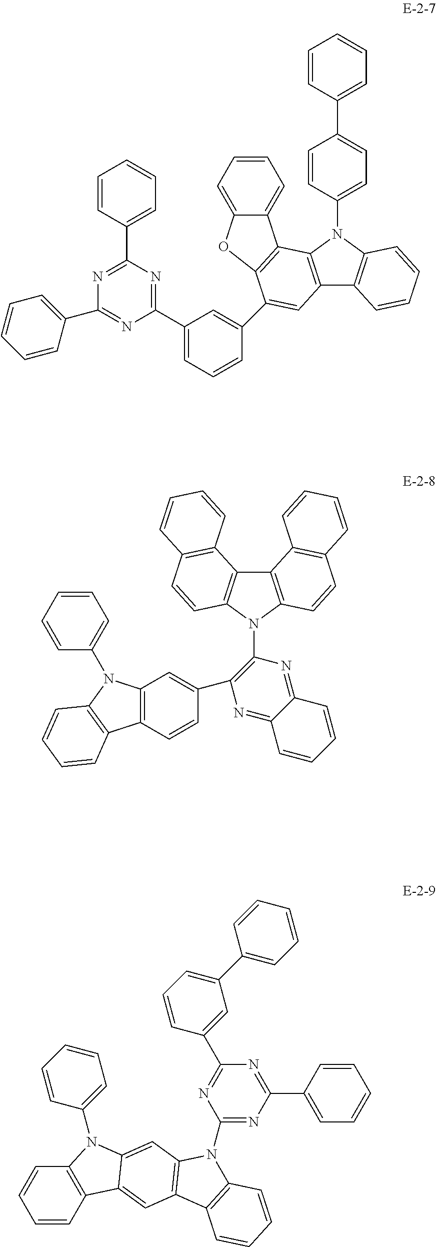 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

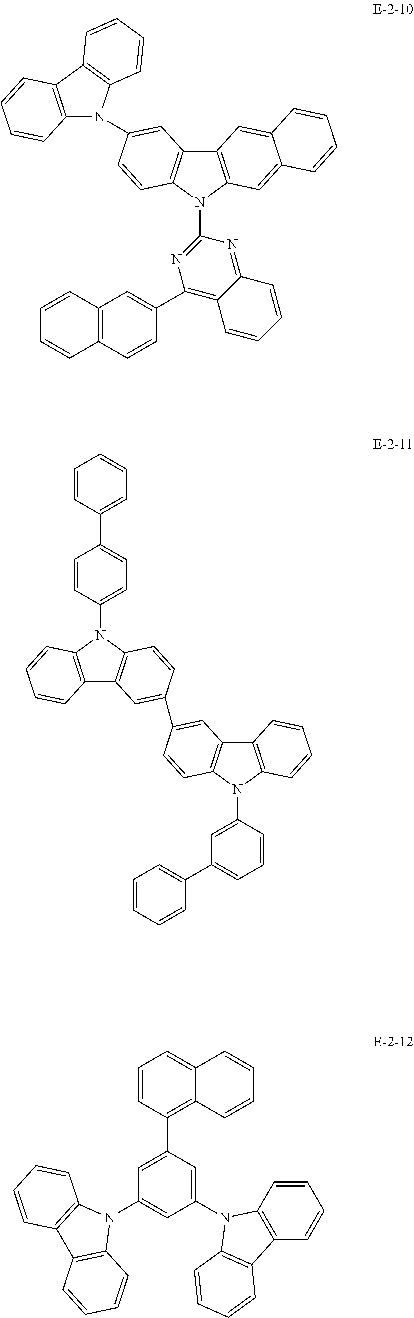 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

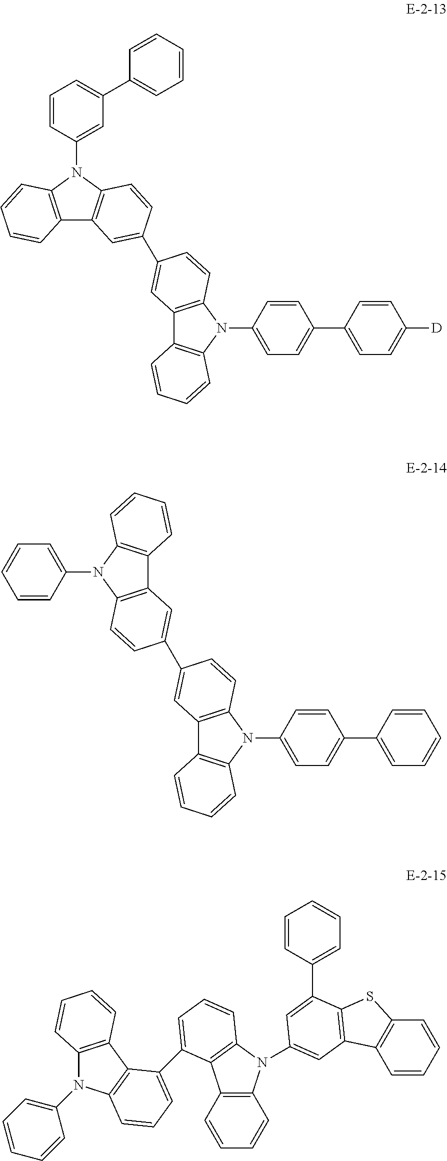 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

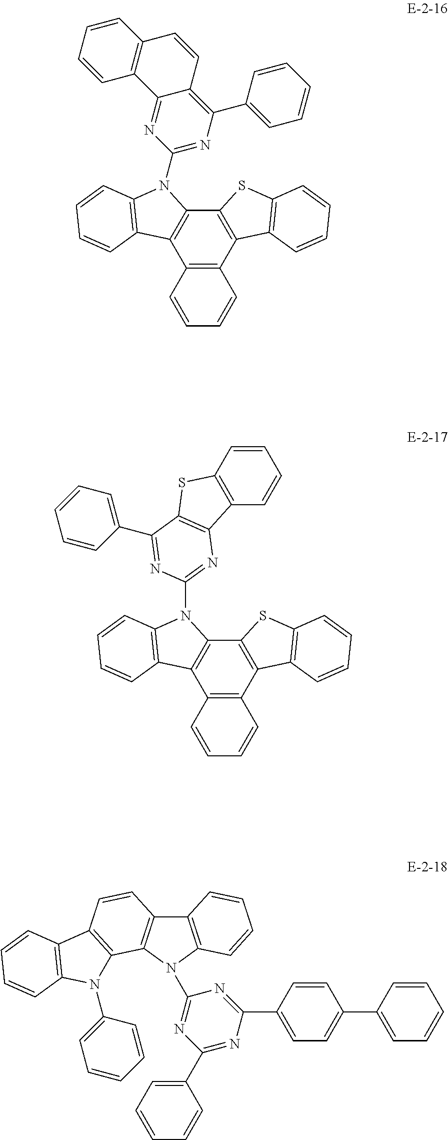 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

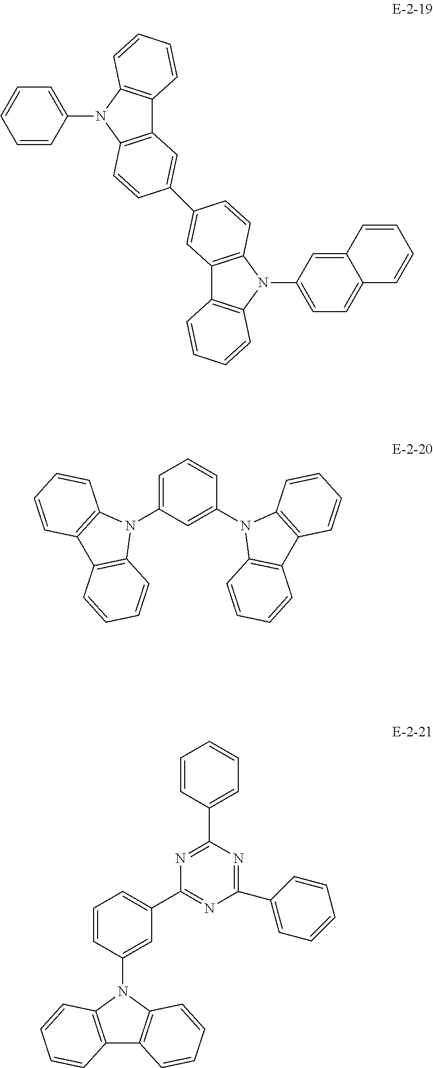 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1]

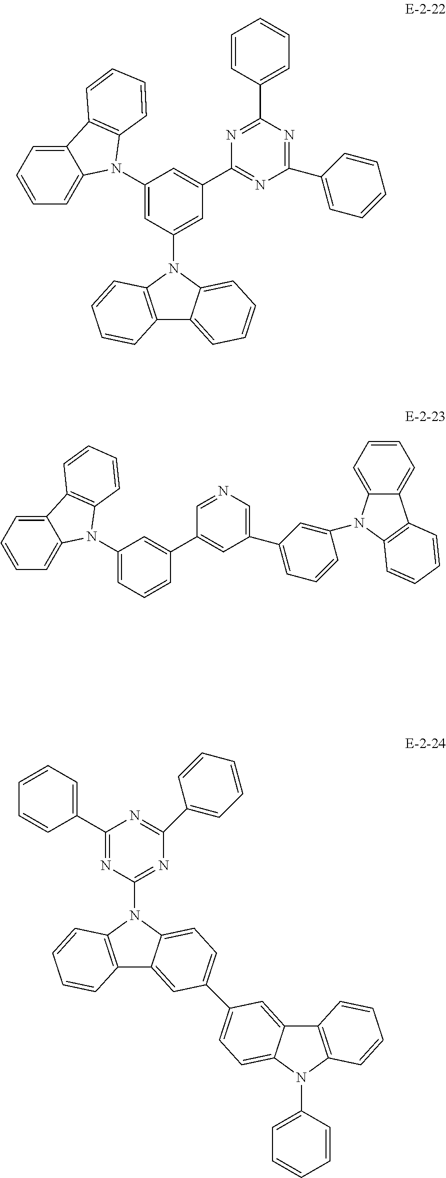 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

In one or more embodiments, the emission layer EML may further include a general material suitable in the art as a host material. For example, in some embodiments, the emission layer EML may include, as a host material, at least one selected from among bis(4-(9H-carbazol-9-yl)phenyl)diphenylsilane (BCPDS), (4-(1-(4-(diphenylamino)phenyl) cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzofuran (PPF), 4,4′,4″-tris(carbazol-9-yl)-triphenylamine (TCTA), and 1,3,5-tris(1-phenyl-1H-benzo[d]imidazol-2-yl)benzene (TPBi). However, embodiments of the present disclosure are not limited thereto, and for example, tris(8-hydroxyquinolino)aluminum (Alq₃), 9,10-di(naphthalen-2-yl)anthracene (ADN), 3-tert-butyl-9,10-di(naphth-2-yl)anthracene (TBADN), distyrylarylene (DSA), 4,4′-bis(9-carbazolyl)-2,2′-dimethylbiphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), and/or the like may be utilized as a host material.

In one or more embodiments, the emission layer EML may include a compound represented by Formula M-a. The compound represented by Formula M-a may be utilized as a phosphorescent dopant material.

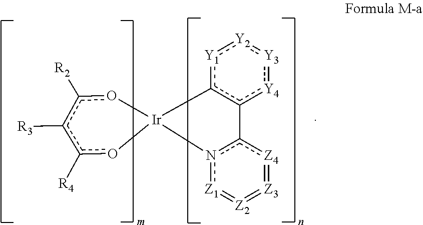

In Formula M-a, Y₁ to Y₄, and Z₁ to Z₄ may each independently be CR₁ or N, and R₁ to R₄ may each independently be hydrogen, deuterium, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. In Formula M-a, m is 0 or 1, and n is 2 or 3. In Formula M-a, when m is 0, n is 3, and when m is 1, n is 2.

The compound represented by Formula M-a may be any one selected from among compounds M-a1 to M-a25. However, the compounds M-a1 to M-a25 are presented as a mere example, and the compound represented by Formula M-a is not limited to those represented by the compounds M-a1 to M-a25.

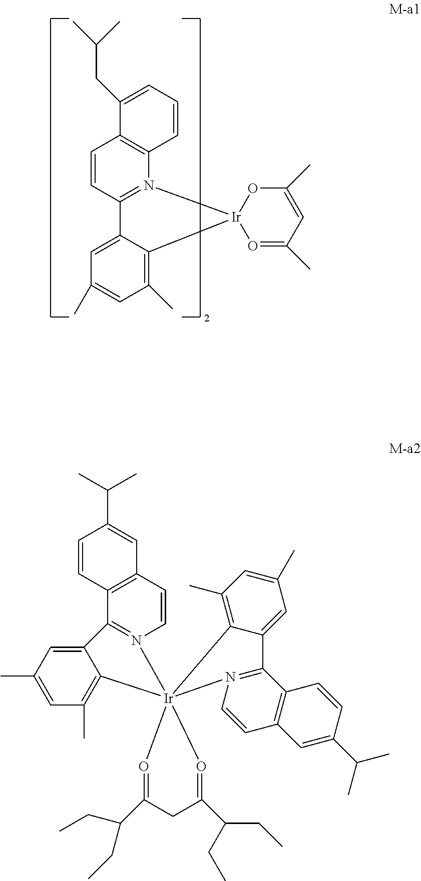

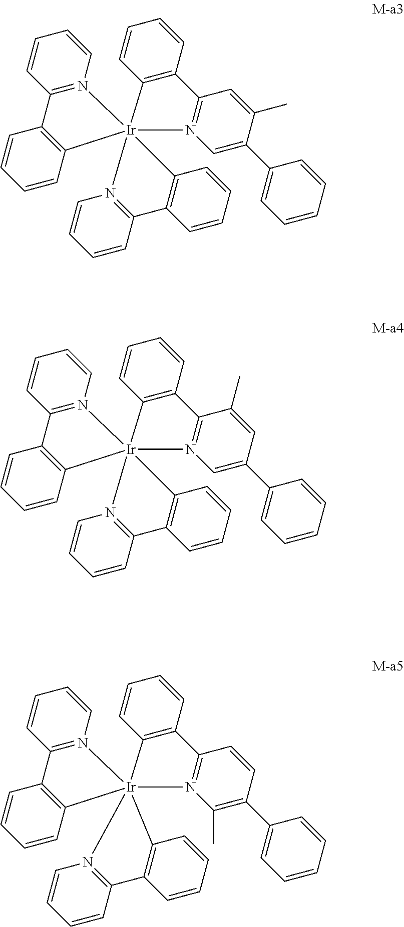

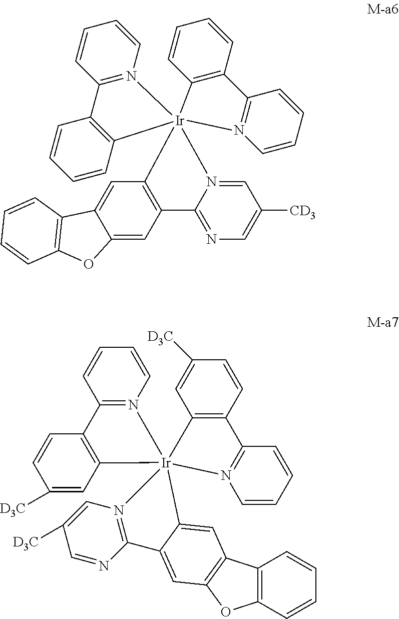

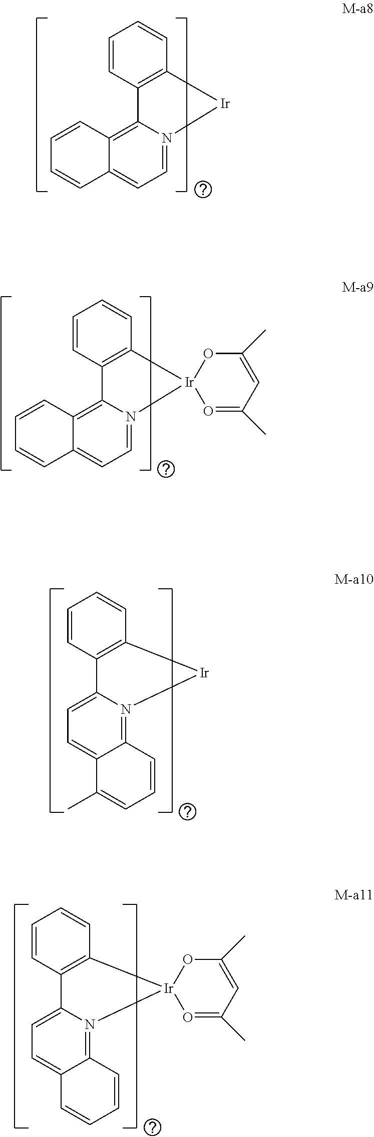

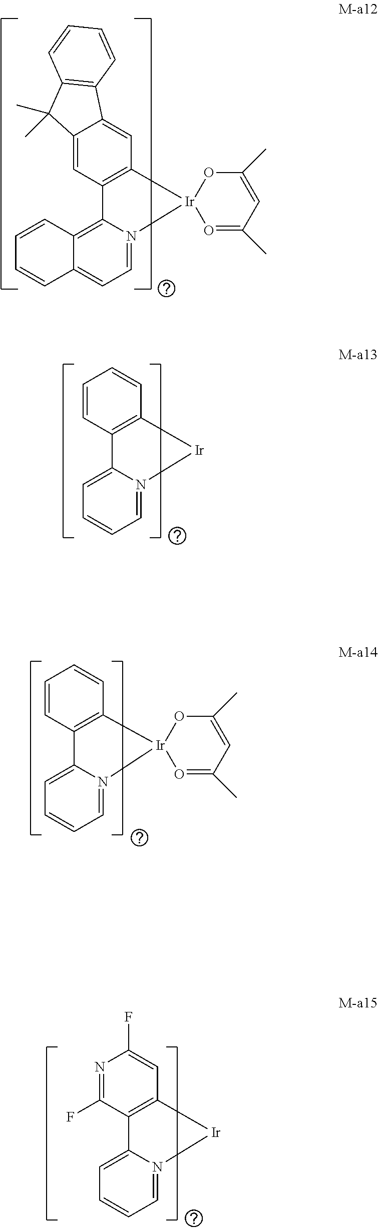

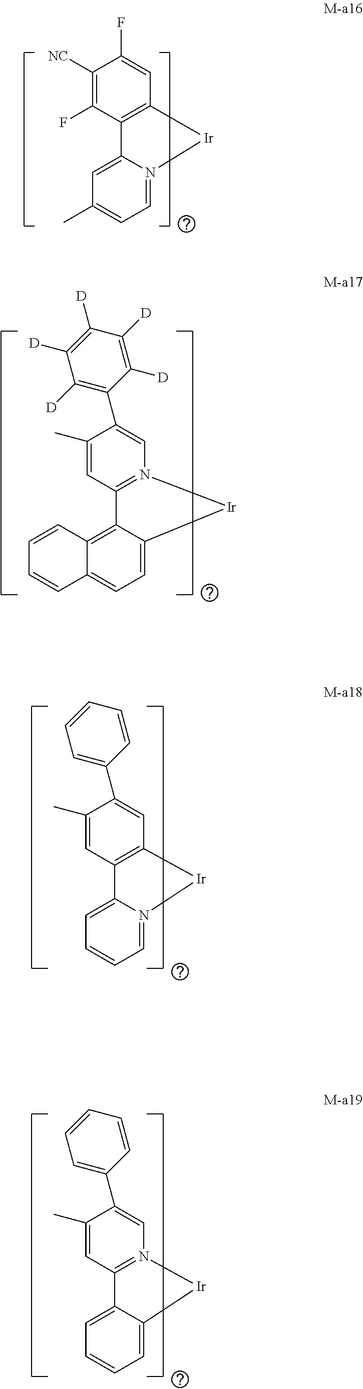

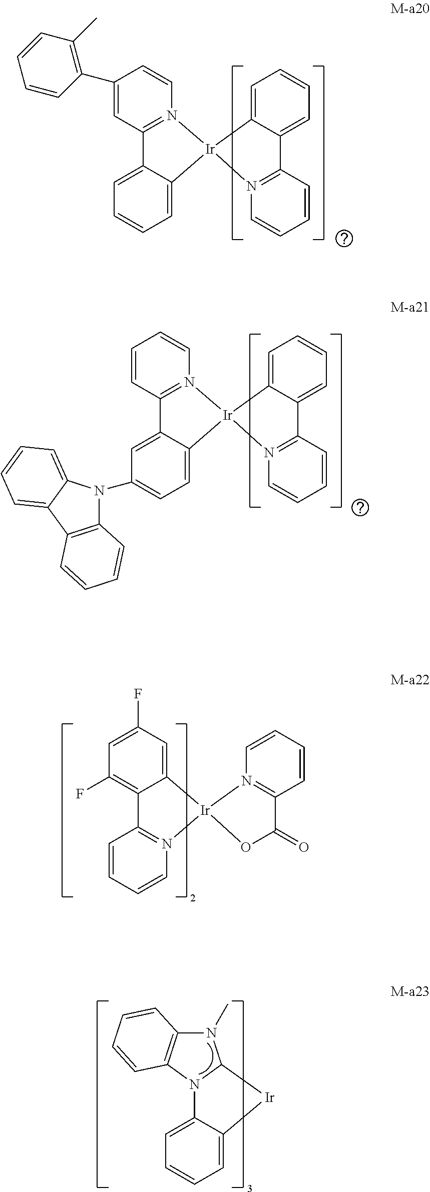

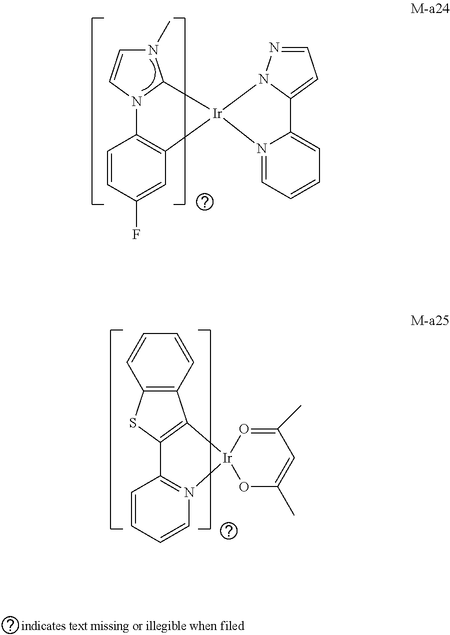

In one or more embodiments, the emission layer EML may include a compound represented by any one selected from among Formulas F-a to F-c. The compounds represented by Formulas F-a to F-c may be utilized as a fluorescent dopant material.

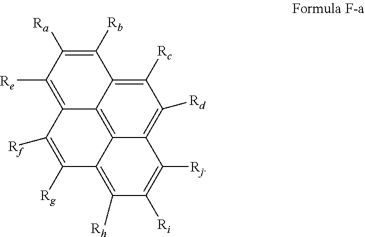

In Formula F-a, two selected from Rₐ to Rⱼ may each independently be substituted with *- NAr₁Ar₂. The others (the remainder) among Rₐ to Rⱼ which are not substituted with *- NAr₁Ar₂ may each independently be hydrogen, deuterium, a halogen, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In *- NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, in some embodiments, at least one of Ar₁ or Ar₂ may be a heteroaryl group containing O or S as a ring-forming atom.

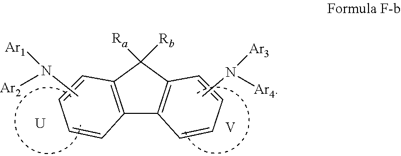

In Formula F-b above, Rₐ and R_{b} may each independently be hydrogen, deuterium, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In Formula F-b, Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms.

In Formula F-b, the number of rings represented by U and V may each independently be 0 or 1. For example, In Formula F-b, when the number of U or V is 1, one ring forms a fused ring in a portion indicated by U or V, and when the number of U or V is 0, it refers to that no ring indicated by U or V is present. For example, when the number of U is 0 and the number of V is 1, or when the number of U is 1 and the number of V is 0, a fused ring having a fluorene core of Formula F-b may be a cyclic compound having four rings. In some embodiments, when both (e.g., simultaneously) U and V are 0, the fused ring of Formula F-b may be a cyclic compound having three rings. In some embodiments, when both (e.g., simultaneously) U and V are 1, the fused ring having a fluorene core of Formula F-b may be a cyclic compound having five rings.

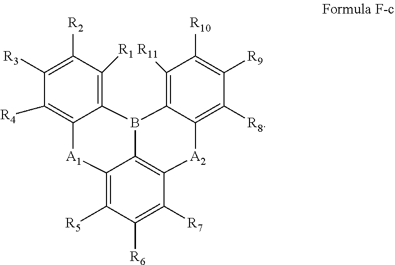

In Formula F-c, A1 and A2 may each independently be O, S, Se, or NRₘ, and Rₘ may be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be hydrogen, deuterium, a halogen, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In Formula F-c, A1 and A2 may each independently be bonded to substituents of neighboring rings to form a fused ring. For example, when A1 and A2 may each independently be NRₘ, A1 may be bonded to R₄ or R₅ to form a ring. In some embodiments, A2 may be bonded to R₇ or R₈ to form a ring.

In one or more embodiments, the emission layer EML may include, as a suitable dopant material, one or more styryl derivatives (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi)), perylene and/or derivatives thereof (e.g., 2,5,8,11-tetra-t-butylperylene (TBP)), pyrene and/or derivatives thereof (e.g., 1,1-dipyrene, 1,4-dipyrenylbenzene, 1,4-bis(N,N-diphenylamino)pyrene), and/or the like.

In one or more embodiments, the emission layer EML may include a suitable phosphorescent dopant material. For example, as a phosphorescent dopant, a metal complex including iridium (Ir), platinum (Pt), osmium (Os), gold (Au), titanium (Ti), zirconium (Zr), hafnium (Hf), europium (Eu), terbium (Tb), or thulium (Tm) may be utilized. In some embodiments, iridium(III) bis(4,6-difluorophenylpyridinato-N,C2′)picolinate (Flrpic), bis(2,4-difluorophenylpyridinato)-tetrakis(1-pyrazolyl)borate iridium(III) (Fir6), platinum octaethyl porphyrin (PtOEP), and/or the like may be utilized as a phosphorescent dopant. However, embodiments of the present disclosure are not limited thereto.

In one or more embodiments, the emission layer EML may include a quantum dot material. In the present disclosure, a quantum dot indicates a crystal of a semiconductor compound. The quantum dot may be to emit light of one or more suitable emission wavelengths depending on the size of the crystal. In some embodiments, the quantum dot may be to emit light of one or more suitable emission wavelengths by regulating an element ratio in the quantum dot compound.

The core of a quantum dot may be selected from a Group II-VI compound, a Group III-VI compound, a Group I-III-VI compound, a Group III-V compound, a Group III-II-V compound, a Group IV-VI compound, a Group IV element, a Group IV compound, and combinations thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and mixtures thereof.

The Group III-VI compound may include a binary compound such as In₂S₃ and In₂Se₃, a ternary compound such as InGaS₃ and InGaSe₃, or any combination thereof.

The Group I-III-VI compound may be selected from a ternary compound selected from the group consisting of AgInS, AglnS₂, CulnS, CulnS₂, AgGaS₂, CuGaS₂ CuGaO₂, AgGaO₂, AgAIO₂, and mixtures thereof; and a quaternary compound such as AgInGaS₂ and/or CulnGaS₂.

The Group III-V compound may be selected from the group consisting of a binary compound selected from the group consisting of GaN, GaP, GaAs, GaSb, AlN, AIP, AIAs, AISb, InN, InP, InAs, InSb, and mixtures thereof; a ternary compound selected from the group consisting of GaNP, GaNAs, GaNSb, GaPAs, GaPSb, AlNP, AlNAs, AlNSb, AIPAS, AIPSb, InGaP, InAIP, InNP, InNAs, InNSb, InPAs, InPSb, and mixtures thereof; and a quaternary compound selected from the group consisting of GaAINP, GaAINAs, GaAINSb, GaAIPAs, GaAIPSb, GalnNP, GalnNAs, GalnNSb, GalnPAs, GalnPSb, InAINP, InAINAs, InAINSb, InAIPAs, InAIPSb, and mixtures thereof. In some embodiments, the Group III-V compound may further include a Group Il metal. For example, InZnP and/or the like may be selected as a Group III-II-V compound.

The Group IV-VI compound may be selected from the group consisting of a binary compound selected from the group consisting of SnS, SnSe, SnTe, PbS, PbSe, PbTe, and mixtures thereof; a ternary compound selected from the group consisting of SnSeS, SnSeTe, SnSTe, PbSeS, PbSeTe, PbSTe, SnPbS, SnPbSe, SnPbTe, and mixtures thereof; and a quaternary compound selected from the group consisting of SnPbSSe, SnPbSeTe, SnPbSTe, and mixtures thereof. The Group IV element may be selected from the group consisting of Si, Ge, and mixtures thereof. The Group IV compound may be a binary compound selected from the group consisting of SiC, SiGe, and mixtures thereof.

The Group IV element or compound may include a single element compound such as Si and Ge, a binary compound such as SiC and SiGe, or any combination thereof.

Each element included in the multi-element compound such as the binary compound, ternary compound, and quaternary compound may be present in particles at a substantially uniform concentration or a non-substantially uniform concentration.

For example, Formula above indicates the types (kinds) of elements included in a compound, and element ratios in the compound may be different. For example, AgInGaS₂ may indicate AgInₓGa₁₋ₓS₂ (x is a real number between 0 and 1).

In some embodiments, the quantum dot may have a single structure having a substantially uniform concentration of each element included in the corresponding quantum dot or a dual structure of a core-shell. For example, materials included in the core may be different from materials included in the shell.

The shell of the quantum dot may serve as a protection layer to prevent or reduce the chemical deformation of the core so as to keep semiconductor properties, and/or a charging layer to impart electrophoresis properties to the quantum dot. The shell may be a single layer or multiple layers. The core/shell structure may have a concentration gradient in which the concentration of an element present in the shell becomes lower towards the core.

Examples of the shell of the quantum dot may be a metal or non-metal oxide, a semiconductor compound, or a combination thereof.

Non-limiting examples of the oxide of metal or non-metal suitable as a shell may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO; a ternary compound such as MgAl₂O₄, CoFe₂O₄, NiFe₂O₄, and/or CoMn₂O₄; or any combination thereof.

Non-limiting examples of the semiconductor compound suitable as a shell may include, as described herein, Group III-VI semiconductor compounds, Group II-VI semiconductor compounds, Group III-V semiconductor compounds, Group III-VI semiconductor compounds, Group I-III-VI semiconductor compounds, Group IV-VI semiconductor compounds, or any combination thereof. For example, the semiconductor compound suitable as a shell may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AIP, AISb, or any combination thereof. The quantum dot may have, in an emission spectrum, a full width of half maximum (FWHM) of about 45 nm or less, about 40 nm or less, or about 30 nm or less. Within this range, the color purity or the color reproducibility of the light emitting device may be improved. In some embodiments, light emitted through the quantum dot is emitted in all directions, and thus a wide viewing angle may be improved.

In some embodiments, the form of a quantum dot is not particularly limited as long as it is a form commonly utilized in the art. In some embodiments, a quantum dot in the form of substantially spherical, pyramidal, multi-arm, or cubic nanoparticles, nanotubes, nanowires, nanofibers, nanoplatelets, and/or the like may be utilized.

As the size of the quantum dot or the ratio of elements in the quantum dot compound is regulated, the energy band gap may be accordingly controlled or selected to obtain light of one or more suitable wavelengths from a quantum dot emission layer. Therefore, by utilizing the quantum dots described above (utilizing quantum dots of different sizes or having different element ratios in the quantum dot compound), a light emitting element emitting light of one or more suitable wavelengths may be obtained. For example, the size of the quantum dots or the ratio of elements in the quantum dot compound may be regulated to emit red, green, and/or blue light. In some embodiments, the quantum dots may be configured to emit white light by combining light of one or more suitable colors. The quantum dots may have a diameter of, for example, about 1 nm to about 10 nm.

The quantum dot may be synthesized through a wet chemical process, a metal organic chemical vapor deposition process, a molecular beam epitaxy process, or a process similar thereto.

The wet chemical process is a method of mixing an organic solvent and a quantum dot precursor material and then growing a quantum dot particle crystal. When the crystal grows, the organic solvent naturally serves as a dispersant coordinated to a surface of the quantum dot crystal and may control the growth of the crystal. Therefore, the wet chemical process is easier than vapor deposition methods such as metal organic chemical vapor deposition (MOCVD) or molecular beam epitaxy (MBE), and may control the growth of quantum dot particles through a low-cost process.

In the light emitting element ED according to one or more embodiments shown in FIGS. 3 to 6, the electron transport region ETR is provided on the emission layer EML. The electron transport region ETR may include at least one selected from among a hole blocking layer HBL, an electron transport layer ETL, and an electron injection layer EIL, but embodiments of the present disclosure are not limited thereto.

The electron transport region ETR may have a single layer formed of a single material, a single layer formed of a plurality of different materials, or a multilayer structure having a plurality of layers formed of a plurality of different materials.

For example, in some embodiments, the electron transport region ETR may have a single layer structure of an electron injection layer EIL or an electron transport layer ETL, and may have a single layer structure formed of an electron injection material and an electron transport material. In some embodiments, the electron transport region ETR may have a single layer structure formed of a plurality of different materials, or may have a structure in which an electron transport layer ETL/electron injection layer EIL, or a hole blocking layer HBL/electron transport layer ETL/electron injection layer EIL are stacked in the stated order from the emission layer EML, but embodiments of the present disclosure are not limited thereto. The electron transport region ETR may have a thickness of, for example, about 1000 Å to about 1500 Å.

The electron transport region ETR may be formed utilizing one or more suitable methods such as a vacuum deposition method, a spin coating method, a casting method, a Langmuir-Blodgett (LB) method, an inkjet printing method, a laser printing method, and/or a laser induced thermal imaging (LITI) method.

In one or more embodiments, the electron transport region ETR may include a compound represented by Formula ET-1.

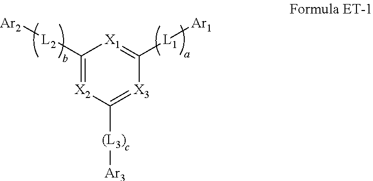

In Formula ET-1, at least one selected from among X₁ to X₃ is N and the others (the remainder) are CRₐ. Rₐ may be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer of 0 to 10. In Formula ET-1, L₁ to Ls may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a to c are an integer of 2 or greater, L₁ to Ls may each independently be a substituted or unsubstituted arylene group having 6 to 30 ring-forming carbon atoms, or a substituted or unsubstituted heteroarylene group having 2 to 30 ring-forming carbon atoms.

In one or more embodiments, the electron transport region ETR may include an anthracene-based compound. However, embodiments of the present disclosure are not limited thereto, and, in some embodiments, the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazol-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(biphenyl-4-yl)-4-phenyl-5-tert-butylphenyl-1,2,4-triazole (TAZ), 4-(naphthalen-1-yl)-3,5-diphenyl-4H-1,2,4-triazole (NTAZ), 2-(biphenyl-4-yl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), berylliumbis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), or a mixture thereof.

In one or more embodiments, the electron transport region ETR may include at least one selected from among compounds ET1 to ET36.

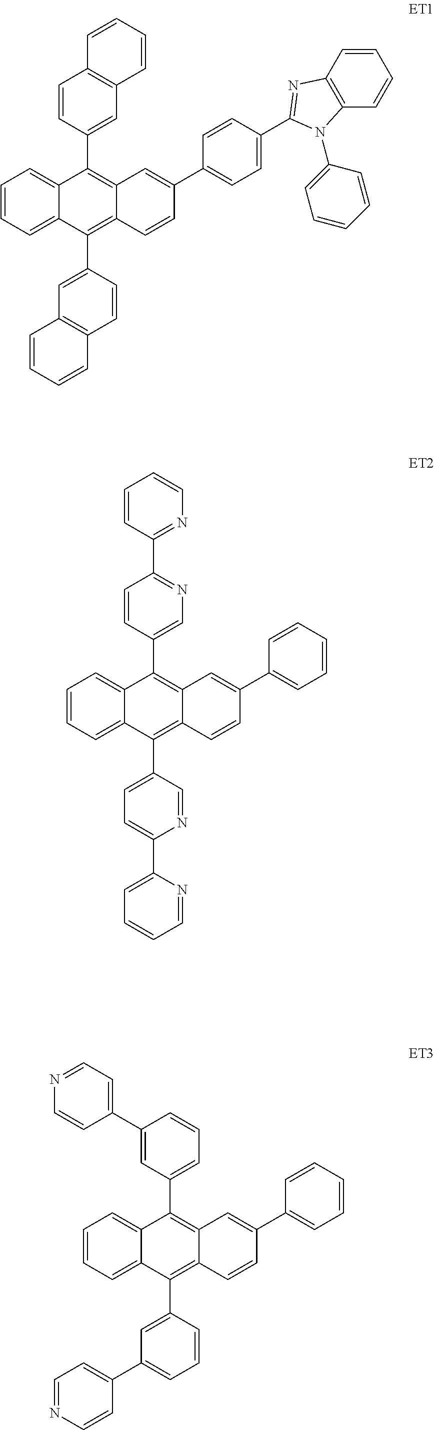 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

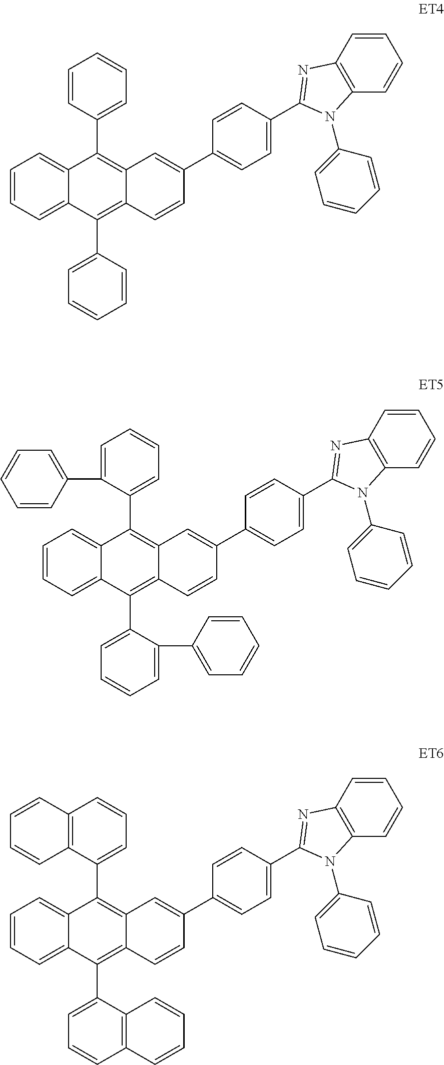 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

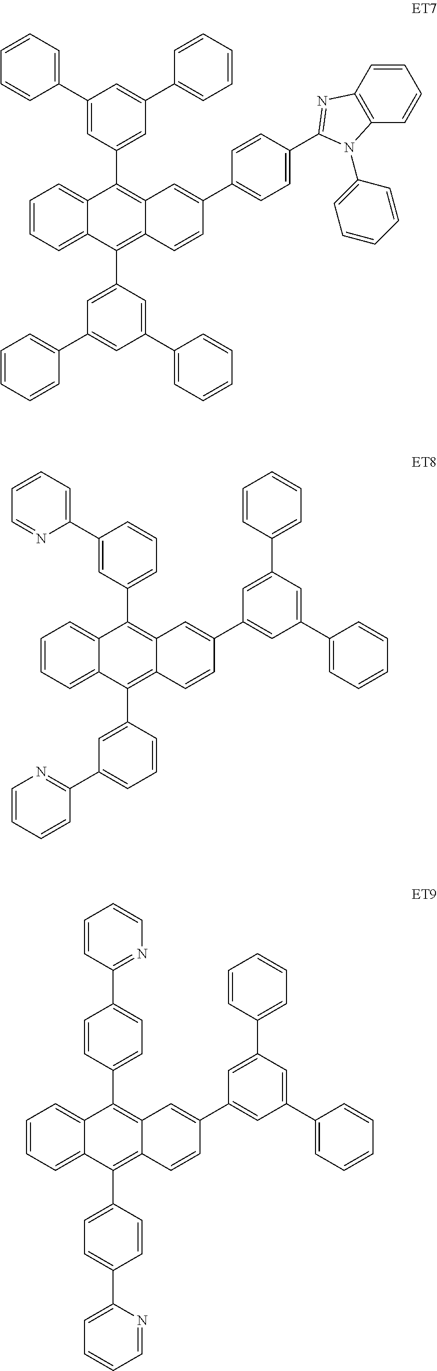 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

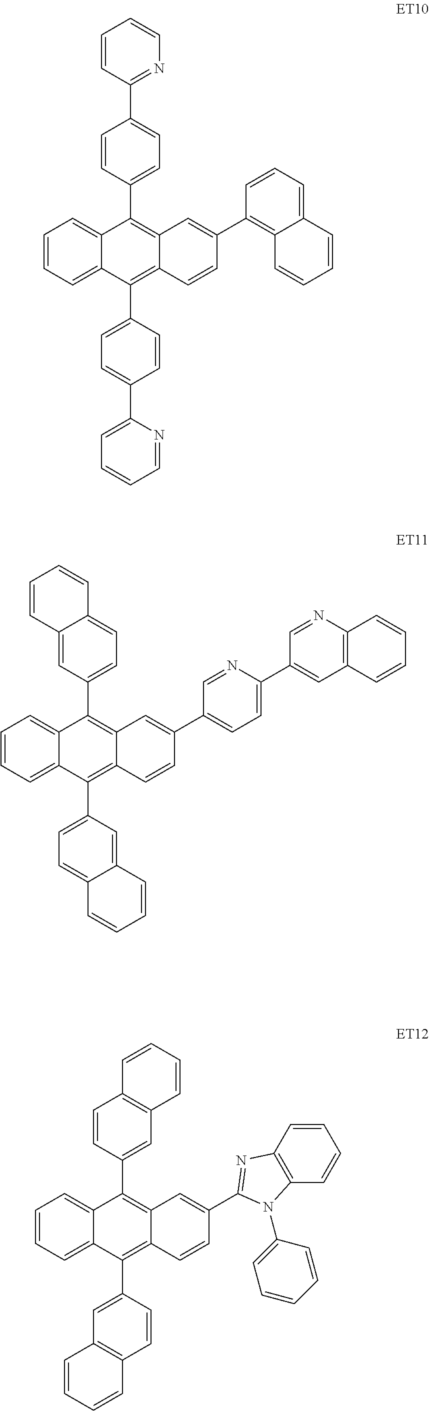 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

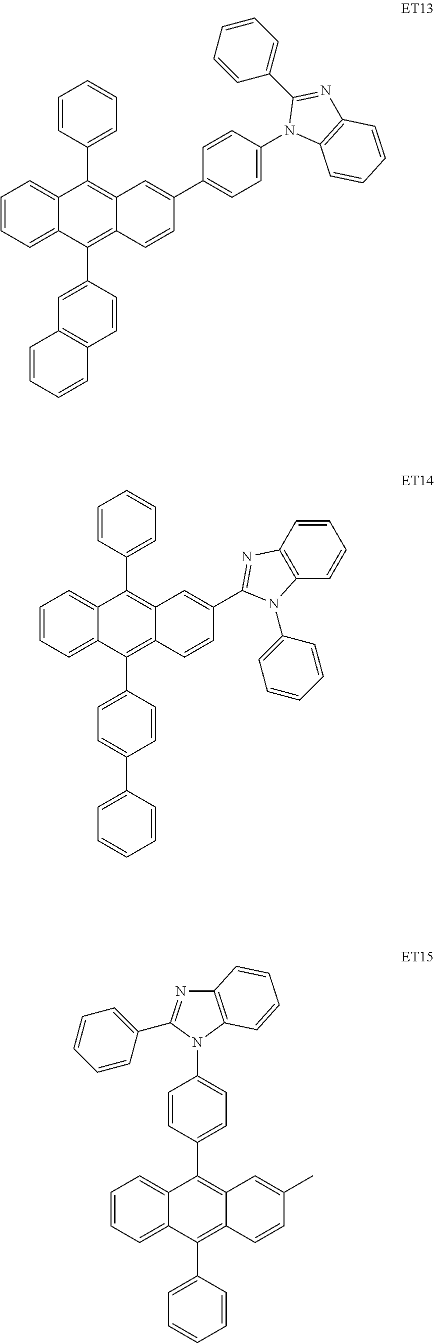 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

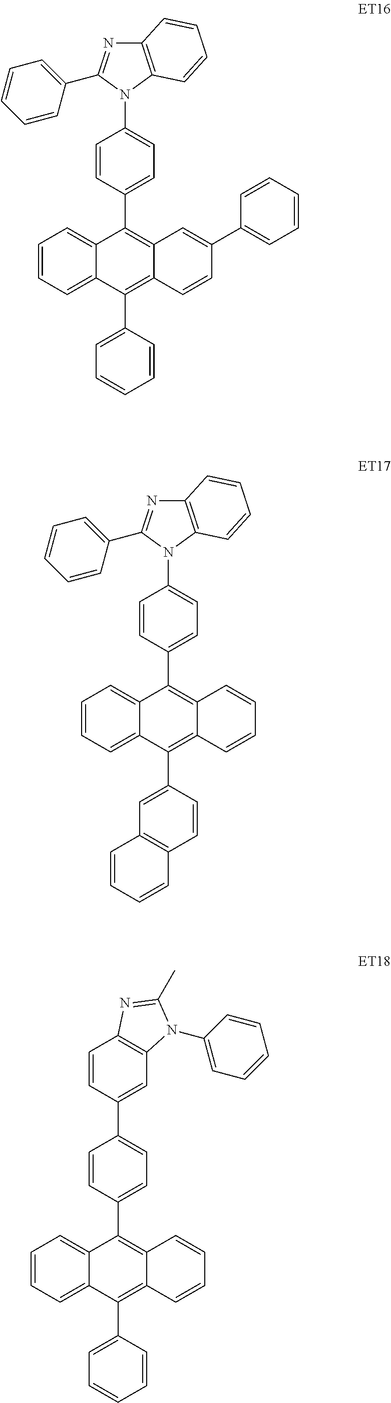 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

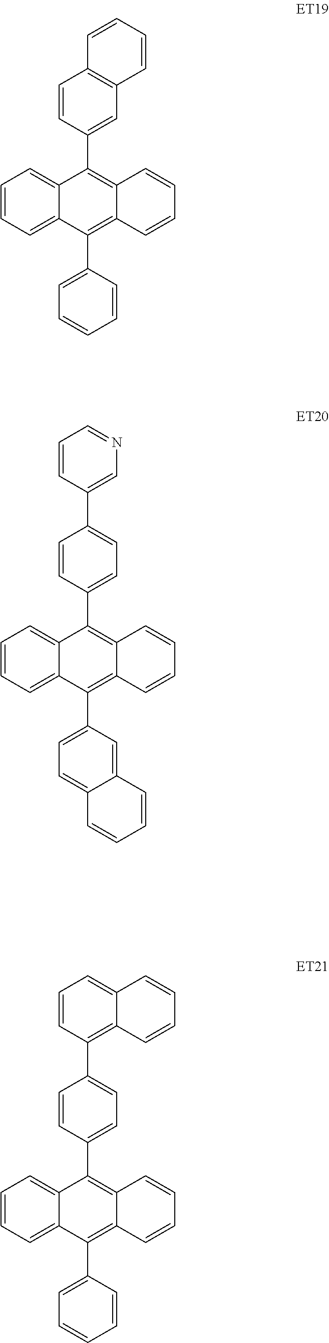

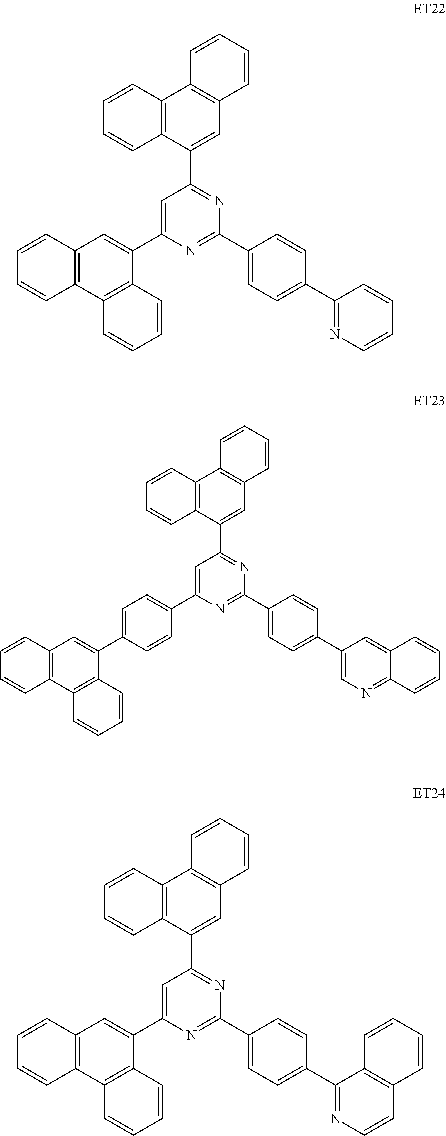 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

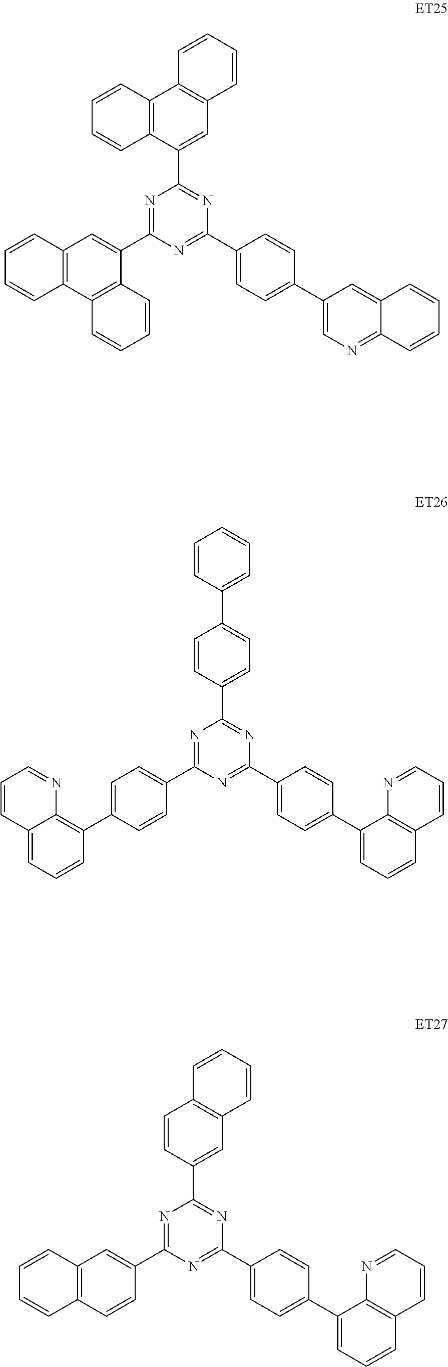 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

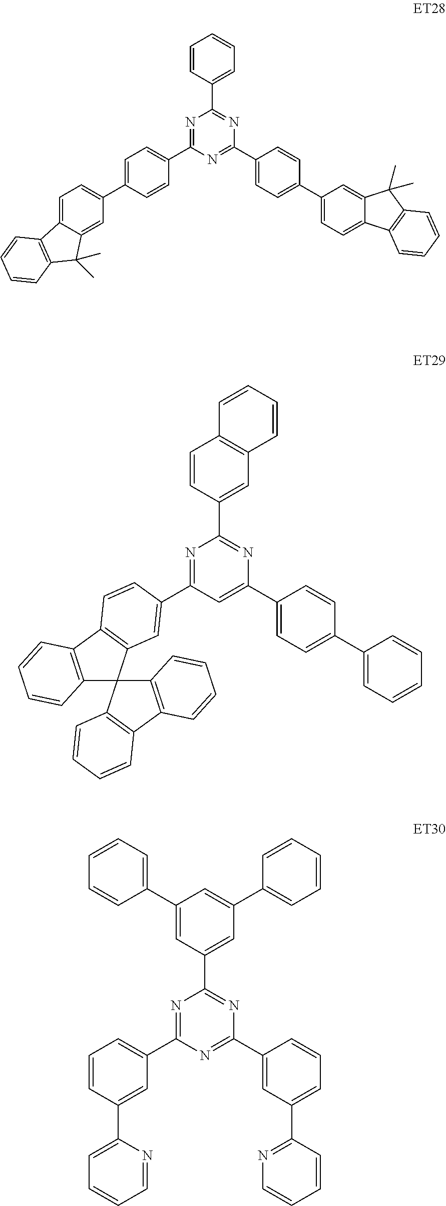 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

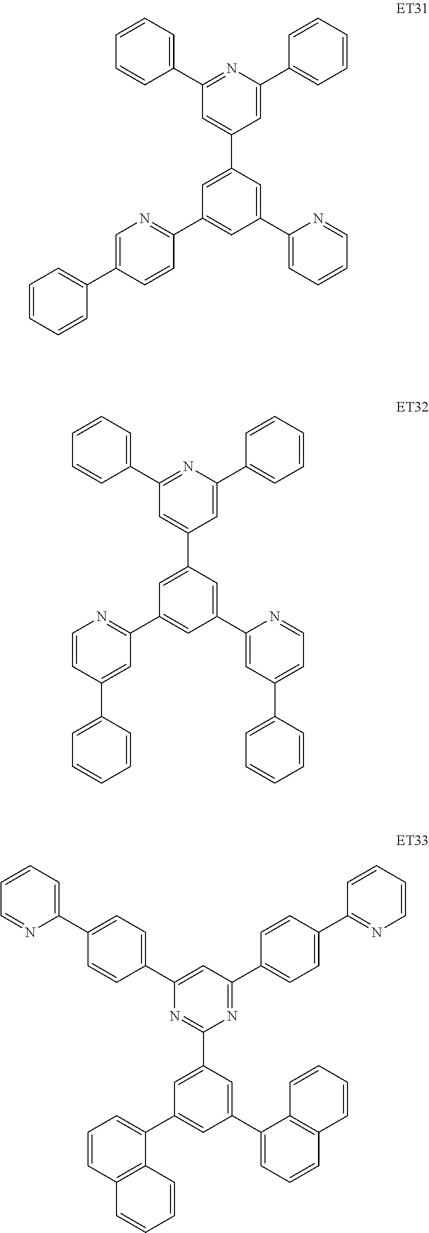 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

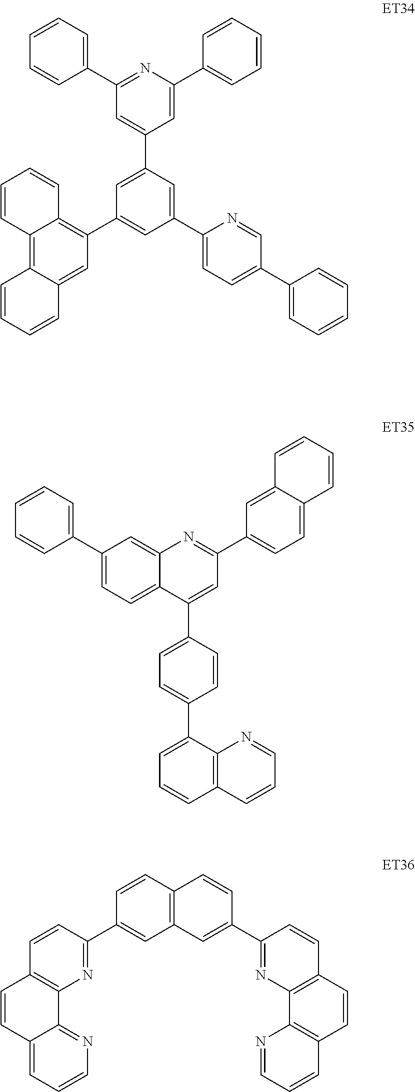 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In some embodiments, the electron transport region ETR may include halogenated metals such as LiF, NaCl, CsF, RbCI, Rbl, Cul, and KI, lanthanide metals such as Yb, or co-deposition materials of a halogenated metal and a lanthanide metal. For example, in some embodiments, the electron transport region ETR may include KI:Yb, Rbl:Yb, LiF:Yb, and/or the like as a co-deposition material. In some embodiments, for the electron transport region ETR, a metal oxide such as Li₂O and BaO, or 8-hydroxyl-lithium quinolate (Liq), and/or the like may be utilized, but embodiments of the present disclosure are limited thereto. In some embodiments, the electron transport region ETR may also be formed of a mixture material of an electron transport material and an insulating organo-metal salt. The organo-metal salt may be a material having an energy band gap of about 4 eV or greater. For example, the organo-metal salt may include, for example, metal acetates, metal benzoates, metal acetoacetates, metal acetylacetonates, and/or metal stearates.

In one or more embodiments, the electron transport region ETR may further include, for example, at least one selected from 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen) in addition to the materials described above, but embodiments of the present disclosure are not limited thereto.

The electron transport region ETR may include the compounds of the electron transport region described above in at least one selected from among the electron injection layer EIL, the electron transport layer ETL, and the hole blocking layer HBL.

When the electron transport region ETR includes an electron transport layer ETL, the electron transport layer ETL may have a thickness of about 100 Å to about 1000 Å, for example, about 150 Å to about 500 Å. When the thickness of the electron transport layer ETL satisfies the above-described range, satisfactory electron transport properties may be obtained without a substantial increase in driving voltage. When the electron transport region ETR includes an electron injection layer EIL, the electron injection layer EIL may have a thickness of about 1 Å to about 100 Å, for example, about 3 Å to about 90 Å. When the thickness of the electron injection layer EIL satisfies the above-described ranges, satisfactory electron injection properties may be obtained without a substantial increase in driving voltage.

The second electrode EL2 may be provided on the electron transport region ETR. The second electrode EL2 may be a common electrode. The second electrode EL2 may be a cathode or an anode but embodiments of the present disclosure are not limited thereto. For example, when the first electrode EL1 is an anode, the second electrode EL2 may be a cathode, and when the first electrode EL1 is a cathode, the second electrode EL2 may be an anode. The second electrode may include at least one selected from Ag, Mg, Cu, Al, Pt, Pd, Au, Ni, Nd, Ir, Cr, Li, Ca, LiF, Mo, Ti, W, In, Sn, and Zn, two or more compounds selected therefrom, two or more mixtures selected therefrom, or an oxide thereof.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), and/or the like.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgAg). In some embodiments, the second electrode EL2 may have a multilayer structure including a reflective film or a transflective film formed of one or more selected from the above-described materials, and a transparent conductive film formed of indium tin oxide (ITO), indium zinc oxide (IZO), zinc oxide (ZnO), indium tin zinc oxide (ITZO), and/or the like. For example, the second electrode EL2 may include the above-described metal materials, a combination of two or more metal materials selected from the above-described metal materials, and/or oxides of the above-described metal materials.

In some embodiments, the second electrode EL2 may be connected with an auxiliary electrode. When the second electrode EL2 is connected with the auxiliary electrode, the resistance of the second electrode EL2 may decrease.

In one or more embodiments, a capping layer CPL may be further disposed on the second electrode EL2 of the light emitting element ED. The capping layer CPL may include a multilayer or a single layer.

In one or more embodiments, the capping layer CPL may be an organic layer or an inorganic layer. For example, when the capping layer CPL includes an inorganic material, the inorganic material may include an alkali metal compound such as LiF, an alkaline earth metal compound such as MgF₂, SiON, SiNₓ, SiO_{y}, and/or the like.

For example, in some embodiments, when the capping layer CPL includes an organic material, the organic material may include a-NPD, NPB, TPD, m-MTDATA, Alq₃ CuPc, N4, N4, N4′, N4′-tetra(biphenyl-4-yl) biphenyl-4,4′-diamine (TPD15), 4,4′,4″-tris(carbazol-9-yl)triphenylamine (TCTA), and/or the like, or may include epoxy resins or acrylates such as methacrylates. However, embodiments of the present disclosure are not limited thereto, for example, in some embodiments, the capping layer CPL may include at least one selected from compounds P₁ to P₅.

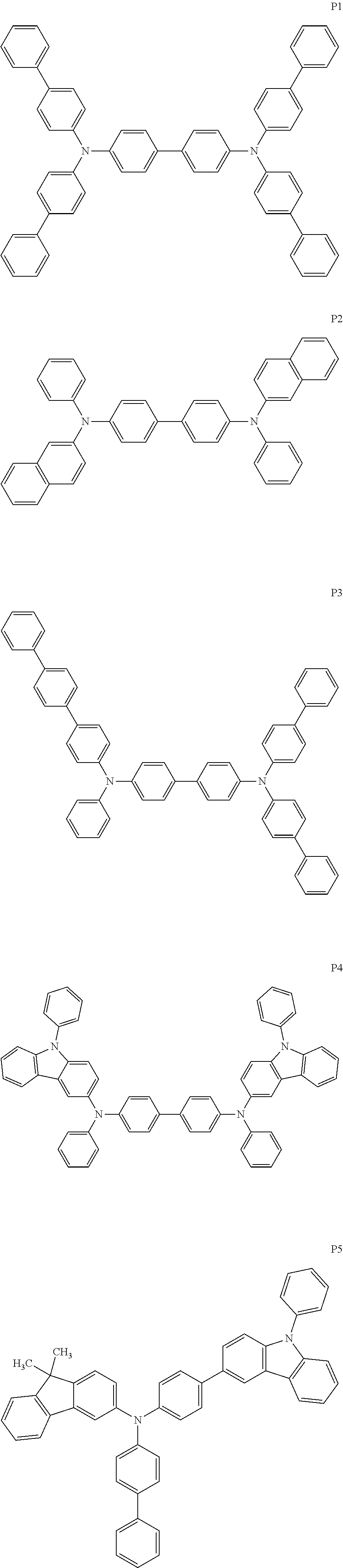 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the capping layer CPL may have a refractive index of about 1.6 or greater. For example, in some embodiments, the capping layer CPL may have a refractive index of about 1.6 or greater in a wavelength range of about 550 nm to about 660 nm.

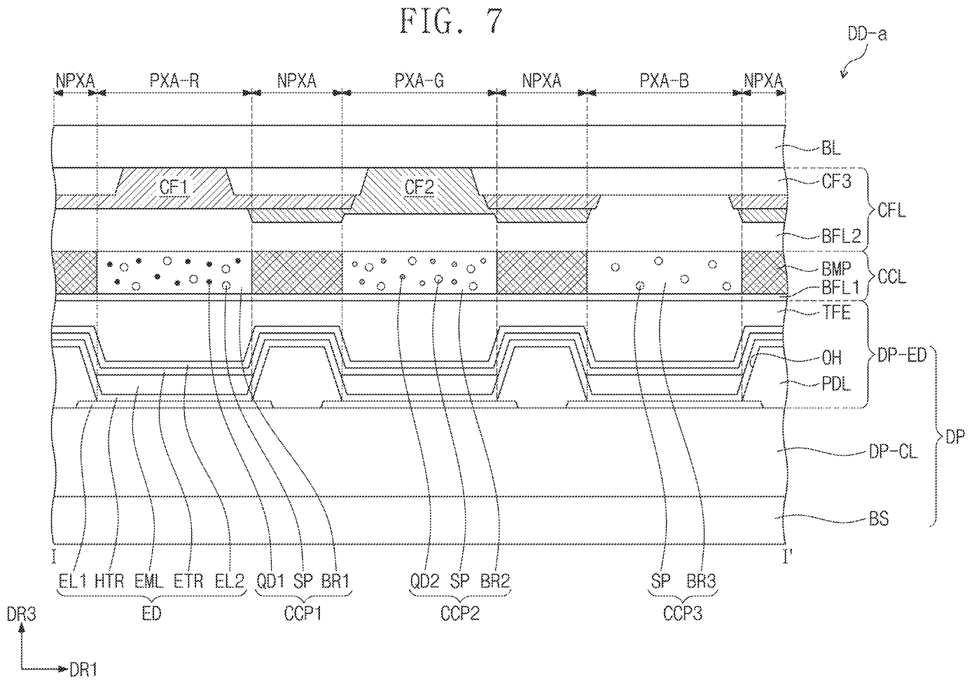

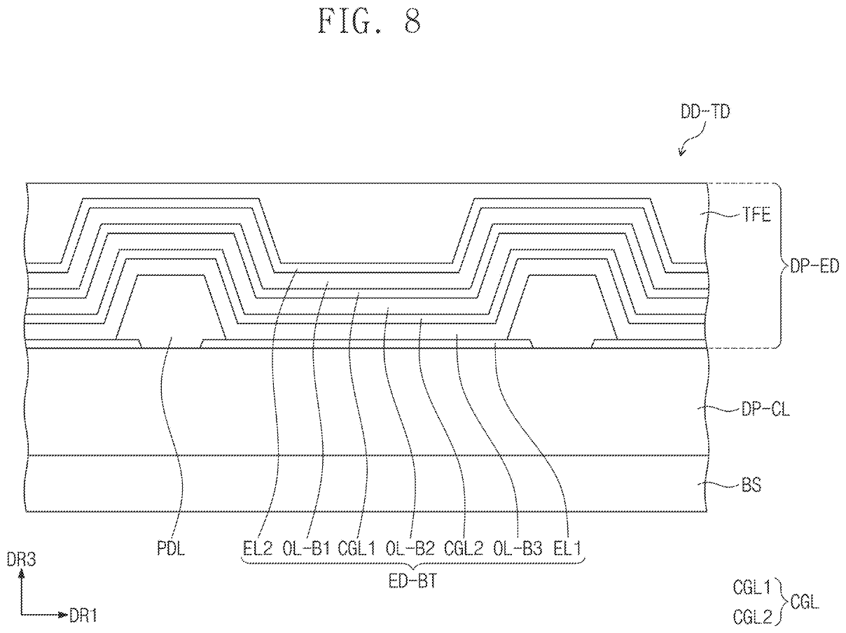

FIG. 7 and FIG. 8 each are a cross-sectional view of a display device according to one or more embodiments of the present disclosure. Hereinafter, in the description of the display device according to one or more embodiments with reference to FIG. 7 and FIG. 8, content overlapping the one described above with reference to FIGS. 1 to 6 will not be described again for conciseness, and only differences will be mainly described.

Referring to FIG. 7, a display device DD-a according to one or more embodiments may include a display panel DP having a display element layer DP-ED, a light control layer CCL disposed on the display panel DP, and a color filter layer CFL.

In an embodiment shown in FIG. 7, the display panel DP may include a base layer BS, a circuit layer DP-CL provided on the base layer BS, and a display element layer DP-ED, and the display element layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In one or more embodiments, a structure of the light emitting element ED shown in FIG. 7 may be the same as the structure of one of the light emitting elements of FIGS. 3 to 6 described above.

The emission layer EML of the light emitting element ED included in the display device DD-a according to one or more embodiments may include the polycyclic compound according to an embodiment described above.

Referring to FIG. 7, the emission layer EML may be disposed in an opening OH defined in a pixel defining films PDL. For example, the emission layer EML separated by the pixel defining films PDL and provided corresponding to each of light emitting regions PXA-R, PXA-G, and PXA-B may be to emit light in substantially the same wavelength ranges. In the display device DD-a of one or more embodiments, the emission layer EML may be to emit blue light. In some embodiments, the emission layer EML may be provided as a common layer throughout the light emitting regions PXA-R, PXA-G, and PXA-B.

The light control layer CCL may be disposed on the display panel DP. The light control layer CCL may include a light converter. The light converter may be a quantum dot or a phosphor. The light converter may wavelength-convert the provided light and emit the wavelength-converted light. For example, the light control layer CCL may be a layer containing quantum dots and/or phosphors.

The light control layer CCL may include a plurality of light control units CCP1, CCP2, and CCP3. The light control units CCP1, CCP2, and CCP3 may be spaced apart from each other.

Referring to FIG. 7, a division pattern BMP may be disposed between the light control units CCP1, CCP2, and CCP3 spaced apart from each other, but embodiments of the present disclosure are not limited thereto. In FIG. 7, the division pattern BMP is shown to non-overlap the light control units CCP1, CCP2, and CCP3, but, in some embodiments, edges of the light control units CCP1, CCP2, and CCP3 may overlap at least a portion of the division pattern BMP.

In one or more embodiments, the light control layer CCL may include a first light control unit CCP1 including a first quantum dot QD1 for converting first color light provided from the light emitting element ED into second color light, a second light control unit CCP2 including a second quantum dot QD2 for converting the first color light into third color light, and a third light control unit CCP3 transmitting the first color light.

In one or more embodiments, the first light control unit CCP1 may provide red light, which is the second color light, and the second light control unit CCP2 may provide green light, which is the third color light. The third light control unit CCP3 may be to transmit and provide blue light, which is the first color light provided from the light emitting element ED. For example, in some embodiments, the first quantum dot QD1 may be a red quantum dot to emit red light, and the second quantum dot QD2 may be a green quantum dot to emit green light. The same descriptions above on the quantum dot may be applied to the quantum dots QD1 and QD2.

In some embodiments, the light control layer CCL may further include scatterers SP. The first light control unit CCP1 may include the first quantum dot QD1 and the scatterers SP, the second light control unit CCP2 may include the second quantum dot QD2 and the scatterers SP, and the third light control unit CCP3 may not include (e.g., may exclude) a (e.g., any) quantum dot but may include the scatterers SP.

The scatterers SP may be inorganic particles. For example, the scatterers SP may include at least one selected from among TiO₂, ZnO, Al₂O₃, SiO₂, and hollow silica. In one or more embodiments, the scatterers SP may include any one selected from among TiO₂, ZnO, Al₂O₃, SiO₂, and hollow silica, or may be a mixture of two or more materials selected from TiO₂, ZnO, Al₂O₃, SiO₂, and hollow silica.

The first light control unit CCP1, the second light control unit CCP2, and the third light control unit CCP3 may respectively include base resins BR1, BR2, and BR3 for dispersing the quantum dots QD1 and QD2 and the scatterers SP. In one or more embodiments, the first light control unit CCP1 may include the first quantum dot QD1 and the scatterers SP dispersed in the first base resin BR1, the second light control unit CCP2 may include the second quantum dot QD2 and the scatterers SP dispersed in the second base resin BR2, and the third light control unit CCP3 may include (e.g., may just include) the scatterers SP dispersed in the third base resin BR3 (e.g., be substantially quantum dot free).

The base resins BR1, BR2, and BR3 are a medium in which the quantum dots QD1 and QD2 and the scatterers SP are dispersed, and may be formed of one or more suitable resin compositions, which may be generally referred to as a binder. For example, the base resins BR1, BR2, and BR3 may each independently be an acrylic-based resin, a urethane-based resin, a silicone-based resin, an epoxy-based resin, and/or the like. The base resins BR1, BR2, and BR3 may be a transparent resin. In one or more embodiments, the first base resin BR1, the second base resin BR2, and the third base resin BR3 may each be the same as or different from each other.

In one or more embodiments, the light control layer CCL may include a barrier layer BFL1. The barrier layer BFL1 may serve to prevent or reduce moisture and/or oxygen (hereinafter referred to as “moisture/oxygen”) from being introduced. The barrier layer BFL1 may be disposed on the light control units CCP1, CCP2, and CCP3 to prevent or reduce the light control units CCP1, CCP2, and CCP3 from being exposed to moisture/oxygen. In some embodiments, the barrier layer BFL1 may cover the light control units CCP1, CCP2, and CCP3. In some embodiments, a barrier layer BFL2 may be provided between the light control units CCP1, CCP2, and CCP3 and filters CF1, CF2, and CF3.

The barrier layers BFL1 and BFL2 may include at least one inorganic layer. For example, in some embodiments, the barrier layers BFL1 and BFL2 may be formed of an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, and/or a thin metal film in which light transmittance is secured, and/or the like. In some embodiments, the barrier layers BFL1 and BFL2 may further include an organic film. The barrier layers BFL1 and BFL2 may each be formed of a single layer or a plurality of layers.

In one or more embodiments, in the display device DD-a, the color filter layer CFL may be disposed on the light control layer CCL. For example, in some embodiments, the color filter layer CFL may be directly disposed on the light control layer CCL. In these embodiments, the barrier layer BFL2 may not be provided.

The color filter layer CFL may include a light blocking unit BM and filters CF1, CF2, and CF3. For example, in some embodiments, the color filter layer CFL may include a first filter CF1 transmitting the second color light, a second filter CF2 transmitting the third color light, and a third filter CF3 transmitting the first color light. For example, in some embodiments, the first filter CF1 may be a red filter, the second filter CF2 may be a green filter, and the third filter CF3 may be a blue filter. The filters CF1, CF2, and CF3 may each include a polymer photosensitive resin, a pigment and/or a dye. The first filter CF1 may include a red pigment and/or a red dye, the second filter CF2 may include a green pigment and/or a green dye, and the third filter CF3 may include a blue pigment and/or a blue dye. However, embodiments of the present disclosure are not limited thereto, for example, in some embodiments, the third filter CF3 may not include (e.g., may exclude) a pigment and/or a dye (e.g., not include any pigment or dye). The third filter CF3 may include a polymer photosensitive resin, but not include a pigment and/or a dye (e.g., not include any pigment or dye). The third filter CF3 may be transparent. The third filter CF3 may be formed of a transparent photosensitive resin.

In one or more embodiments, the first filter CF1 and the second filter CF2 may be yellow filters. The first filter CF1 and the second filter CF2 may not be separated and may be provided as a single body. The first to third filters CF1, CF2, and CF3 may be disposed corresponding to the red light emitting region PXA-R, the green light emitting region PXA-G, and the blue light emitting region PXA-B, respectively.

The light blocking unit BM may be a black matrix. The light blocking unit BM may be formed by including an organic light blocking material and/or an inorganic light blocking material, both (e.g., simultaneously) including a black pigment and/or a black dye. The light blocking unit BM may separate borders between the adjacent filters CF1, CF2, and CF3. In some embodiments, the light blocking unit BM may be formed of a blue filter.

A base substrate BL may be disposed on the color filter layer CFL. The base substrate BL may be a member providing a base surface on which the color filter layer CFL and the light control layer CCL are disposed. The base substrate BL may be a glass substrate, a metal substrate, a plastic substrate, and/or the like. However, embodiments of the present disclosure are not limited thereto, and the base substrate BL may be an inorganic layer, an organic layer, or a composite material layer. In some embodiments, the base substrate BL may not be provided.

FIG. 8 is a cross-sectional view showing a portion of a display device according to one or more embodiments of the present disclosure. In a display device DD-TD of an embodiment, a light emitting element ED-BT may include a plurality of light emitting structures OL-B1, OL-B2, and OL-B3. The light emitting element ED-BT may include a first electrode EL1 and a second electrode EL2 facing each other, and the plurality of light emitting structures OL-B1, OL-B2, and OL-B3 provided by being sequentially stacked in a thickness direction between the first electrode EL1 and the second electrode EL2. The light emitting structures OL-B1, OL-B2, and OL-B3 each may include an emission layer EML (FIG. 7), and a hole transport region HTR and an electron transport region ETR disposed with the emission layer EML (FIG. 7) therebetween.

For example, in some embodiments, the light emitting element ED-BT included in the display device DD-TD may be a light emitting element having a tandem structure including a plurality of emission layers.

In one or more embodiments shown in FIG. 8, light emitted from each of the light emitting structures OL-B1, OL-B2, and OL-B3 may all be blue light. However, embodiments of the present disclosure are not limited thereto, and wavelength ranges of light emitted from each of the light emitting structures OL-B1, OL-B2, and OL-B3 may be different from each other. For example, in one or more embodiments, the light emitting element ED-BT including the plurality of light emitting structures OL-B1, OL-B2, and OL-B3 emitting light in different wavelength ranges may be to emit white light (e.g., combined white light).

A charge generation layer CGL (e.g., CGL1 and CGL2) may be disposed between neighboring light emitting structures OL-B1, OL-B2, and OL-B3. The charge generation layer CGL may include a p-type or kind charge (e.g., P-charge) generation layer and/or an n-type or kind charge (e.g., N-charge) generation layer.

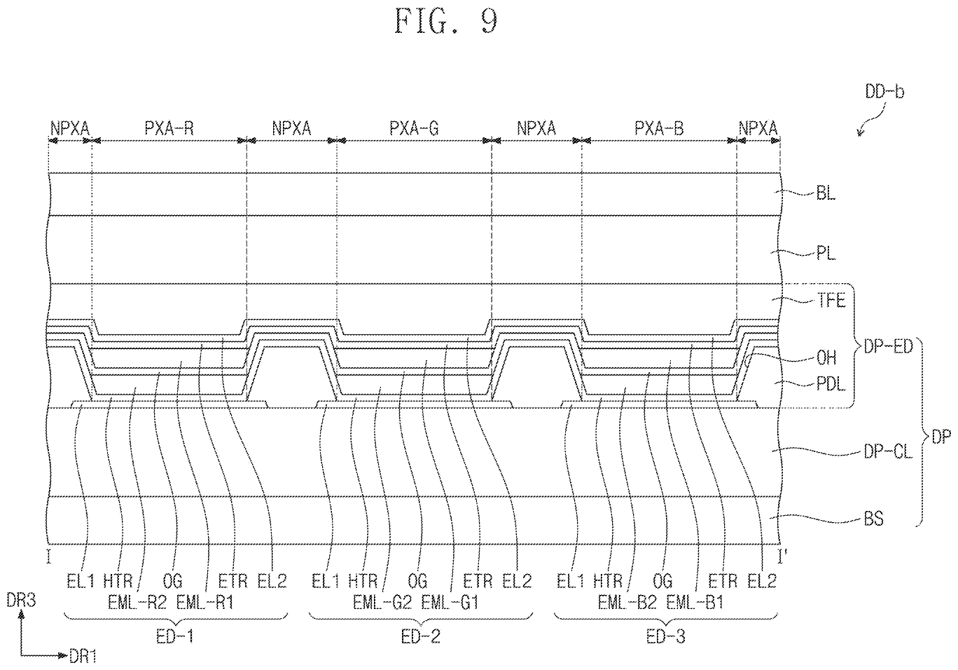

Referring to FIG. 9, a display device DD-b according to an embodiment may include light emitting elements ED-1, ED-2, and ED-3 in each of which two emission layers are stacked. Compared to the display device DD according to an embodiment shown in FIG. 2, the difference is that in the embodiment shown in FIG. 9, the first to third light emitting elements ED-1, ED-2, and ED-3 each include two emission layers stacked in a thickness direction. In each of the first to third light emitting elements ED-1, ED-2, and ED-3, the two emission layers may be to emit light in substantially the same wavelength range.

In one or more embodiments, the first light emitting element ED-1 may include a first red emission layer EML-R₁ and a second red emission layer EML-R₂. The second light emitting element ED-2 may include a first green emission layer EML-G1 and a second green emission layer EML-G2. In addition, the third light emitting element ED-3 may include a first blue emission layer EML-B1 and a second blue emission layer EML-B2. A light emitting auxiliary portion OG may be disposed between the first red emission layer EML-R₁ and the second red emission layer EML-R₂, between the first green emission layer EML-G1 and the second green emission layer EML-G2, and between the first blue emission layer EML-B1 and the second blue emission layer EML-B2.

The light emitting auxiliary portion OG may include a single layer or multiple layers. The light emitting auxiliary portion OG may include a charge generation layer. In one or more embodiments, the light emitting auxiliary portion OG may include an electron transport region, a charge generation layer, and a hole transport region that are sequentially stacked (e.g., in the stated order). The light emitting auxiliary portion OG may be provided as a common layer throughout the first to third light emitting elements ED-1, ED-2, and ED-3. However, embodiments of the present disclosure are not limited thereto, and, in some embodiments, the light emitting auxiliary portion OG may be provided to be patterned inside openings OH defined in a pixel defining films PDL.

The first red emission layer EML-R₁, the first green emission layer EML-G1, and the first blue emission layer EML-B1 may be disposed between the electron transport region ETR and the light emitting auxiliary portion OG. The second red emission layer EML-R₂, the second green emission layer EML-G2, and the second blue emission layer EML-B2 may be disposed between the light emitting auxiliary portion OG and the hole transport region HTR.

For example, in one or more embodiments, the light emitting element ED-1 may include a first electrode EL1, a hole transport region HTR, a second red emission layer EML-R₂, a light emitting auxiliary portion OG, a first red emission layer EML-R₁, an electron transport region ETR, and a second electrode EL2, which are sequentially stacked. The second light emitting element ED-2 may include a first electrode EL1, a hole transport region HTR, a second green emission layer EML-G2, a light emitting auxiliary portion OG, a first green emission layer EML-G1, an electron transport region ETR, and a second electrode EL2, which are sequentially stacked. The third light emitting element ED-3 may include a first electrode EL1, a hole transport region HTR, a second blue emission layer EML-B2, a light emitting auxiliary portion OG, a first blue emission layer EML-B1, an electron transport region ETR, and a second electrode EL2, which are sequentially stacked.

In some embodiments, an optical auxiliary layer PL may be disposed on the display element layer DP-ED. The optical auxiliary layer PL may include a polarizing layer. The optical auxiliary layer PL may be disposed on the display panel DP to control reflected light in the display panel DP due to external light. In some embodiments, the optical auxiliary layer PL may not be provided in the display device.

In one or more embodiments, at least one emission layer included in a display device DD-b shown in FIG. 9 may include the polycyclic compound according to one or more embodiments described above. For example, in one or more embodiments, at least one of the first blue emission layer EML-B1 or the second blue emission layer EML-B2 may include the polycyclic compound according to one or more embodiments.

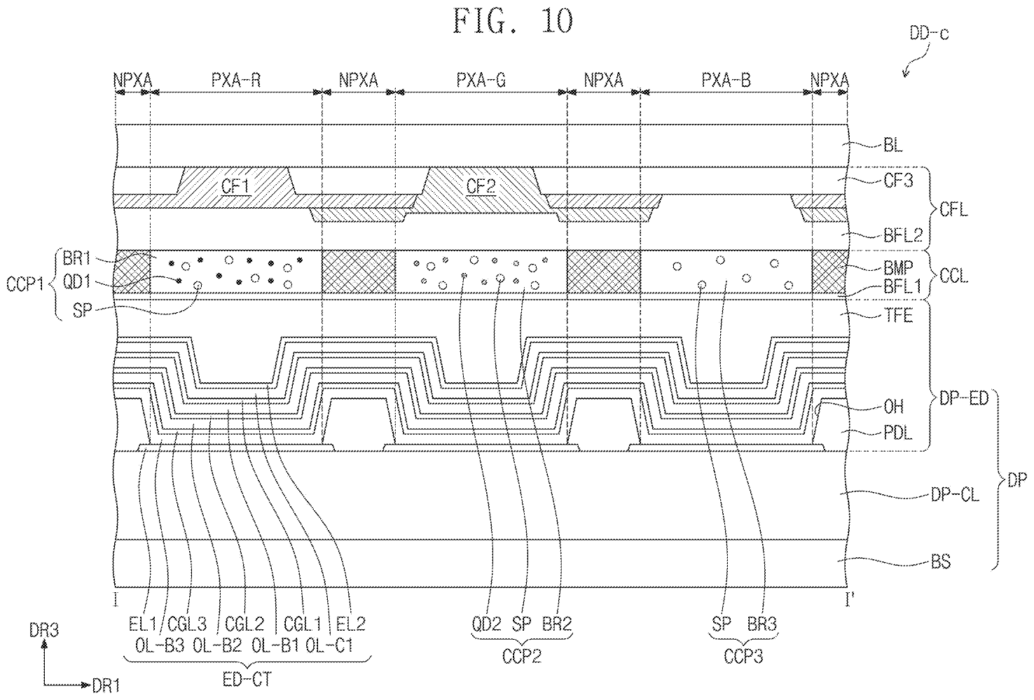

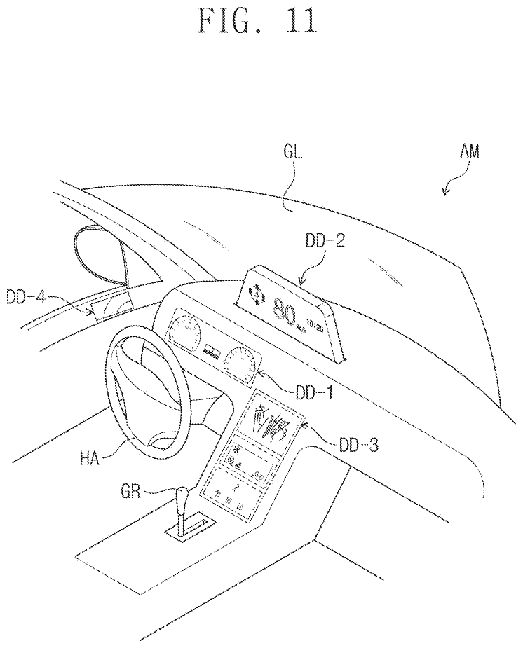

Unlike FIG. 8 and FIG. 9, the display device DD-c shown in FIG. 10 is illustrated to include four light emitting structures OL-B1, OL-B2, OL-B3, and OL-C1. A light emitting element ED-CT may include a first electrode EL1 and a second electrode EL2 facing each other, and first to fourth light emitting structures OL-B1, OL-B2, OL-B3, and OL-C1 stacked in a thickness direction between the first electrode EL1 and the second electrode EL2. Charge generation layers CGL1, CGL2, and CGL3 may be disposed between the first to fourth light emitting structures OL-B1, OL-B2, OL-B3, and OL-C1. Among the four light emitting structures, the first to third light emitting structures OL-B1, OL-B2, and OL-B3 may be to emit blue light, and the fourth light emitting structure OL-C1 may be to emit green light. However, embodiments of the present disclosure are not limited thereto, and the first to fourth light emitting structures OL-B1, OL-B2, OL-B3, and OL-C1 may be to emit light having different wavelength ranges.

The charge generation layers CGL1, CGL2, and CGL3 disposed between the neighboring light emitting structures OL-B1, OL-B2, OL-B3, and OL-C1 may include a p-type or kind charge (e.g., P-charge) generation layer and/or an n-type or kind charge (e.g., N-charge) generation layer.

At least one selected from among the light emitting structures OL-B1, OL-B2, OL-B3, and OL-C1 included in the display device DD-c according to one or more embodiments may include the polycyclic compound according to one or more embodiments described above. For example, in one or more embodiments, at least one selected from the first to third light emitting structures OL-B1, OL-B2, and OL-B3 may include the polycyclic compound according to one or more embodiments, which is described above.

The light emitting element ED according to one or more embodiments of the present disclosure may include the polycyclic compound according to one or more embodiments described above in at least one functional layer disposed between the first electrode EL1 and the second electrode EL2, and may thus exhibit excellent or suitable light emitting efficiency and improved lifespan characteristics. For example, in one or more embodiments, the polycyclic compound according to one or more embodiments may be included in the emission layer EML of the light emitting element ED, and the light emitting element may exhibit both (e.g., simultaneously) high efficiency and long lifespan characteristics.

FIG. 11 is a perspective view schematically showing an electronic device according to one or more embodiments of the present disclosure. In FIG. 11, a portion of a vehicle AM is shown as an electronic device by way of example. This is presented as a mere example, and the electronic device may be one or more suitable vehicles of transportation, such as bicycles, motorcycles, trains, ships, and/or airplanes.

Referring to FIG. 11, the vehicle AM may include first to fourth vehicle display devices DD-1, DD-2, DD-3, and DD-4. The descriptions of display devices DD, DD-a, DD-TD, DD-b, and DD-c described above with reference to FIGS. 1, 2, and 7 to 10 may apply to at least one selected from among the first to fourth display devices DD-1, DD-2, DD-3, and DD-4.

In one or more embodiments, at least one selected from among the first to fourth display devices DD-1, DD-2, DD-3, and DD-4 may include the light emitting element ED described with reference to FIGS. 3 to 6. In some embodiments, the first to fourth display devices DD-1, DD-2, DD-3, and DD-4 may each independently include a plurality of light emitting elements ED (see FIGS. 3 to 6). Each of the light emitting elements ED may include a first electrode EL1, a hole transport region HTR, an emission layer EML, an electron transport region ETR, and a second electrode EL2 (see FIGS. 3 to 6). In some embodiments, the emission layer EML may include the polycyclic compound of one or more embodiments described above. Accordingly, the first to fourth vehicle display devices DD-1, DD-2, DD-3, and DD-4 may display improved image quality.

Referring to FIG. 11, the vehicle AM may include a steering wheel HA and a gear GR for operating the vehicle AM. In addition, the vehicle AM may include a front window GL disposed to face a driver.

The first display device DD-1 may be disposed in a first region overlapping the steering wheel HA. For example, the first display device DD-1 may be a digital cluster displaying first information of the vehicle AM. The first information may include a first scale indicating driving speed of the vehicle AM, a second scale indicating engine revolutions per minute (RPM), and an image indicating fuel gauge, and/or the like. The first scale and the second scale may be displayed as digital images.

The second display device DD-2 may be disposed in a second region facing a driver seat and overlapping the front window GL. The driver seat may be a seat in which the steering wheel HA faces. For example, the second display device DD-2 may be a head up display HUD displaying second information of the vehicle AM. The second display device DD-2 may be optically transparent. The second information may include digital numbers indicating driving speed of the vehicle AM and may further include information such as current time.

The third display device DD-3 may be disposed in a third region adjacent to the gear GR. For example, the third display device DD-3 may be a center information display CID for the vehicle, which is disposed between a driver seat and a passenger seat, and displays third information. The passenger seat may be a seat spaced apart from the driver seat with the gear GR therebetween. The third information may include information about road conditions (e.g., navigation information), music or radio play, video play, temperature inside the vehicle AM, and/or the like.

The fourth display device DD-4 may be disposed in a fourth region spaced apart from the steering wheel HA and the gear GR and adjacent to a side of the vehicle AM. For example, the fourth display device DD-4 may be a digital side mirror displaying fourth information. The fourth information may include images of conditions outside the vehicle AM, which are taken by a camera module disposed outside the vehicle AM.

The first to fourth information described above are presented as an example, and the first to fourth display devices DD-1, DD-2, DD-3, and DD-4 may further display information about inside and/or outside the vehicle. The first to fourth information may include different information. However, embodiments of the present disclosure are not limited thereto, and some of the first to fourth information may include the same information.

Hereinafter, with reference to Examples and Comparative Examples, a polycyclic compound and a light emitting element of one or more embodiments of the present disclosure will be described in more detail. In addition, Examples are shown only for the understanding of the present disclosure, and the scope of the present disclosure is not limited thereto.

### EXAMPLES

### 1. Synthesis of Polycyclic Compounds

First, a process of synthesizing polycyclic compounds according to one or more embodiments of the present disclosure will be described in more detail by presenting a process of synthesizing Compounds 1, 2, 3, 4, 19, 37, 38, 44, 74, 117, and 118 as an example. In addition, the process of synthesizing polycyclic compounds, which will be described hereinafter, is provided as an example, and thus a process of synthesizing polycyclic compounds according to one or more embodiments of the present disclosure is not limited to Examples.

### (1) Synthesis of Compound 1

Compound 1 according to one or more embodiments may be synthesized according to, for example, Reaction Formula 1.

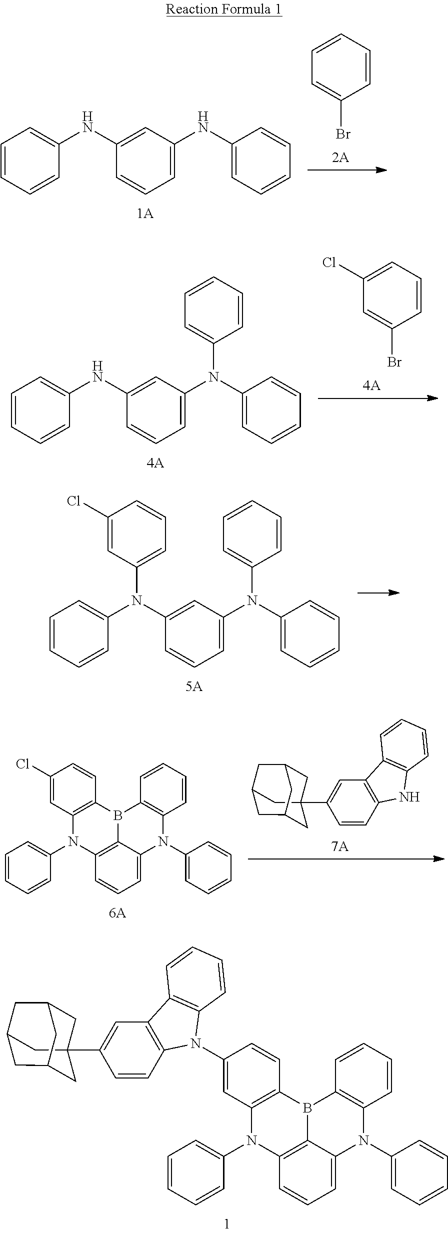

### 1) Synthesis of Intermediate Compound 3A

In an Ar atmosphere, in a three-neck flask (2000 mL), 1A (100 g), 2A (bromobenzene, 60.4 g), bis(dibenzylideneacetone)palladium(0) (Pd(dba)₂, 4.42 g), tri-tert-butylphosphonium tetrafluoroborate (4.46 g), sodium tert-butoxide (NaOtBu, 44 g), and toluene (800 mL) were added, and heated and stirred at 60° C. for 6 hours. After returning to room temperature, water was added thereto to extract a product utilizing toluene, an organic layer was collected and dried over MgSO₄, and then a solvent was distilled off under reduced pressure. The resulting product was purified through silica gel column chromatography to obtain 3A (76.8 g, yield: 60%). The mass number of 3A as determined through Fast atom bombardment mass spectrometry (FAB-MS) was 336.

### 2) Synthesis of Intermediate Compound 5A

In an Ar atmosphere, in a three-neck flask (1000 mL), 3A (76.8 g), 4A (1-bromo-3-chlorobenzene, 52.4 g), bis(dibenzylideneacetone)palladium(0) (Pd(dba)₂, 2.62 g), tri-tert-butylphosphonium tetrafluoroborate (2.64 g), sodium tert-butoxide (NaOtBu, 26.2 g), and toluene (800 mL) were added, and heated and stirred at 60° C. for 6 hours. After returning to room temperature, water was added thereto to extract a product utilizing toluene, an organic layer was collected and dried over MgSO₄, and then a solvent was distilled off under reduced pressure. The resulting product was purified through silica gel column chromatography to obtain 5A (89.8 g, yield: 88%). The mass number of 5A as determined through FAB-MS was 447.

### 3) Synthesis of Intermediate Compound 6A

In an Ar atmosphere, in a three-neck flask (1000 mL), 5A (89.8 g) was added, dissolved in o-dichlorobenzene (ODCB, 300 mL), and cooled to 0° C. utilizing ice, and boron triiodide (Bl₃, 147.4 g) was added thereto, and the mixture was heated and stirred at 160° C. for 6 hours, and cooled to 0° C. utilizing ice, and N,N-diisopropylethylamine (DIPEA, 280 mL) was added thereto. After returning to room temperature, a reaction solution was filtered utilizing silica gel, and a filtration solvent (e.g., a solvent of the filtrate) was distilled off under reduced pressure. The obtained product was purified through silica gel column chromatography, preparative HPLC (eluent: CH₂Cl₂), and recrystallization in toluene to obtain 6A (18.2 g yield: 20%). The mass number of 6A as determined through FAB-MS was 455.

### 4) Synthesis of Intermediate Compound 7A

In an Ar atmosphere, in a three-neck flask (1000 mL), carbazole (19.4 g) and AICI₃ (15.5 g) were added and dissolved in CH₂Cl₂ (500 mL), cooled to 0° C. utilizing ice, and then stirred. Thereafter, 1-bromoadamantane (25 g) was slowly added. After returning to room temperature, water was added thereto to extract a product utilizing CH₂Cl₂, an organic layer was collected and dried utilizing MgSO₄, and then a solvent was distilled off under reduced pressure. The obtained product was purified through silica gel column chromatography to obtain 7A (22.8 g, yield: 65%). The mass number of 7A as determined through FAB-MS was 301.

### 5) Synthesis of Compound 1

In an Ar atmosphere, in a three-neck flask (500 mL), 6A (34 g), 7A (3.2 g), bis(dibenzylideneacetone)palladium(0) (Pd(dba)₂, 0.50 g), tri-tert-butylphosphonium tetrafluoroborate (0.51 g), sodium tert-butoxide (NaOtBu, 1.7 g), and toluene (100 mL) were added, and heated and stirred at 120° C. for 6 hours. After returning to room temperature, water was added thereto to extract a product utilizing toluene, an organic layer was collected and dried over MgSO₄, and then a solvent was distilled off under reduced pressure. The resulting product was purified through silica gel column chromatography to obtain Compound 1 (5.0 g, yield: 80%). The mass number of Compound 1 as determined through FAB-MS was 720.

### (2) Synthesis of Compound 2

Compound 2 according to one or more embodiments may be synthesized according to, for example, Reaction Formula 2.

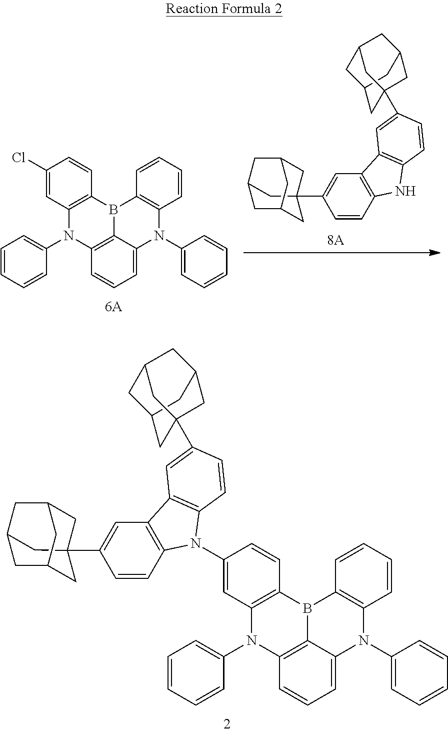 [SMILES: Clc1ccc2c(c1)N(c1ccccc1)c1cccc3c1B2c1ccccc1N3c1ccccc1 ; c1cc2[nH]c3ccc(C45CC6CC(CC(C6)C4)C5)cc3c2cc1C12CC3CC(CC(C3)C1)C2 ; c1ccc(N2c3ccccc3B3c4ccc(-n5c6ccc(C78CC9CC(CC(C9)C7)C8)cc6c6cc(C78CC9CC(CC(C9)C7)C8)ccc65)cc4N(c4ccccc4)c4cccc2c43)cc1]

### 1) Synthesis of Intermediate Compound 8A

In an Ar atmosphere, in a three-neck flask (1000 mL), carbazole (22.5 g) and AICI₃ (28.4 g) were added and dissolved in CH₂Cl₂ (500 mL), cooled to 0° C. utilizing ice, and then stirred. Thereafter, 1-bromoadamantane (35.1 g) was slowly added. After returning to room temperature, water was added thereto to extract a product utilizing CH₂Cl₂, an organic layer was collected and dried utilizing MgSO₄, and then a solvent was distilled off under reduced pressure. The obtained product was purified through silica gel column chromatography to obtain 8A (24 g, yield: 76%). The mass number of 8A as determined through FAB-MS was 436.

### 2) Synthesis of Compound 2

In an Ar atmosphere, in a three-neck flask (500 mL), 6A (3.5 g), 8A (4 g), bis(dibenzylideneacetone)palladium(0) (Pd(dba)₂, 0.44 g), tri-tert-butylphosphonium tetrafluoroborate (0.44 g), sodium tert-butoxide (NaOtBu, 1.1 g), and toluene (100 mL) were added, and heated and stirred at 120° C. for 6 hours. After returning to room temperature, water was added thereto to extract a product utilizing toluene, an organic layer was collected and dried over MgSO₄, and then a solvent was distilled off under reduced pressure. The resulting product was purified through silica gel column chromatography to obtain Compound 2 (5.2 g, yield: 80%). The mass number of Compound 2 as determined through FAB-MS was 854.

### (3) Synthesis of Compound 3

Compound 3 according to one or more embodiments may be synthesized according to, for example, Reaction Formula 3.

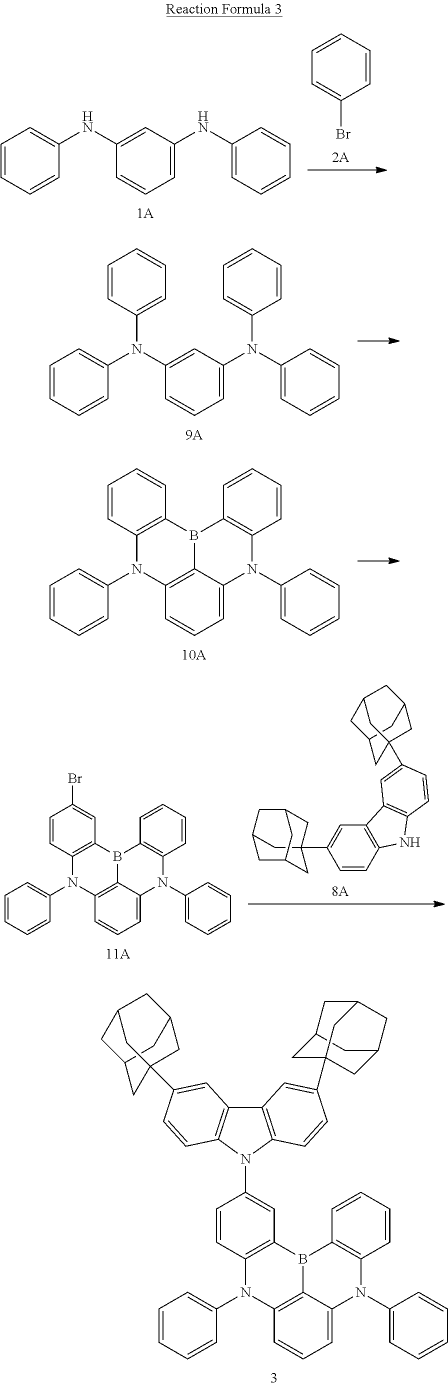

### 1) Synthesis of Intermediate Compound 9A

In an Ar atmosphere, in a three-neck flask (2000 mL), 1A (40 g), 2A (bromobenzene, 53 g), bis(dibenzylideneacetone)palladium(0) (Pd(dba)₂, 2.65 g), tri-tert-butylphosphonium tetrafluoroborate (2.67 g), sodium tert-butoxide (NaOtBu, 44 g), and toluene (700 mL) were added, and heated and stirred at 60° C. for 6 hours. After returning to room temperature, water was added thereto to extract a product utilizing toluene, an organic layer was collected and dried over MgSO₄, and then a solvent was distilled off under reduced pressure. The resulting product was purified through silica gel column chromatography to obtain 9A (48.2 g, yield: 76%). The mass number of 9A as determined through FAB-MS was 413.

### 2) Synthesis of Intermediate Compound 10A

In an Ar atmosphere, in a three-neck flask (1000 mL), 9A (48.2 g) was added, dissolved in o-dichlorobenzene (ODCB, 200 mL), and cooled to 0° C. utilizing ice, and boron triiodide (Bl₃, 91.6 g) was added thereto, and the mixture was heated and stirred at 160° C. for 6 hours, and cooled to 0° C. utilizing ice, and N,N-diisopropylethylamine (DIPEA, 160 mL) was added thereto. After returning to room temperature, a reaction solution was filtered utilizing silica gel, and a filtration solvent was distilled off under reduced pressure. The obtained product was purified through silica gel column chromatography, preparative HPLC (eluent: CH₂Cl₂), and recrystallization in toluene to obtain 10A (7.4 g yield: 15%). The mass number of 10A as determined through FAB-MS was 420.

### 3) Synthesis of Intermediate Compound 11A

In an Ar atmosphere, in a three-neck flask (500 mL), 10A (7.4 g) was added, dissolved in CH₂Cl₂ (200 mL), cooled to 0° C. utilizing ice, and N-bromosuccinimide (NBS, 3.14 g) was added thereto and stirred. After returning to room temperature, water was added thereto to extract a product utilizing CH₂Cl₂, an organic layer was collected and dried utilizing MgSO₄, and then a solvent was distilled off under reduced pressure. The resulting product was purified through silica gel column chromatography to obtain 11A (4.4 g, yield: 50%). The mass number of 11A as determined through FAB-MS was 499.

### 4) Synthesis of Compound 3

In an Ar atmosphere, in a three-neck flask (500 mL), 11A (4.4 g), 8A (4.6 g), bis(dibenzylideneacetone)palladium(0) (Pd(dba)₂, 0.51 g), tri-tert-butylphosphonium tetrafluoroborate (0.51 g), sodium tert-butoxide (NaOtBu, 1.3 g), and toluene (200 mL) were added, and heated and stirred at 120° C. for 6 hours. After returning to room temperature, water was added thereto to extract a product utilizing toluene, an organic layer was collected and dried over MgSO₄, and then a solvent was distilled off under reduced pressure. The resulting product was purified through silica gel column chromatography to obtain Compound 3 (6.2 g, yield: 82%). The mass number of Compound 3 as determined through FAB-MS was 854.

### (4) Synthesis of Compound 4

Compound 4 according to one or more embodiments may be synthesized according to, for example, Reaction Formula 4.

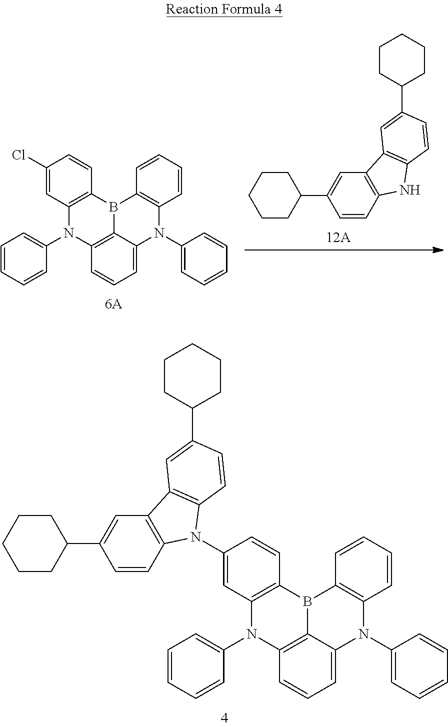 [SMILES: Clc1ccc2c(c1)N(c1ccccc1)c1cccc3c1B2c1ccccc1N3c1ccccc1 ; c1cc2[nH]c3ccc(C4CCCCC4)cc3c2cc1C1CCCCC1 ; c1ccc(N2c3ccccc3B3c4ccc(-n5c6ccc(C7CCCCC7)cc6c6cc(C7CCCCC7)ccc65)cc4N(c4ccccc4)c4cccc2c43)cc1]

### 1) Synthesis of Intermediate Compound 12A

In an Ar atmosphere, in a three-neck flask (1000 mL), carbazole (10 g) and AICI₃ (16 g) were added and dissolved in CH₂Cl₂ (500 mL), cooled to 0° C. utilizing ice, and then stirred. Thereafter, bromocyclohexane (19.5 g) was slowly added. After returning to room temperature, water was added thereto to extract a product utilizing CH₂Cl₂, an organic layer was collected and dried utilizing MgSO₄, and then a solvent was distilled off under reduced pressure. The obtained product was purified through silica gel column chromatography to obtain 12A (14 g, yield: 70%). The mass number of 12A as determined through FAB-MS was 332.

### 2) Synthesis of Compound 4

In an Ar atmosphere, in a three-neck flask (500 mL), 6A (4 g), 12A (3.5 g), bis(dibenzylideneacetone)palladium(0) (Pd(dba)₂, 0.51 g), tri-tert-butylphosphonium tetrafluoroborate (0.51 g), sodium tert-butoxide (NaOtBu, 1.26 g), and toluene (100 mL) were added, and heated and stirred at 120° C. for 6 hours. After returning to room temperature, water was added thereto to extract a product utilizing toluene, an organic layer was collected and dried over MgSO₄, and then a solvent was distilled off under reduced pressure. The resulting product was purified through silica gel column chromatography to obtain Compound 4 (5.3 g, yield: 81%). The mass number of Compound 4 as determined through FAB-MS was 854.

### (5) Synthesis of Compound 19

Compound 19 according to one or more embodiments may be synthesized according to, for example, Reaction Formula 5.

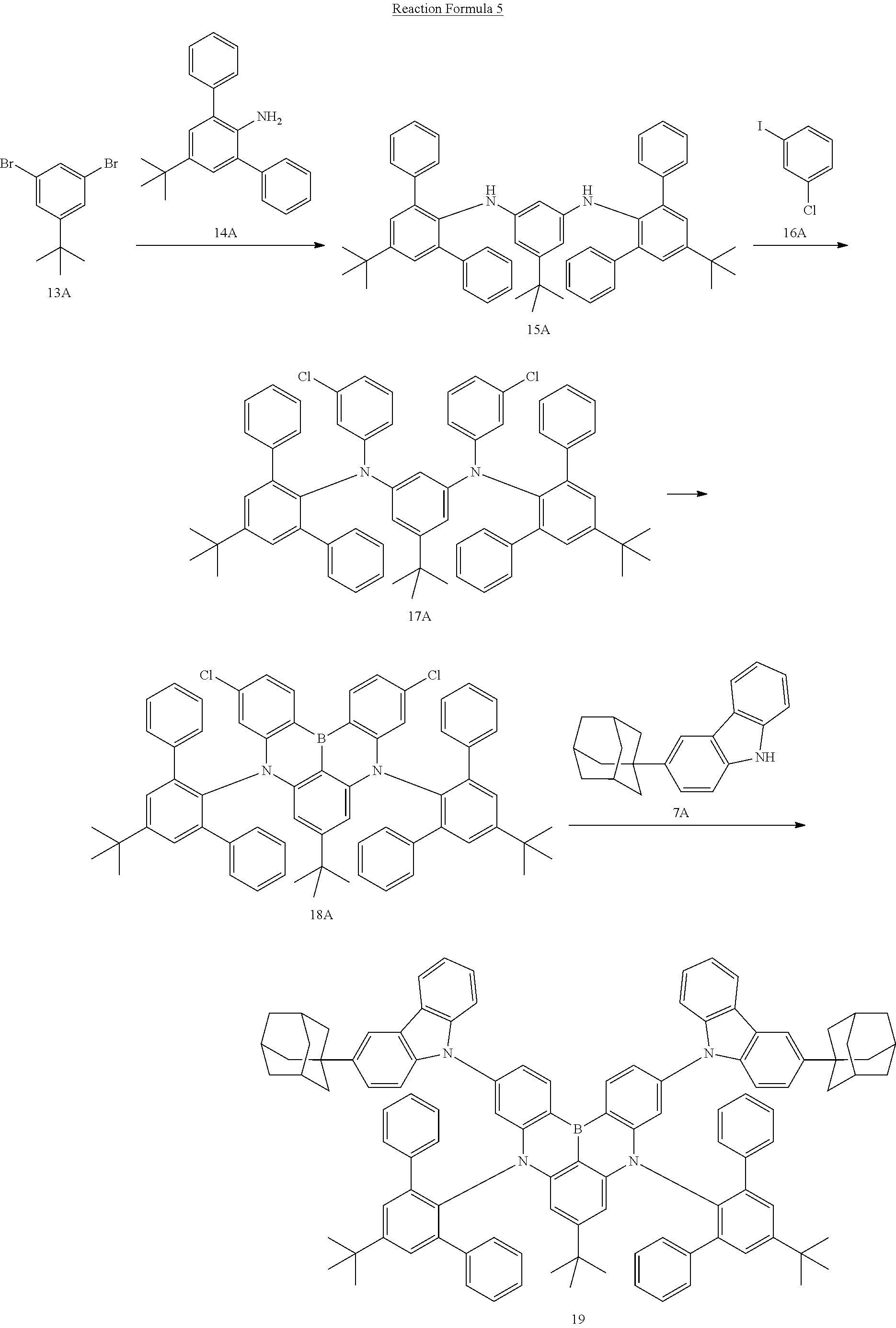

### 1) Synthesis of Intermediate Compound 15A

In an Ar atmosphere, in a three-neck flask (2000 mL), 13A (1,3-dibromo-5-tert-butylbenzene, 50 g), 14A (103 g), bis(dibenzylideneacetone)palladium(0) (Pd(dba)₂, 2.95 g), tri-tert-butylphosphonium tetrafluoroborate (2.98 g), sodium tert-butoxide (NaOtBu, 41.1 g), and toluene (700 mL) were added, and heated and stirred at 60° C. for 6 hours. After returning to room temperature, water was added thereto to extract a product utilizing toluene, an organic layer was collected and dried over MgSO₄, and then a solvent was distilled off under reduced pressure. The resulting product was purified through silica gel column chromatography to obtain 15A (110 g, yield: 88%). The mass number of 15A as determined through FAB-MS was 733.

### 2) Synthesis of Intermediate Compound 17A

In an Ar atmosphere, in a three-neck flask (1000 mL), 15A (110 g), 16A (1-chloro-3-iodobenzene, 286 g), Cul (60 g), and K₂CO₃ (124 g) were added, and the mixture was heated and stirred at 210° C. for 32 hours. After returning to room temperature, water was added thereto to extract a product utilizing CH₂Cl₂, an organic layer was collected and dried utilizing MgSO₄, and then a solvent was distilled off under reduced pressure. The resulting product was purified through silica gel column chromatography to obtain 17A (100 g, yield: 70%). The mass number of 17A as determined through FAB-MS was 954.

### 3) Synthesis of Intermediate Compound 18A

In an Ar atmosphere, in a three-neck flask (1000 mL), 17A (110 g) was added, dissolved in o-dichlorobenzene (ODCB, 200 mL), and cooled to 0° C. utilizing ice, and boron triiodide (Bl₃, 90.3 g) was added thereto, and the mixture was heated and stirred at 160° C. for 6 hours, and then cooled to 0° C. utilizing ice, and N,N-diisopropylethylamine (DIPEA, 160 mL) was added thereto. After returning to room temperature, a reaction solution was filtered utilizing silica gel, and a filtration solvent was distilled off under reduced pressure. The obtained product was purified through silica gel column chromatography, preparative HPLC (eluent: CH₂Cl₂), and recrystallization in toluene to obtain 18A (18.7 g yield: 17%). The mass number of 18A as determined through FAB-MS was 962.

### 4) Synthesis of Compound 19

In an Ar atmosphere, in a three-neck flask (500 mL), 18A (4 g), 7A (3.1 g), bis(dibenzylideneacetone)palladium(0) (Pd(dba)₂, 0.24 g), tri-tert-butylphosphonium tetrafluoroborate (0.24 g), sodium tert-butoxide (NaOtBu, 1.2 g), and toluene (100 mL) were added, and heated and stirred at 120° C. for 6 hours. After returning to room temperature, water was added thereto to extract a product utilizing toluene, an organic layer was collected and dried over MgSO₄, and then a solvent was distilled off under reduced pressure. The resulting product was purified through silica gel column chromatography to obtain Compound 19 (4.9 g, yield: 79%). The mass number of Compound 19 as determined through FAB-MS was 1492.

### (6) Synthesis of Compound 37

Compound 37 according to one or more embodiments may be synthesized according to, for example, Reaction Formula 6.

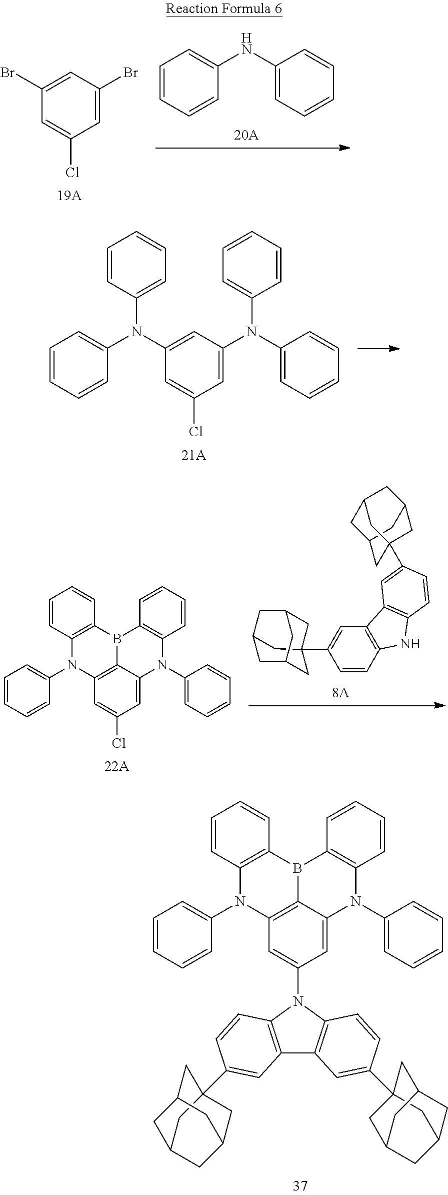

### 1) Synthesis of Intermediate Compound 21A

In an Ar atmosphere, in a three-neck flask (2000 mL), 19A (1,3-dibromo-5-chlorobenzene, 30 g), 20A (diphenylamine, 37.6 g), bis(dibenzylideneacetone)palladium(0) (Pd(dba)₂, 1.91 g), tri-tert-butylphosphonium tetrafluoroborate (1.93 g), sodium tert-butoxide (NaOtBu, 26.6 g), and toluene (700 mL) were added, and heated and stirred at 60° C. for 6 hours. After returning to room temperature, water was added thereto to extract a product utilizing toluene, an organic layer was collected and dried over MgSO₄, and then a solvent was distilled off under reduced pressure. The resulting product was purified through silica gel column chromatography to obtain 21A (41.2 g, yield: 83%). The mass number of 21A as determined through FAB-MS was 447.

### 2) Synthesis of Intermediate Compound 22A

In an Ar atmosphere, in a three-neck flask (1000 mL), 21A (41.2 g) was added, dissolved in o-dichlorobenzene (ODCB, 200 mL), and cooled to 0° C. utilizing ice, and boron triiodide (Bl₃, 72.2 g) was added thereto, and the mixture was heated and stirred at 160 ºC for 6 hours, and cooled to 0° C. utilizing ice, and N,N-diisopropylethylamine (DIPEA, 127 mL) was added thereto. After returning to room temperature, a reaction solution was filtered utilizing silica gel, and a filtration solvent was distilled off under reduced pressure. The obtained product was purified through silica gel column chromatography, preparative HPLC (eluent: CH₂Cl₂), and recrystallization in toluene to obtain 22A (7.5 g yield: 18%). The mass number of 22A as determined through FAB-MS was 455.

### 3) Synthesis of Compound 37

In an Ar atmosphere, in a three-neck flask (500 mL), 22A (4 g), 8A (4.6 g), bis(dibenzylideneacetone)palladium(0) (Pd(dba)₂, 0.51 g), tri-tert-butylphosphonium tetrafluoroborate (0.52 g), sodium tert-butoxide (NaOtBu, 2.15 g), and toluene (100 mL) were added, and heated and stirred at 120° C. for 6 hours. After returning to room temperature, water was added thereto to extract a product utilizing toluene, an organic layer was collected and dried over MgSO₄, and then a solvent was distilled off under reduced pressure. The resulting product was purified through silica gel column chromatography to obtain Compound 37 (6.2 g, yield: 81%). The mass number of Compound 37 as determined through FAB-MS was 854.

### (7) Synthesis of Compound 38

Compound 38 according to one or more embodiments may be synthesized according to, for example, Reaction Formula 7.

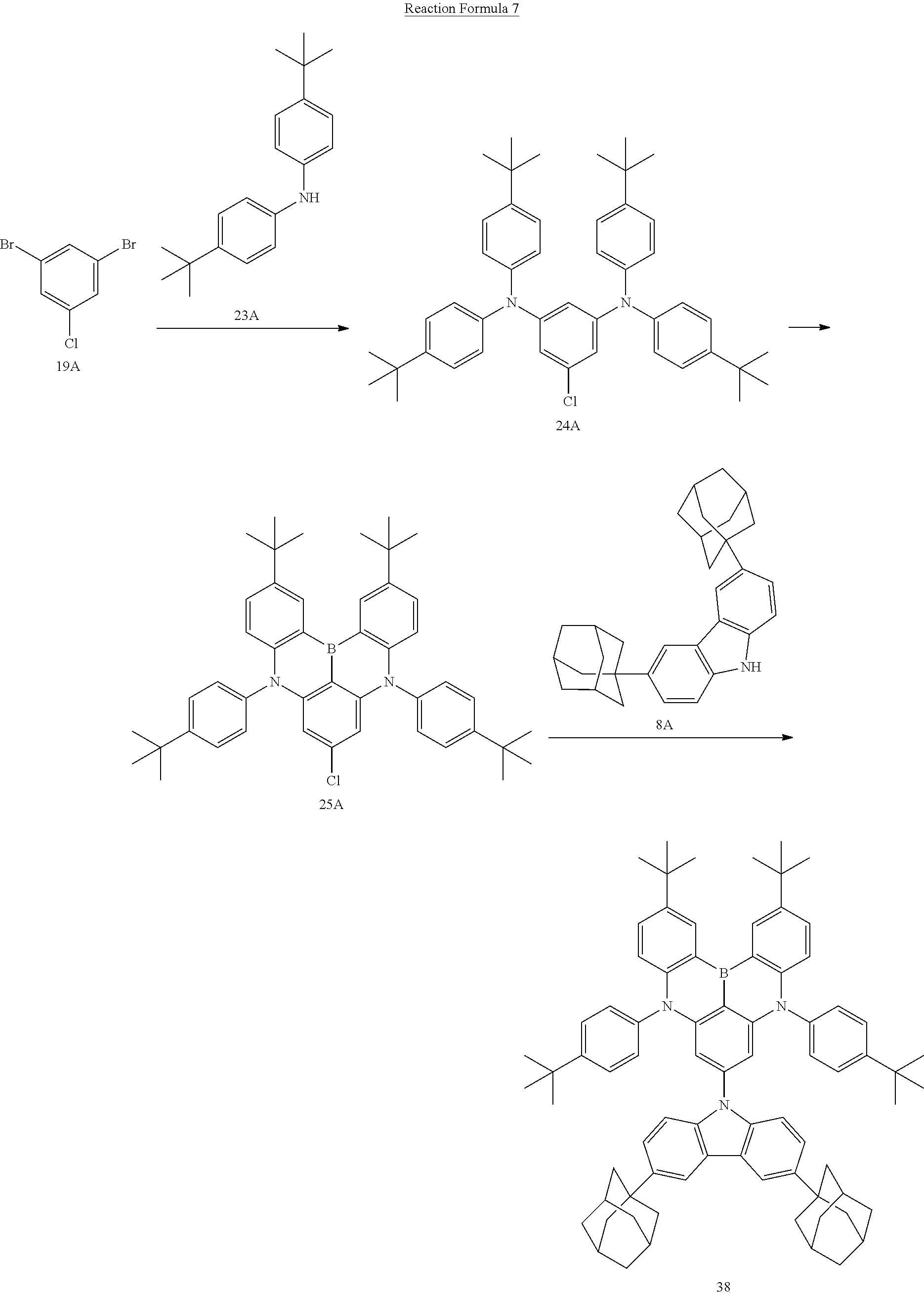

### 1) Synthesis of Intermediate Compound 24A

In an Ar atmosphere, in a three-neck flask (2000 mL), 19A (1,3-dibromo-5-chlorobenzene, 30 g), 23A (bis(4-(tert-butyl)phenyl)amine, 62.5 g), bis(dibenzylideneacetone)palladium(0) (Pd(dba)₂, 1.91 g), tri-tert-butylphosphonium tetrafluoroborate (1.93 g), sodium tert-butoxide (NaOtBu, 26.6 g), and toluene (700 mL) were added, and heated and stirred at 60° C. for 6 hours. After returning to room temperature, water was added thereto to extract a product utilizing toluene, an organic layer was collected and dried over MgSO₄, and then a solvent was distilled off under reduced pressure. The resulting product was purified through silica gel column chromatography to obtain 24A (60 g, yield: 80%). The mass number of 24A as determined through FAB-MS was 671.

### 2) Synthesis of Intermediate Compound 25A

In an Ar atmosphere, in a three-neck flask (1000 mL), 24A (60 g) was added, dissolved in o-dichlorobenzene (ODCB, 200 mL), and cooled to 0° C. utilizing ice, and boron triiodide (Bl₃, 70 g) was added thereto, and the mixture was heated and stirred at 160° C. for 6 hours, and cooled to 0° C. utilizing ice, and N,N-diisopropylethylamine (DIPEA, 127 mL) was added thereto. After returning to room temperature, a reaction solution was filtered utilizing silica gel, and a filtration solvent was distilled off under reduced pressure. The obtained product was purified through silica gel column chromatography, preparative HPLC (eluent: CH₂Cl₂), and recrystallization in toluene to obtain 25A (12.2 g yield: 20%). The mass number of 25A as determined through FAB-MS was 679.

### 3) Synthesis of Compound 38

In an Ar atmosphere, in a three-neck flask (500 mL), 25A (4 g), 8A (3.1 g), bis(dibenzylideneacetone)palladium(0) (Pd(dba)₂, 0.34 g), tri-tert-butylphosphonium tetrafluoroborate (0.34 g), sodium tert-butoxide (NaOtBu, 1.1 g), and toluene (100 mL) were added, and heated and stirred at 120° C. for 6 hours. After returning to room temperature, water was added thereto to extract a product utilizing toluene, an organic layer was collected and dried over MgSO₄, and then a solvent was distilled off under reduced pressure. The resulting product was purified through silica gel column chromatography to obtain Compound 38 (5.1 g, yield: 80%). The mass number of Compound 38 as determined through FAB-MS was 1078.

### (8) Synthesis of Compound 44

Compound 44 according to one or more embodiments may be synthesized according to, for example, Reaction Formula 8.

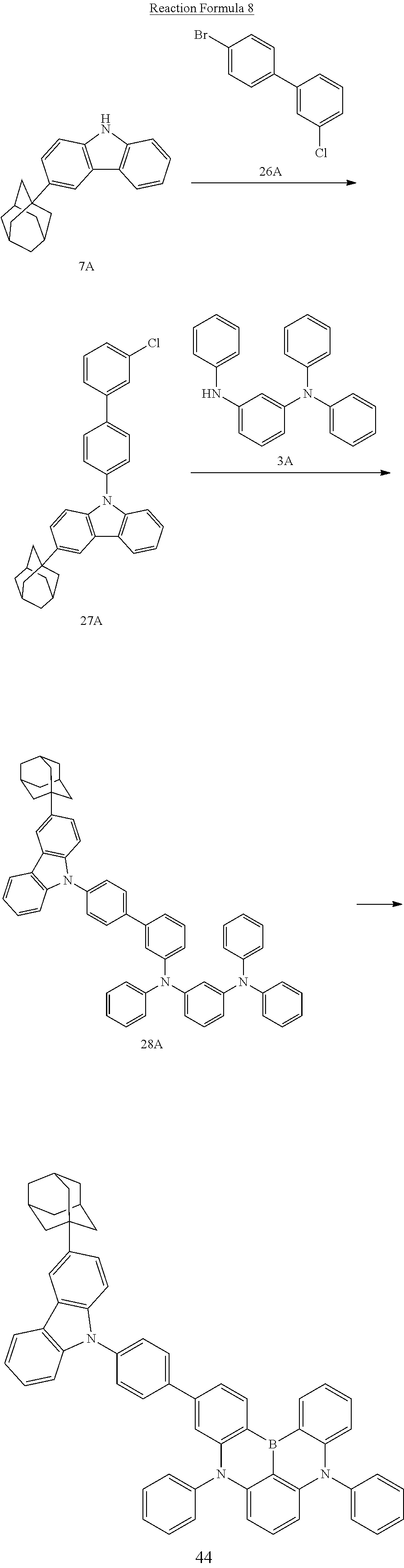 [SMILES: c1ccc2c(c1)[nH]c1ccc(C34CC5CC(CC(C5)C3)C4)cc12 ; Clc1cccc(-c2ccc(Br)cc2)c1 ; Clc1cccc(-c2ccc(-n3c4ccccc4c4cc(C56CC7CC(CC(C7)C5)C6)ccc43)cc2)c1 ; c1ccc(Nc2cccc(N(c3ccccc3)c3ccccc3)c2)cc1 ; c1ccc(N(c2ccccc2)c2cccc(N(c3ccccc3)c3cccc(-c4ccc(-n5c6ccccc6c6cc(C78CC9CC(CC(C9)C7)C8)ccc65)cc4)c3)c2)cc1 ; c1ccc(N2c3ccccc3B3c4ccc(-c5ccc(-n6c7ccccc7c7cc(C89CC%10CC(CC(C%10)C8)C9)ccc76)cc5)cc4N(c4ccccc4)c4cccc2c43)cc1]

### 1) Synthesis of Intermediate Compound 27A

In an Ar atmosphere, in a three-neck flask (2000 mL), 7A (33.5 g), 26A (26.8 g), bis(dibenzylideneacetone)palladium(0) (Pd(dba)₂, 3.4 g), tri-tert-butylphosphonium tetrafluoroborate (3.4 g), sodium tert-butoxide (NaOtBu, 11 g), and toluene (500 mL) were added, and heated and stirred at 100° C. for 6 hours. After returning to room temperature, water was added thereto to extract a product utilizing toluene, an organic layer was collected and dried over MgSO₄, and then a solvent was distilled off under reduced pressure. The resulting product was purified through silica gel column chromatography to obtain 27A (38.6 g, yield: 79%). The mass number of 27A as determined through FAB-MS was 487.

### 2) Synthesis of Intermediate Compound 28A

In an Ar atmosphere, in a three-neck flask (2000 mL), 27A (38.6 g), 3A (26.6 g), bis(dibenzylideneacetone)palladium(0) (Pd(dba)₂, 3.1 g), tri-tert-butylphosphonium tetrafluoroborate (3.1 g), sodium tert-butoxide (NaOtBu, 8.8 g), and toluene (500 mL) were added, and heated and stirred at 120° C. for 12 hours. After returning to room temperature, water was added thereto to extract a product utilizing toluene, an organic layer was collected and dried over MgSO₄, and then a solvent was distilled off under reduced pressure. The resulting product was purified through silica gel column chromatography to obtain 28A (42.3 g, yield: 69%). The mass number of 28A as determined through FAB-MS was 787.

### 3) Synthesis of Compound 44

In an Ar atmosphere, in a three-neck flask (1000 mL), 28A (42.8 g) was added, dissolved in o-dichlorobenzene (ODCB, 200 mL), and cooled to 0° C. utilizing ice, and boron triiodide (Bl₃, 85.4 g) was added thereto, and the mixture was heated and stirred at 150° C. for 6 hours, and cooled to 0° C. utilizing ice, and N,N-diisopropylethylamine (DIPEA, 145 mL) was added thereto. After returning to room temperature, a reaction solution was filtered utilizing silica gel, and a filtration solvent was distilled off under reduced pressure. The obtained product was purified through silica gel column chromatography, preparative HPLC (eluent: CH₂Cl₂), and recrystallization in toluene to obtain Compound 44 (4.7 g yield: 11%). The mass number of Compound 44 as determined through FAB-MS was 795.

### (9) Synthesis of Compound 74

Compound 74 according to one or more embodiments may be synthesized according to, for example, Reaction Formula 9.

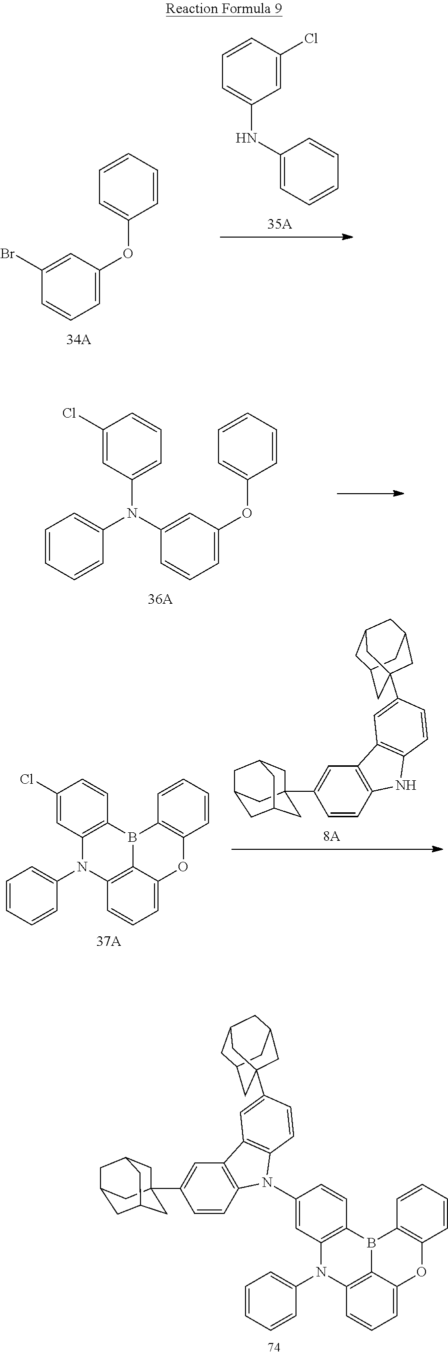

### 1) Synthesis of Intermediate Compound 36A

In an Ar atmosphere, in a three-neck flask (2000 mL), 34A (20 g), 35A (20 g), bis(dibenzylideneacetone)palladium(0) (Pd(dba)₂, 1.39 g), tri-tert-butylphosphonium tetrafluoroborate (2.03 g), sodium tert-butoxide (NaOtBu, 15.4 g), and toluene (700 mL) were added, and heated and stirred at 60° C. for 6 hours. After returning to room temperature, water was added thereto to extract a product utilizing toluene, an organic layer was collected and dried over MgSO₄, and then a solvent was distilled off under reduced pressure. The resulting product was purified through silica gel column chromatography to obtain 36A (24 g, yield: 80%). The mass number of 36A as determined through FAB-MS was 372.

### 2) Synthesis of Intermediate Compound 37A

In an Ar atmosphere, in a three-neck flask (1000 mL), 36A (24 g) was added, dissolved in o-dichlorobenzene (ODCB, 200 mL), and cooled to 0° C. utilizing ice, and boron triiodide (Bl₃, 50 g) was added thereto, and the mixture was heated and stirred at 160° C. for 6 hours, and cooled to 0° C. utilizing ice, and N,N-diisopropylethylamine (DIPEA, 160 mL) was added thereto. After returning to room temperature, a reaction solution was filtered utilizing silica gel, and a filtration solvent was distilled off under reduced pressure. The obtained product was purified through silica gel column chromatography, preparative HPLC (eluent: CH₂Cl₂), and recrystallization in toluene to obtain 37A (4.2 g yield: 17%). The mass number of 37A as determined through FAB-MS was 380.

### 3) Synthesis of Compound 74

In an Ar atmosphere, in a three-neck flask (500 mL), 37A (4.2 g), 8A (7.2 g), bis(dibenzylideneacetone)palladium(0) (Pd(dba)₂, 0.65 g), tri-tert-butylphosphonium tetrafluoroborate (0.94 g), sodium tert-butoxide (NaOtBu, 3.3 g), and toluene (100 mL) were added, and heated and stirred at 120° C. for 6 hours. After returning to room temperature, water was added thereto to extract a product utilizing toluene, an organic layer was collected and dried over MgSO₄, and then a solvent was distilled off under reduced pressure. The resulting product was purified through silica gel column chromatography to obtain Compound 74 (6.9 g, yield: 80%). The mass number of Compound 74 as determined through FAB-MS was 779.

### (10) Synthesis of Compound 117

Compound 117 according to one or more embodiments may be synthesized according to, for example, Reaction Formula 10.

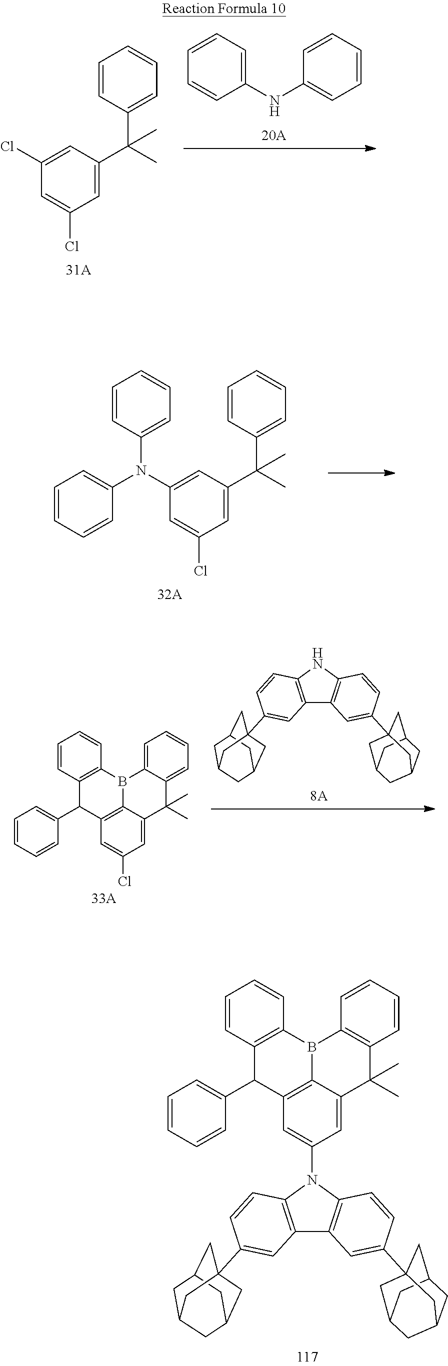

### 1) Synthesis of Intermediate Compound 32A

In an Ar atmosphere, in a three-neck flask (2000 mL), 31A (26.4 g), 20A (16.9 g), bis(dibenzylideneacetone)palladium(0) (Pd(dba)₂, 1.26 g), tri-tert-butylphosphonium tetrafluoroborate (1.26 g), sodium tert-butoxide (NaOtBu, 15.4 g), and toluene (700 mL) were added, and heated and stirred at 120° C. for 6 hours. After returning to room temperature, water was added thereto to extract a product utilizing toluene, an organic layer was collected and dried over MgSO₄, and then a solvent was distilled off under reduced pressure. The resulting product was purified through silica gel column chromatography to obtain 32A (31.8 g, yield: 80%). The mass number of 32A as determined through FAB-MS was 397.

### 2) Synthesis of Intermediate Compound 33A

In an Ar atmosphere, in a three-neck flask (1000 mL), 32A (31.8 g) was added, dissolved in o-dichlorobenzene (ODCB, 160 mL), and cooled to 0° C. utilizing ice, and boron triiodide (Bl₃, 110.2 g) was added thereto, and the mixture was heated and stirred at 190° C. for 12 hours, and cooled to 0° C. utilizing ice, and N,N-diisopropylethylamine (DIPEA, 150 mL) was added thereto. After returning to room temperature, a reaction solution was filtered utilizing silica gel, and a filtration solvent was distilled off under reduced pressure. The obtained product was purified through silica gel column chromatography, preparative HPLC (eluent: CH₂Cl₂), and recrystallization in toluene to obtain 33A (2.6 g yield: 8%). The mass number of 33A as determined through FAB-MS was 405.

### 3) Synthesis of Compound 117

In an Ar atmosphere, in a three-neck flask (100 mL), 33A (2.6 g), 8A (3.1 g), bis(dibenzylideneacetone)palladium(0) (Pd(dba)₂, 0.32 g), tri-tert-butylphosphonium tetrafluoroborate (0.32 g), sodium tert-butoxide (NaOtBu, 837 mg), and toluene (50 mL) were added, and heated and stirred at 120° C. for 8 hours. After returning to room temperature, water was added thereto to extract a product utilizing toluene, an organic layer was collected and dried over MgSO₄, and then a solvent was distilled off under reduced pressure. The resulting product was purified through silica gel column chromatography to obtain Compound 117 (2.6 g, yield: 52%). The mass number of Compound 117 as determined through FAB-MS was 805.

### (11) Synthesis of Compound 118

Compound 118 according to one or more embodiments may be synthesized according to, for example, Reaction Formula 11.

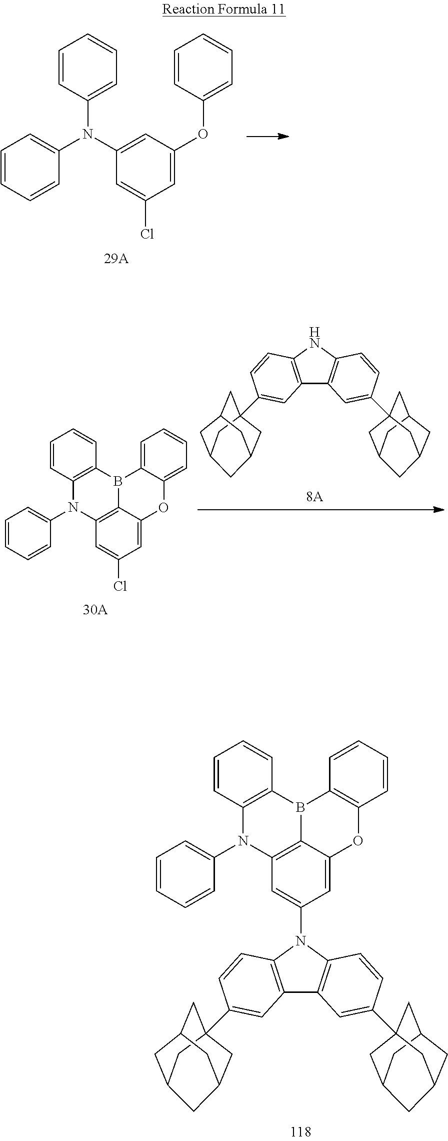

### 1) Synthesis of Intermediate Compound 30A

29A utilized in the synthesis of 30A was synthesized according to a method described in patent document (United States, US20220216406 A1), the relevant content of which is incorporated herein in its entirety by reference.

In an Ar atmosphere, in a three-neck flask (1000 mL), 29A (37.1 g) was added, dissolved in o-dichlorobenzene (ODCB, 200 mL), and cooled to 0° C. utilizing ice, and boron triiodide (Bl₃, 117.5 g) was added thereto, and the mixture was heated and stirred at 180 ºC for 12 hours, and cooled to 0° C. utilizing ice, and N,N-diisopropylethylamine (DIPEA, 150 mL) was added thereto. After returning to room temperature, a reaction solution was filtered utilizing silica gel, and a filtration solvent was distilled off under reduced pressure. The obtained product was purified through silica gel column chromatography, preparative HPLC (eluent: CH₂Cl₂), and recrystallization in toluene to obtain 30A (3.4 g yield: 9%). The mass number of 30A as determined through FAB-MS was 379.

### 2) Synthesis of Compound 118

In an Ar atmosphere, in a three-neck flask (500 mL), 30A (3.4 g), 8A (4.4 g), bis(dibenzylideneacetone)palladium(0) (Pd(dba)₂, 0.42 g), tri-tert-butylphosphonium tetrafluoroborate (0.42 g), sodium tert-butoxide (NaOtBu, 11 g), and toluene (80 mL) were added, and heated and stirred at 120° C. for 9 hours. After returning to room temperature, water was added thereto to extract a product utilizing toluene, an organic layer was collected and dried over MgSO₄, and then a solvent was distilled off under reduced pressure. The resulting product was purified through silica gel column chromatography to obtain Compound 118 (2.9 g, yield: 42%). The mass number of Compound 118 as determined through FAB-MS was 778.

2. Preparation and Evaluation of light emitting elements including polycyclic compounds

### (1) Preparation of Light Emitting Elements

Light emitting elements of one or more embodiments containing a polycyclic compound of one or more embodiments in an emission layer were prepared utilizing a method described herein. A light emitting element of Example was prepared utilizing the above-described Example compound as a dopant material of an emission layer. Comparative Example corresponds to a light emitting element prepared utilizing the Comparative Example Compound as a dopant material of an emission layer. Example compounds and Comparative Example Compounds each applied to an emission layer are as follows.

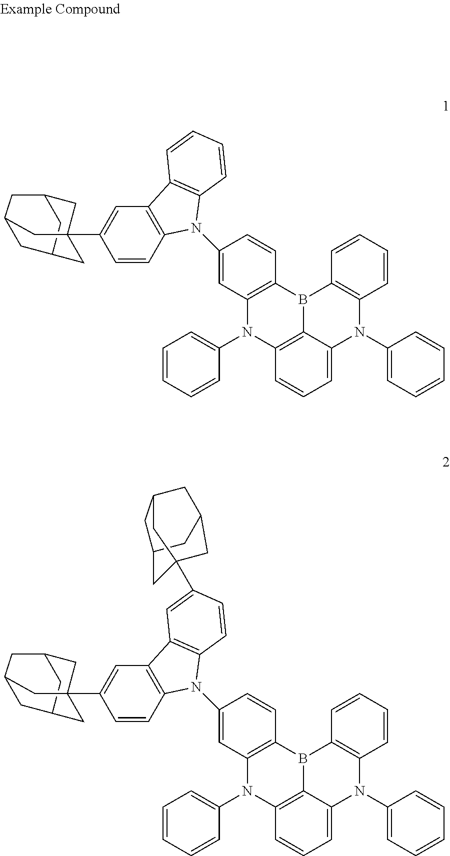 [SMILES: c1ccc(N2c3ccccc3B3c4ccc(-n5c6ccccc6c6cc(C78CC9CC(CC(C9)C7)C8)ccc65)cc4N(c4ccccc4)c4cccc2c43)cc1 ; c1ccc(N2c3ccccc3B3c4ccc(-n5c6ccc(C78CC9CC(CC(C9)C7)C8)cc6c6cc(C78CC9CC(CC(C9)C7)C8)ccc65)cc4N(c4ccccc4)c4cccc2c43)cc1]

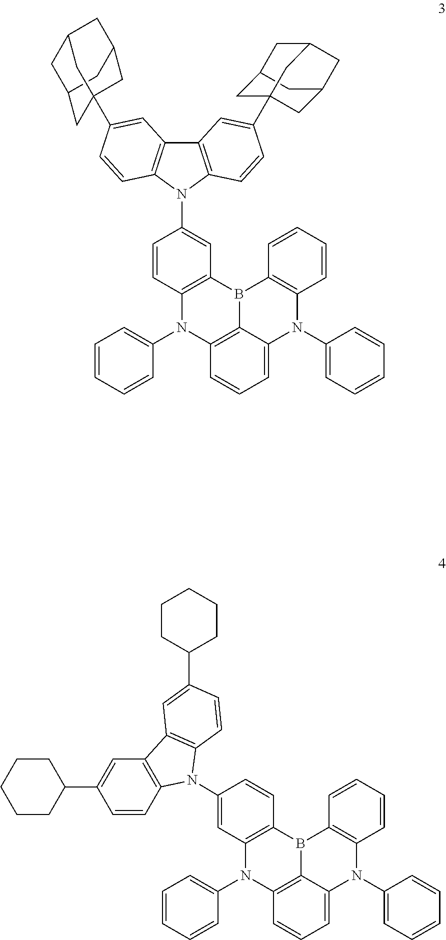 [SMILES: c1ccc(N2c3ccccc3B3c4cc(-n5c6ccc(C78CC9CC(CC(C9)C7)C8)cc6c6cc(C78CC9CC(CC(C9)C7)C8)ccc65)ccc4N(c4ccccc4)c4cccc2c43)cc1 ; c1ccc(N2c3ccccc3B3c4ccc(-n5c6ccc(C7CCCCC7)cc6c6cc(C7CCCCC7)ccc65)cc4N(c4ccccc4)c4cccc2c43)cc1]

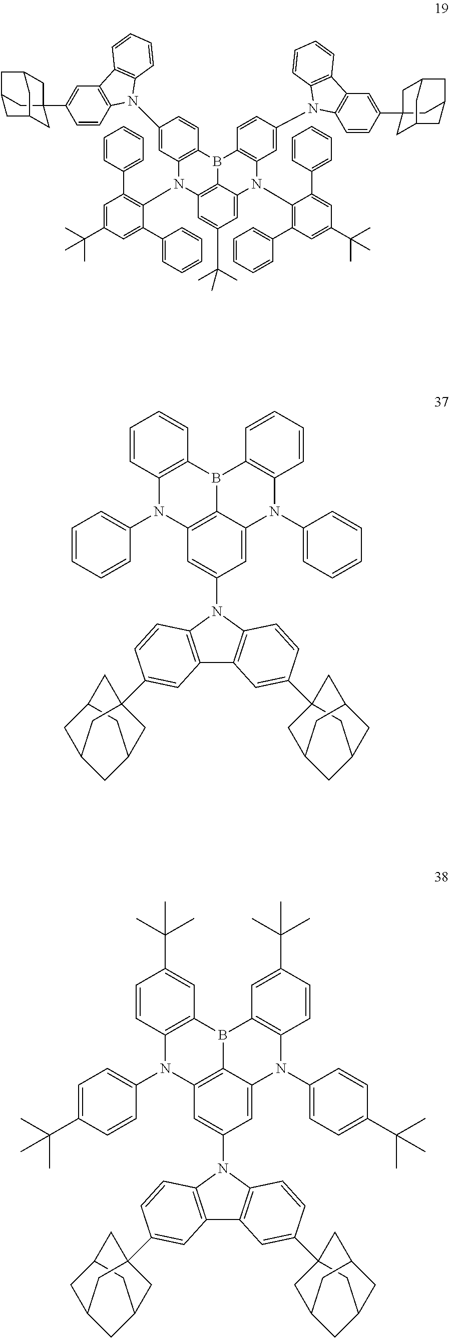 [SMILES: CC(C)(C)c1cc(-c2ccccc2)c(N2c3cc(-n4c5ccccc5c5cc(C67CC8CC(CC(C8)C6)C7)ccc54)ccc3B3c4ccc(-n5c6ccccc6c6cc(C78CC9CC(CC(C9)C7)C8)ccc65)cc4N(c4c(-c5ccccc5)cc(C(C)(C)C)cc4-c4ccccc4)c4cc(C(C)(C)C)cc2c43)c(-c2ccccc2)c1 ; c1ccc(N2c3ccccc3B3c4ccccc4N(c4ccccc4)c4cc(-n5c6ccc(C78CC9CC(CC(C9)C7)C8)cc6c6cc(C78CC9CC(CC(C9)C7)C8)ccc65)cc2c43)cc1 ; CC(C)(C)c1ccc(N2c3ccc(C(C)(C)C)cc3B3c4cc(C(C)(C)C)ccc4N(c4ccc(C(C)(C)C)cc4)c4cc(-n5c6ccc(C78CC9CC(CC(C9)C7)C8)cc6c6cc(C78CC9CC(CC(C9)C7)C8)ccc65)cc2c43)cc1]

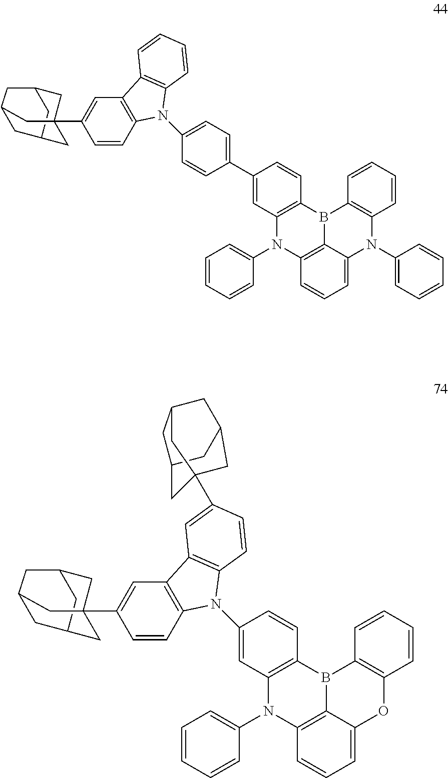 [SMILES: c1ccc(N2c3ccccc3B3c4ccc(-c5ccc(-n6c7ccccc7c7cc(C89CC%10CC(CC(C%10)C8)C9)ccc76)cc5)cc4N(c4ccccc4)c4cccc2c43)cc1 ; c1ccc(N2c3cc(-n4c5ccc(C67CC8CC(CC(C8)C6)C7)cc5c5cc(C67CC8CC(CC(C8)C6)C7)ccc54)ccc3B3c4ccccc4Oc4cccc2c43)cc1]

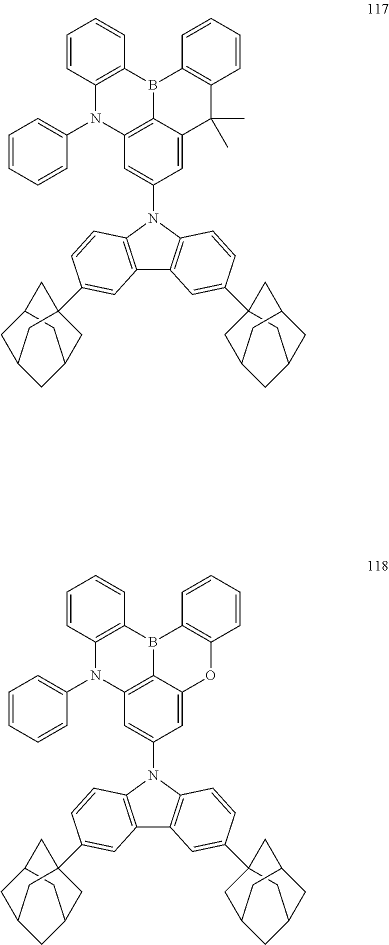 [SMILES: CC1(C)c2ccccc2B2c3ccccc3N(c3ccccc3)c3cc(-n4c5ccc(C67CC8CC(CC(C8)C6)C7)cc5c5cc(C67CC8CC(CC(C8)C6)C7)ccc54)cc1c32 ; c1ccc(N2c3ccccc3B3c4ccccc4Oc4cc(-n5c6ccc(C78CC9CC(CC(C9)C7)C8)cc6c6cc(C78CC9CC(CC(C9)C7)C8)ccc65)cc2c43)cc1]

### Comparative Example Compound

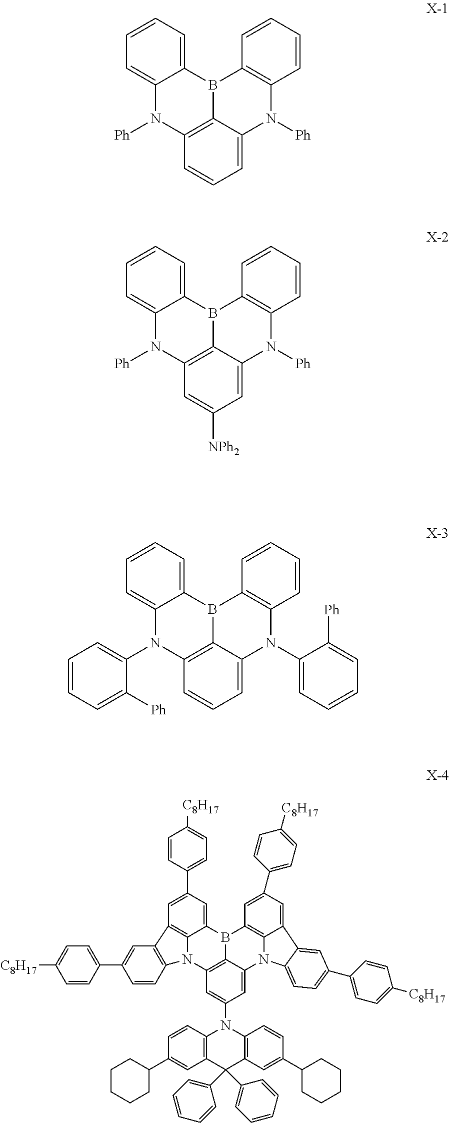

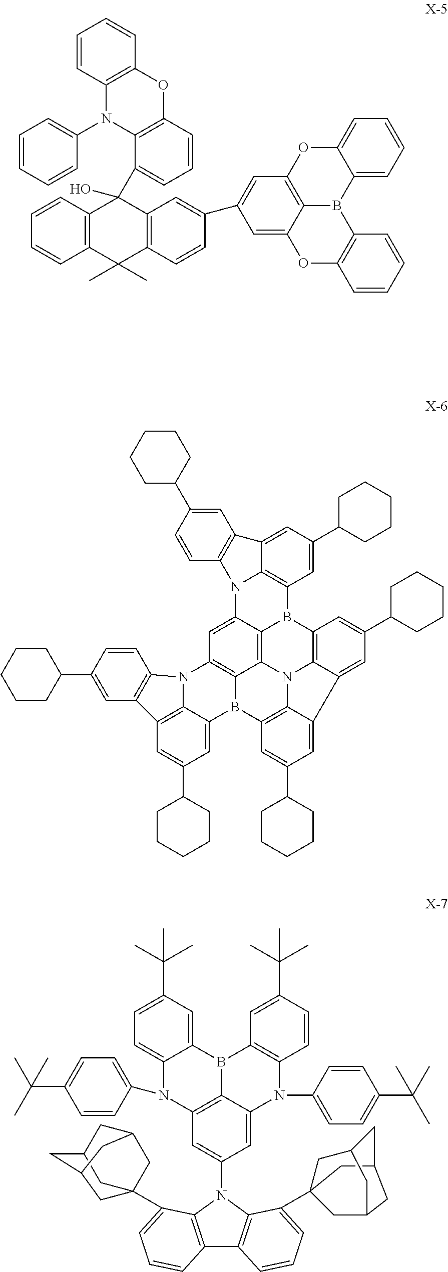 [SMILES: CC1(C)c2ccccc2C(O)(c2cccc3c2N(c2ccccc2)c2ccccc2O3)c2cc(-c3cc4c5c(c3)Oc3ccccc3B5c3ccccc3O4)ccc21 ; c1cc2c(cc1C1CCCCC1)c1cc(C3CCCCC3)cc3c1n2-c1cc2c4c5c1B3c1cc(C3CCCCC3)cc3c6cc(C7CCCCC7)cc(c6n-5c13)B4c1cc(C3CCCCC3)cc3c4cc(C5CCCCC5)ccc4n-2c13 ; CC(C)(C)c1ccc(N2c3ccc(C(C)(C)C)cc3B3c4cc(C(C)(C)C)ccc4N(c4ccc(C(C)(C)C)cc4)c4cc(-n5c6c(C78CC9CC(CC(C9)C7)C8)cccc6c6cccc(C78CC9CC(CC(C9)C7)C8)c65)cc2c43)cc1]

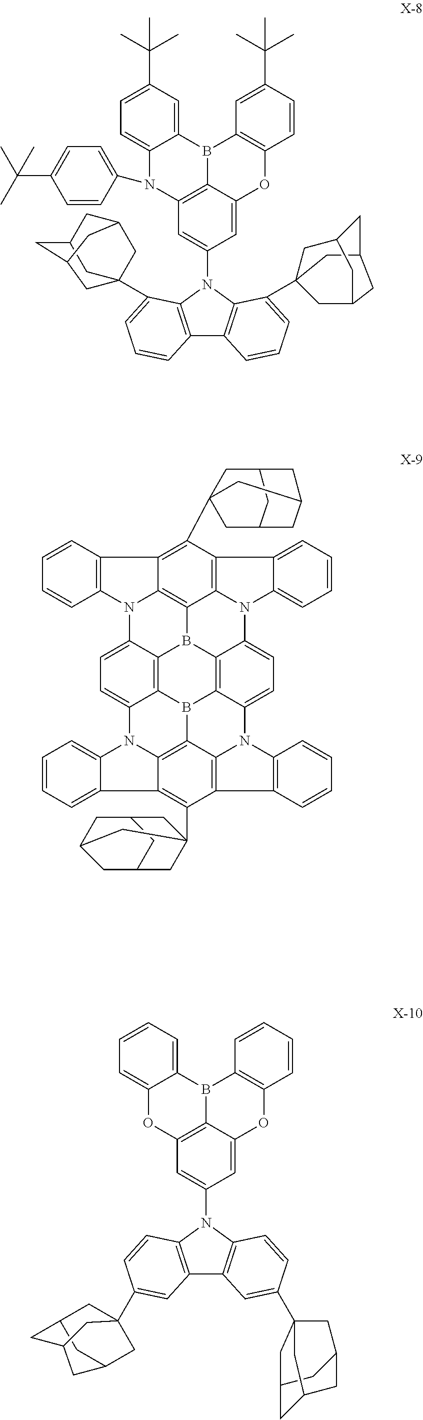 [SMILES: CC(C)(C)c1ccc(N2c3ccc(C(C)(C)C)cc3B3c4cc(C(C)(C)C)ccc4Oc4cc(-n5c6c(C78CC9CC(CC(C9)C7)C8)cccc6c6cccc(C78CC9CC(CC(C9)C7)C8)c65)cc2c43)cc1 ; c1ccc2c(c1)c1c(C34CC5CC(CC(C5)C3)C4)c3c4ccccc4n4c3c3c1n2-c1ccc2c5c1B3c1c-4ccc3c1B5c1c4c(c(C56CC7CC(CC(C7)C5)C6)c5c6ccccc6n-3c15)c1ccccc1n4-2 ; c1ccc2c(c1)Oc1cc(-n3c4ccc(C56CC7CC(CC(C7)C5)C6)cc4c4cc(C56CC7CC(CC(C7)C5)C6)ccc43)cc3c1B2c1ccccc1O3]

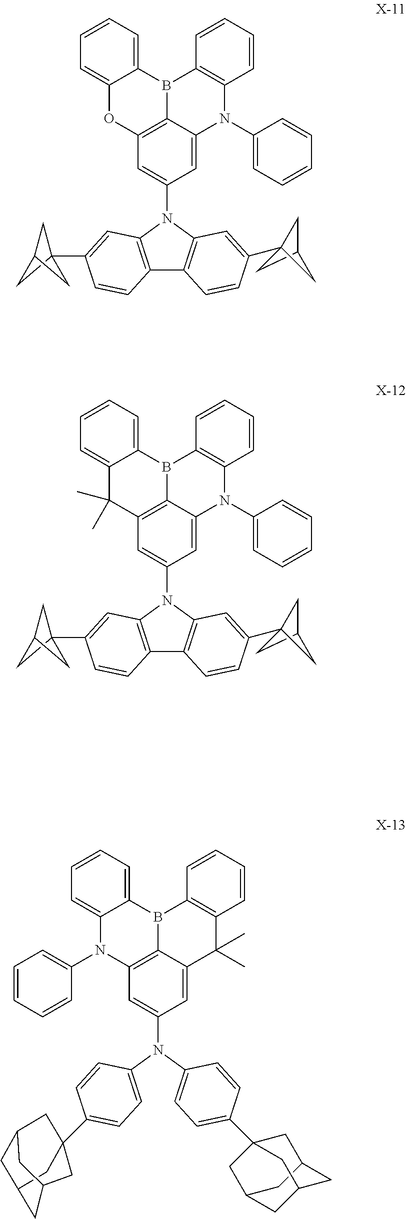 [SMILES: c1ccc(N2c3ccccc3B3c4ccccc4Oc4cc(-n5c6cc(C78CC(C7)C8)ccc6c6ccc(C78CC(C7)C8)cc65)cc2c43)cc1 ; CC1(C)c2ccccc2B2c3ccccc3N(c3ccccc3)c3cc(-n4c5cc(C67CC(C6)C7)ccc5c5ccc(C67CC(C6)C7)cc54)cc1c32 ; CC1(C)c2ccccc2B2c3ccccc3N(c3ccccc3)c3cc(N(c4ccc(C56CC7CC(CC(C7)C5)C6)cc4)c4ccc(C56CC7CC(CC(C7)C5)C6)cc4)cc1c32]

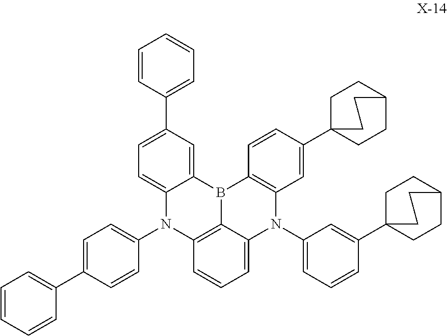 [SMILES: c1ccc(-c2ccc(N3c4ccc(-c5ccccc5)cc4B4c5ccc(C67CCC(CC6)CC7)cc5N(c5cccc(C67CCC(CC6)CC7)c5)c5cccc3c54)cc2)cc1]

A first electrode having a thickness of 150 nm was formed, utilizing ITO. A hole injection layer with a thickness of 10 nm is formed on the first electrode, utilizing dipyrazino[2,3-f:2′,3′-h]quinoxaline-2,3,6,7,10,11-hexacarbonitrile (HAT-CN). A hole transport layer having a thickness of 80 nm was formed on the hole injection layer, utilizing a-NPD (N,N′-bis(naphthalen-1-yl)-N,N′-bis(phenyl)-2,2′-dimethylbenzidine). An auxiliary emission layer having a thickness of 5 nm was formed on the hole transport layer, utilizing mCP (1,3-bis(carbazol-9-yl)benzene). On the auxiliary emission layer, mCBP (3,3′-di(9H-carbazol-9-yl)-1,1′-biphenyl) and a respective Example compound were co-deposited at a mass ratio of 99:1 to form an emission layer having a thickness of 20 nm. For Comparative Examples, a respective Comparative Example Compound instead of Example Compounds was applied to a corresponding light emitting element of Comparative Examples. An electron transport layer having a thickness of 30 nm was formed on the emission layer, utilizing TPBi (2,2′,2″-(1,3,5-benzinetriyl)-tris(1-phenyl-1-H-benzimidazole)). An electron injection layer having a thickness of 0.5 nm was formed on the electron transport layer, utilizing LiF. A second electrode having a thickness of 100 nm was formed on the electron injection layer, utilizing Al. Each layer was formed through vacuum deposition.

Functional layer compounds utilized in the preparation of each of the light emitting elements of Examples and Comparative Examples are disclosed below. The following materials are suitable materials, and were utilized for the preparation of light emitting elements after sublimation-purifying commercially available products.

### Functional Layer Compound

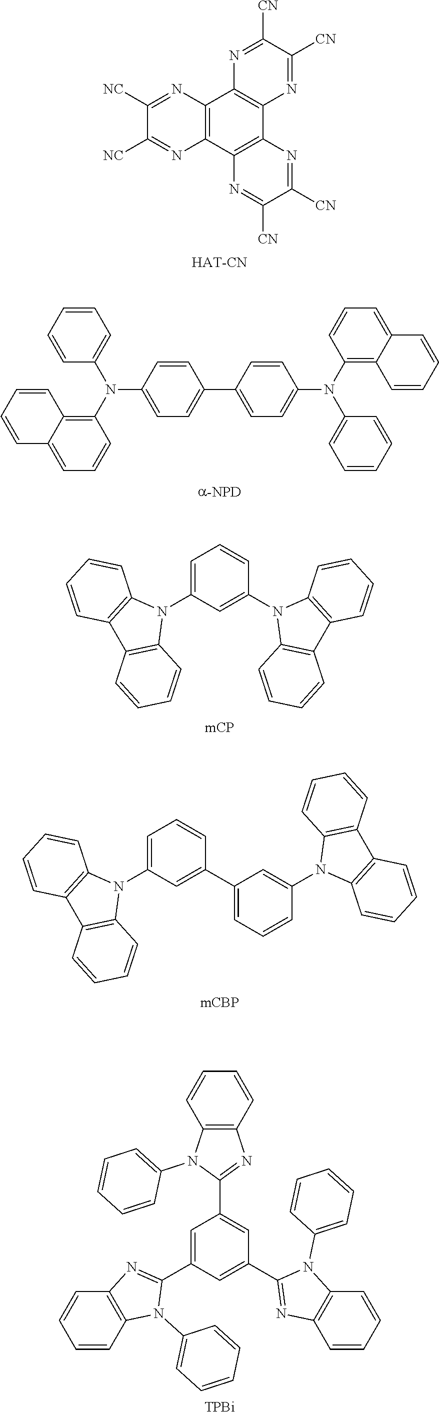

The lifespan (LT₅₀) of a light emitting element is the time from an initial luminance of 900 cd/m² to 50% luminance deterioration, and relative lifespan is presented with respect to Comparative Example 14.

TABLE 1

| | Dopant | Relative element lifespan LT₅₀ |
|---|---|---|
| Example 1 | Example Compound 1 | 2.3 |
| Example 2 | Example Compound 2 | 2.6 |
| Example 3 | Example Compound 3 | 2.2 |
| Example 4 | Example Compound 4 | 2.4 |
| Example 5 | Example Compound 19 | 3.9 |
| Example 6 | Example Compound 37 | 2.3 |
| Example 7 | Example Compound 38 | 2.5 |
| Example 8 | Example Compound 44 | 2.1 |
| Example 9 | Example Compound 74 | 2.1 |
| Example 10 | Example Compound 117 | 1.9 |
| Example 11 | Example Compound 118 | 1.8 |
| Comparative | Comparative Example | 1.2 |
| Example 1 | Compound X-1 | |
| Comparative | Comparative Example | 1.4 |
| Example 2 | Compound X-2 | |
| Comparative | Comparative Example | 1.3 |
| Example 3 | Compound X-3 | |
| Comparative | Comparative Example | 1.6 |
| Example 4 | Compound X-4 | |
| Comparative | Comparative Example | 0.1 |
| Example 5 | Compound X-5 | |
| Comparative | Comparative Example | 1.7 |
| Example 6 | Compound X-6 | |
| Comparative | Comparative Example | 0.9 |
| Example 7 | Compound X-7 | |
| Comparative | Comparative Example | 0.8 |
| Example 8 | Compound X-8 | |
| Comparative | Comparative Example | 0.6 |
| Example 9 | Compound X-9 | |
| Comparative | Comparative Example | 0.1 |
| Example 10 | Compound X-10 | |
| Comparative | Comparative Example | 0.3 |
| Example 11 | Compound X-11 | |
| Comparative | Comparative Example | 0.5 |
| Example 12 | Compound X-12 | |
| Comparative | Comparative Example | 0.6 |
| Example 13 | Compound X-13 | |
| Comparative | Comparative Example | 1.0 |
| Example 14 | Compound X-14 | |

Referring to Table 1, Examples 1 to 11, which are light emitting elements to which the polycyclic compound of one or more embodiments of the present disclosure was applied, each exhibited longer lifespan than Comparative Examples 1 to 14.

The polycyclic compound of an embodiment of the present disclosure may include a core structure in which three benzene rings are fused through one boron atom, a first atom, and a second atom. The first atom and the second atom may each independently be selected from an oxygen atom, a sulfur atom, a selenium atom, a carbon atom, a silicon atom, and a nitrogen atom. When the first atom and the second atom are nitrogen atoms, a phenyl group may be bonded to the nitrogen atoms. In addition, in the polycyclic compound of an embodiment, an N-containing tricyclic heterocyclic group substituted with at least one cycloalkyl group may be bonded to three benzene rings of the core structure or a phenyl group bonded to a nitrogen atom. The number of ring-forming carbon atoms in at least one cycloalkyl group is 5 to 30.

As the polycyclic compound represented by Formula 1 of the present disclosure has a structure in which an N-containing tricyclic heterocyclic group substituted with at least one cycloalkyl group is introduced into the core structure, the characteristics of a light emitting element, for example, the lifespan of the element, was improved. Without wishing to be bound by any theory, it is believed that the N-containing tricyclic heterocyclic group substituted with at least one cycloalkyl group introduced in one or more embodiments of the present disclosure is a bulky electron donor unit, and thus molecules including N-containing tricyclic heterocyclic group substituted with the cycloalkyl group has improved stability to increase the lifespan of a light emitting element to which the polycyclic compound of an embodiment of the present disclosure was applied.

Comparative Example Compounds X-1 to X-3 applied to the light emitting elements of Comparative Examples 1 to 3 do not include a cycloalkyl group in molecules. It is believed that the lifespan of the elements is shown to be low as there is no stacking prevention resulting from the introduction of the cycloalkyl group.

It is believed that Comparative Example Compounds X-4, X-6, and X-9 applied to the light emitting elements of Comparative Examples 4, 6, and 9 are compounds having a different core structure from the compounds of Examples, and thus have degradation in stability and show the low lifespan of an element.

Comparative Example Compounds X-7 and X-8 applied to the light emitting elements of Comparative Examples 7 and 8 have a structure in which a cycloalkyl group is substituted at positions 1 and 8 of a carbazole group bonded to the core structure. It is believed that the structure causes distortion of molecule and reduces the stability of molecules, resulting in low lifespan of an element.

Comparative Examples Compounds X-5 and X-10 applied to the light emitting elements of Comparative Examples 5 and 10 have a structure including one boron atom and two oxygen atoms in the core structure. It is believed that the structure causes distortion of molecule and reduces the stability of molecules, resulting in low lifespan of an element.

In Comparative Example Compounds X-11 and X-12 applied to the light emitting elements of Comparative Examples 11 and 12, each of a plurality of rings included in a cycloalkyl group substituted on a carbazole group has less than 5 ring-forming carbon atoms. It is believed that the structure causes distortion of molecule and reduces the stability of molecules, resulting in low lifespan of an element.

Comparative Example Compound X-13 applied to the light emitting element of Comparative Example 13 has a structure in which a cycloalkyl group is substituted on diphenylamine. It is believed that the stability of molecules and lifespan of an element are shown to be low as an ortho position of amine is not substituted.

It is believed that Comparative Example Compound X-14 applied to the light emitting element of Comparative Example 14 has a structure in which a cycloalkyl group is directly bonded to the core structure, and thus the stability of molecules and lifespan of an element are shown to be low.

A light emitting element of one or more embodiments of the present disclosure may exhibit long lifespan.

A polycyclic compound of one or more embodiments of the present disclosure is included in an emission layer of a light emitting element, and may thus contribute to improving the lifespan of the light emitting element.

As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure”.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

In the present disclosure, when particles are spherical, “diameter” indicates a particle diameter or an average particle diameter, and when the particles are non-spherical, the “diameter” indicates a major axis length or an average major axis length. The diameter (or size) of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter (or size) is referred to as D50. D50 refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

The light-emitting element, the display device, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the present disclosure has been described with reference to one or more embodiments of the present disclosure, it will be understood that the present disclosure should not be limited to these embodiments but one or more suitable changes and modifications may be made by those skilled in the art without departing from the spirit and scope of the present disclosure.

Accordingly, the technical scope of the present disclosure is not intended to be limited to the contents set forth in the detailed description of the specification, but is intended to be defined by the appended claims and equivalents thereof.

What is claimed is:

1. A light emitting element comprising:
a first electrode;
a second electrode facing the first electrode; and
at least one functional layer between the first electrode and the second electrode,
wherein the at least one functional layer comprises a first compound represented by Formula 1: 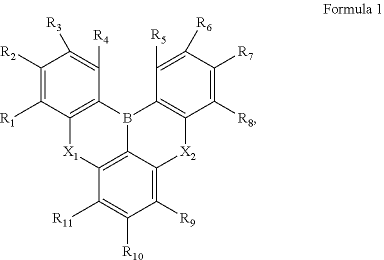
wherein in Formula 1,
X₁ and X₂ are each independently O, S, Se, CRₐR_{b}, SiR_{c}R_{d}, or NR₁₂, and X₁ and X₂ are not both O,
Rₐ to R_{d} are each independently hydrogen, a substituted or unsubstituted alkyl group having 1 to 30 carbon atoms, or a substituted or unsubstituted aryl group having 6 to 30 ring-forming carbon atoms, and
at least one selected from among R₁ to R₁₂ is represented by Formula 2, and the remainder are each independently hydrogen, deuterium, a halogen, a cyano group, a substituted or unsubstituted oxy group, a substituted or unsubstituted thio group, a substituted or unsubstituted silyl group, a substituted or unsubstituted amine group, a substituted or unsubstituted alkyl group having 1 to 30 carbon atoms, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 2 to 30 ring-forming carbon atoms, 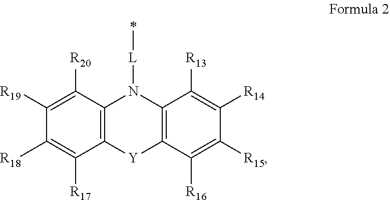
and
wherein in Formula 2,
L is a direct linkage or a substituted or unsubstituted arylene group having 6 to 30 ring-forming carbon atoms,
Y is a direct linkage, O, S, Se, CRₑR_{f}, SiR_{g}Rₕ, or NRᵢ,
Rₑ to Rᵢ are each independently a substituted or unsubstituted alkyl group having 1 to 30 carbon atoms, or a substituted or unsubstituted aryl group having 6 to 30 ring-forming carbon atoms,
at least one selected from among R₁₄ to R₁₉ is a substituted or unsubstituted cycloalkyl group having 5 to 30 ring-forming carbon atoms, and the remainder are each independently hydrogen or deuterium,
when R₁₄ to R₁₉ are a crosslinked cycloalkyl group, each of a plurality of rings in the crosslinked cycloalkyl group has 5 to 10 ring-forming carbon atoms,
R₁₃ and R₂₀ are each independently hydrogen, deuterium, or a substituted or unsubstituted cycloalkyl group having 3 to 30 ring-forming carbon atoms, and
Formula 1 comprises a structure in which one or more hydrogens are substituted with deuterium.

2. The light emitting element of claim 1, wherein Formula 2 is represented by Formula 2-1a or Formula 2-1b: 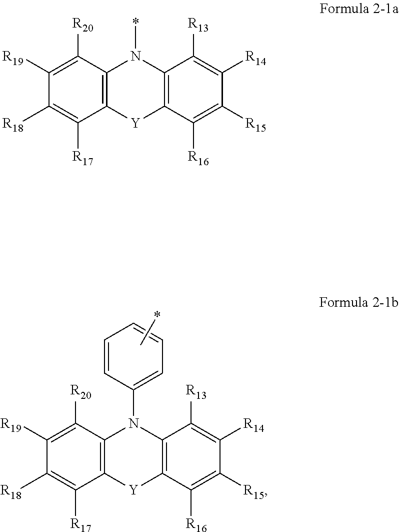
and
wherein in Formulas 2-1a and 2-1b,
Y, and R₁₃ to R₂₀ are each independently the same as defined in Formula 2.

3. The light emitting element of claim 1, wherein Formula 2 is represented by any one selected from among Formulas 2-2a to 2-2g: 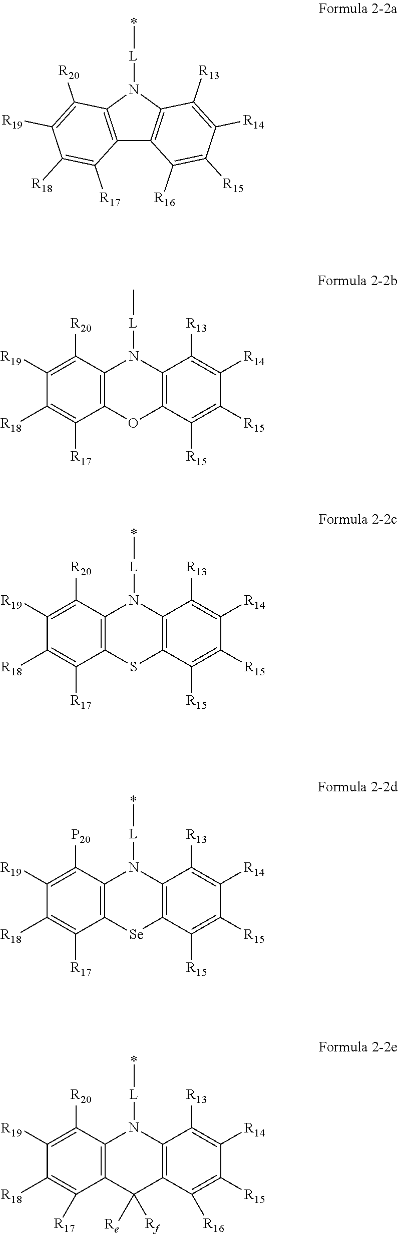 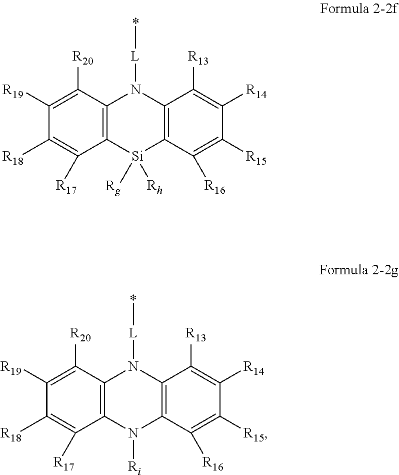
and
wherein in Formulas 2-2a to 2-2g,
Rₑ to Rᵢ are each independently an unsubstituted methyl group or an unsubstituted phenyl group, and
L, and R₁₃ to R₂₀ are each independently the same as defined in Formula 2.

4. The light emitting element of claim 1, wherein Formula 2 is represented by any one selected from among Formulas 2-3a to 2-3e: 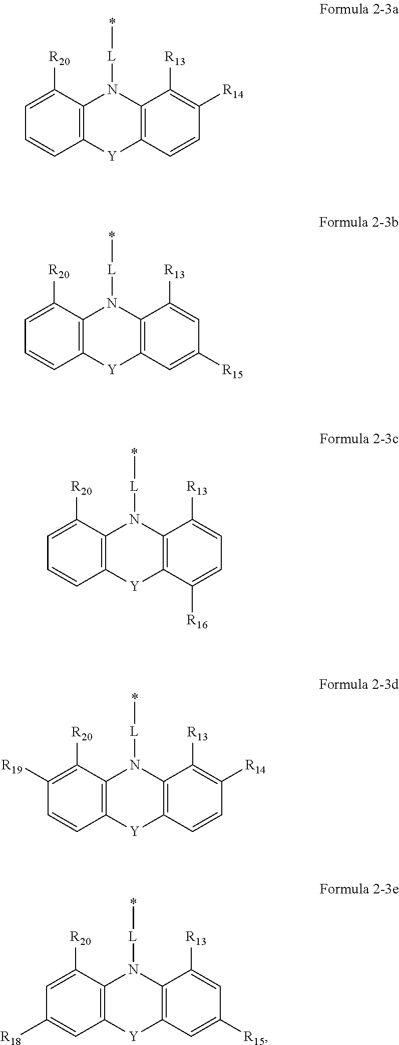
and
wherein in Formulas 2-3a to 2-3e,
R₁₄, R₁₅, R₁₆, R₁₈, and R₁₉ are each independently a substituted or unsubstituted cycloalkyl group having 5 to 30 ring-forming carbon atoms,
L, Y, R₁₃, and R₂₀ are each independently the same as defined in Formula 2, and
Formulas 2-3a to 2-3e each comprise a structure in which one or more hydrogens are substituted with deuterium.

5. The light emitting element of claim 1, wherein at least one selected from among R₁₄ to R₁₉ is represented by any one selected from among Formulas A1 to A5, and the remainder are each independently hydrogen or deuterium:

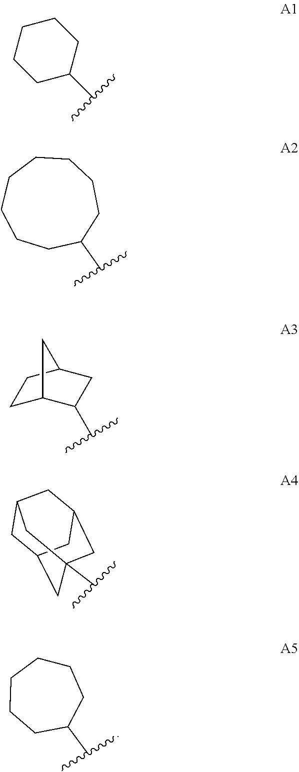 [SMILES: *C1CCCCC1 ; *C1CCCCCCCC1 ; *C1CC2CCC1C2 ; *C12CC3CC(CC(C3)C1)C2 ; *C1CCCCCC1]

6. The light emitting element of claim 1, wherein Rₐ to Rₐ are each independently hydrogen, an unsubstituted methyl group, or an unsubstituted phenyl group.

7. The light emitting element of claim 1, wherein the at least one functional layer comprises at least one selected from compounds of Compound Group 1:
Compound Group 1 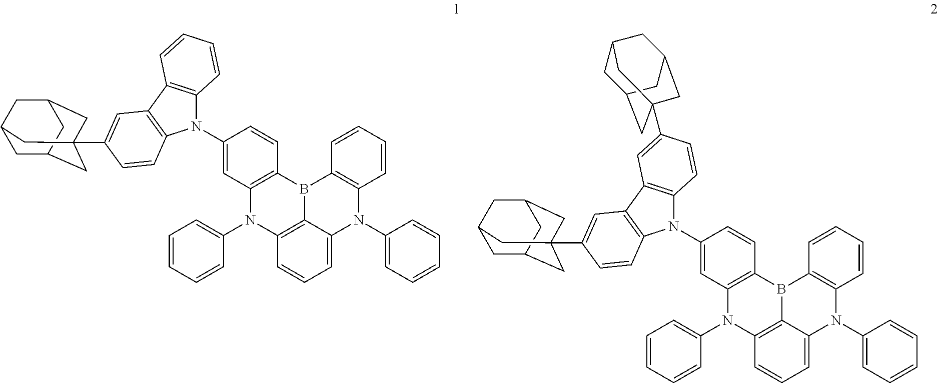 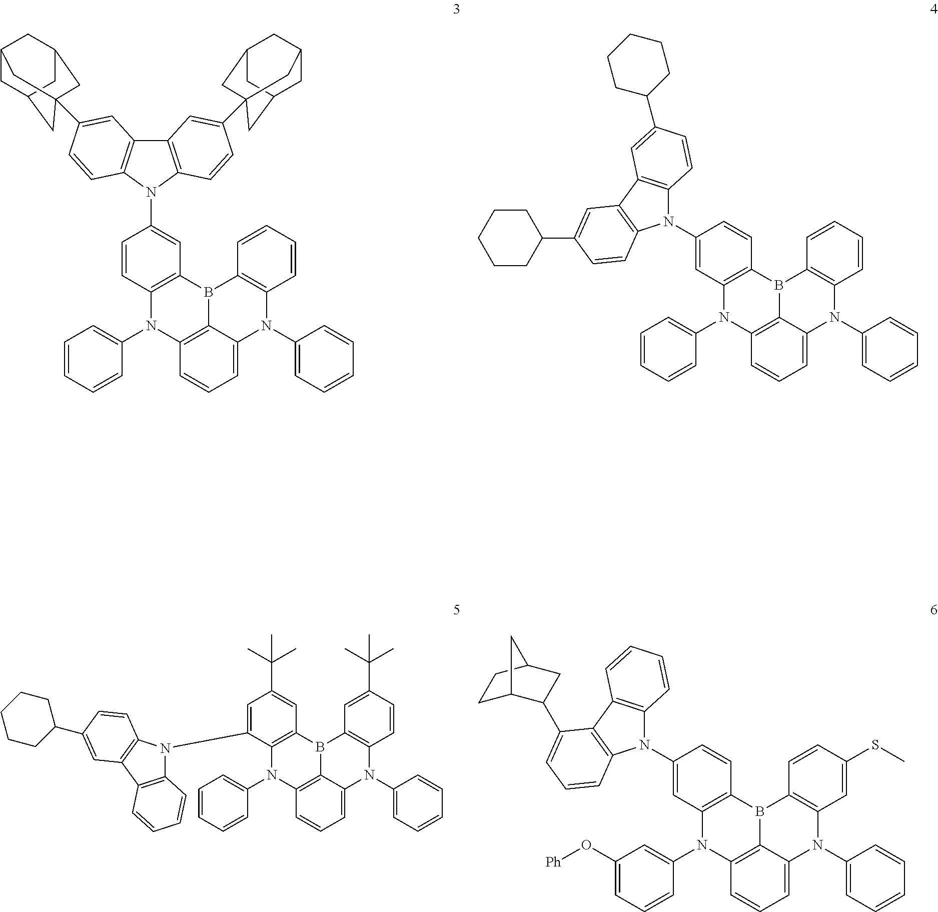 [SMILES: c1ccc(N2c3ccccc3B3c4cc(-n5c6ccc(C78CC9CC(CC(C9)C7)C8)cc6c6cc(C78CC9CC(CC(C9)C7)C8)ccc65)ccc4N(c4ccccc4)c4cccc2c43)cc1 ; c1ccc(N2c3ccccc3B3c4ccc(-n5c6ccc(C7CCCCC7)cc6c6cc(C7CCCCC7)ccc65)cc4N(c4ccccc4)c4cccc2c43)cc1 ; CC(C)(C)c1ccc2c(c1)B1c3cc(C(C)(C)C)cc(-n4c5ccccc5c5cc(C6CCCCC6)ccc54)c3N(c3ccccc3)c3cccc(c31)N2c1ccccc1 ; CSc1ccc2c(c1)N(c1ccccc1)c1cccc3c1B2c1ccc(-n2c4ccccc4c4c(C5CC6CCC5C6)cccc42)cc1N3c1cccc(Oc2ccccc2)c1] 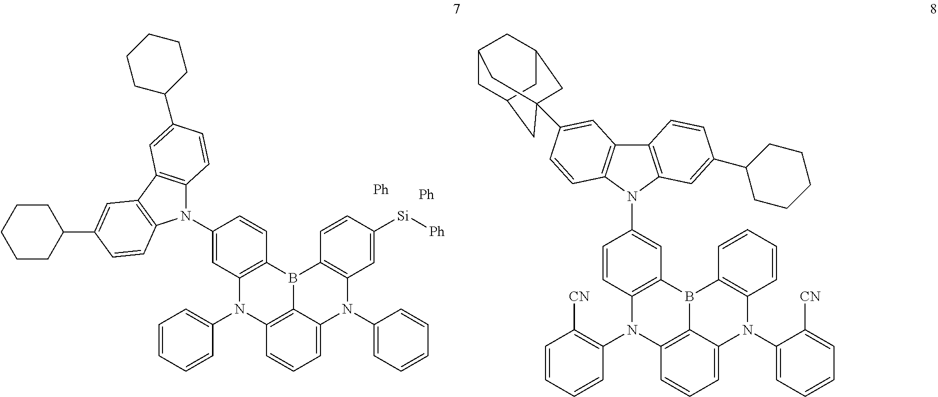 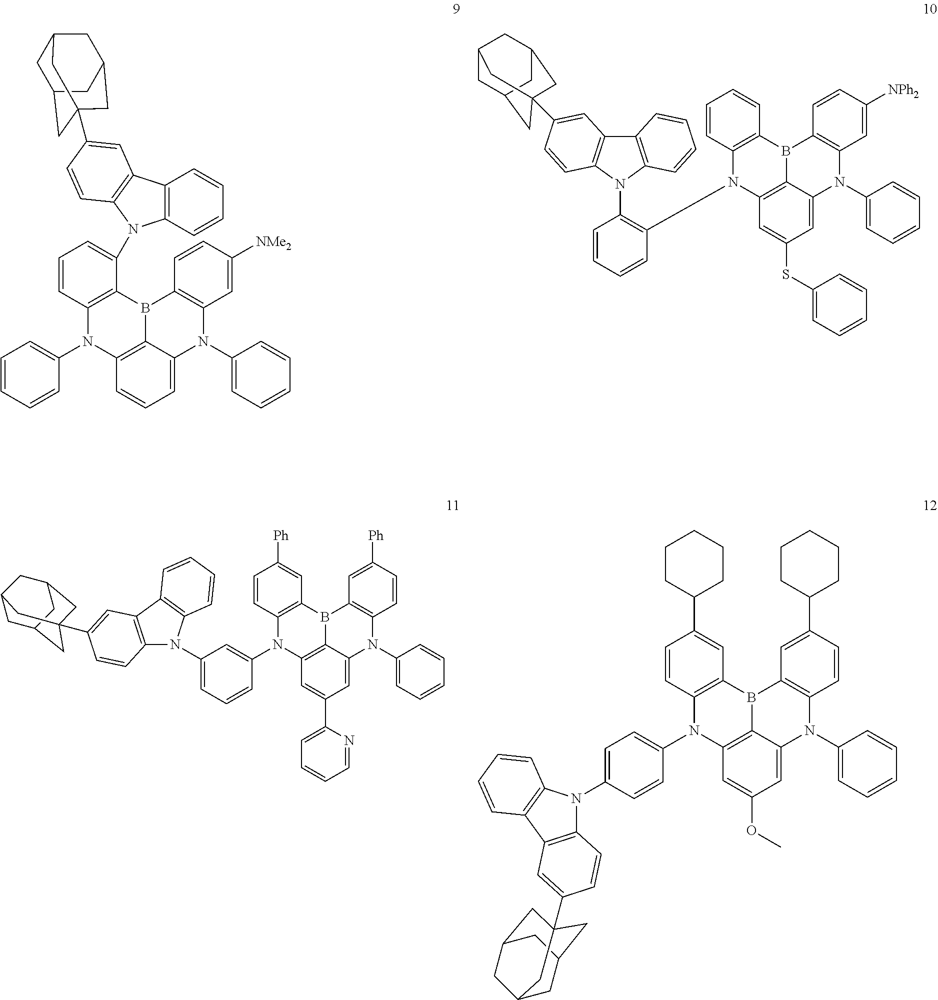 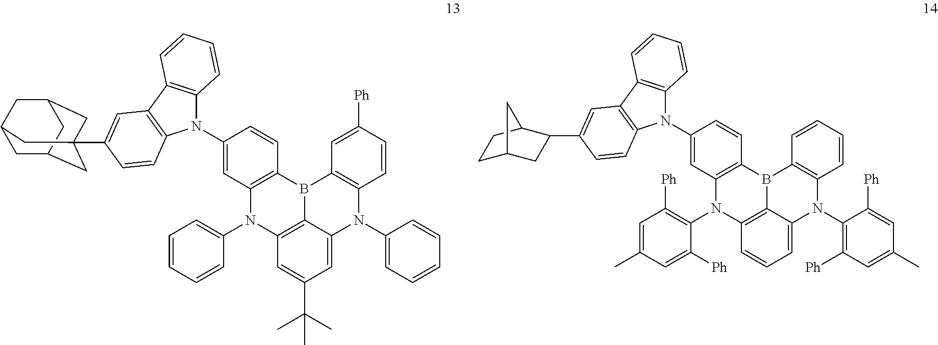 [SMILES: CC(C)(C)c1cc2c3c(c1)N(c1ccccc1)c1cc(-n4c5ccccc5c5cc(C67CC8CC(CC(C8)C6)C7)ccc54)ccc1B3c1cc(-c3ccccc3)ccc1N2c1ccccc1 ; Cc1cc(-c2ccccc2)c(N2c3ccccc3B3c4ccc(-n5c6ccccc6c6cc(C7CC8CCC7C8)ccc65)cc4N(c4c(-c5ccccc5)cc(C)cc4-c4ccccc4)c4cccc2c43)c(-c2ccccc2)c1] 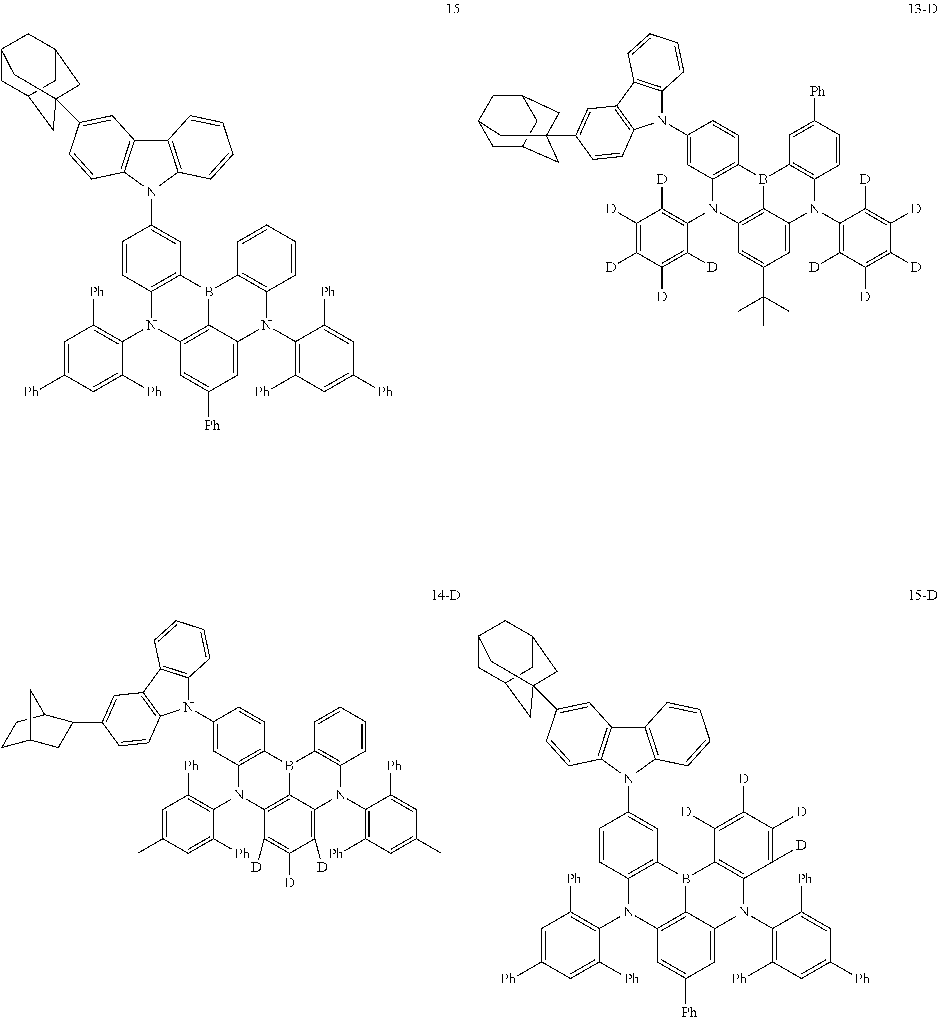 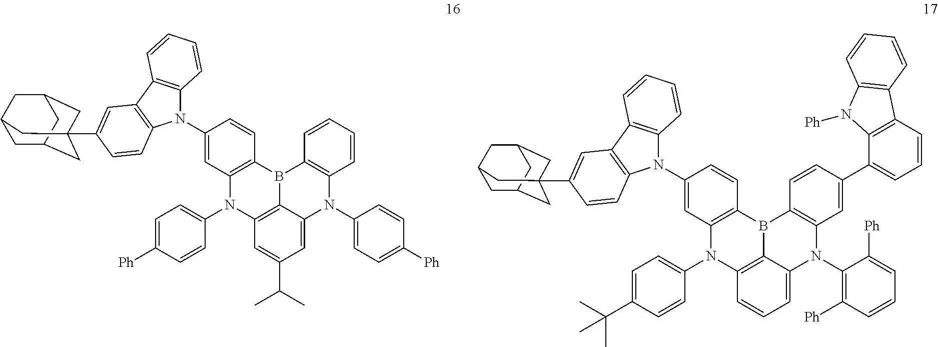 [SMILES: CC(C)c1cc2c3c(c1)N(c1ccc(-c4ccccc4)cc1)c1cc(-n4c5ccccc5c5cc(C67CC8CC(CC(C8)C6)C7)ccc54)ccc1B3c1ccccc1N2c1ccc(-c2ccccc2)cc1 ; CC(C)(C)c1ccc(N2c3cc(-n4c5ccccc5c5cc(C67CC8CC(CC(C8)C6)C7)ccc54)ccc3B3c4ccc(-c5cccc6c7ccccc7n(-c7ccccc7)c56)cc4N(c4c(-c5ccccc5)cccc4-c4ccccc4)c4cccc2c43)cc1] 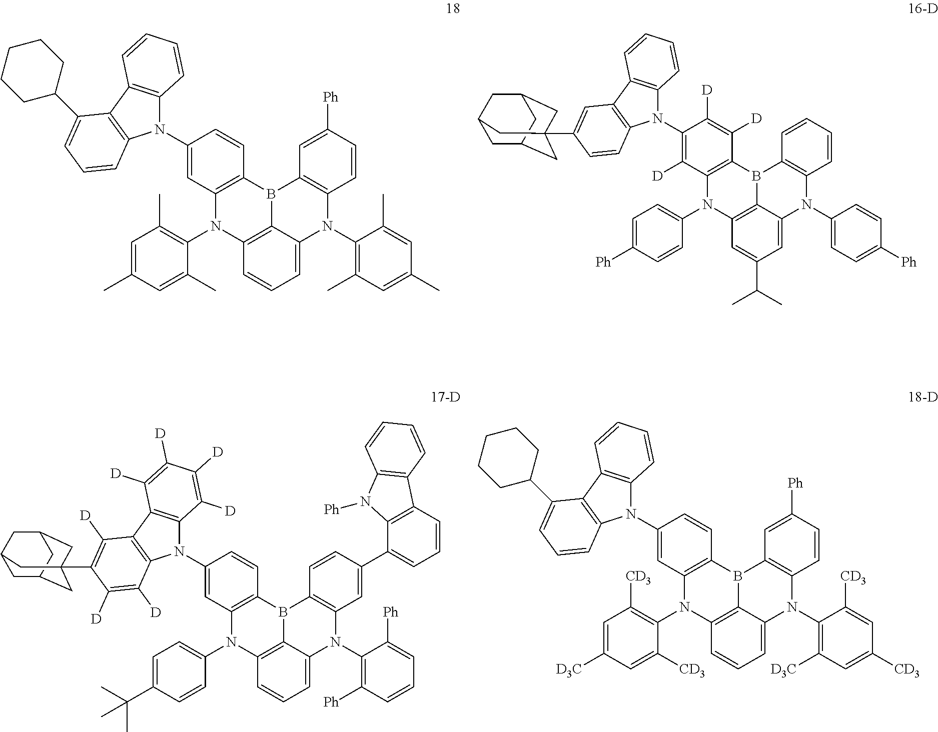 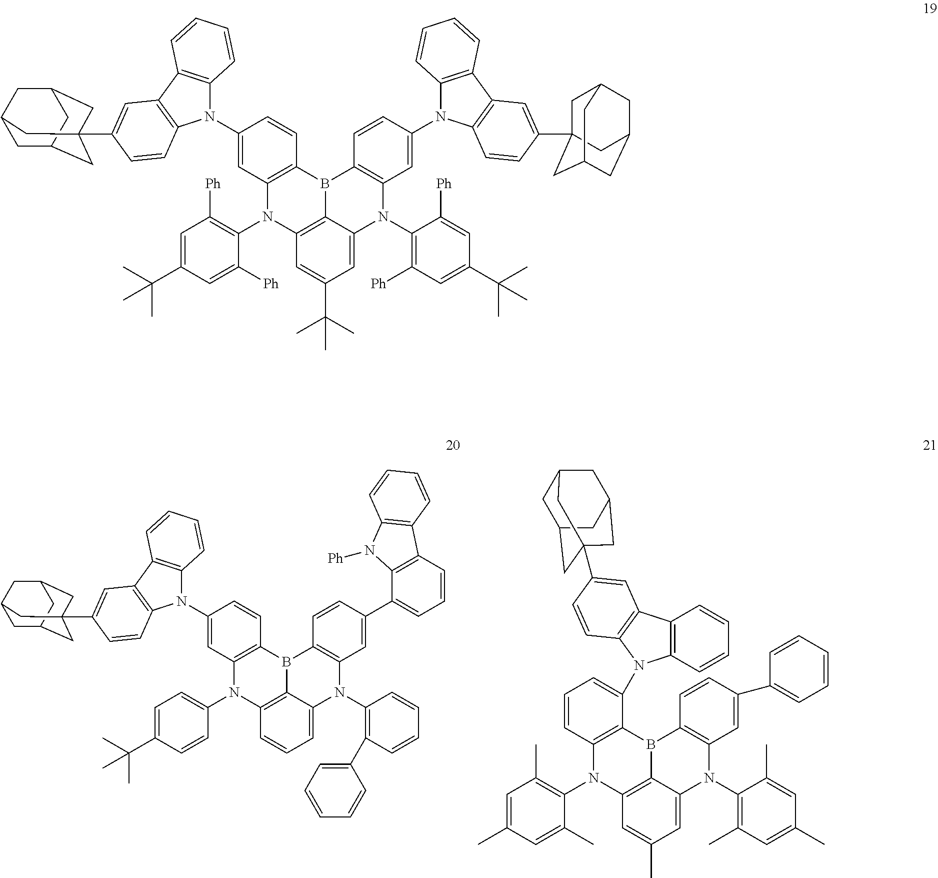 [SMILES: CC(C)(C)c1cc(-c2ccccc2)c(N2c3cc(-n4c5ccccc5c5cc(C67CC8CC(CC(C8)C6)C7)ccc54)ccc3B3c4ccc(-n5c6ccccc6c6cc(C78CC9CC(CC(C9)C7)C8)ccc65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1ccc(N2c3cc(-n4c5ccccc5c5cc(C67CC8CC(CC(C8)C6)C7)ccc54)ccc3B3c4ccc(-c5cccc6c7ccccc7n(-c7ccccc7)c56)cc4N(c4ccccc4-c4ccccc4)c4cccc2c43)cc1 ; Cc1cc(C)c(N2c3cc(-c4ccccc4)ccc3B3c4c2cc(C)cc4N(c2c(C)cc(C)cc2C)c2cccc(-n4c5ccccc5c5cc(C67CC8CC(CC(C8)C6)C7)ccc54)c23)c(C)c1] 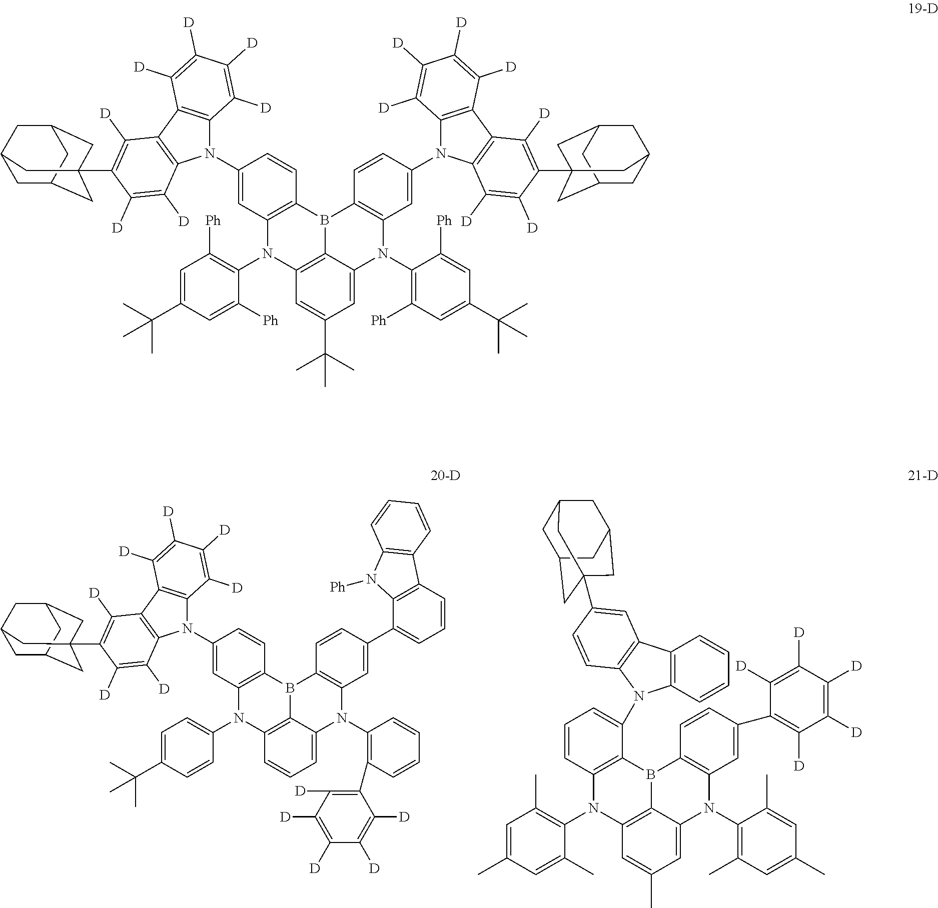 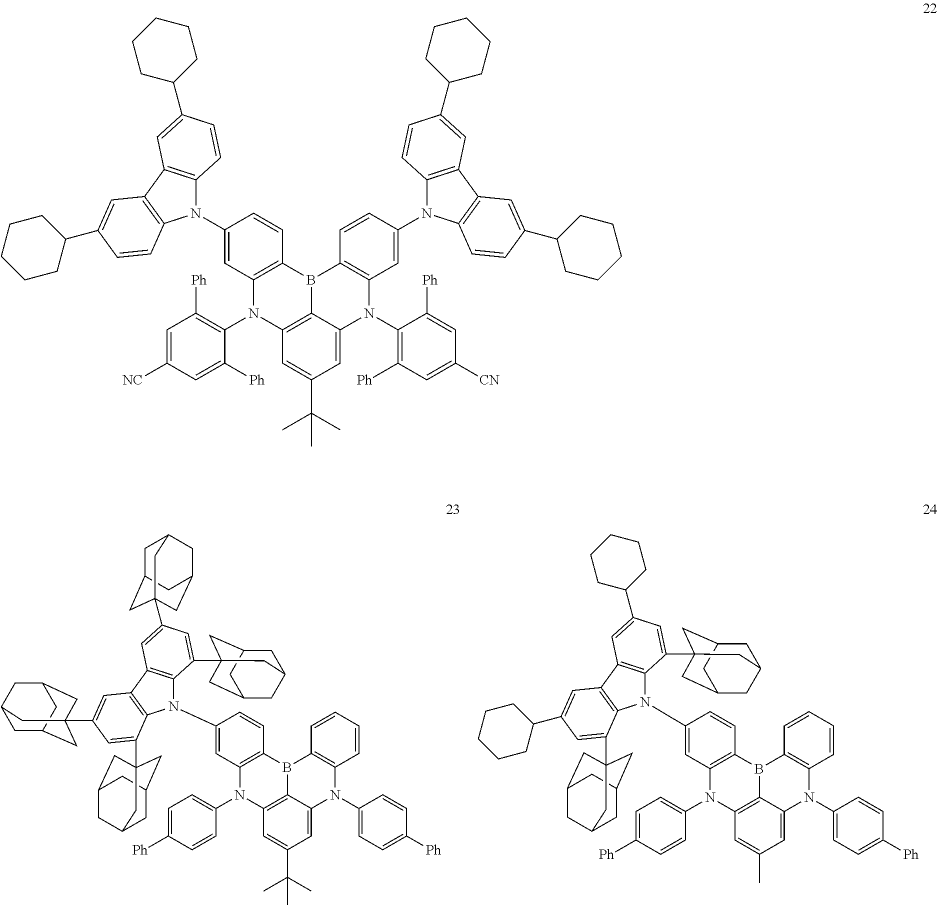 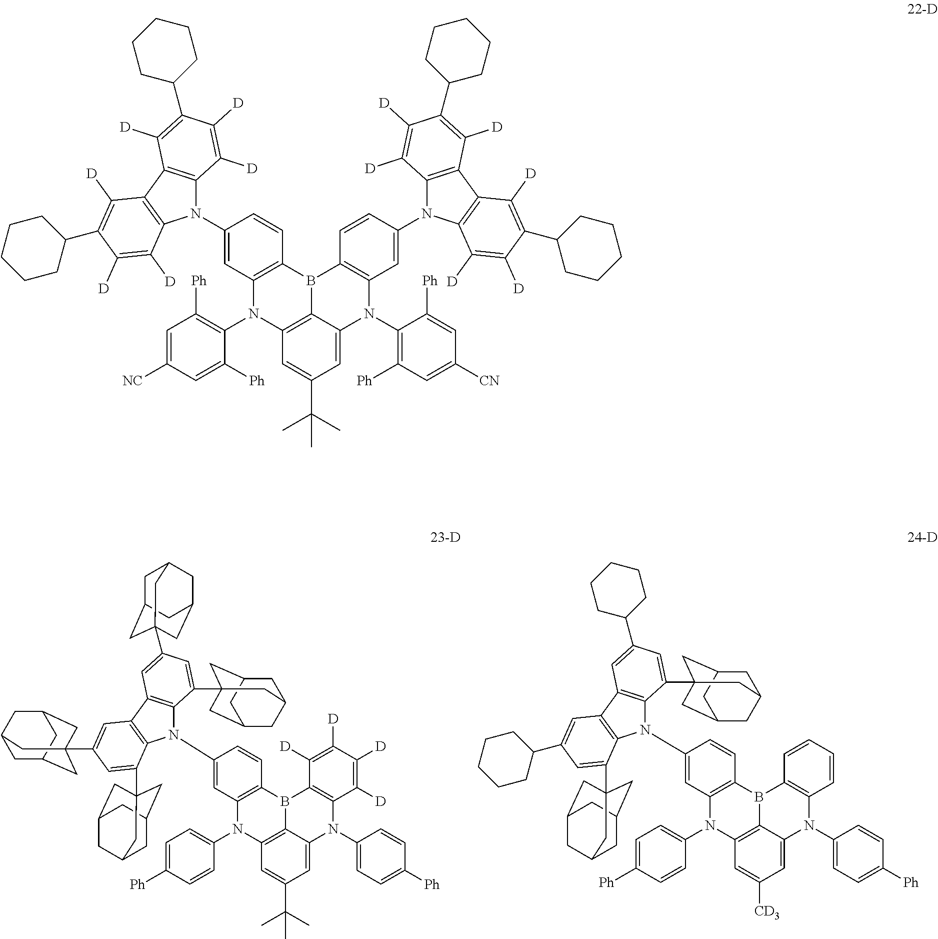 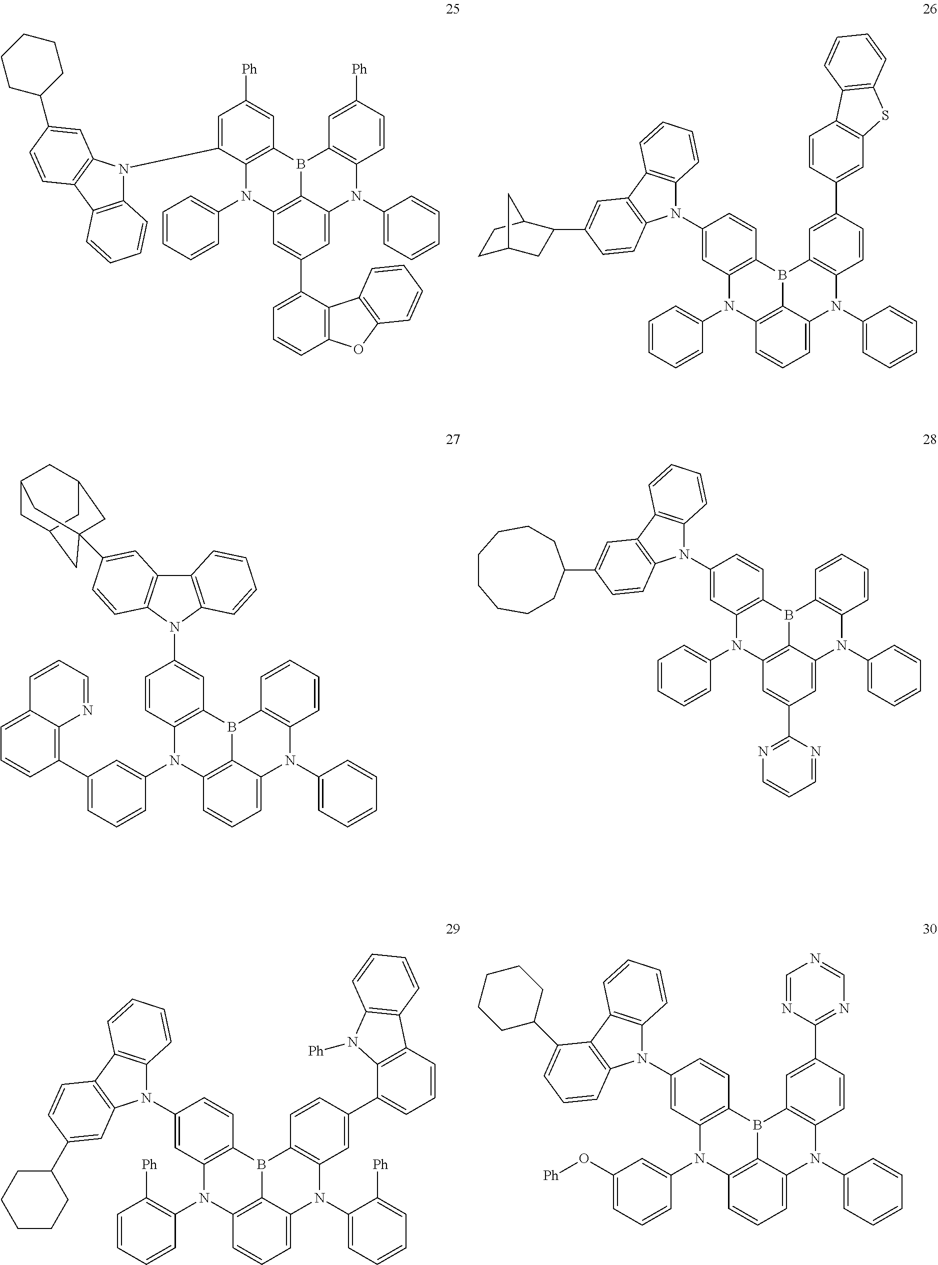 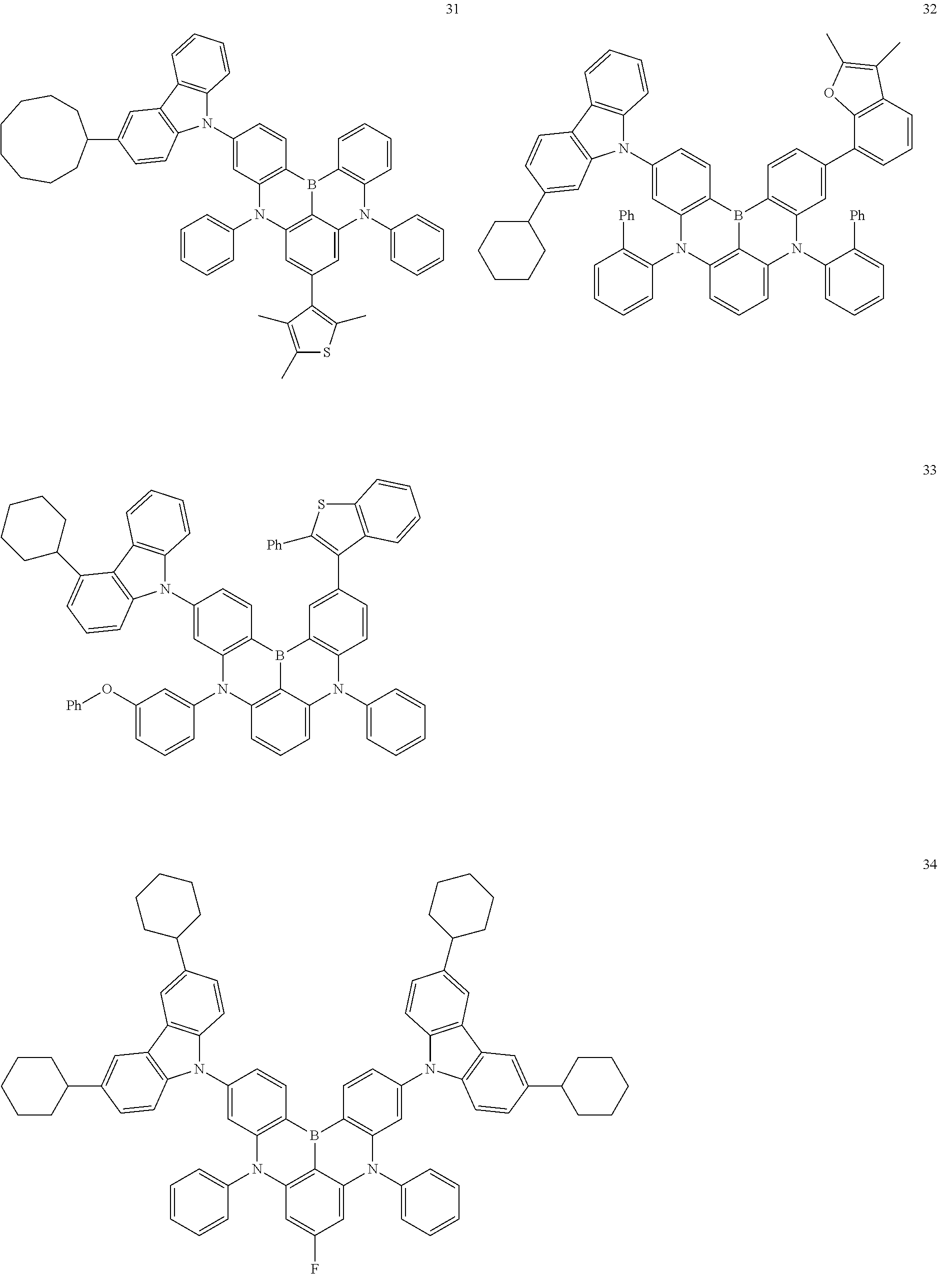 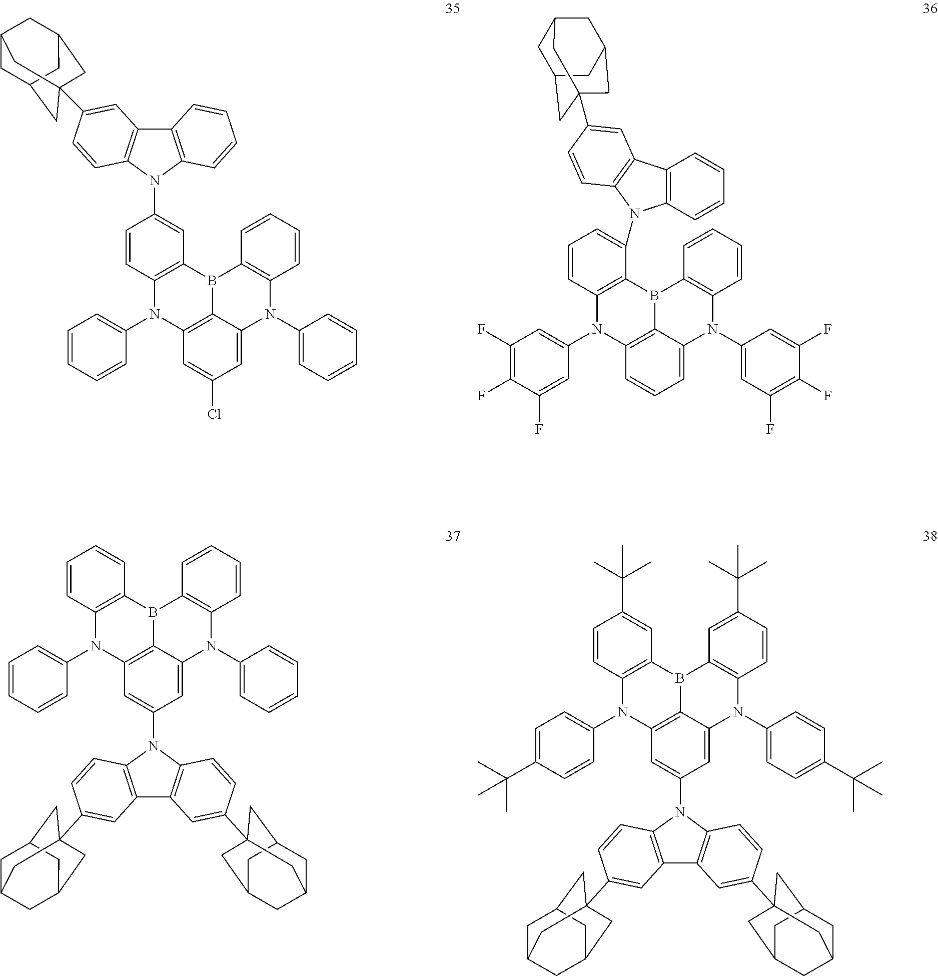 [SMILES: Clc1cc2c3c(c1)N(c1ccccc1)c1ccc(-n4c5ccccc5c5cc(C67CC8CC(CC(C8)C6)C7)ccc54)cc1B3c1ccccc1N2c1ccccc1 ; Fc1cc(N2c3ccccc3B3c4c2cccc4N(c2cc(F)c(F)c(F)c2)c2cccc(-n4c5ccccc5c5cc(C67CC8CC(CC(C8)C6)C7)ccc54)c23)cc(F)c1F ; c1ccc(N2c3ccccc3B3c4ccccc4N(c4ccccc4)c4cc(-n5c6ccc(C78CC9CC(CC(C9)C7)C8)cc6c6cc(C78CC9CC(CC(C9)C7)C8)ccc65)cc2c43)cc1 ; CC(C)(C)c1ccc(N2c3ccc(C(C)(C)C)cc3B3c4cc(C(C)(C)C)ccc4N(c4ccc(C(C)(C)C)cc4)c4cc(-n5c6ccc(C78CC9CC(CC(C9)C7)C8)cc6c6cc(C78CC9CC(CC(C9)C7)C8)ccc65)cc2c43)cc1] 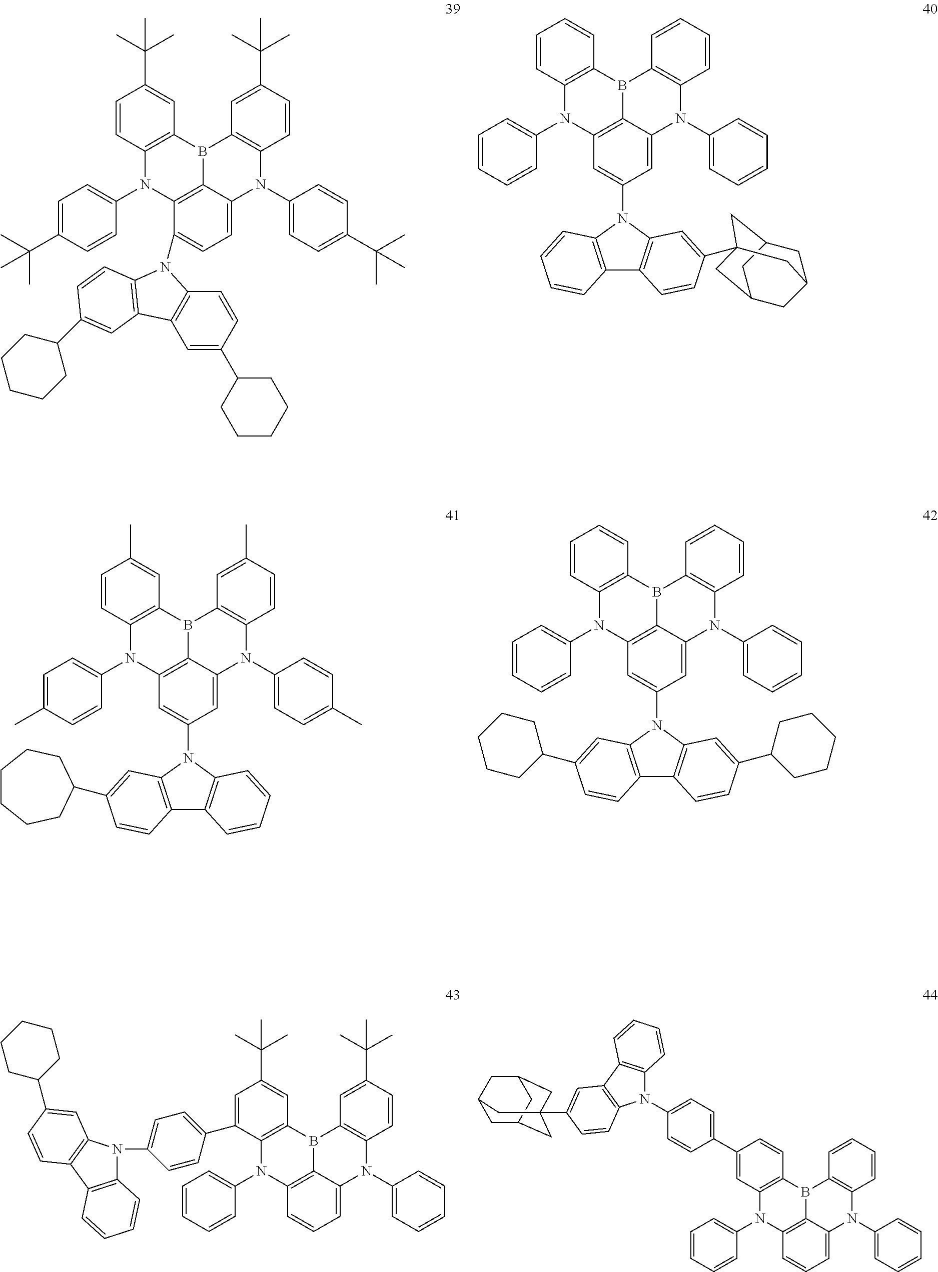 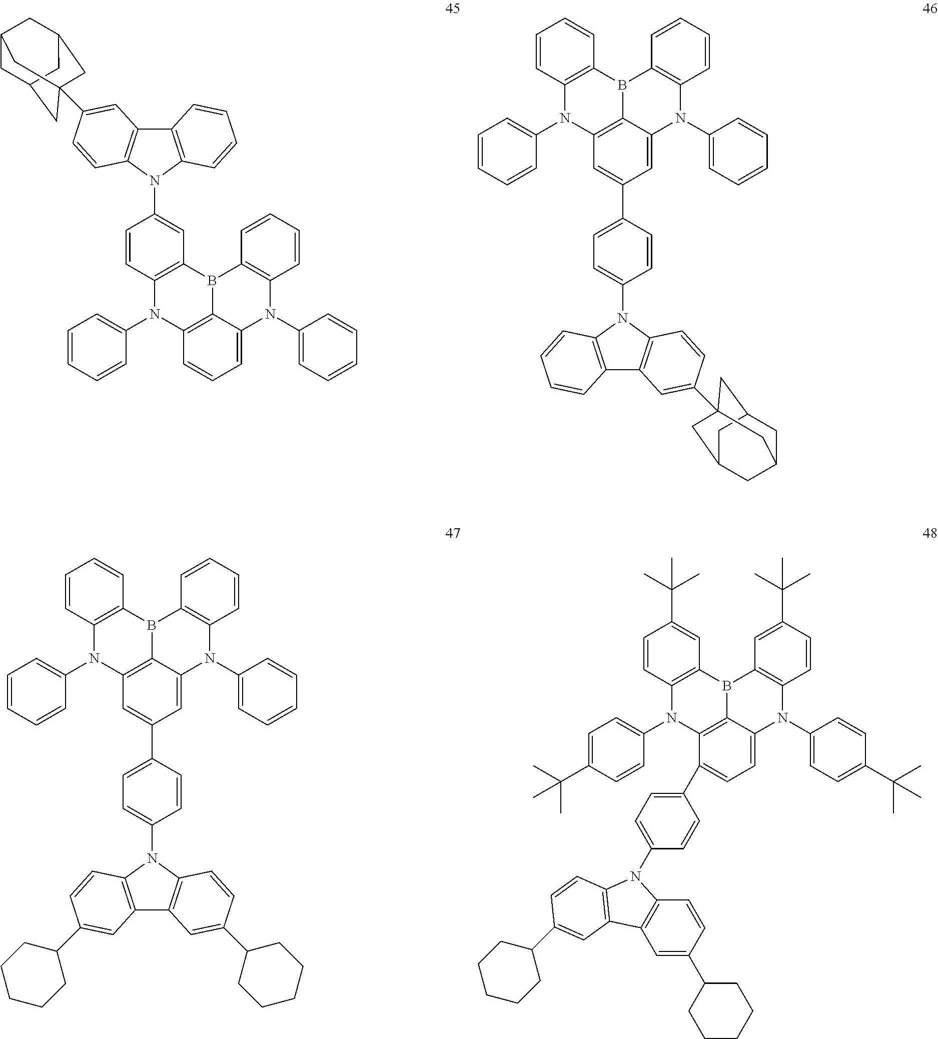 [SMILES: c1ccc(N2c3ccccc3B3c4cc(-n5c6ccccc6c6cc(C78CC9CC(CC(C9)C7)C8)ccc65)ccc4N(c4ccccc4)c4cccc2c43)cc1 ; c1ccc(N2c3ccccc3B3c4ccccc4N(c4ccccc4)c4cc(-c5ccc(-n6c7ccccc7c7cc(C89CC%10CC(CC(C%10)C8)C9)ccc76)cc5)cc2c43)cc1 ; c1ccc(N2c3ccccc3B3c4ccccc4N(c4ccccc4)c4cc(-c5ccc(-n6c7ccc(C8CCCCC8)cc7c7cc(C8CCCCC8)ccc76)cc5)cc2c43)cc1 ; CC(C)(C)c1ccc(N2c3ccc(C(C)(C)C)cc3B3c4cc(C(C)(C)C)ccc4N(c4ccc(C(C)(C)C)cc4)c4c(-c5ccc(-n6c7ccc(C8CCCCC8)cc7c7cc(C8CCCCC8)ccc76)cc5)ccc2c43)cc1] 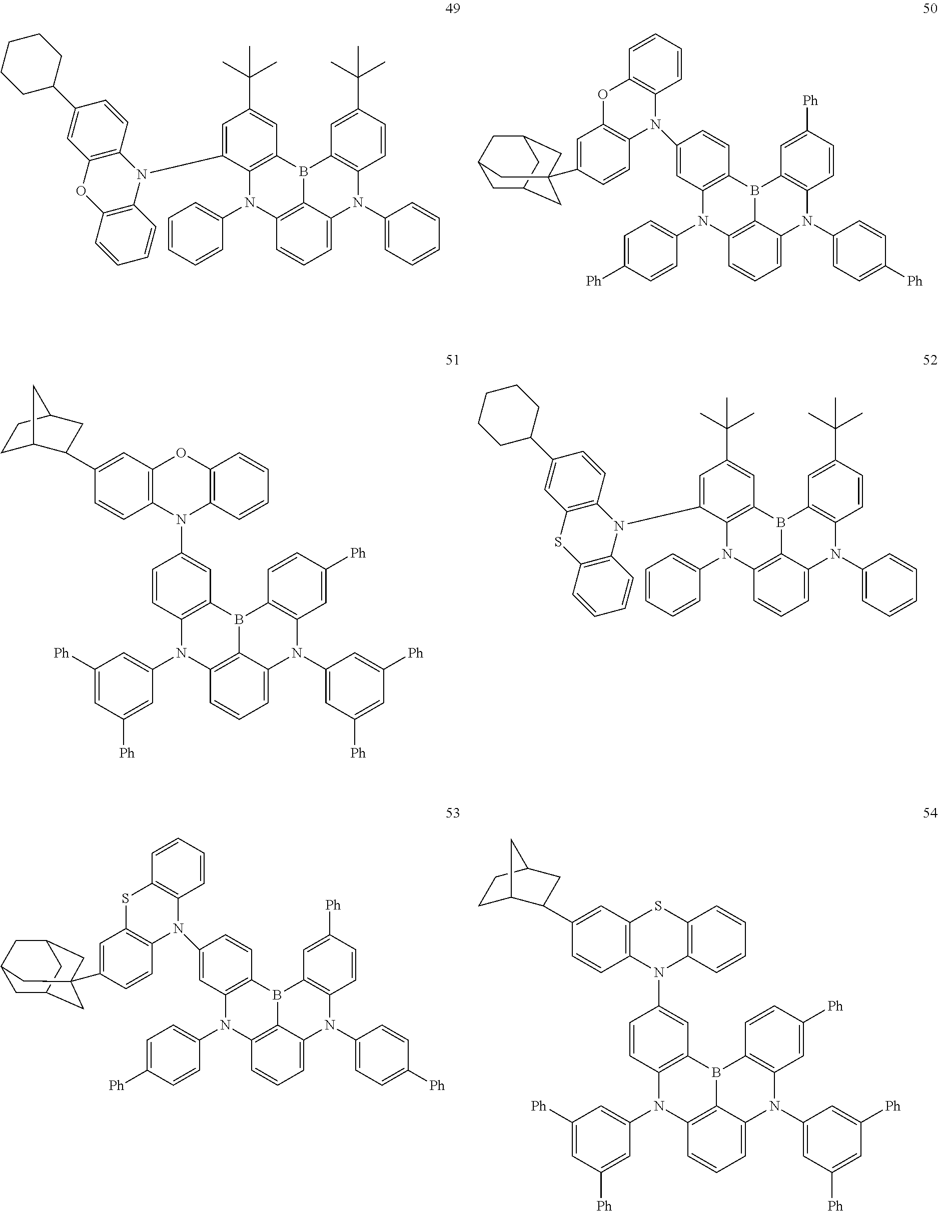 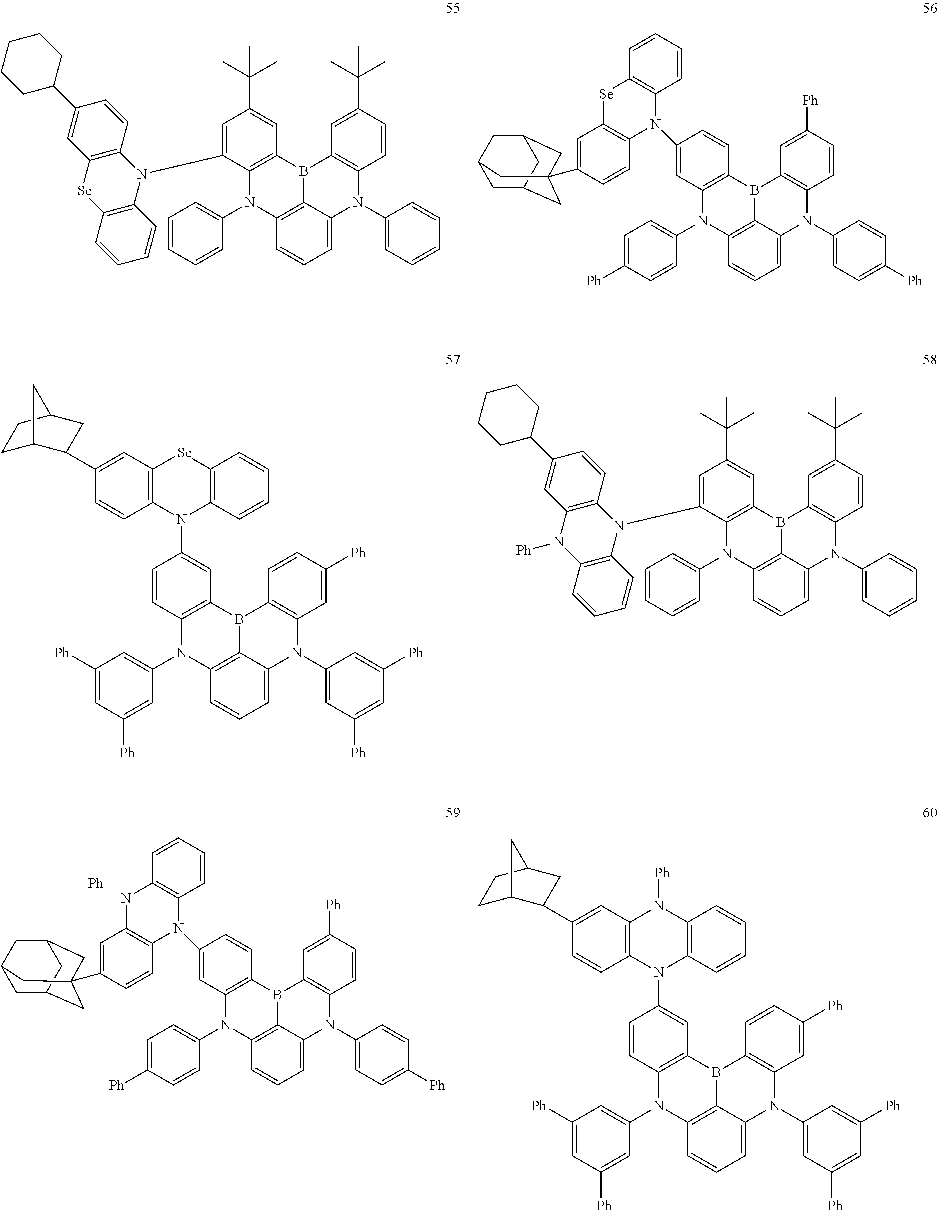 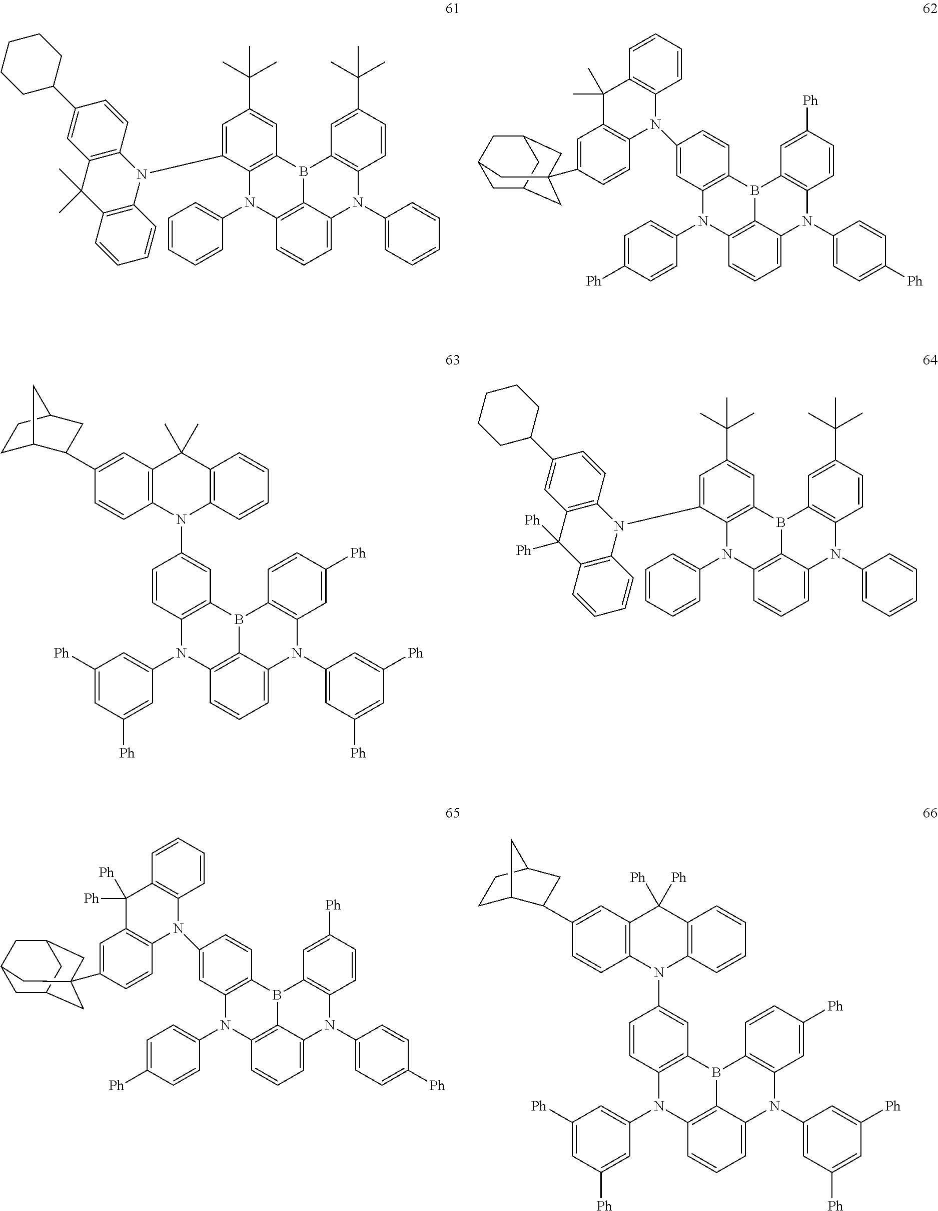 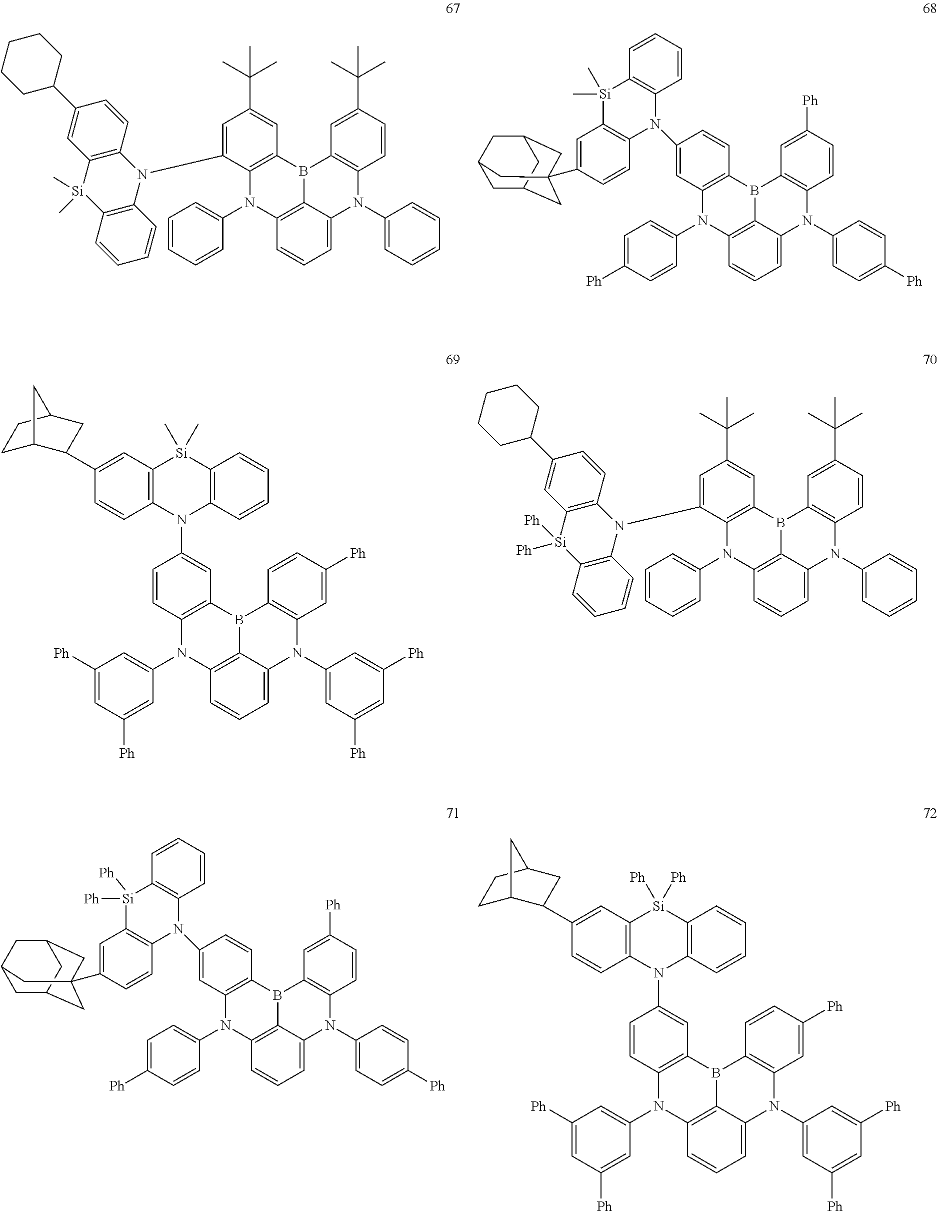 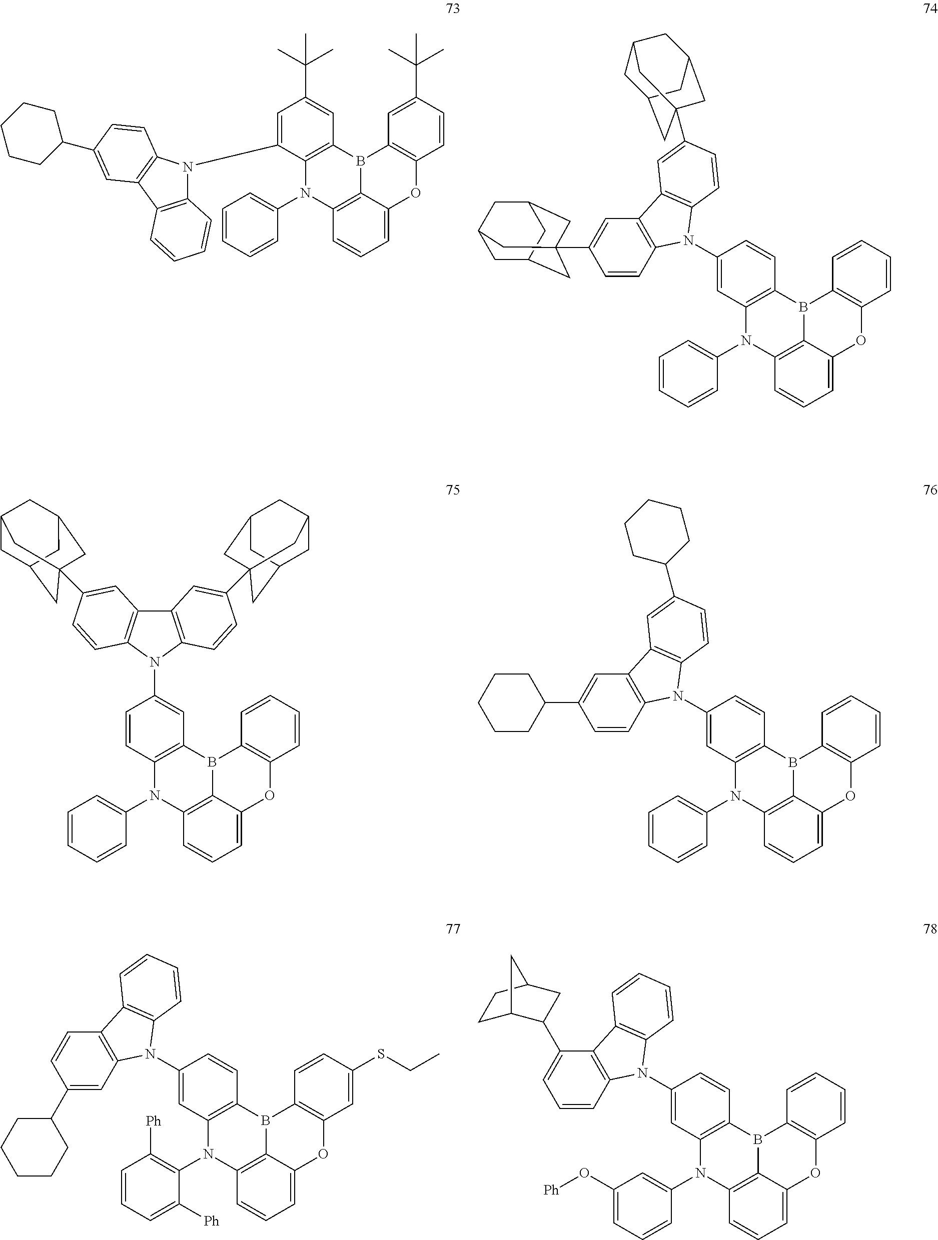 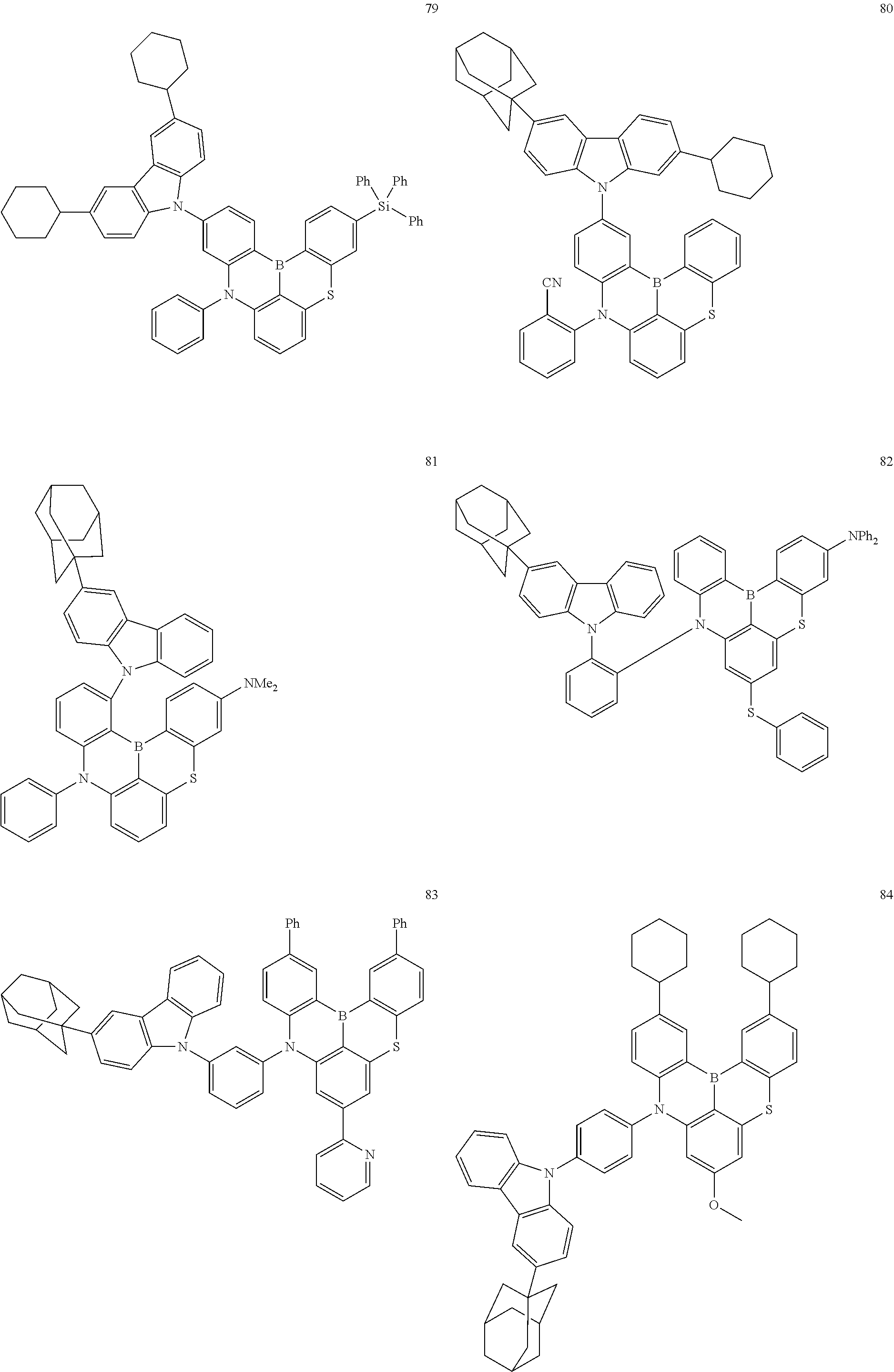 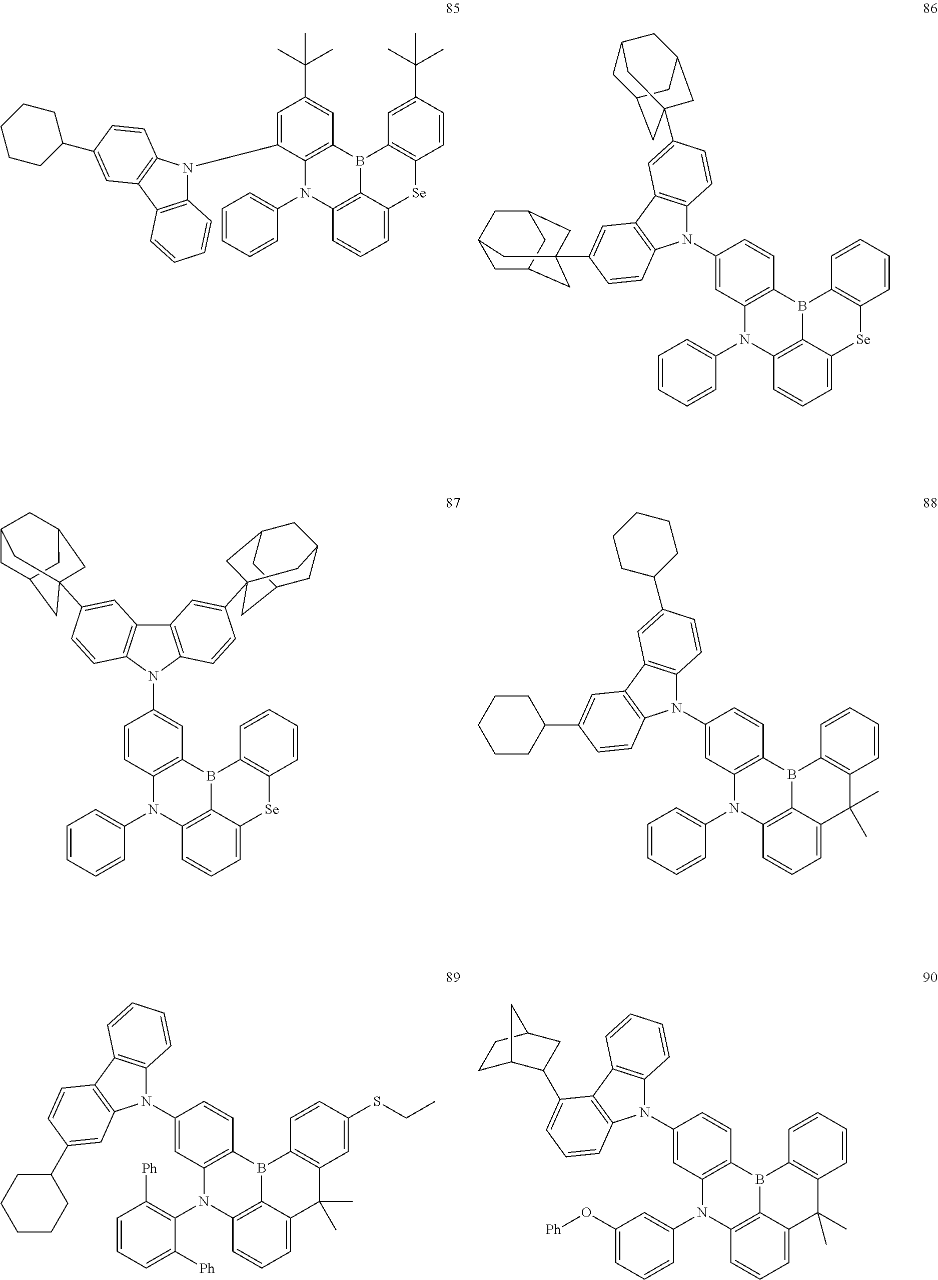 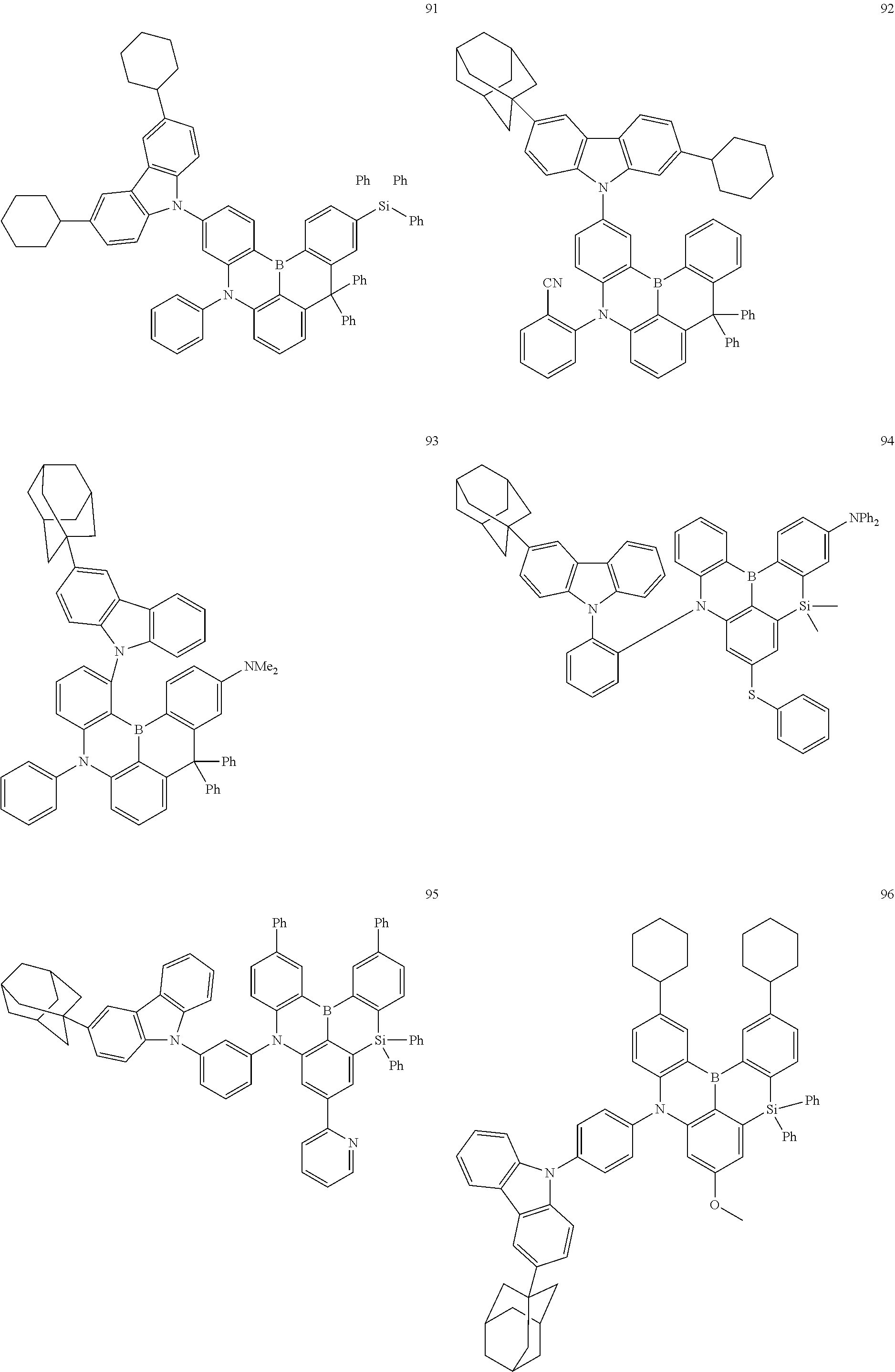 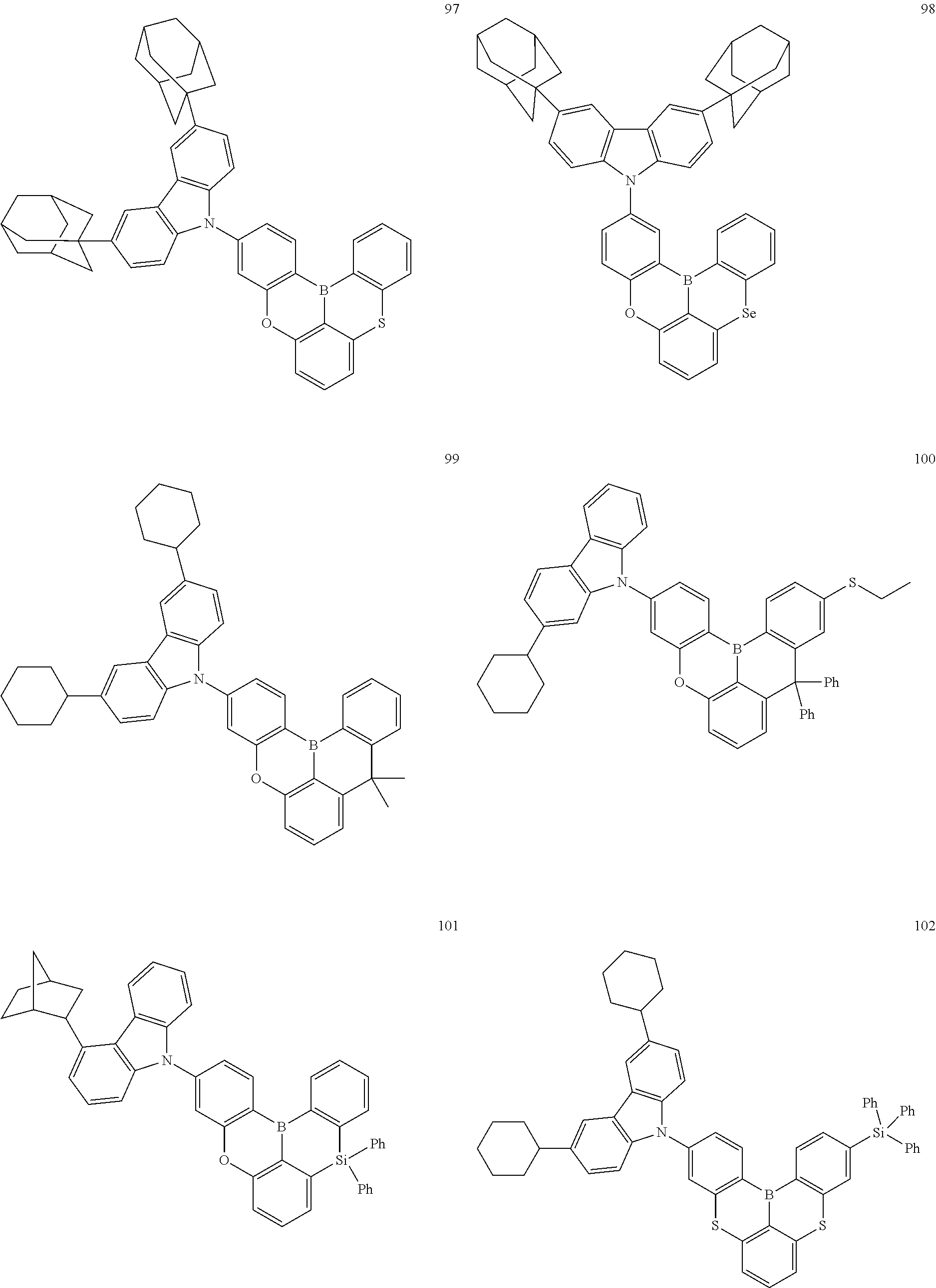 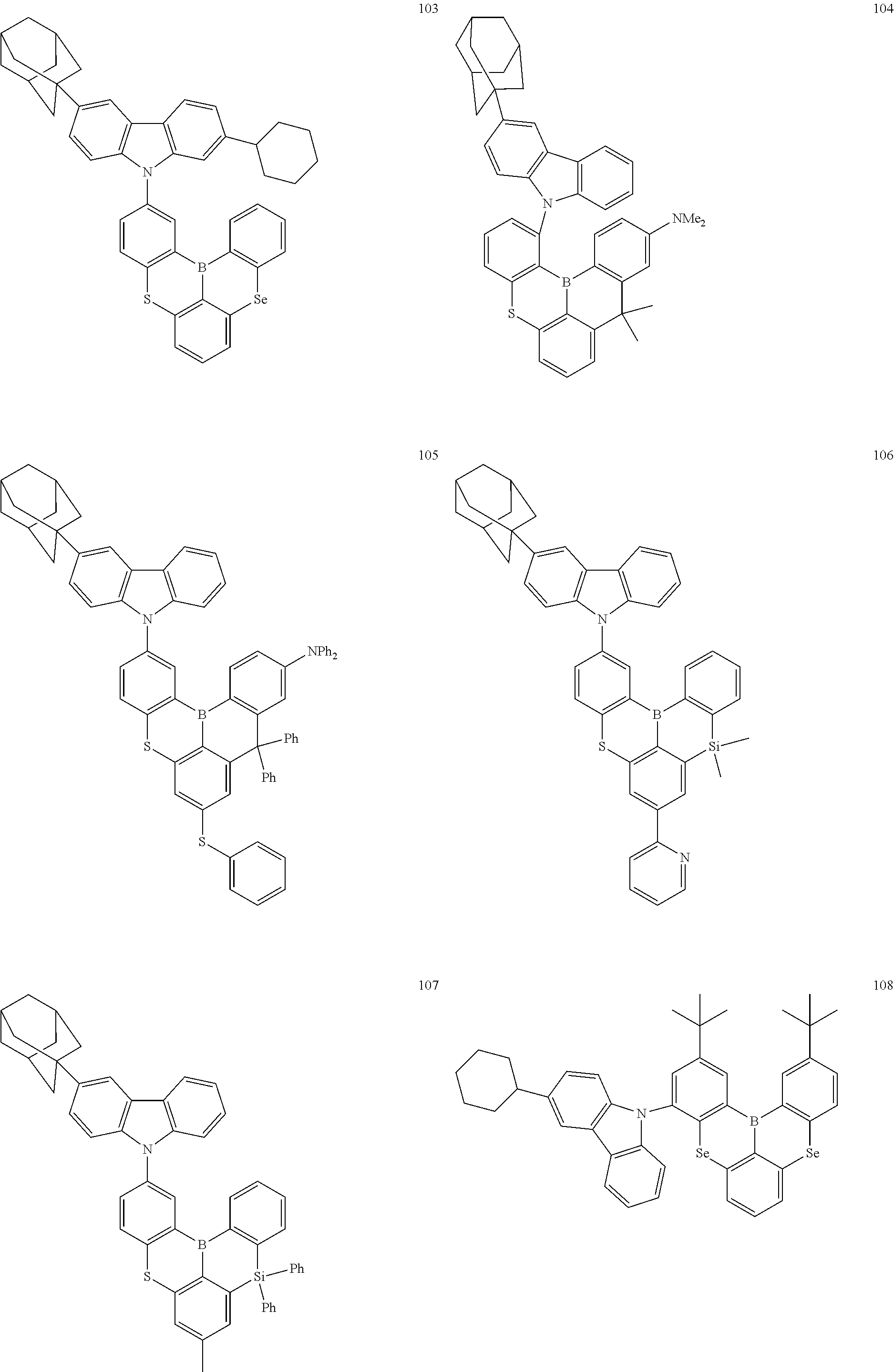 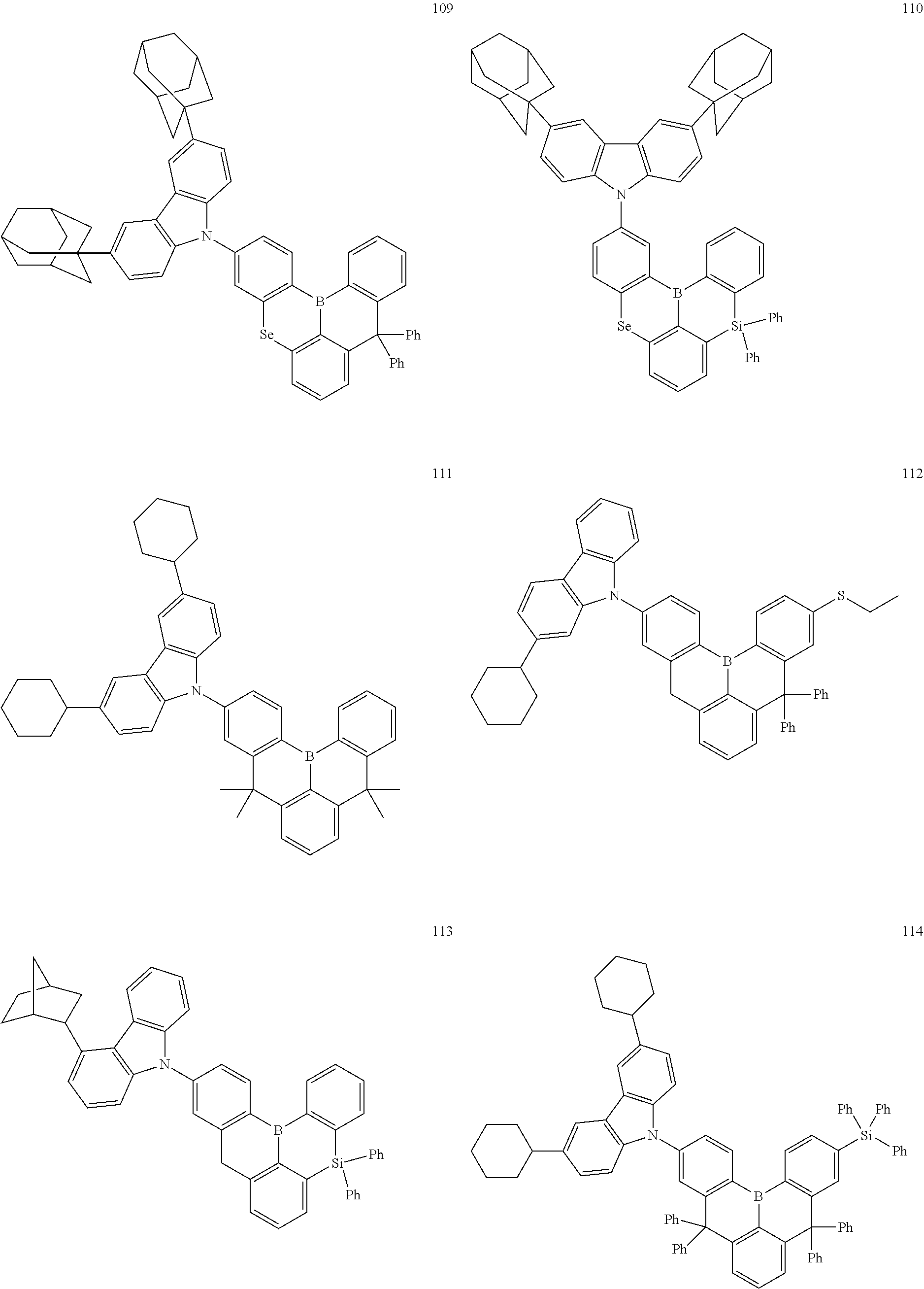 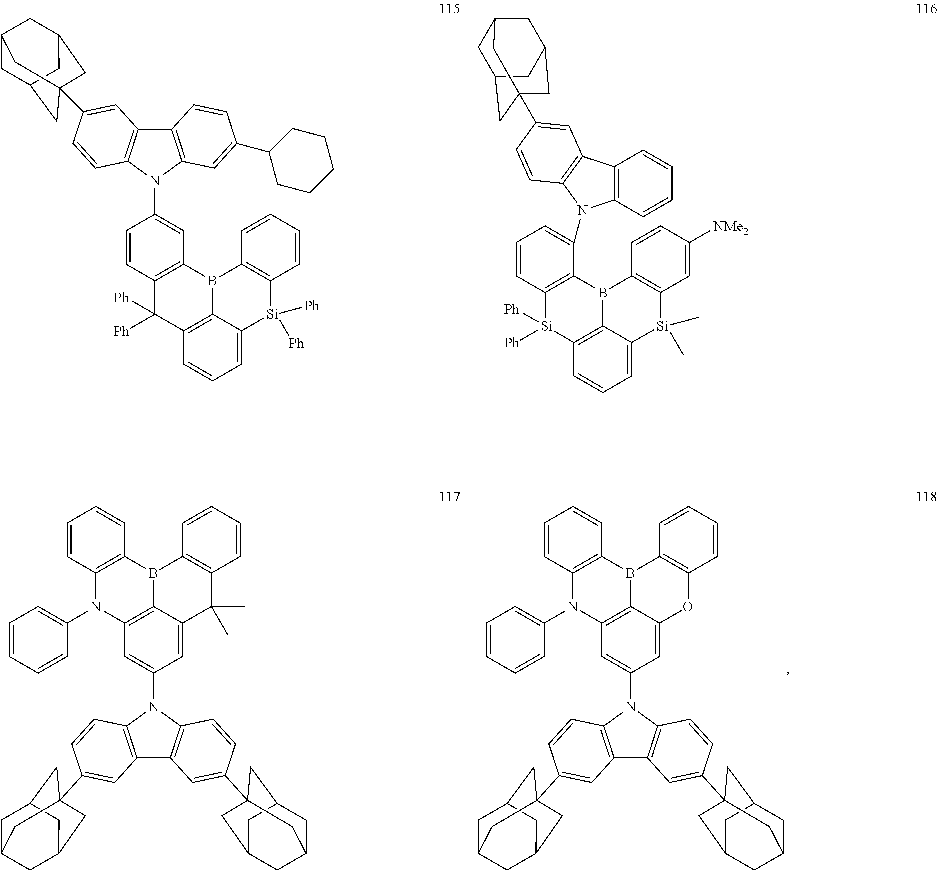 [SMILES: c1ccc(C2(c3ccccc3)c3ccc(-n4c5ccc(C67CC8CC(CC(C8)C6)C7)cc5c5ccc(C6CCCCC6)cc54)cc3B3c4ccccc4[Si](c4ccccc4)(c4ccccc4)c4cccc2c43)cc1 ; CN(C)c1ccc2c(c1)[Si](C)(C)c1cccc3c1B2c1c(-n2c4ccccc4c4cc(C56CC7CC(CC(C7)C5)C6)ccc42)cccc1[Si]3(c1ccccc1)c1ccccc1 ; CC1(C)c2ccccc2B2c3ccccc3N(c3ccccc3)c3cc(-n4c5ccc(C67CC8CC(CC(C8)C6)C7)cc5c5cc(C67CC8CC(CC(C8)C6)C7)ccc54)cc1c32 ; c1ccc(N2c3ccccc3B3c4ccccc4Oc4cc(-n5c6ccc(C78CC9CC(CC(C9)C7)C8)cc6c6cc(C78CC9CC(CC(C9)C7)C8)ccc65)cc2c43)cc1]
and
wherein in Compound Group 1, “D” is deuterium, “Ph” is an unsubstituted phenyl group, and “Me” is an unsubstituted methyl group.

8. The light emitting element of claim 1, wherein the at least one functional layer further comprises at least one selected from among a second compound represented by Formula HT and a third compound represented by Formula ET: 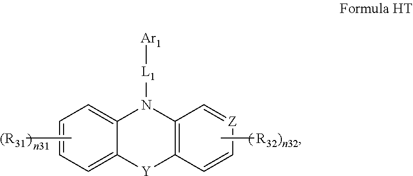
wherein in Formula HT,
L₁ is a direct linkage, a substituted or unsubstituted arylene group having 6 to 30 ring-forming carbon atoms, or a substituted or unsubstituted heteroarylene group having 2 to 30 ring-forming carbon atoms,
Ar₁ is a substituted or unsubstituted aryl group having 6 to 30 ring-forming carbon atoms, or a substituted or unsubstituted heteroaryl group having 2 to 30 ring-forming carbon atoms,
Y is a direct linkage, CR_{y1}R_{y2}, or SiR_{y3}R_{y4},
Z is CR_{z} or N,
R_{y1} to R_{y4}, R₃₁, R₃₂, and R_{z} are each independently hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring, and
n31 is an integer of 0 to 4, and n32 is an integer of 0 to 3, and 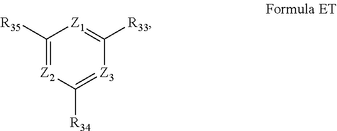
and
wherein in Formula ET,
Z₁ to Z₃ are each independently N or CR₃₆, and at least one selected from among Z₁ to Z₃ is N, and
R₃₃ to R₃₆ are each independently hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring.

9. The light emitting element of claim 8, wherein the at least one functional layer comprises the first compound, the second compound, and the third compound.

10. The light emitting element of claim 8, wherein the at least one functional layer comprises an emission layer, a hole transport region between the first electrode and the emission layer, and an electron transport region between the emission layer and the second electrode,
the emission layer comprising:
the first compound; and
at least one selected from among the second compound and the third compound.

11. The light emitting element of claim 10, wherein the emission layer is to emit delayed fluorescence.

12. The light emitting element of claim 10, wherein the emission layer is to emit blue light.

13. The light emitting element of claim 8, wherein the at least one functional layer further comprises a fourth compound represented by Formula PS: 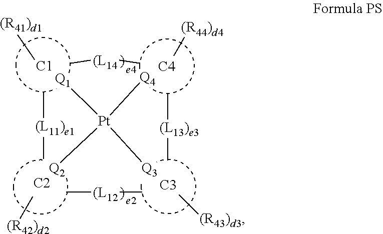
and
wherein in Formula PS,
Q₁ to Q₄ are each independently C or N,
C1 to C4 are each independently a substituted or unsubstituted hydrocarbon ring having 5 to 30 ring-forming carbon atoms, or a substituted or unsubstituted heterocycle having 2 to 30 ring-forming carbon atoms,
L₁₁ to L₁₄ are each independently a direct linkage, 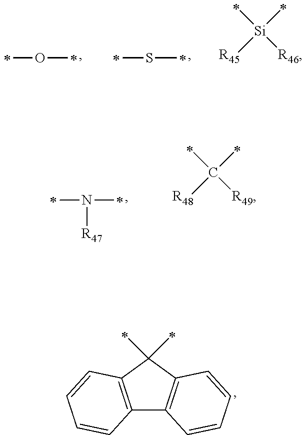
a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, and in L₁₁ to L₁₄, “-*” is a site linked to C1 to C4,
e1 to e4 are each independently 0 or 1,
R₄₁ to R₄₉ are each independently hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring, and
d1 to d4 are each independently an integer of 0 to 4.

14. The light emitting element of claim 13, wherein the at least one functional layer comprises the first compound, the second compound, the third compound, and the fourth compound.

15. A light emitting element comprising:
a first electrode;
a second electrode facing the first electrode; and
an emission layer between the first electrode and the second electrode,
wherein the emission layer comprises a polycyclic compound represented by Formula 1: 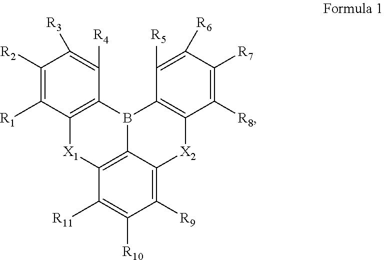
and
wherein in Formula 1,
X₁ and X₂ are each independently O, S, Se, CRₐR_{b}, SiRcRa, or NR₁₂, and X₁ and X₂ are not both O,
at least one selected from among R₁ to R₁₂ is an N-containing tricyclic heteroaryl group, and the remainder are each independently hydrogen, deuterium, a halogen, a cyano group, a substituted or unsubstituted oxy group, a substituted or unsubstituted thio group, a substituted or unsubstituted silyl group, a substituted or unsubstituted amine group, a substituted or unsubstituted alkyl group having 1 to 30 carbon atoms, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 2 to 30 ring-forming carbon atoms,
the N-containing tricyclic heteroaryl group is substituted with at least one substituted or unsubstituted cycloalkyl group having 5 to 30 ring-forming carbon atoms,
when the at least one substituted or unsubstituted cycloalkyl group having 5 to 30 ring-forming carbon atoms is a crosslinked cycloalkyl group, each of a plurality of rings in the crosslinked cycloalkyl group has 5 to 30 ring-forming carbon atoms,
Rₐ to Rₐ are each independently hydrogen, a substituted or unsubstituted alkyl group having 1 to 30 carbon atoms, or a substituted or unsubstituted aryl group having 6 to 30 ring-forming carbon atoms, and
Formula 1 comprises a structure in which one or more hydrogens are substituted with deuterium.

16. The light emitting element of claim 15, wherein the at least one substituted or unsubstituted cycloalkyl group having 5 to 30 ring-forming carbon atoms is represented by any one selected from among Formulas A1 to A5:

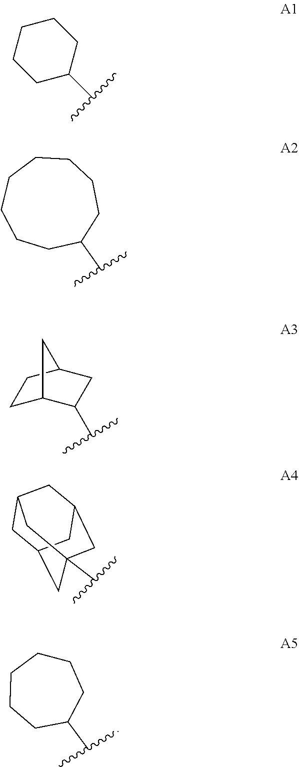 [SMILES: *C1CCCCC1 ; *C1CCCCCCCC1 ; *C1CC2CCC1C2 ; *C12CC3CC(CC(C3)C1)C2 ; *C1CCCCCC1]

17. A polycyclic compound represented by Formula 1: 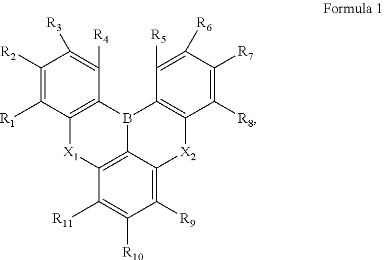
wherein in Formula 1,
X₁ and X₂ are each independently O, S, Se, CRₐR_{b}, SiR_{c}R_{d}, or NR₁₂, and X₁ and X₂ are not both O,
Rₐ to R_{d} are each independently hydrogen, a substituted or unsubstituted alkyl group having 1 to 30 carbon atoms, or a substituted or unsubstituted aryl group having 6 to 30 ring-forming carbon atoms, and
at least one selected from among R₁ to R₁₂ is represented by Formula 2, and the remainder are each independently hydrogen, deuterium, a halogen, a cyano group, a substituted or unsubstituted oxy group, a substituted or unsubstituted thio group, a substituted or unsubstituted silyl group, a substituted or unsubstituted amine group, a substituted or unsubstituted alkyl group having 1 to 30 carbon atoms, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 2 to 30 ring-forming carbon atoms, 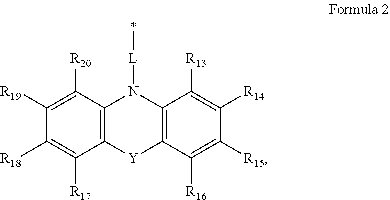
and
wherein in Formula 2,
L is a direct linkage or a substituted or unsubstituted arylene group having 6 to 30 ring-forming carbon atoms,
Y is a direct linkage, O, S, Se, CRₑR_{f}, SiR_{g}Rₙ, or NRᵢ,
Rₑ to Rᵢ are each independently a substituted or unsubstituted alkyl group having 1 to 30 carbon atoms, or a substituted or unsubstituted aryl group having 6 to 30 ring-forming carbon atoms,
at least one selected from among R₁₄ to R₁₉ is a substituted or unsubstituted cycloalkyl group having 5 to 30 ring-forming carbon atoms, and the remainder are each independently hydrogen or deuterium,
when R₁₄ to R₁₉ are a crosslinked cycloalkyl group, each of a plurality of rings in the crosslinked cycloalkyl group has 5 to 10 ring-forming carbon atoms,
R₁₃ and R₂₀ are each independently hydrogen, deuterium, or a substituted or unsubstituted cycloalkyl group having 3 to 30 ring-forming carbon atoms, and
Formula 1 comprises a structure in which one or more hydrogens are substituted with deuterium.

18. The polycyclic compound of claim 17, wherein Formula 2 is represented by Formula 2-1a or Formula 2-1b: 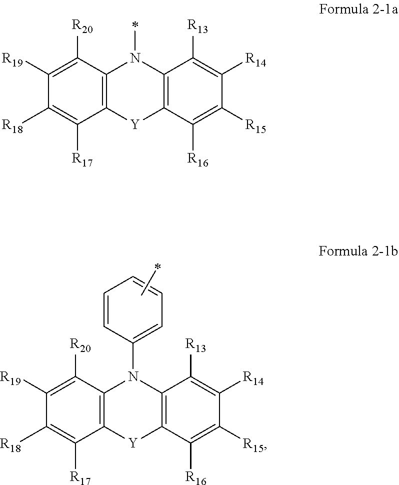
and
wherein in Formulas 2-1a and 2-1b,
Y, and R₁₃ to R₂₀ are each independently the same as defined in Formula 2.

19. The polycyclic compound of claim 17, wherein Formula 2 is represented by any one selected from among Formulas 2-2a to 2-2g: 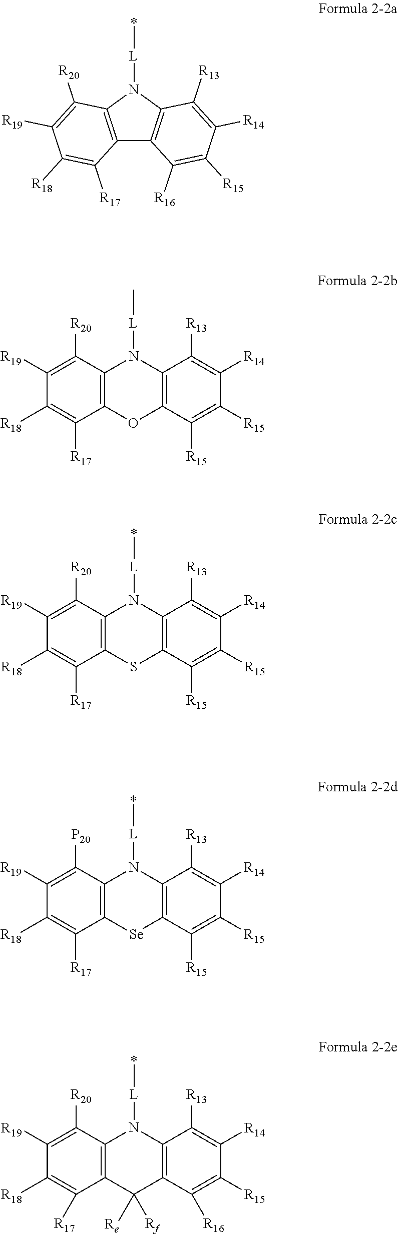 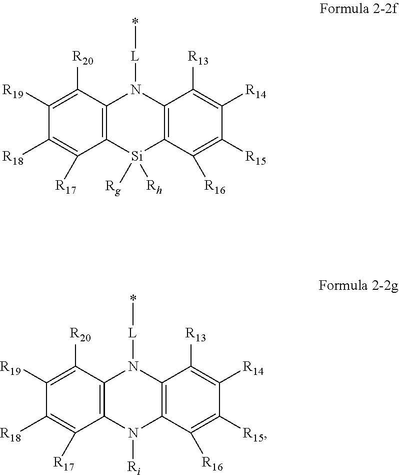
and
wherein in Formulas 2-2a to 2-2g,
Rₑ to Rᵢ are each independently an unsubstituted methyl group or an unsubstituted phenyl group, and
L, and R₁₃ to R₂₀ are each independently the same as defined in Formula 2.

20. The polycyclic compound of claim 17, wherein Formula 2 is represented by any one selected from among Formulas 2-3a to 2-3e: 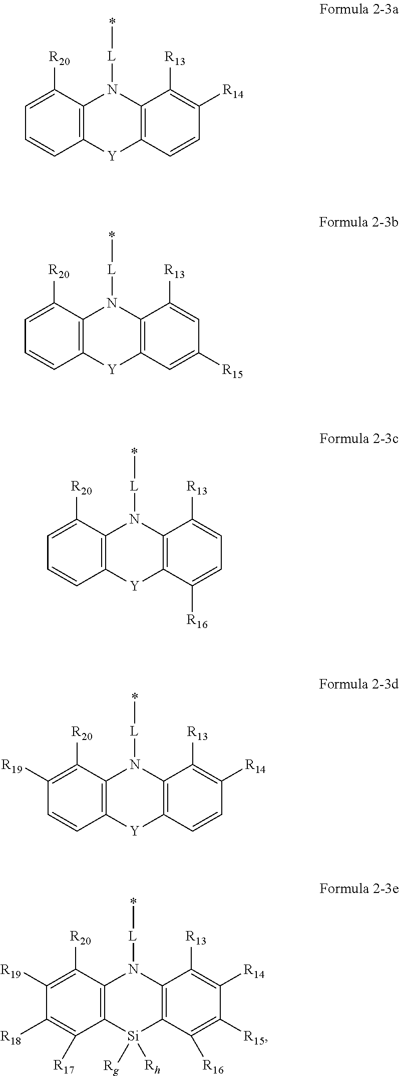
and
wherein in Formulas 2-3a to 2-3e,
R₁₄, R₁₅, R₁₆, R₁₈, and R₁₉ are each independently a substituted or unsubstituted cycloalkyl group having 5 to 30 ring-forming carbon atoms,
L, Y, R₁₃, and R₂₀ are each independently the same as defined in Formula 2, and
Formulas 2-3a to 2-3e each comprise a structure in which one or more hydrogens are substituted with deuterium.

21. The polycyclic compound of claim 17, wherein at least one selected from among R₁₄ to R₁₉ is represented by any one selected from among Formulas A1 to A5, and the remainder are each independently hydrogen or deuterium:

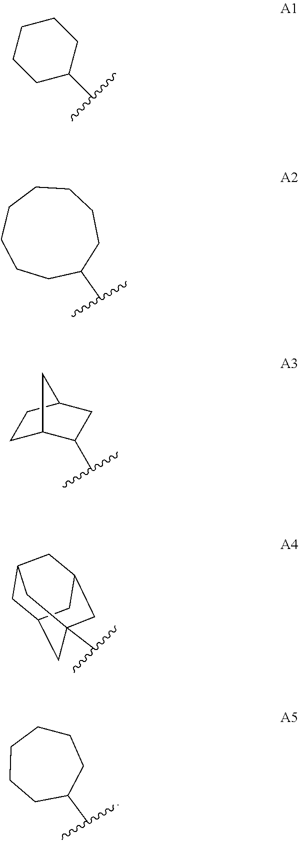 [SMILES: *C1CCCCC1 ; *C1CCCCCCCC1 ; *C1CC2CCC1C2 ; *C12CC3CC(CC(C3)C1)C2 ; *C1CCCCCC1]

22. The polycyclic compound of claim 17, wherein Rₐ to R_{d} are each independently hydrogen, an unsubstituted methyl group, or an unsubstituted phenyl group.

23. The polycyclic compound of claim 17, wherein the polycyclic compound represented by Formula 1 is represented by any one selected from among compounds of Compound Group 1:
Compound Group 1 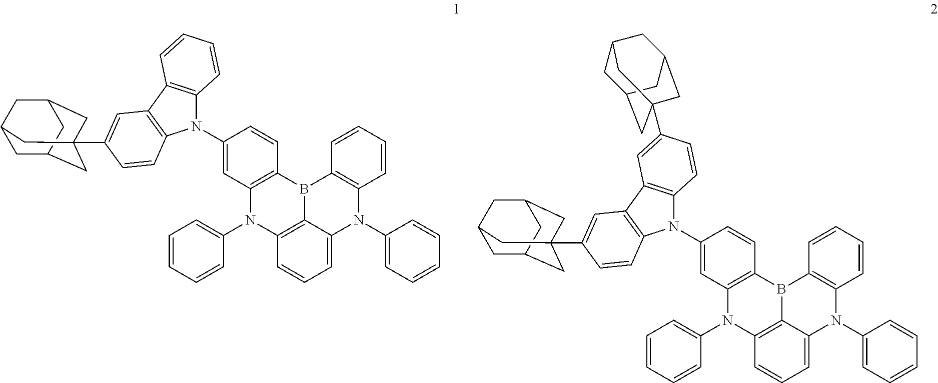 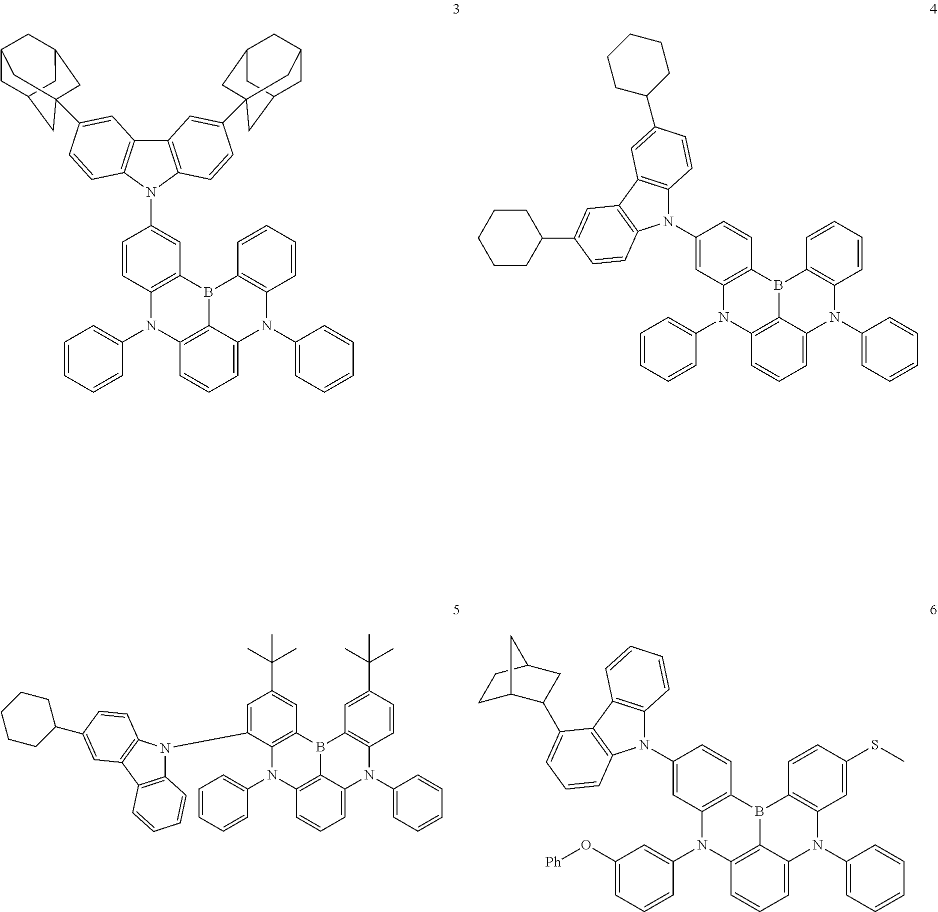 [SMILES: c1ccc(N2c3ccccc3B3c4cc(-n5c6ccc(C78CC9CC(CC(C9)C7)C8)cc6c6cc(C78CC9CC(CC(C9)C7)C8)ccc65)ccc4N(c4ccccc4)c4cccc2c43)cc1 ; c1ccc(N2c3ccccc3B3c4ccc(-n5c6ccc(C7CCCCC7)cc6c6cc(C7CCCCC7)ccc65)cc4N(c4ccccc4)c4cccc2c43)cc1 ; CC(C)(C)c1ccc2c(c1)B1c3cc(C(C)(C)C)cc(-n4c5ccccc5c5cc(C6CCCCC6)ccc54)c3N(c3ccccc3)c3cccc(c31)N2c1ccccc1 ; CSc1ccc2c(c1)N(c1ccccc1)c1cccc3c1B2c1ccc(-n2c4ccccc4c4c(C5CC6CCC5C6)cccc42)cc1N3c1cccc(Oc2ccccc2)c1] 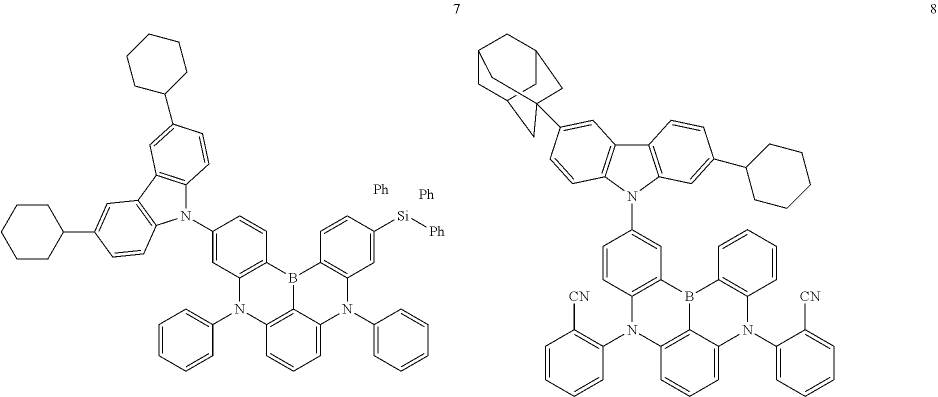 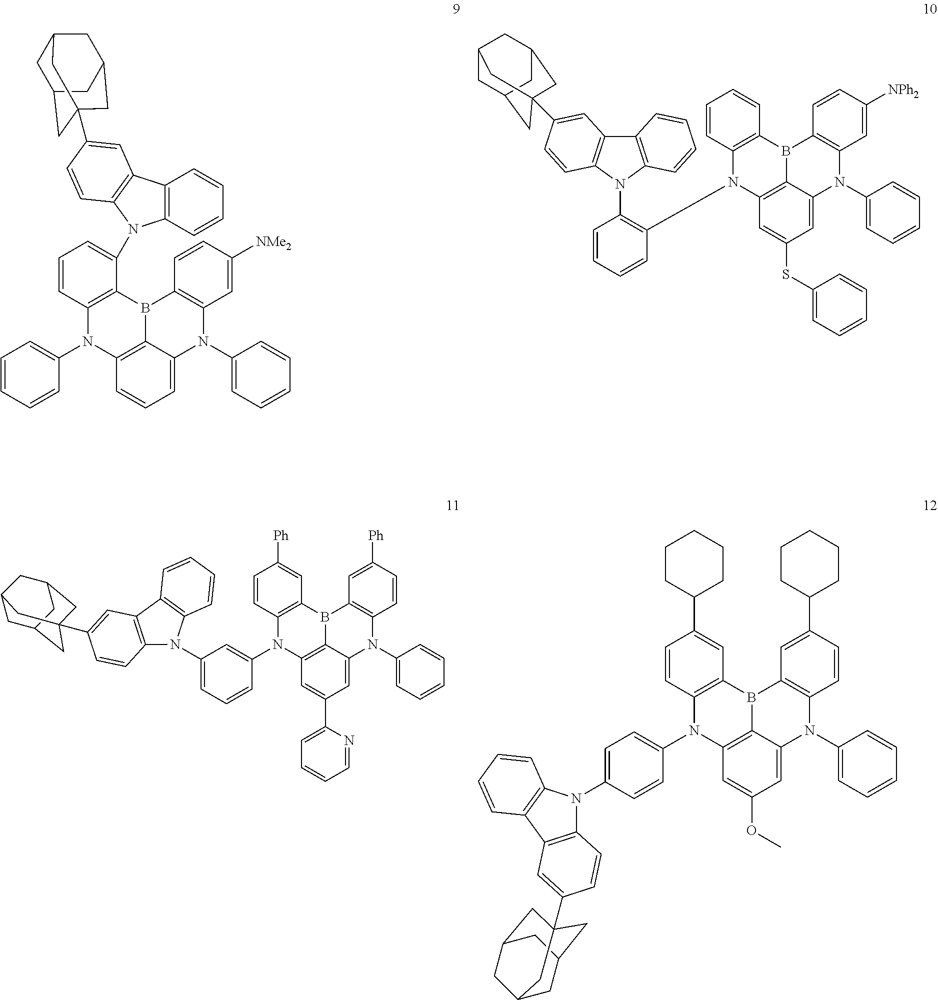 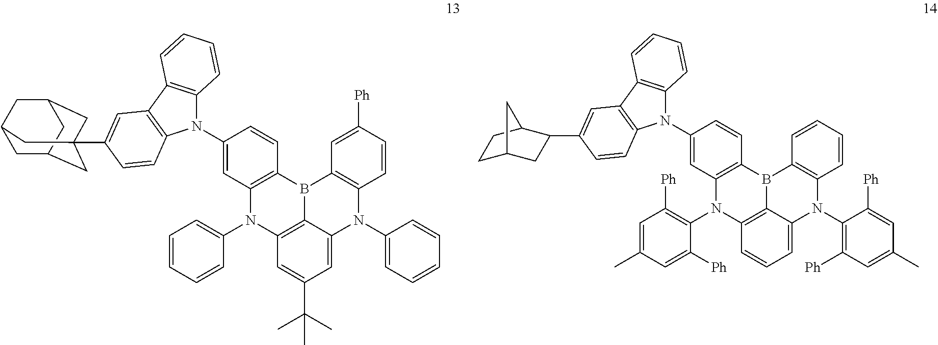 [SMILES: CC(C)(C)c1cc2c3c(c1)N(c1ccccc1)c1cc(-n4c5ccccc5c5cc(C67CC8CC(CC(C8)C6)C7)ccc54)ccc1B3c1cc(-c3ccccc3)ccc1N2c1ccccc1 ; Cc1cc(-c2ccccc2)c(N2c3ccccc3B3c4ccc(-n5c6ccccc6c6cc(C7CC8CCC7C8)ccc65)cc4N(c4c(-c5ccccc5)cc(C)cc4-c4ccccc4)c4cccc2c43)c(-c2ccccc2)c1] 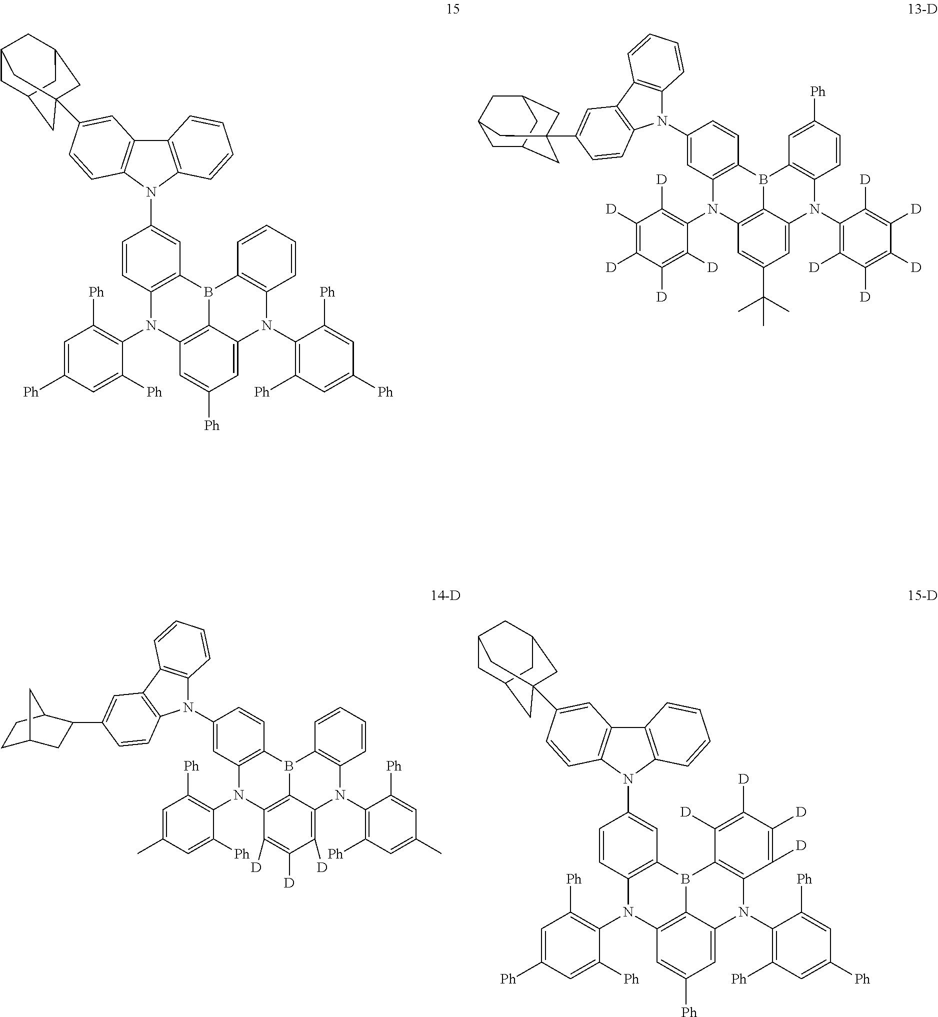 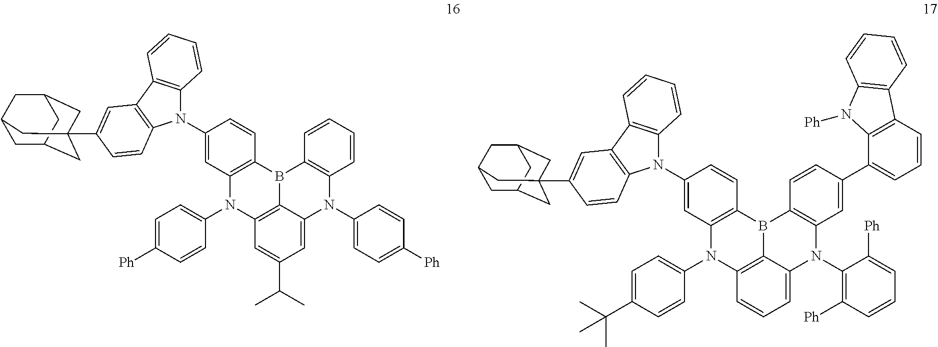 [SMILES: CC(C)c1cc2c3c(c1)N(c1ccc(-c4ccccc4)cc1)c1cc(-n4c5ccccc5c5cc(C67CC8CC(CC(C8)C6)C7)ccc54)ccc1B3c1ccccc1N2c1ccc(-c2ccccc2)cc1 ; CC(C)(C)c1ccc(N2c3cc(-n4c5ccccc5c5cc(C67CC8CC(CC(C8)C6)C7)ccc54)ccc3B3c4ccc(-c5cccc6c7ccccc7n(-c7ccccc7)c56)cc4N(c4c(-c5ccccc5)cccc4-c4ccccc4)c4cccc2c43)cc1] 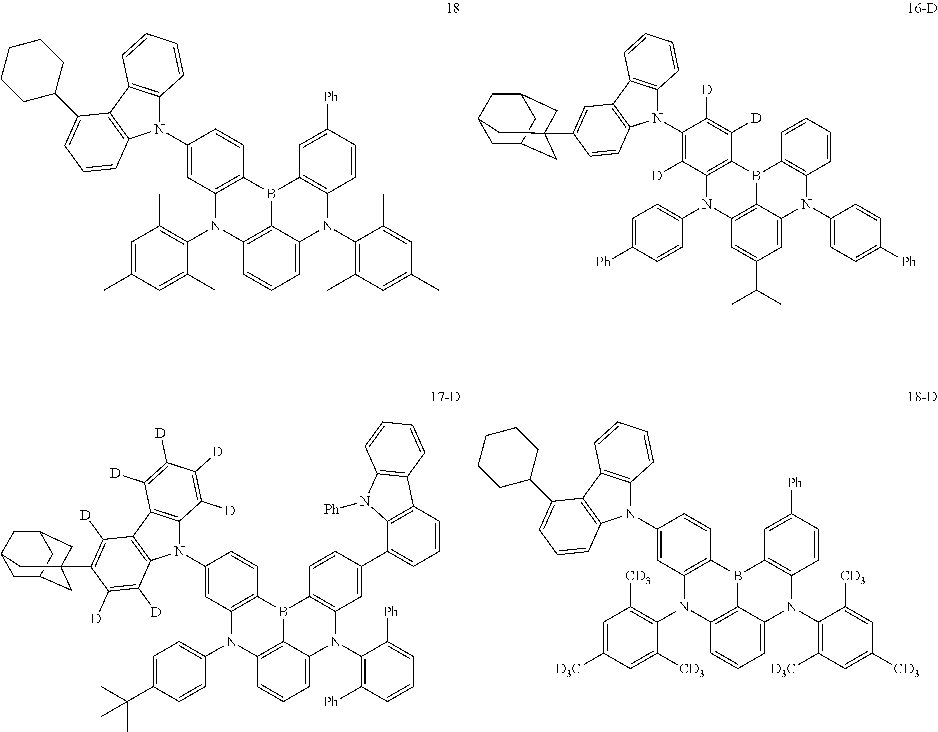 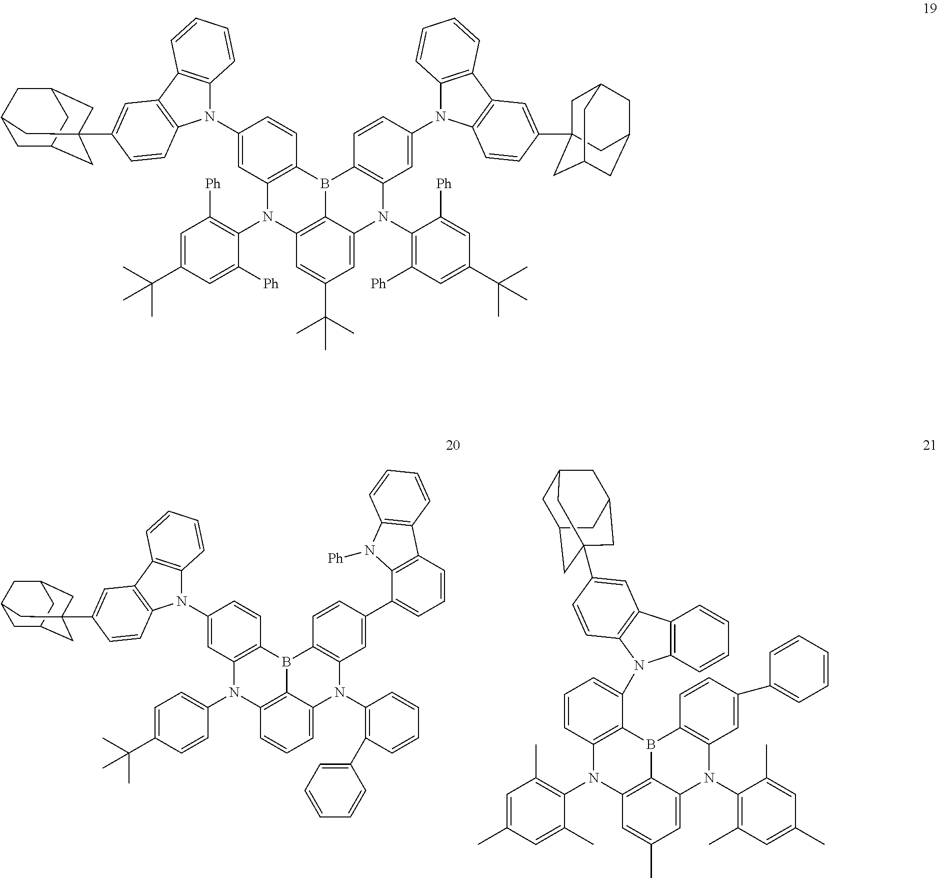 [SMILES: CC(C)(C)c1cc(-c2ccccc2)c(N2c3cc(-n4c5ccccc5c5cc(C67CC8CC(CC(C8)C6)C7)ccc54)ccc3B3c4ccc(-n5c6ccccc6c6cc(C78CC9CC(CC(C9)C7)C8)ccc65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1ccc(N2c3cc(-n4c5ccccc5c5cc(C67CC8CC(CC(C8)C6)C7)ccc54)ccc3B3c4ccc(-c5cccc6c7ccccc7n(-c7ccccc7)c56)cc4N(c4ccccc4-c4ccccc4)c4cccc2c43)cc1 ; Cc1cc(C)c(N2c3cc(-c4ccccc4)ccc3B3c4c2cc(C)cc4N(c2c(C)cc(C)cc2C)c2cccc(-n4c5ccccc5c5cc(C67CC8CC(CC(C8)C6)C7)ccc54)c23)c(C)c1] 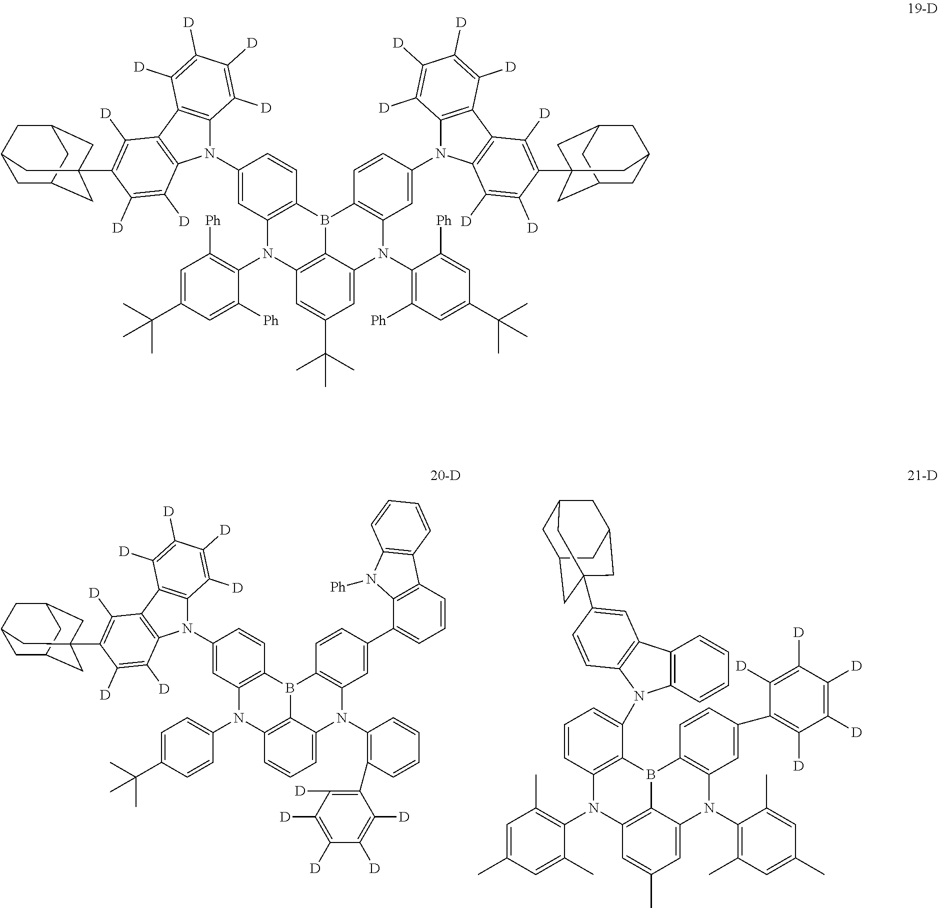 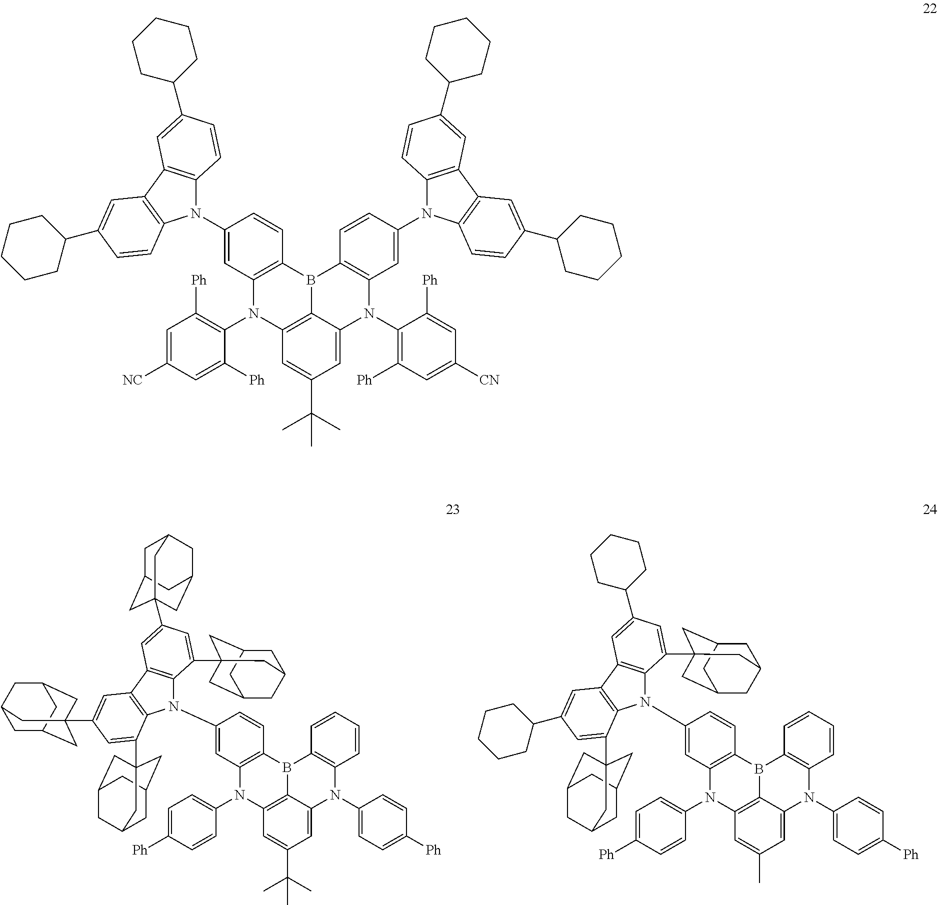 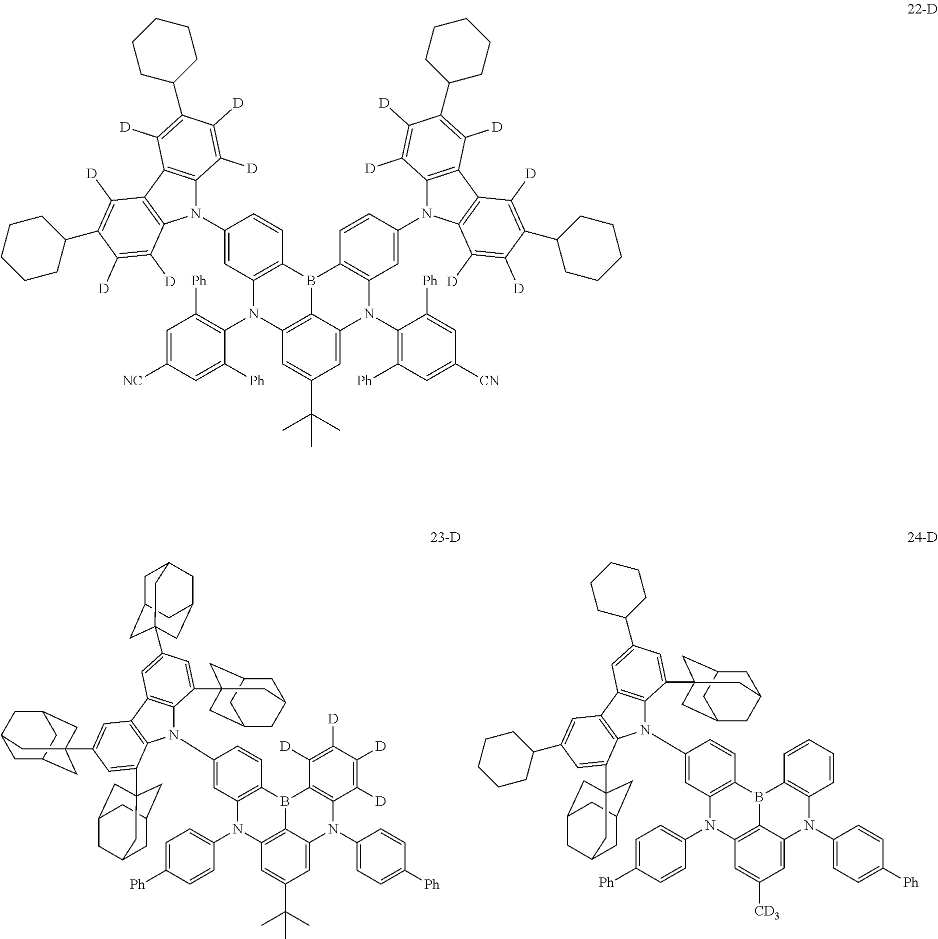 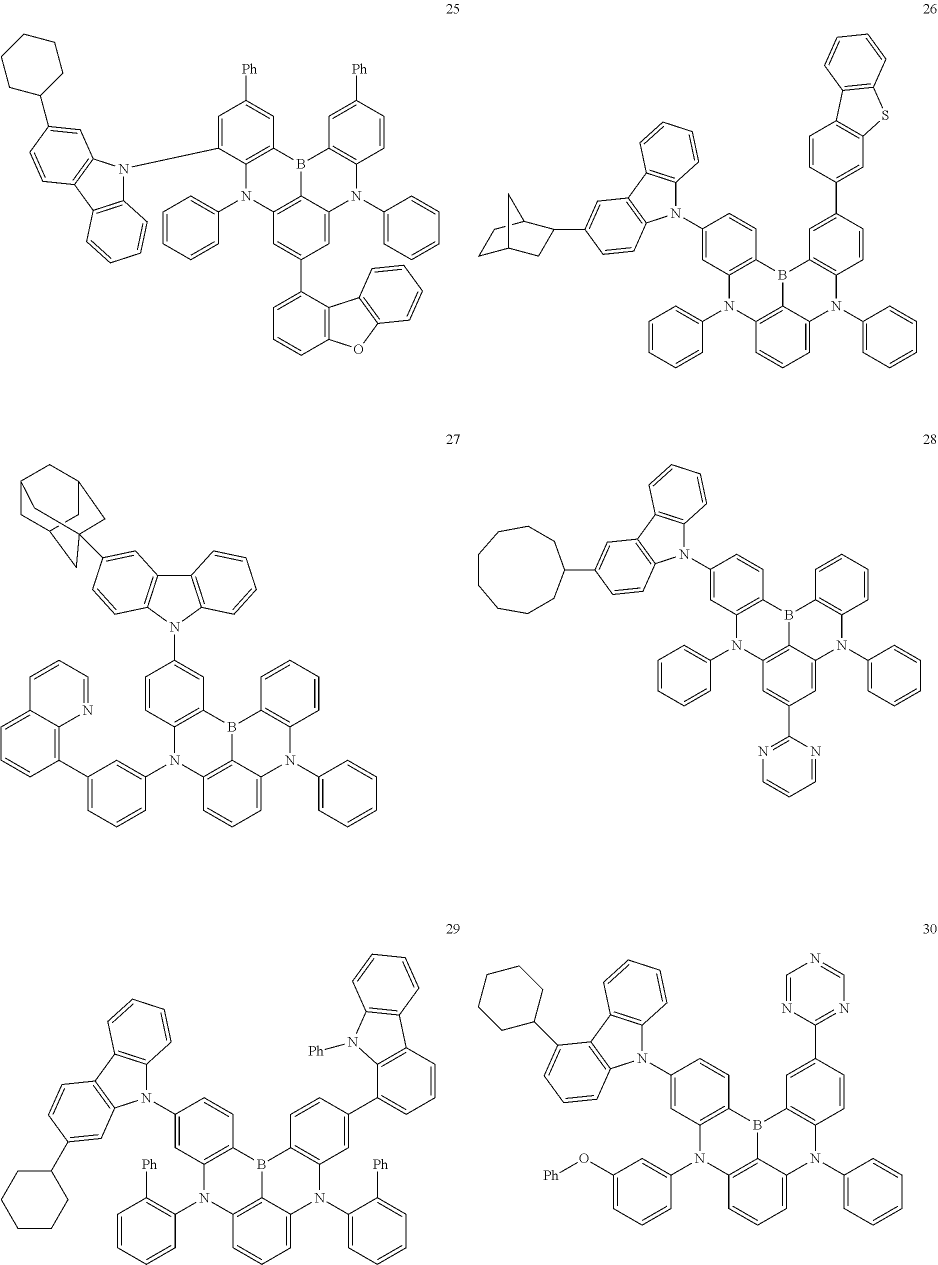 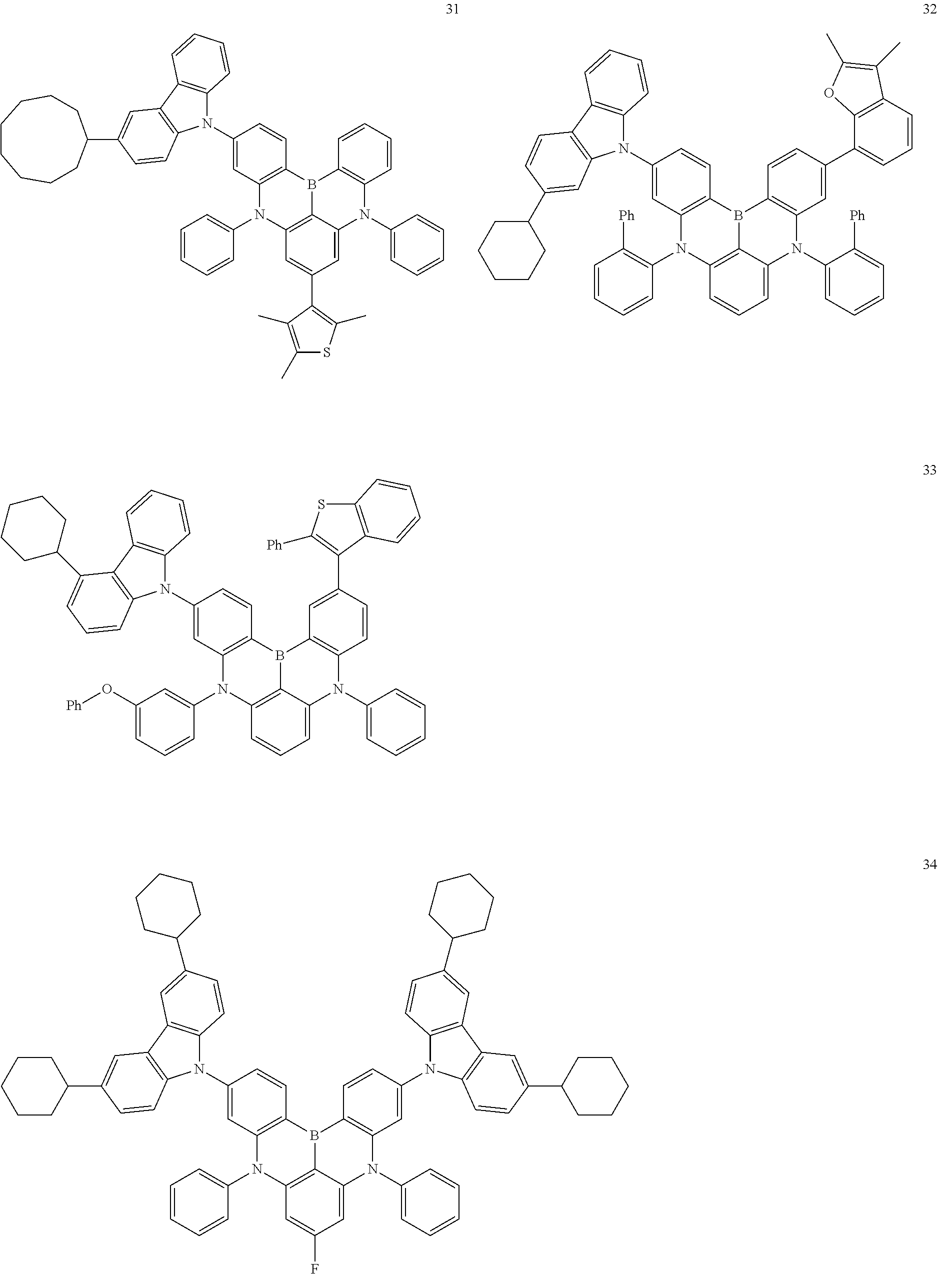 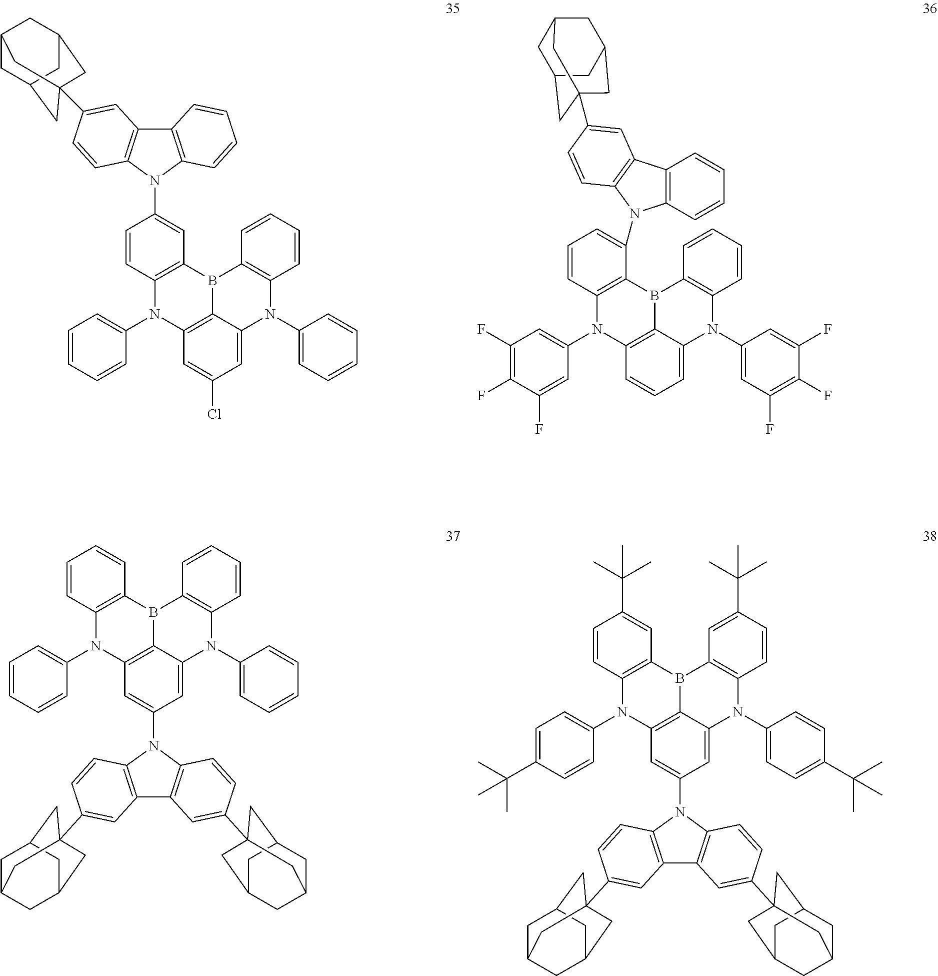 [SMILES: Clc1cc2c3c(c1)N(c1ccccc1)c1ccc(-n4c5ccccc5c5cc(C67CC8CC(CC(C8)C6)C7)ccc54)cc1B3c1ccccc1N2c1ccccc1 ; Fc1cc(N2c3ccccc3B3c4c2cccc4N(c2cc(F)c(F)c(F)c2)c2cccc(-n4c5ccccc5c5cc(C67CC8CC(CC(C8)C6)C7)ccc54)c23)cc(F)c1F ; c1ccc(N2c3ccccc3B3c4ccccc4N(c4ccccc4)c4cc(-n5c6ccc(C78CC9CC(CC(C9)C7)C8)cc6c6cc(C78CC9CC(CC(C9)C7)C8)ccc65)cc2c43)cc1 ; CC(C)(C)c1ccc(N2c3ccc(C(C)(C)C)cc3B3c4cc(C(C)(C)C)ccc4N(c4ccc(C(C)(C)C)cc4)c4cc(-n5c6ccc(C78CC9CC(CC(C9)C7)C8)cc6c6cc(C78CC9CC(CC(C9)C7)C8)ccc65)cc2c43)cc1] 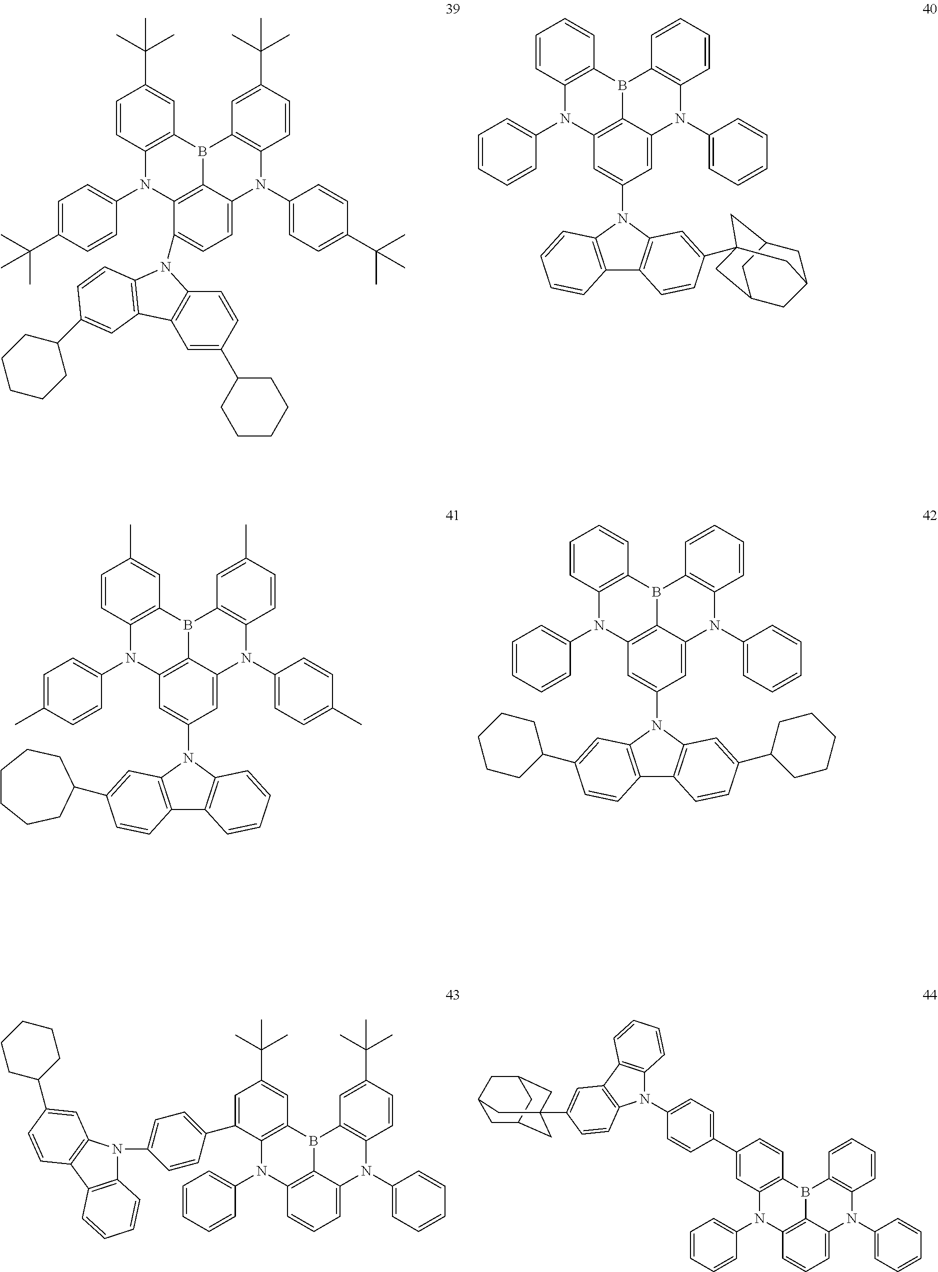 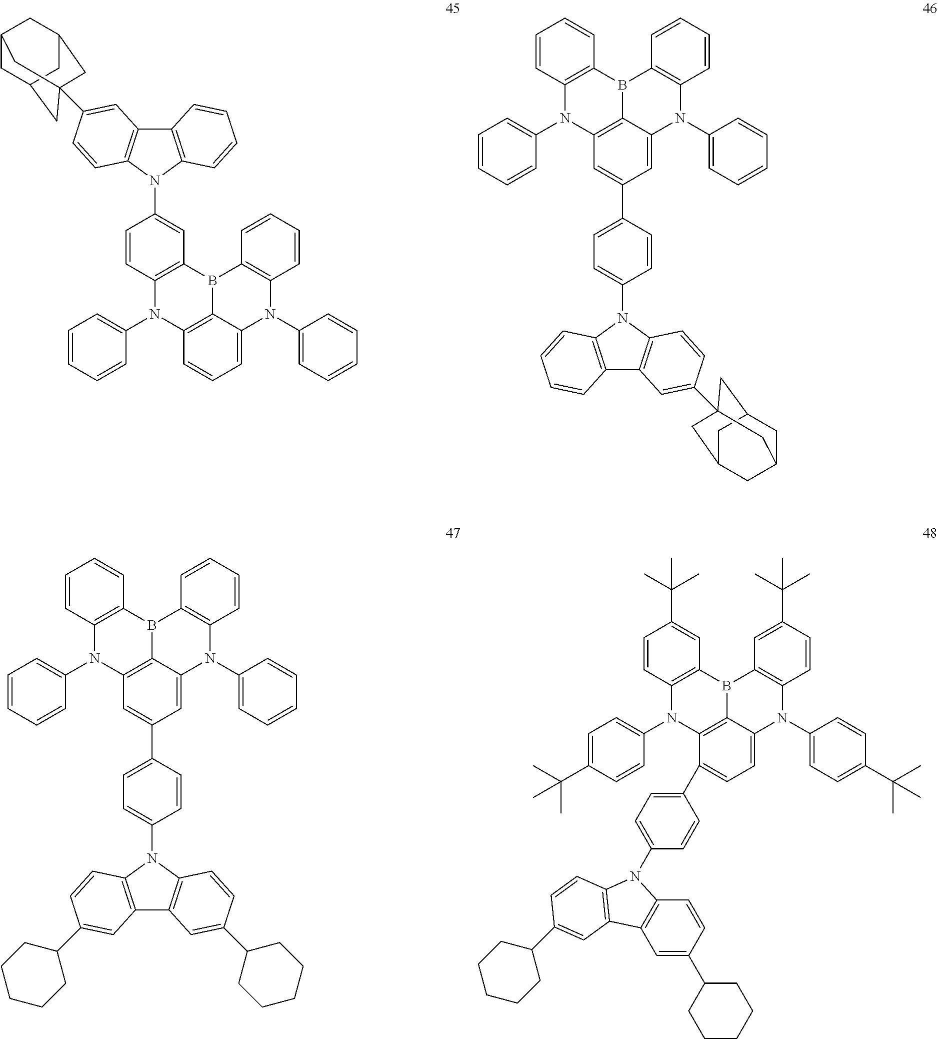 [SMILES: c1ccc(N2c3ccccc3B3c4cc(-n5c6ccccc6c6cc(C78CC9CC(CC(C9)C7)C8)ccc65)ccc4N(c4ccccc4)c4cccc2c43)cc1 ; c1ccc(N2c3ccccc3B3c4ccccc4N(c4ccccc4)c4cc(-c5ccc(-n6c7ccccc7c7cc(C89CC%10CC(CC(C%10)C8)C9)ccc76)cc5)cc2c43)cc1 ; c1ccc(N2c3ccccc3B3c4ccccc4N(c4ccccc4)c4cc(-c5ccc(-n6c7ccc(C8CCCCC8)cc7c7cc(C8CCCCC8)ccc76)cc5)cc2c43)cc1 ; CC(C)(C)c1ccc(N2c3ccc(C(C)(C)C)cc3B3c4cc(C(C)(C)C)ccc4N(c4ccc(C(C)(C)C)cc4)c4c(-c5ccc(-n6c7ccc(C8CCCCC8)cc7c7cc(C8CCCCC8)ccc76)cc5)ccc2c43)cc1] 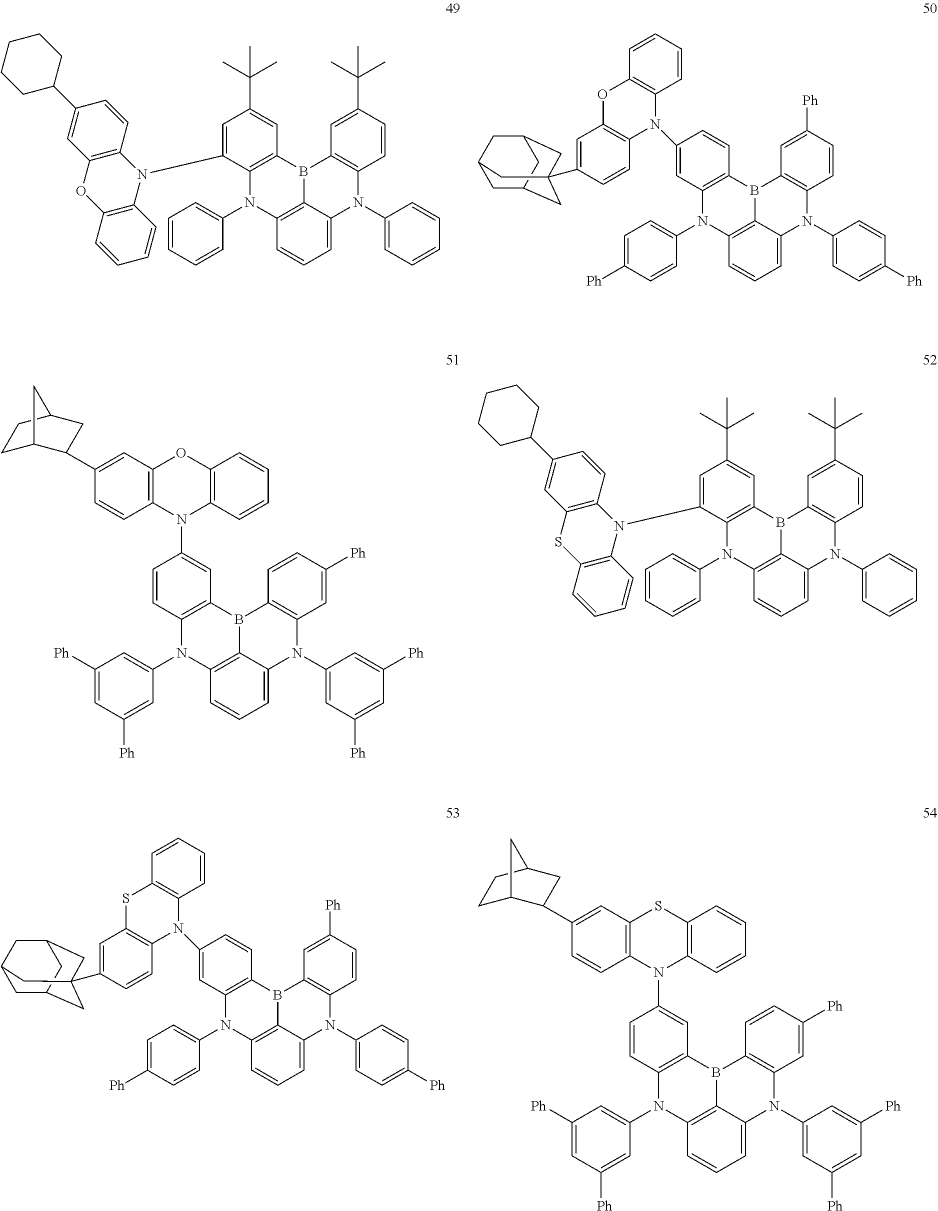 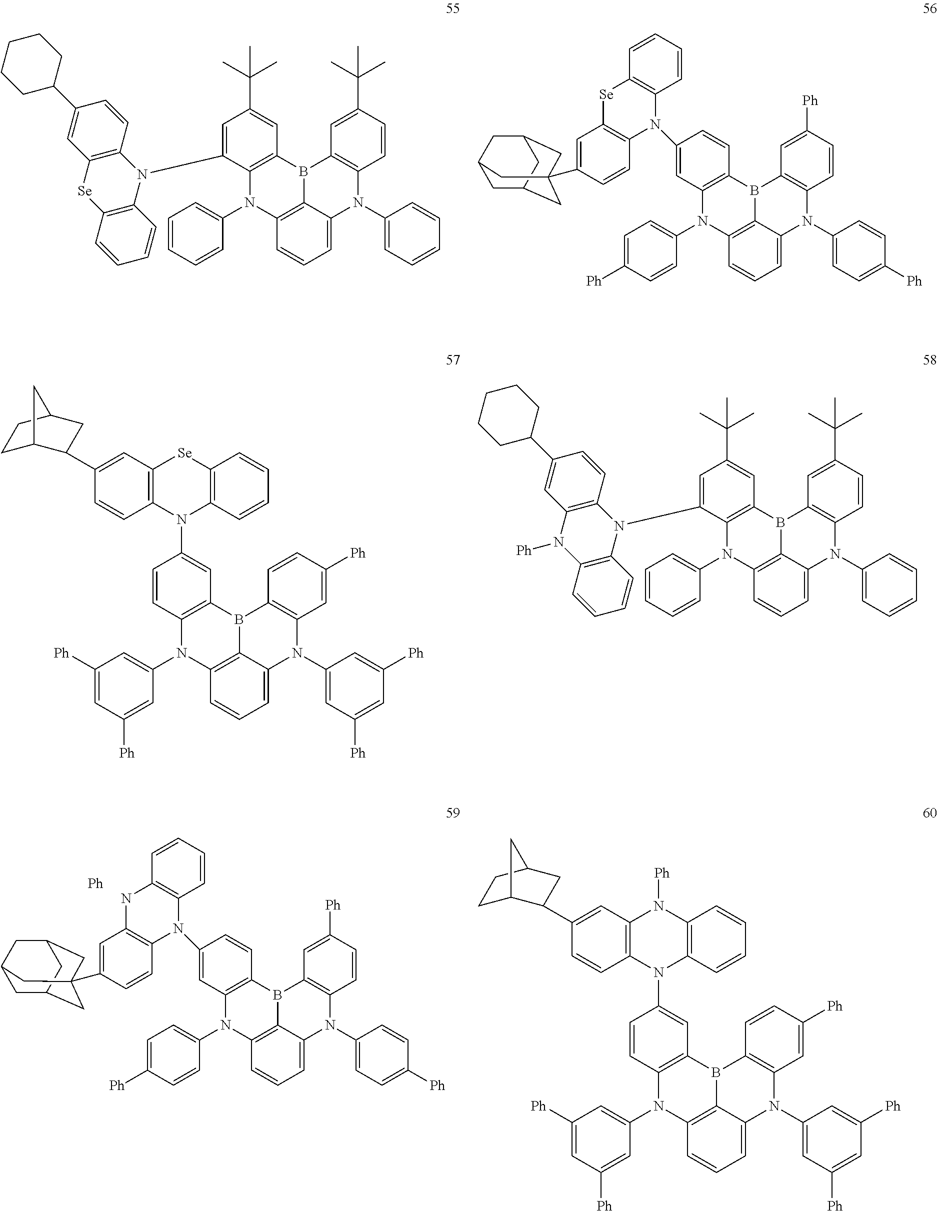 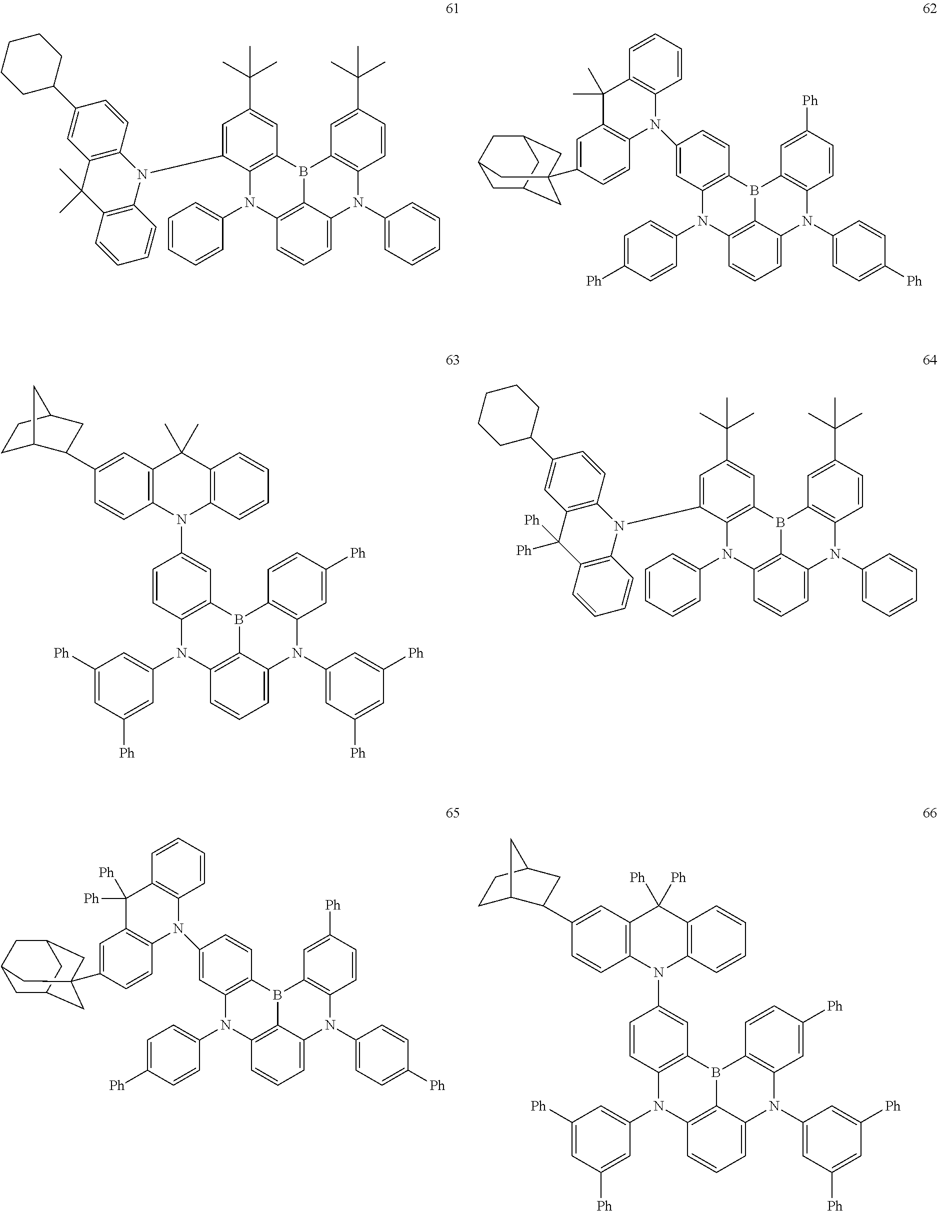 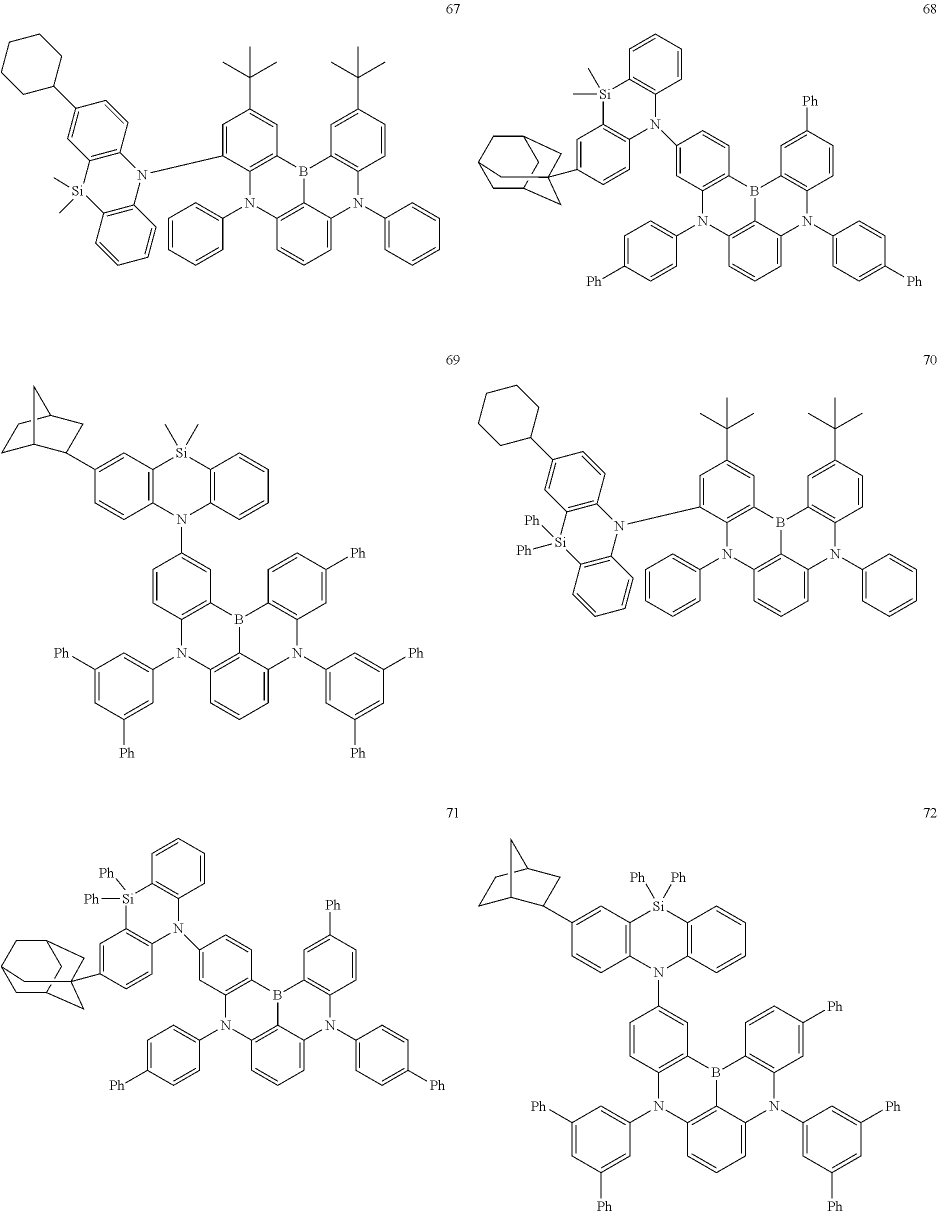 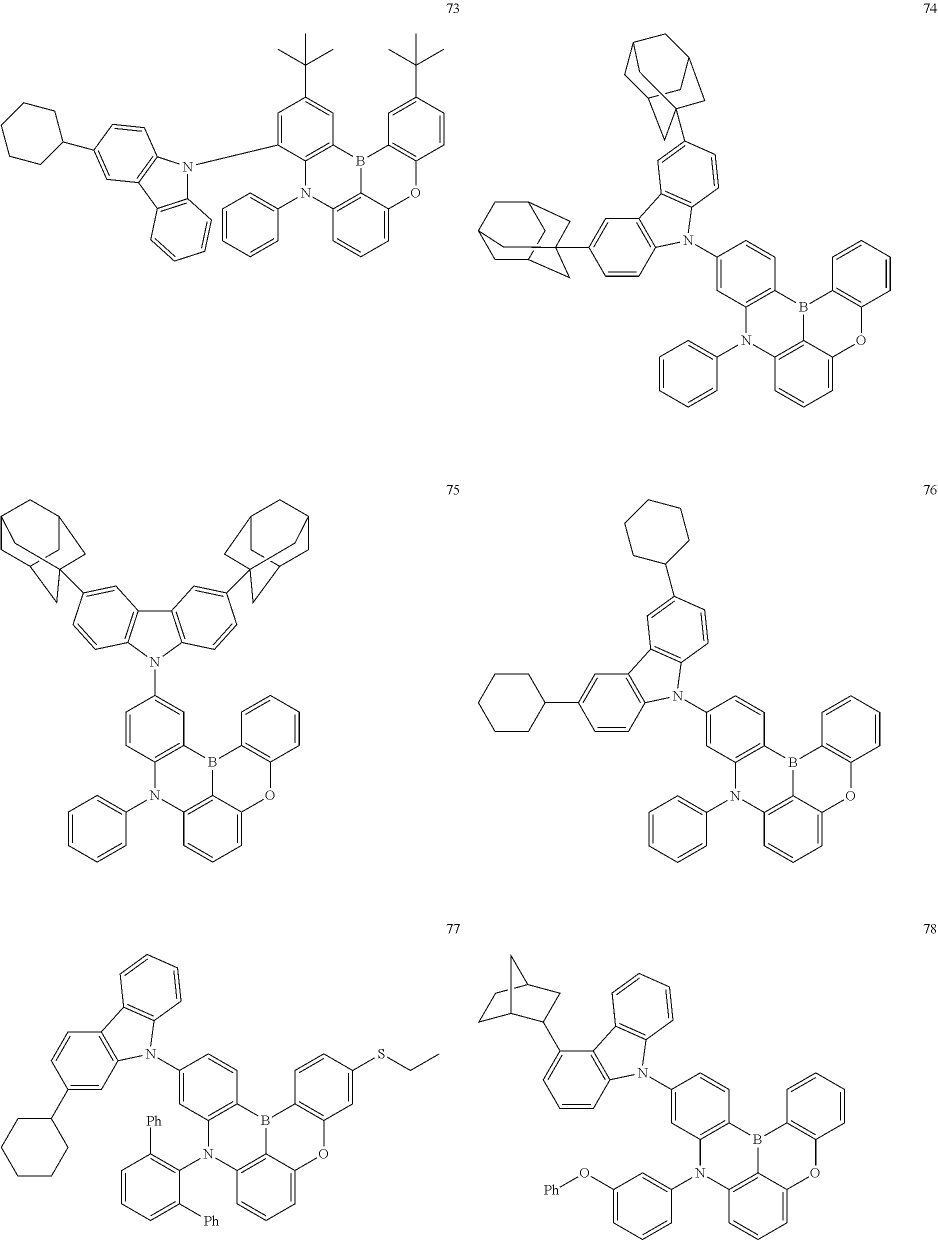 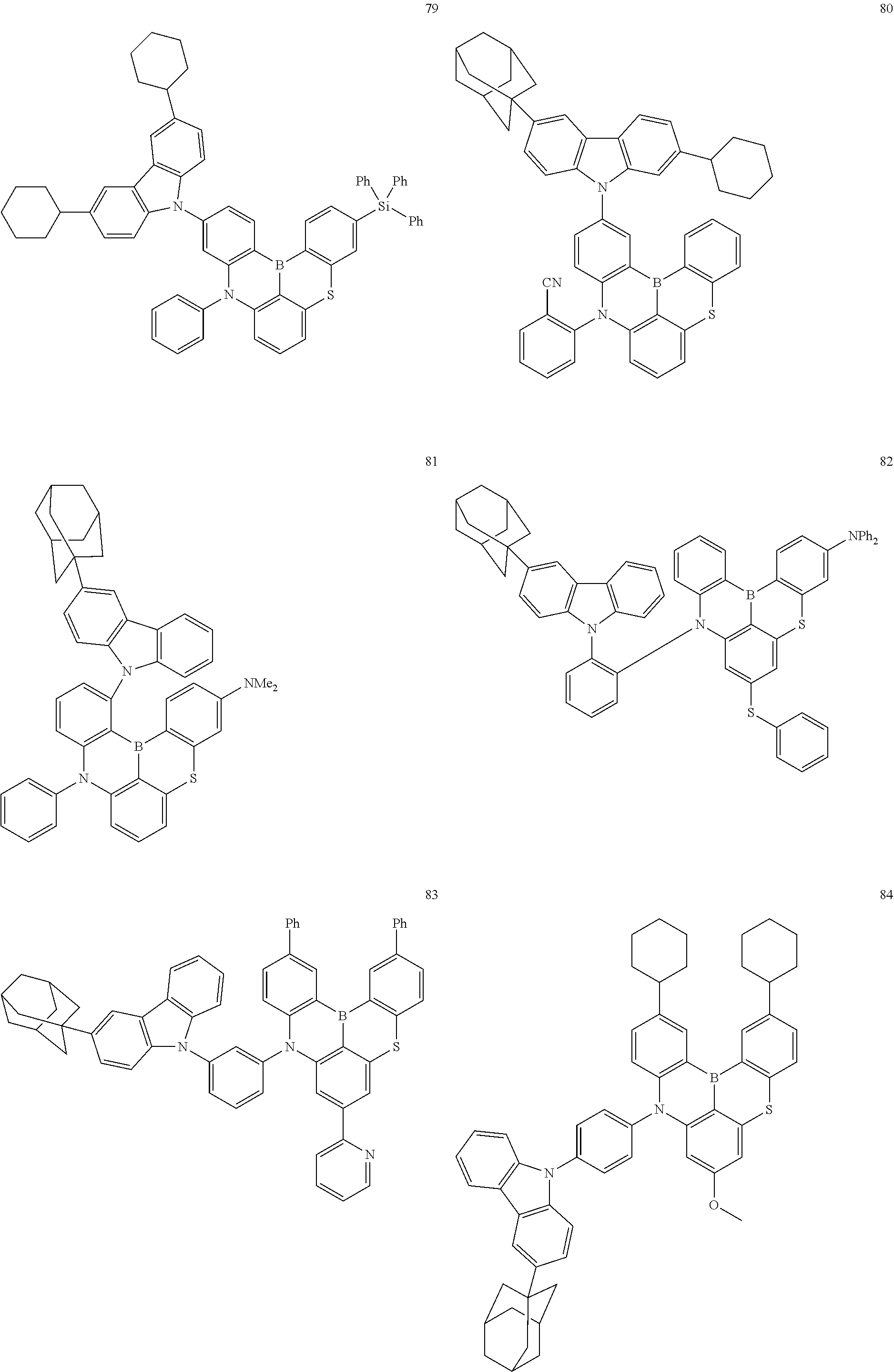 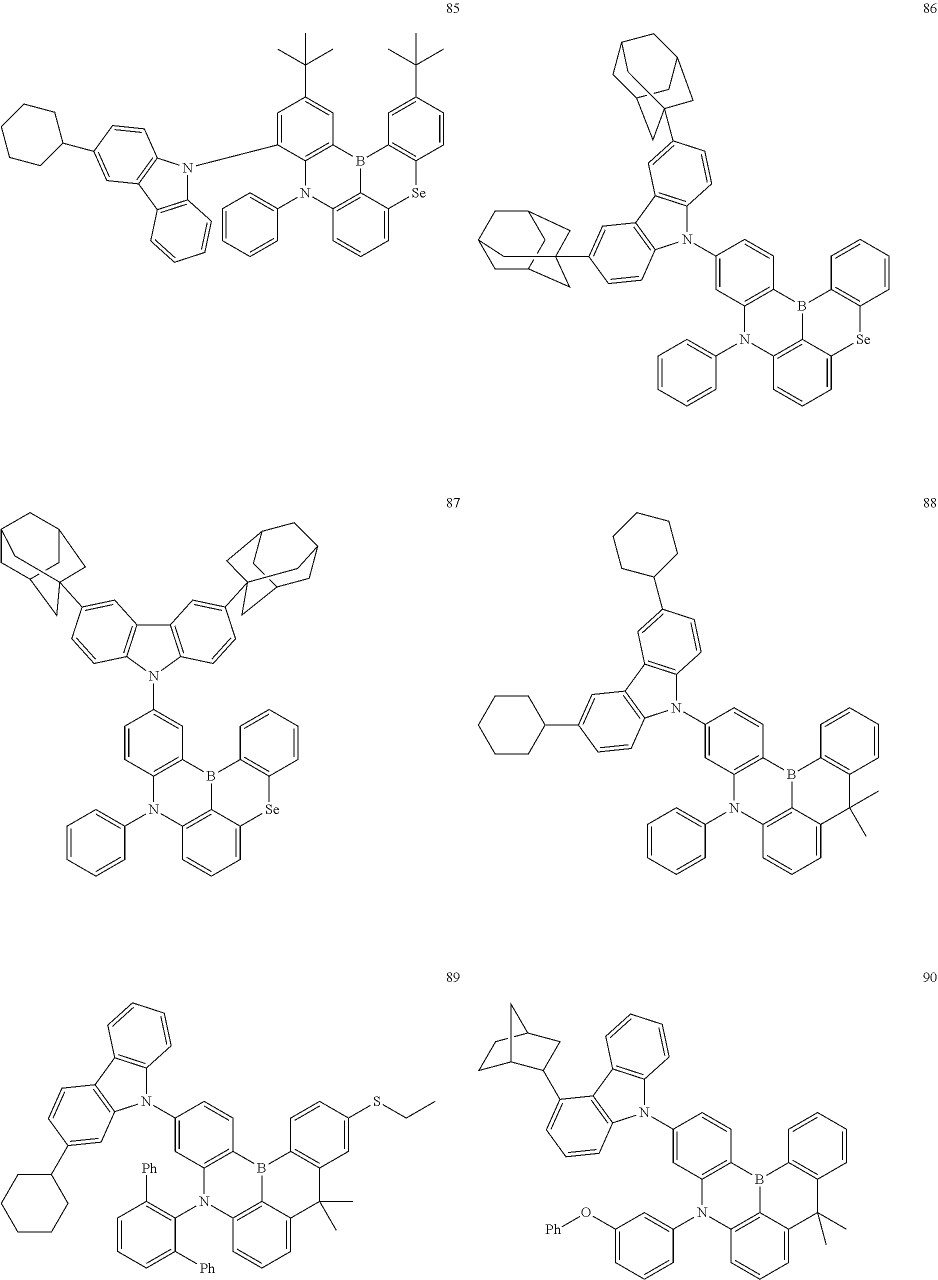 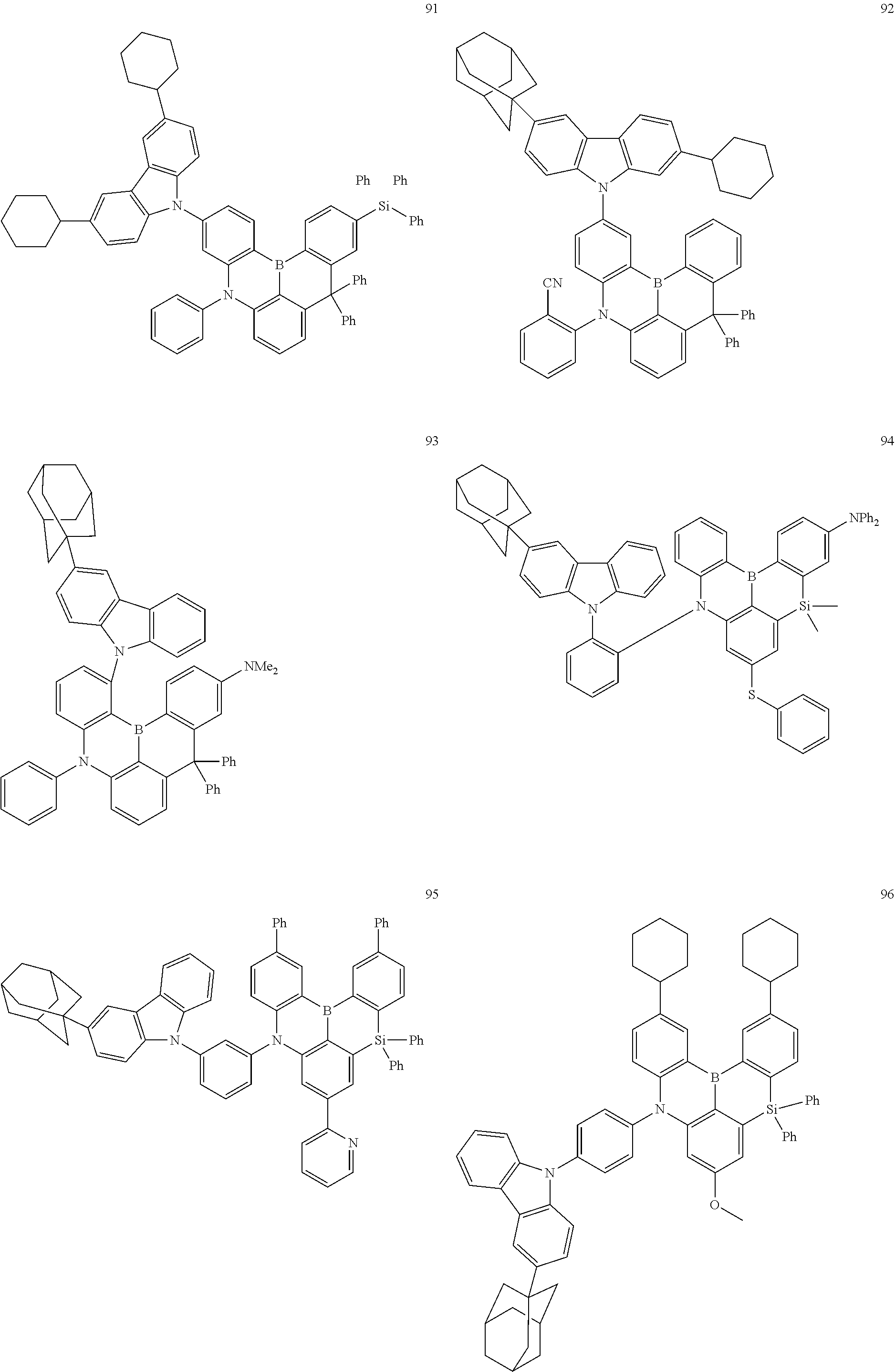 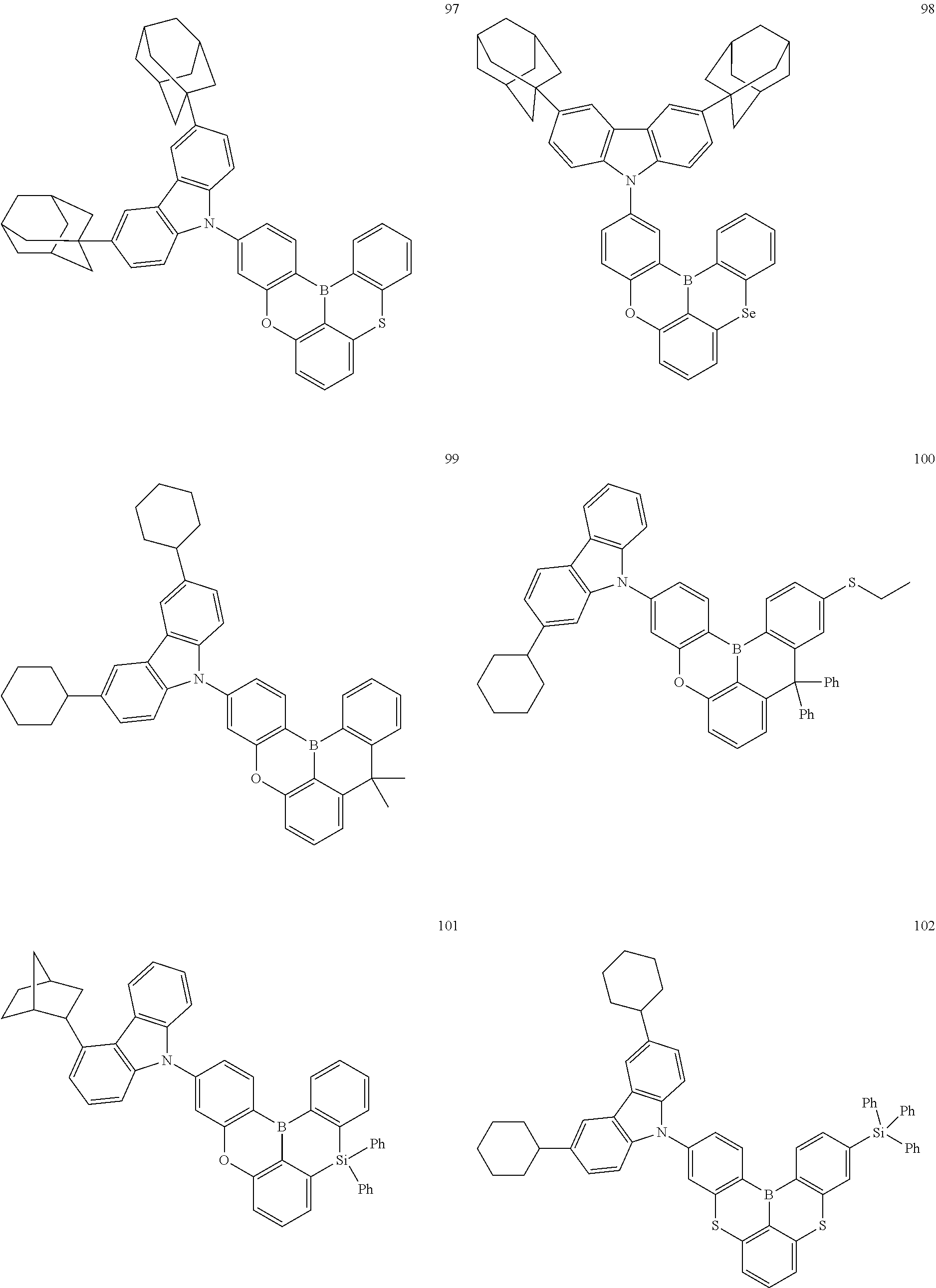 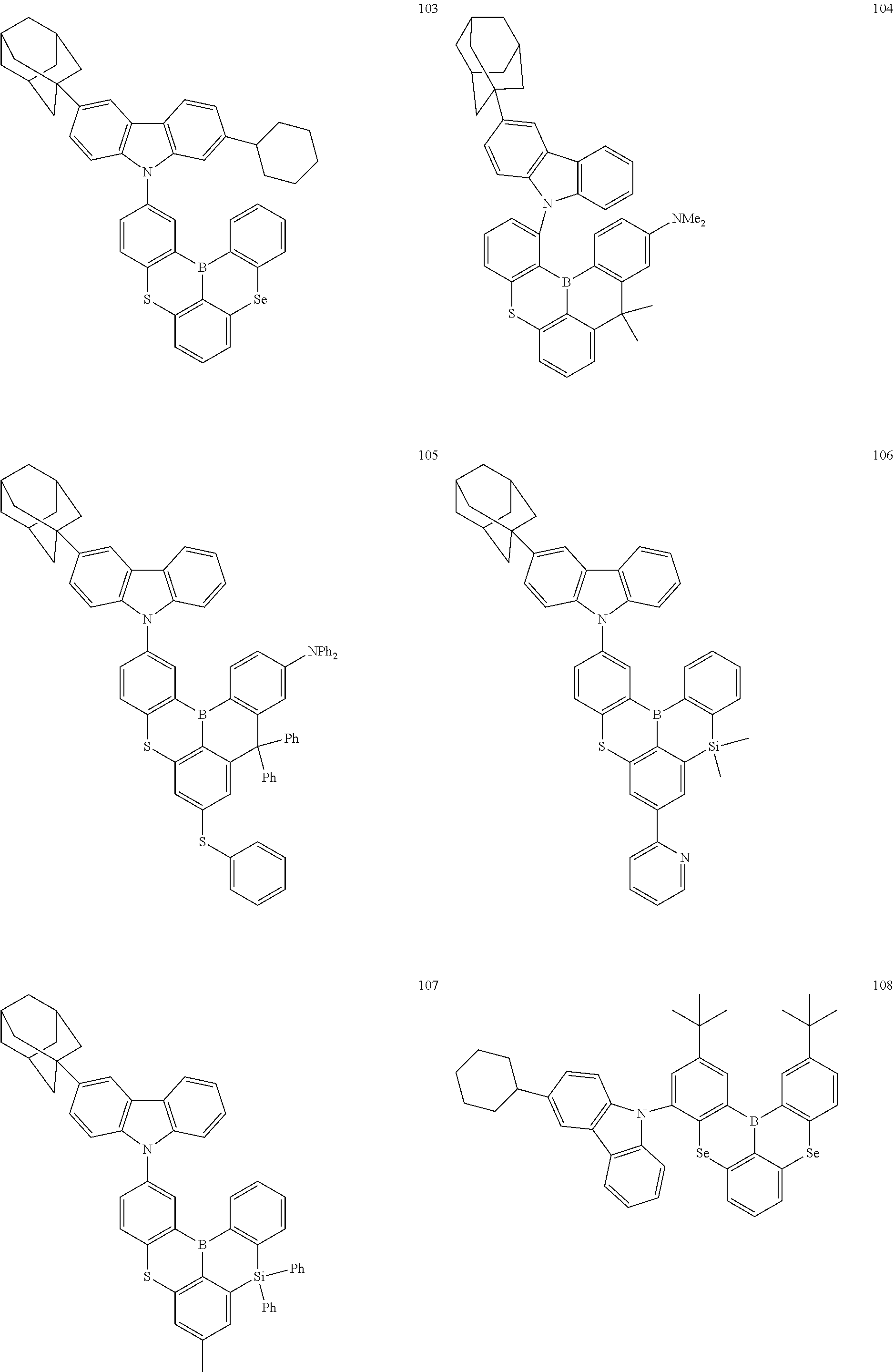 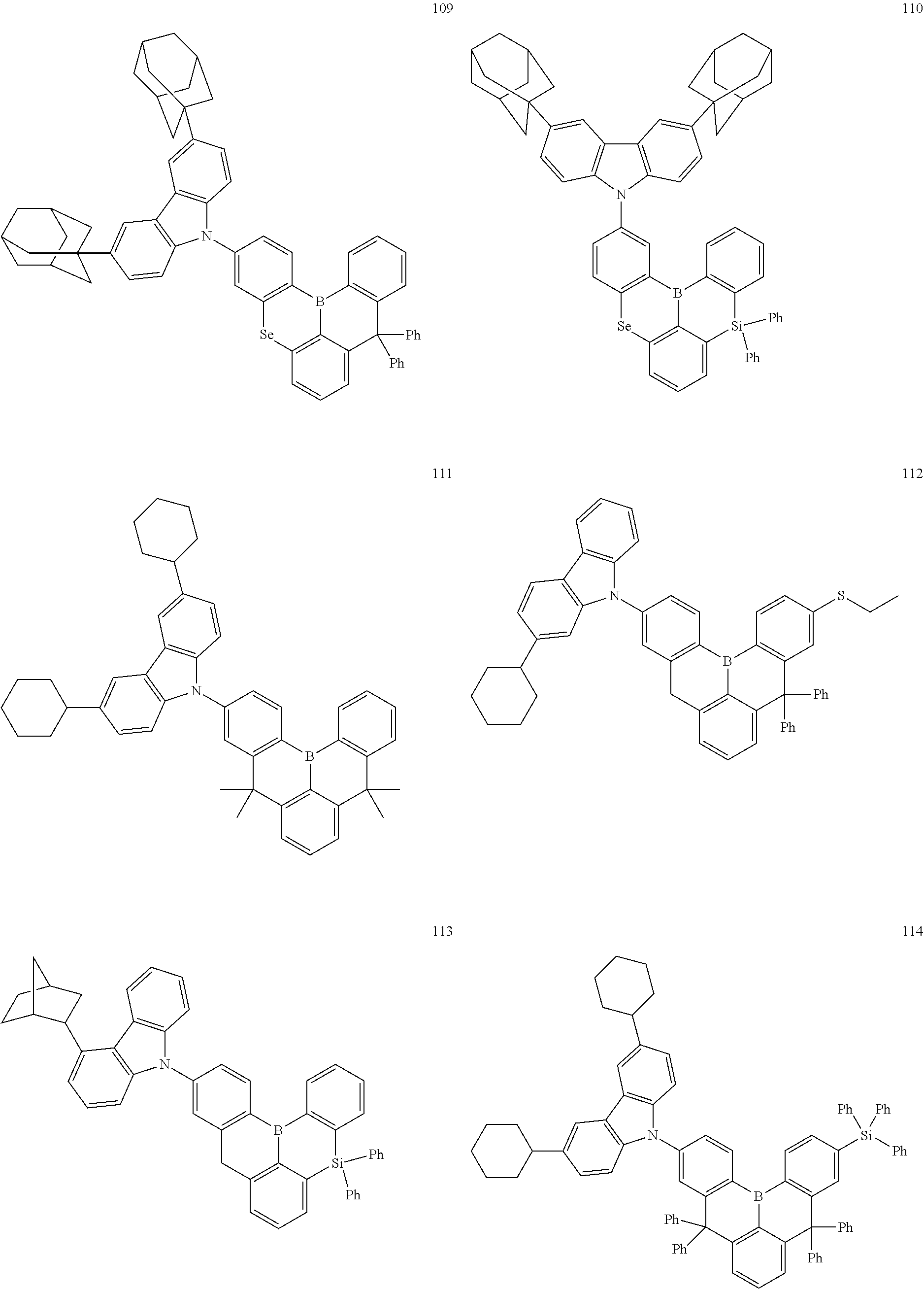 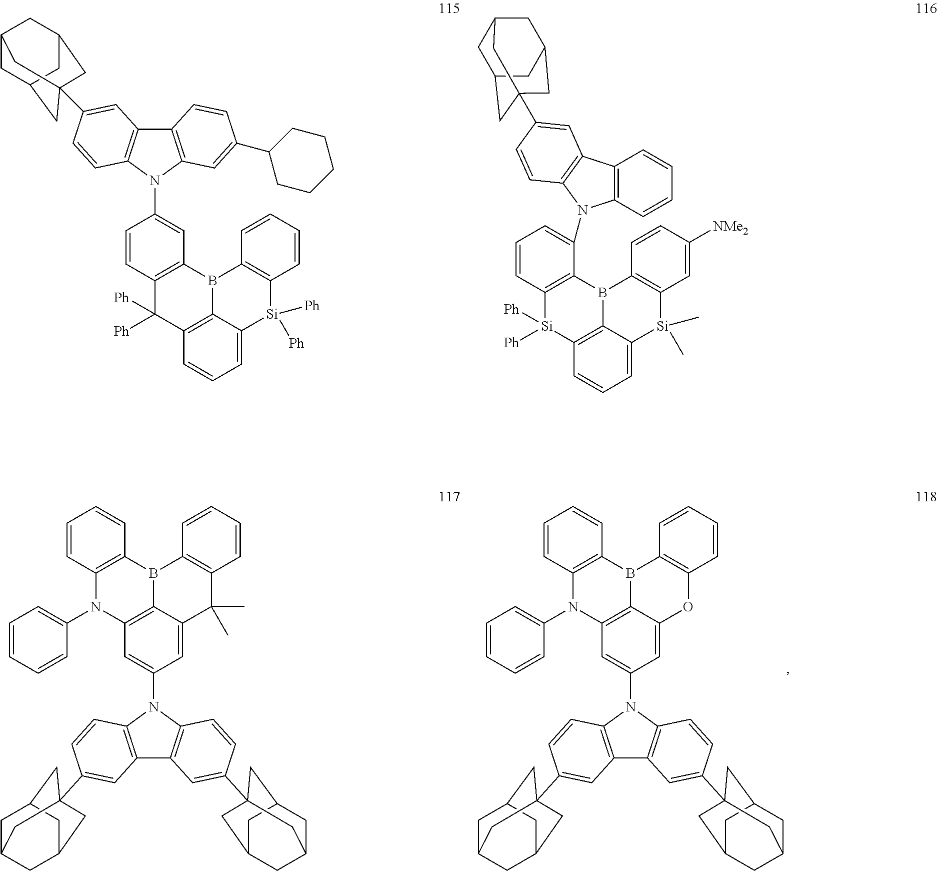 [SMILES: c1ccc(C2(c3ccccc3)c3ccc(-n4c5ccc(C67CC8CC(CC(C8)C6)C7)cc5c5ccc(C6CCCCC6)cc54)cc3B3c4ccccc4[Si](c4ccccc4)(c4ccccc4)c4cccc2c43)cc1 ; CN(C)c1ccc2c(c1)[Si](C)(C)c1cccc3c1B2c1c(-n2c4ccccc4c4cc(C56CC7CC(CC(C7)C5)C6)ccc42)cccc1[Si]3(c1ccccc1)c1ccccc1 ; CC1(C)c2ccccc2B2c3ccccc3N(c3ccccc3)c3cc(-n4c5ccc(C67CC8CC(CC(C8)C6)C7)cc5c5cc(C67CC8CC(CC(C8)C6)C7)ccc54)cc1c32 ; c1ccc(N2c3ccccc3B3c4ccccc4Oc4cc(-n5c6ccc(C78CC9CC(CC(C9)C7)C8)cc6c6cc(C78CC9CC(CC(C9)C7)C8)ccc65)cc2c43)cc1]
and
wherein in Compound Group 1, “D” is a deuterium atom, “Ph” is an unsubstituted phenyl group, and “Me” is an unsubstituted methyl group.
